(19) United States
(12) Patent Application Publication
(10) Pub. No.: US 2021/0126036 A1
(43) Pub. Date: Apr. 29, 2021

(54) CIRCUIT BOARD, SEMICONDUCTOR DEVICE, AND ELECTRONIC DEVICE

(71) Applicant: SONY SEMICONDUCTOR SOLUTIONS CORPORATION, KANAGAWA (JP)

(72) Inventors: AKIRA ARAHATA, KANAGAWA, (JP); TAKASHI MIYAMOTO, KANAGAWA, (JP)

(21) Appl. No.: 17/250,270

(22) PCT Filed: Jun. 11, 2019
(86) PCT No.: PCT/JP2019/023106

§ 371 Date: Dec. 23, 2020

(30) Foreign Application Priority Data
Jun. 25, 2018 (JP) 2018-120132

(51) Int. Cl. H01L 27/146; H05K 1/02; H04N 5/3745; H04N 5/357

(52) U.S. Cl. CPC H01L 27/14636; H05K 1/0216; H04N 5/357; H04N 5/3745; H01L 27/14623

(57) ABSTRACT

The present technology relates to a circuit board, a semiconductor device, and an electronic device that can more effectively curb occurrence of noise in a signal. A circuit board includes a first conductor layer having at least a first conductor portion including a conductor having a shape in which a first basic pattern having a planar or mesh shape is repeated on a single plane, a second conductor layer having at least a second conductor portion including a conductor having a shape in which a second basic pattern having a planar or mesh shape is repeated on a single plane, and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, and the first basic pattern and the second basic pattern form a differential structure, and the third basic pattern and the fourth basic pattern form a differential structure. The present technology can be applied to, for example, a circuit board of a semiconductor device.

### TECHNICAL FIELD

The present technology relates to a circuit board, a semiconductor device, and an electronic device, and more particularly, to a circuit board, a semiconductor device, and an electronic device capable of curbing occurrence of noise in a signal more effectively.

### BACKGROUND ART

In a solid-state imaging device represented by a CMOS (complementary metal oxide semiconductor) image sensor, noise may occur in a pixel signal generated by each pixel due to an internal configuration of the solid-state imaging device.

For example, some active elements such as transistors or diodes present inside a solid-state imaging device generate minute amounts of hot carrier light, and when this emitted hot carrier light leaks into a photoelectric conversion unit formed in a pixel, noise occurs in a pixel signal.

As a method of curbing the noise caused by the hot carrier light generated from the active element, a technology for causing a wiring formed between an active element and a photoelectric conversion unit to have a light shielding structure is known (see PTL 1, for example).

Further, for example, noise (inductive noise) may occur in a pixel signal due to an induced electromotive force caused by a magnetic field generated due to an internal configuration of a solid-state imaging device. Specifically, a conductor loop including a control line to which a control signal for selecting a pixel from which a pixel signal is read out is transferred when the pixel signal is read out from a certain pixel, and a signal line to which the pixel signal read out from the selected pixel is transferred is formed on the pixel array.

When there is a wiring near the conductor loop including the control line and the signal line, a magnetic flux passing through the conductor loop may be generated due to change in the current flowing through the wiring and thus, an induced electromotive force may be generated in the conductor loop and inductive noise may occur in the pixel signal. Hereinafter, a conductor loop in which a magnetic flux occurs due to change in a current flowing in the wiring near the conductor loop and thus an induced electromotive force occurs is referred to as a victim conductor loop.

A method of curbing inductive noise inside an electronic device includes a method of offsetting an occurring magnetic flux by forming a wiring causing a magnetic flux inside an electronic device as a two-layer mesh wiring (see PTL 2, for example).

### CITATION LIST

### Patent Literature

[PTL 1]

WO 2013/115075

[PTL 2]

JP 2014-57426A

### SUMMARY

### Technical Problem

However, in the invention described in PTL 2 described above, inductive noise can be curbed, but shielding the emitted hot carrier light is not considered.

The present technology has been made in view of such a situation, and is intended to be able to more effectively curb occurrence of noise in a signal.

### Solution to Problem

A circuit board according to a first aspect of the present technology includes a first conductor layer having at least a first conductor portion including a conductor having a shape in which a first basic pattern having a planar or mesh shape is repeated on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

A semiconductor device according to a second aspect of the present technology includes a circuit board, the circuit board including: a first conductor layer having at least a first conductor portion including a conductor having a shape in which a first basic pattern having a planar or mesh shape is repeated on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

An electronic device according to a third aspect of the present technology includes a semiconductor device including a circuit board, the circuit board including: a first conductor layer having at least a first conductor portion including a conductor having a shape in which a first basic pattern having a planar or mesh shape is repeated on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

In the first to third aspects of the present technology, the first conductor layer having at least the first conductor portion including a conductor having a shape a first basic pattern having a planar or mesh shape is repeated on a single plane, the second conductor layer having at least a second conductor portion including a conductor having a shape in which a second basic pattern having a planar or mesh shape is repeated on a single plane, and the third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane are provided, the first basic pattern and the second basic pattern form a differential structure, and the third basic pattern and the fourth basic pattern form a differential structure.

The circuit board, the semiconductor device, and the electronic device may be independent devices or may be modules incorporated in other devices.

### ADVANTAGEOUS OF INVENTION

According to the first to third aspects of the present technology, it is possible to curb occurrence of noise in a signal.

The effects described here are not necessarily limited and may be any effects described in the present disclosure.

### BRIEF DESCRIPTION OF DRAWINGS

FIG. 1 is a diagram illustrating change in induced electromotive force due to change in a conductor loop.

FIG. 2 is a block diagram illustrating a configuration example of a solid-state imaging device to which the present technology is applied.

FIG. 3 is a block diagram illustrating an example of main components of a pixel and analog processing unit.

FIG. 4 is a diagram illustrating a detailed configuration example of a pixel array.

FIG. 5 is a circuit diagram illustrating a configuration example of a pixel.

FIG. 6 is a block diagram illustrating a cross-sectional structure example of a solid-state imaging device.

FIG. 7 is a schematic configuration diagram illustrating a planar arrangement example of circuit blocks including a region in which an active element group has been formed.

FIG. 8 is a diagram illustrating an example of a positional relationship between a light shielding target region of a light shielding structure, a region of an active element group, and a buffer region.

FIG. 9 is a diagram illustrating a first comparative example of conductor layers A and B.

FIG. 10 is a diagram illustrating conditions of a current flowing in the first comparative example.

FIG. 11 is a diagram illustrating results of simulation of inductive noise corresponding to the first comparative example.

FIG. 12 is a diagram illustrating a first configuration example of the conductor layers A and B.

FIG. 13 is a diagram illustrating conditions of a current flowing in a first configuration example.

FIG. 14 is a diagram illustrating results of simulation of inductive noise corresponding to the first configuration example.

FIG. 15 is a diagram illustrating a second configuration example of the conductor layers A and B.

FIG. 16 is a diagram illustrating conditions of a current flowing in a second configuration example.

FIG. 17 is a diagram illustrating results of simulation of the inductive noise corresponding to the second configuration example.

FIG. 18 is a diagram illustrating a second comparative example of the conductor layers A and B.

FIG. 19 is a diagram illustrating results of simulation of inductive noise corresponding to the second comparative example.

FIG. 20 is a diagram illustrating a third comparative example of the conductor layers A and B.

FIG. 21 is a diagram illustrating results of simulation of inductive noise corresponding to the third comparative example.

FIG. 22 is a diagram illustrating a third configuration example of the conductor layers A and B.

FIG. 23 is a diagram illustrating conditions of a current flowing in the third configuration example.

FIG. 24 is a diagram illustrating results of simulation of inductive noise corresponding to the third configuration example.

FIG. 25 is a diagram illustrating a fourth configuration example of the conductor layers A and B.

FIG. 26 is a diagram illustrating a fifth configuration example of the conductor layers A and B.

FIG. 27 is a diagram illustrating a sixth configuration example of the conductor layers A and B.

FIG. 28 is a diagram illustrating results of simulation of inductive noise corresponding to the fourth to sixth configuration examples.

FIG. 29 is a diagram illustrating a seventh configuration example of the conductor layers A and B.

FIG. 30 is a diagram illustrating conditions of a current flowing in the seventh configuration example.

FIG. 31 is a diagram illustrating results of simulation of inductive noise corresponding to the seventh configuration example.

FIG. 32 is a diagram illustrating an eighth configuration example of the conductor layers A and B.

FIG. 33 is a diagram illustrating a ninth configuration example of the conductor layers A and B.

FIG. 34 is a diagram illustrating a tenth configuration example of the conductor layers A and B.

FIG. 35 is a diagram illustrating results of simulation of inductive noise corresponding to the eighth to tenth configuration examples.

FIG. 36 is a diagram illustrating an eleventh configuration example of the conductor layers A and B.

FIG. 37 is a diagram illustrating conditions of a current flowing in the eleventh configuration example.

FIG. 38 is a diagram illustrating results of simulation of inductive noise corresponding to the eleventh configuration example.

FIG. 39 is a diagram illustrating a twelfth configuration example of the conductor layers A and B.

FIG. 40 is a diagram illustrating a thirteenth configuration example of the conductor layers A and B.

FIG. 41 is a diagram illustrating results of simulation of inductive noise corresponding to the twelfth and thirteenth configuration examples.

FIG. 42 is a plan view illustrating a first arrangement example of pads in a semiconductor substrate.

FIG. 43 is a plan view illustrating a second arrangement example of the pads in the semiconductor substrate.

FIG. 44 is a plan view illustrating a third arrangement example of the pads in the semiconductor substrate.

FIG. 45 is a diagram illustrating an example of a conductor of which a resistance value in an Y direction differs from a resistance value in an X direction.

FIG. 46 is a diagram illustrating a modification example in which a conductor period of an X direction of the second configuration example of the conductor layers A and B is halved, and effects thereof.

FIG. 47 is a diagram illustrating a modification example in which a conductor period of an X direction of the fifth configuration example of the conductor layers A and B is halved, and effects thereof.

FIG. 48 is a diagram illustrating a modification example in which a conductor period of an X direction of the sixth configuration example of the conductor layers A and B is halved, and effects thereof.

FIG. 49 is a diagram illustrating a modification example in which a conductor period of a Y direction of the second configuration example of the conductor layers A and B is halved, and effects thereof.

FIG. 50 is a diagram illustrating a modification example in which a conductor period of a Y direction of the fifth configuration example of the conductor layers A and B is halved, and effects thereof.

FIG. 51 is a diagram illustrating a modification example in which a conductor period of a Y direction of the sixth configuration example of the conductor layers A and B is halved, and effects thereof.

FIG. 52 is a diagram illustrating a modification example in which a conductor width of an X direction of the second configuration example of the conductor layers A and B is doubled thereof, and effects thereof.

FIG. 53 is a diagram illustrating a modification example in which a conductor width of an X direction of the fifth configuration example of the conductor layers A and B is doubled, and effects thereof.

FIG. 54 is a diagram illustrating a modification example in which a conductor width of an X direction of the sixth configuration example of the conductor layers A and B is doubled, and effects thereof.

FIG. 55 is a diagram illustrating a modification example in which a conductor width of a Y direction of the second configuration example of the conductor layers A and B is doubled, and effects thereof.

FIG. 56 is a diagram illustrating a modification example in which a conductor width of a Y direction of the fifth configuration example of the conductor layers A and B is doubled, and effects thereof.

FIG. 57 is a diagram illustrating a modification example in which a conductor width of a Y direction of the sixth configuration example of the conductor layers A and B is doubled, and effects thereof.

FIG. 58 is a diagram illustrating a modification example of a mesh conductor forming each configuration example of the conductor layers A and B.

FIG. 59 is a diagram illustrating improvement of a degree of freedom in a layout.

FIG. 60 is a diagram illustrating reduction of a voltage drop (IR-Drop).

FIG. 61 is a diagram illustrating reduction of a voltage drop (IR-Drop).

FIG. 62 is a diagram illustrating reduction of capacitive noise.

FIG. 63 is a diagram illustrating a main conductor portion and a lead conductor portion of a conductor layer.

FIG. 64 is a diagram illustrating an eleventh configuration example of the conductor layers A and B.

FIG. 65 is a diagram illustrating a fourteenth configuration example of the conductor layers A and B.

FIG. 66 is a diagram illustrating a first modification example of the fourteenth configuration example of the conductor layers A and B.

FIG. 67 is a diagram illustrating a second modification example of the fourteenth configuration example of the conductor layers A and B.

FIG. 68 is a diagram illustrating a third modification example of the fourteenth configuration example of the conductor layers A and B.

FIG. 69 is a diagram illustrating a fifteenth configuration example of the conductor layers A and B.

FIG. 70 is a diagram illustrating a first modification example of the fifteenth configuration example of the conductor layers A and B.

FIG. 71 is a diagram illustrating a second modification example of the fifteenth configuration example of the conductor layers A and B.

FIG. 72 is a diagram illustrating a sixteenth configuration example of the conductor layers A and B.

FIG. 73 is a diagram illustrating a first modification example of the sixteenth configuration example of the conductor layers A and B.

FIG. 74 is a diagram illustrating a second modification example of the sixteenth configuration example of the conductor layers A and B.

FIG. 75 is a diagram illustrating a seventeenth configuration example of the conductor layers A and B.

FIG. 76 is a diagram illustrating a first modification example of the seventeenth configuration example of the conductor layers A and B.

FIG. 77 is a diagram illustrating a second modification example of the seventeenth configuration example of the conductor layers A and B.

FIG. 78 is a diagram illustrating an eighteenth configuration example of the conductor layers A and B.

FIG. 79 is a diagram illustrating a nineteenth configuration example of the conductor layers A and B.

FIG. 80 is a diagram illustrating a modification example of the nineteenth configuration example of the conductor layers A and B.

FIG. 81 is a diagram illustrating a twentieth configuration example of the conductor layers A and B.

FIG. 82 is a diagram illustrating a twenty-first configuration example of the conductor layers A and B.

FIG. 83 is a diagram illustrating a twenty-second configuration example of the conductor layers A and B.

FIG. 84 is a diagram illustrating another configuration example of the conductor layer B in the twenty-second configuration example.

FIG. 85 is a diagram illustrating a twenty-third configuration example of the conductor layers A and B.

FIG. 86 is a diagram illustrating a twenty-fourth configuration example of the conductor layers A and B.

FIG. 87 is a diagram illustrating a twenty-fifth configuration example of the conductor layers A and B.

FIG. 88 is a diagram illustrating a twenty-sixth configuration example of the conductor layers A and B.

FIG. 89 is a diagram illustrating a twenty-seventh configuration example of the conductor layers A and B.

FIG. 90 is a diagram illustrating a twenty-eighth configuration example of the conductor layers A and B.

FIG. 91 is a diagram illustrating another configuration example of the conductor layer A in the twenty-eighth configuration example.

FIG. 92 is a plan view illustrating an entire conductor layer A formed on a substrate.

FIG. 93 is a plan view illustrating a fourth arrangement example of the pads.

FIG. 94 is a plan view illustrating a fifth arrangement example of the pads.

FIG. 95 is a plan view illustrating a sixth arrangement example of the pads.

FIG. 96 is a plan view illustrating a seventh arrangement example of the pads.

FIG. 97 is a plan view illustrating an eighth arrangement example of the pads.

FIG. 98 is a plan view illustrating a ninth arrangement example of the pads.

FIG. 99 is a plan view illustrating a tenth arrangement example of the pads.

FIG. 100 is a plan view illustrating an eleventh arrangement example of the pads.

FIG. 101 is a plan view illustrating a twelfth arrangement example of the pads.

FIG. 102 is a plan view illustrating a thirteenth arrangement example of the pads.

FIG. 103 is a plan view illustrating a fourteenth arrangement example of the pads.

FIG. 104 is a plan view illustrating a fifteenth arrangement example of the pads.

FIG. 105 is a plan view illustrating a sixteenth arrangement example of the pads.

FIG. 106 is a plan view illustrating a seventeenth arrangement example of the pads.

FIG. 107 is a plan view illustrating an eighteenth arrangement example of the pads.

FIG. 108 is a plan view illustrating a nineteenth arrangement example of the pads.

FIG. 109 is cross-sectional view illustrating a substrate arrangement example of a victim conductor loop and an aggressor conductor loop.

FIG. 110 is cross-sectional view illustrating a substrate arrangement example of a victim conductor loop and an aggressor conductor loop.

FIG. 111 is a diagram illustrating an arrangement example of a victim conductor loop and an aggressor conductor loop in a structure in which three types of substrates are stacked.

FIG. 112 is a diagram illustrating an arrangement example of a victim conductor loop and an aggressor conductor loop in a structure in which three types of substrates are stacked.

FIG. 113 is a diagram illustrating a package stack example of a first semiconductor substrate and a second semiconductor substrate forming a solid-state imaging device.

FIG. 114 is cross-sectional view illustrating a configuration example in which a conductive shield is provided.

FIG. 115 is cross-sectional view illustrating a configuration example in which a conductive shield is provided.

FIG. 116 is a diagram illustrating an arrangement with respect to a signal line of the conductive shield, and a first configuration example having a planar shape.

FIG. 117 is a diagram illustrating an arrangement with respect to a signal line of the conductive shield, and a second configuration example having a planar shape.

FIG. 118 is a diagram illustrating an arrangement with respect to a signal line of the conductive shield, and a third configuration example having a planar shape.

FIG. 119 is a diagram illustrating an arrangement with respect to a signal line of the conductive shield, and a fourth configuration example having a planar shape.

FIG. 120 is a diagram illustrating an arrangement example when a conductor layer includes three layers.

FIG. 121 is a diagram illustrating a problem when a conductor layer includes three layers.

FIG. 122 is a diagram illustrating a first configuration example of the three-layer conductor layer.

FIG. 123 is a diagram illustrating a second configuration example of the three-layer conductor layer.

FIG. 124 is a diagram illustrating a first modification example of the second configuration example of the three-layer conductor layer.

FIG. 125 is a diagram illustrating a second modification example of the second configuration example of the three-layer conductor layer.

FIG. 126 is a diagram illustrating a third configuration example of the three-layer conductor layer.

FIG. 127 is a diagram illustrating a modification example of the third configuration example of the three-layer conductor layer.

FIG. 128 is a diagram illustrating a fourth configuration example of the three-layer conductor layer.

FIG. 129 is a diagram illustrating a first modification example of the fourth configuration example of the three-layer conductor layer.

FIG. 130 is a diagram illustrating a second modification example of the fourth configuration example of the three-layer conductor layer.

FIG. 131 is a diagram illustrating a fifth configuration example of the three-layer conductor layer.

FIG. 132 is a diagram illustrating a sixth configuration example of the three-layer conductor layer.

FIG. 133 is a diagram illustrating a modification example of the sixth configuration example of the three-layer conductor layer.

FIG. 134 is a diagram illustrating a seventh configuration example of the three-layer conductor layer.

FIG. 135 is a diagram illustrating an eighth configuration example of the three-layer conductor layer.

FIG. 136 is a diagram illustrating a first modification example of the eighth configuration example of the three-layer conductor layer.

FIG. 137 is a diagram illustrating a second modification example of the eighth configuration example of the three-layer conductor layer.

FIG. 138 is a diagram illustrating a third modification example of the eighth configuration example of the three-layer conductor layer.

FIG. 139 is a diagram illustrating a fourth modification example of the eighth configuration example of the three-layer conductor layer.

FIG. 140 is a diagram illustrating a fifth modification example of the eighth configuration example of the three-layer conductor layer.

FIG. 141 is a diagram illustrating a ninth configuration example of the three-layer conductor layer.

FIG. 142 is a diagram illustrating a first modification example of the ninth configuration example of the three-layer conductor layer.

FIG. 143 is a diagram illustrating a second modification example of the ninth configuration example of the three-layer conductor layer.

FIG. 144 is a diagram illustrating a third modification example of the ninth configuration example of the three-layer conductor layer.

FIG. 145 is a diagram illustrating a fourth modification example of the ninth configuration example of the three-layer conductor layer.

FIG. 146 is a diagram illustrating a tenth configuration example of the three-layer conductor layer.

FIG. 147 is a diagram illustrating a modification example of the tenth configuration example of the three-layer conductor layer.

FIG. 148 is a diagram illustrating an eleventh configuration example of the three-layer conductor layer.

FIG. 149 is a diagram illustrating a twelfth configuration example of the three-layer conductor layer.

FIG. 150 is a diagram illustrating a first modification example of the twelfth configuration example of the three-layer conductor layer.

FIG. 151 is a diagram illustrating a second modification example of the twelfth configuration example of the three-layer conductor layer.

FIG. 152 is a diagram illustrating a thirteenth configuration example of the three-layer conductor layer.

FIG. 153 is a diagram illustrating a fourteenth configuration example of the three-layer conductor layer.

FIG. 154 is a diagram illustrating a first modification example of the fourteenth configuration example of the three-layer conductor layer.

FIG. 155 is a diagram illustrating a second modification example of the fourteenth configuration example of the three-layer conductor layer.

FIG. 156 is a diagram illustrating third to fifth modification examples of the fourteenth configuration example of the three-layer conductor layer.

FIG. 157 is a diagram illustrating sixth to eighth modification examples of the fourteenth configuration example of the three-layer conductor layer.

FIG. 158 is a diagram illustrating ninth to eleventh modification examples of the fourteenth configuration example of the three-layer conductor layer.

FIG. 159 is a diagram illustrating twelfth to fourteen modification examples of the fourteenth configuration example of the three-layer conductor layer.

FIG. 160 is a diagram illustrating fifteenth to seventeenth modification examples of the fourteenth configuration example of the three-layer conductor layer.

FIG. 161 is a diagram illustrating eighteenth to twentieth modification examples of the fourteenth configuration example of the three-layer conductor layer.

FIG. 162 is a diagram illustrating twenty-first to twenty-third modification examples of the fourteenth configuration example of the three-layer conductor layer.

FIG. 163 is a diagram illustrating twenty-fourth to twenty-sixth modification examples of the fourteenth configuration example of the three-layer conductor layer.

FIG. 164 is a block diagram illustrating a configuration example of an imaging device.

FIG. 165 is a block diagram illustrating an example of a schematic configuration of an in-body information acquisition system.

FIG. 166 is a diagram illustrating an example of a schematic configuration of an endoscopic surgery system.

FIG. 167 is a block diagram illustrating an example of a functional configuration of a camera head and a CCU.

FIG. 168 is a block diagram illustrating an example of a schematic configuration of a vehicle control system.

FIG. 169 is an illustrative drawing illustrating an example of an installation position of an outside-vehicle information detection unit and an imaging unit.

### DESCRIPTION OF EMBODIMENTS

Hereinafter, the best mode (hereinafter, referred to as an embodiment) for carrying out the present technology will be described in detail with reference to the drawings. The description will be given in the following order.

1. Victim conductor loop and magnetic flux

2. Configuration example of solid-state imaging device (semiconductor device) that is embodiment of present technology

3. Structure for shielding emitted hot carrier light

4. Configuration examples of conductor layers A and B

5. Arrangement examples of electrodes on semiconductor substrate on which conductor layers A and B are formed

6. Modification examples of configuration examples of conductor layers A and B

7. Modification examples of mesh conductor

8. Various effects

9. Configuration examples in which lead portions differ

10. Configuration examples of connection to pad

11. Arrangement examples of conductive shields

12. Configuration examples when conductor layer includes three layers

13. Application examples

14. Configuration example of imaging device

15. Example of application to in-body information acquisition system

16. Example of application to endoscopic surgery system

17. Example of application to moving objects

<1. Victim Conductor Loop and Magnetic Flux>

For example, in a solid-state imaging device (a semiconductor device) such as a CMOS image sensor, when there is a circuit in which a victim conductor loop is formed near a power supply wiring and a magnetic flux passing through the inside of a loop surface of the victim conductor loop changes, the induced electromotive force generated in the victim conductor loop may change and noise may occur in the pixel signal. The victim conductor loop may be formed to include a conductor at least in a part thereof. Further, the victim conductor loop may be entirely formed of a conductor.

Here, the victim conductor loop (a first conductor loop) refers to a conductor loop on the side that is influenced by change in magnetic field intensity that occurs near the victim conductor loop. On the other hand, a conductor loop that is present near the victim conductor loop, causes change in the magnetic field intensity due to the change in the flowing current, and has an influence on the victim conductor loop is referred to as an aggressor conductor loop (a second conductor loop).

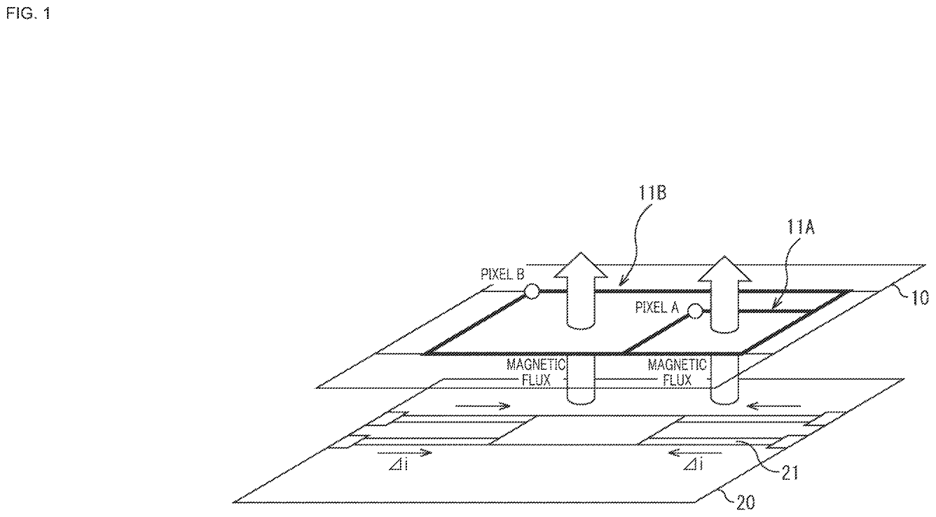

FIG. 1 is a diagram illustrating change in induced electromotive force due to changes in a victim conductor loop. For example, the solid-state imaging device such as the CMOS image sensor illustrated in FIG. 1 has a configuration in which a pixel substrate 10 and a logic substrate 20 are stacked in this order from the top. In the solid-state imaging device of FIG. 1, at least a part of the victim conductor loop 11 (11A and 11B) is formed in a pixel region of the pixel substrate 10, and a power supply wiring 21 for supplying (digital) power is formed near the victim conductor loop 11 of the logic substrate 20 stacked on the pixel substrate 10.

A magnetic flux generated by the power supply wiring 21 passes through the inside of a loop surface of the victim conductor loop 11 on the pixel substrate 10, thereby generating an induced electromotive force in the victim conductor loop 11.

The induced electromotive force Vemf generated in the victim conductor loop 11 can be calculated using Equations (1) and (2) below. Φ denotes a magnetic flux, H denotes a magnetic field intensity, μ denotes a magnetic permeability, and S denotes an area of the victim conductor loop 11.

$$\begin{matrix}[ Math . 1 ] & \\ Φ = {\int }_{S} μ H \cdot dS \\ [ Math . 2 ] & ( 1 ) \\ {V}_{em f} = - \frac{d Φ}{dt} & ( 2 )\end{matrix}$$

A loop path of the victim conductor loop 11 formed in the pixel region of the pixel substrate 10 changes depending on a position of a pixel selected as a readout target pixel from which a pixel signal is read out. In the case of the example of FIG. 1, a loop path of the victim conductor loop 11A formed when a pixel A is selected differs from a loop path of a victim conductor loop 11B formed when a pixel B at a position different from the pixel A is selected. In other words, an effective shape of the conductor loop changes depending on a position of the selected pixel.

When the loop path of the victim conductor loop 11 changes in this way, the magnetic flux passing through the inside of the loop surface of the victim conductor loop changes, and the induced electromotive force generated in the victim conductor loop due to the change may greatly change. Noise (inductive noise) may occur in the pixel signal read out from the pixel due to the change in the induced electromotive force. Striped image noise may occur in a captured image due to the inductive noise. That is, image quality of the captured image may be degraded.

Therefore, the present disclosure proposes a technology for curbing occurrence of inductive noise caused by an induced electromotive force in a victim conductor loop.

<2. Configuration Example of Solid-State Imaging Device (Semiconductor Device) that is Embodiment of Present Technology>

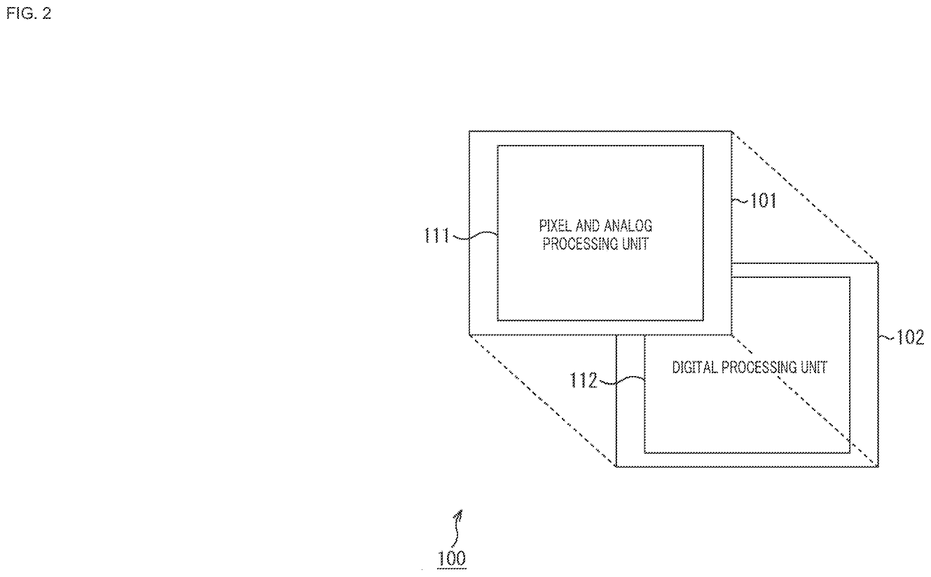

FIG. 2 is a block diagram illustrating a main configuration example of the solid-state imaging device that is an embodiment of the present technology.

A solid-state imaging device 100 illustrated in FIG. 2 is a device that photoelectrically converts light coming from a subject and outputs image data. For example, the solid-state imaging device 100 is configured as, for example, a backside illumination type CMOS image sensor using a CMOS.

As illustrated in FIG. 2, the solid-state imaging device 100 has a configuration in which a first semiconductor substrate 101 and a second semiconductor substrate 102 are stacked.

A pixel and analog processing unit 111 having pixels, an analog circuit, or the like is formed on the first semiconductor substrate 101. A digital processing unit 112 including, for example, a digital circuit is formed in the second semiconductor substrate 102.

The first semiconductor substrate 101 and the second semiconductor substrate 102 overlap each other while being insulated from each other. That is, a configuration of the pixel and analog processing unit 111 and a configuration of the second semiconductor substrate 102 are basically insulated from each other. Although not illustrated, a configuration formed in the pixel and analog processing unit 111 is electrically connected to a configuration formed in the digital processing unit 112 by, for example, a conductive via (VIA), a through silicon via (TSV), the same type of metal bonding such as a Cu—Cu bonding, an Au—Au bonding, or an Al—Al bonding, a different type of metal bonding such as a Cu—Au bonding, a Cu—Al bonding, or an Au—Al bonding, or a bonding wire, as necessary (required portions).

Further, the solid-state imaging device 100 including the two- stacked layer substrate has been described as an example in FIG. 2, but the number of layers of the substrate forming the solid-state imaging device 100 is arbitrary. For example, the substrate may include a single layer or may include three or more layers. Hereinafter, a case in which the substrate includes two layers as in the example of FIG. 2 will be described.

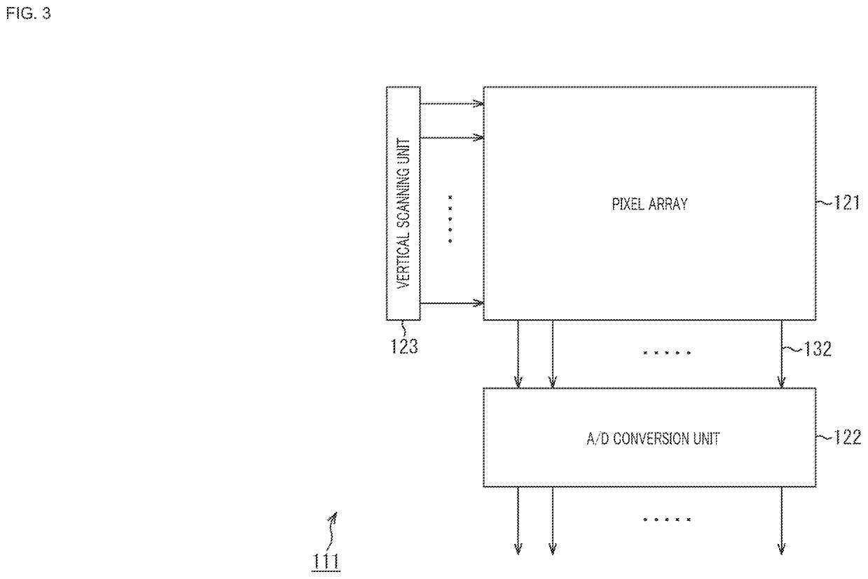

FIG. 3 is a block diagram illustrating an example of main components formed in the pixel and analog processing unit 111.

A pixel array 121, an A/D conversion unit 122, a vertical scanning unit 123, and the like are formed in the pixel and analog processing unit 111, as illustrated in FIG. 3.

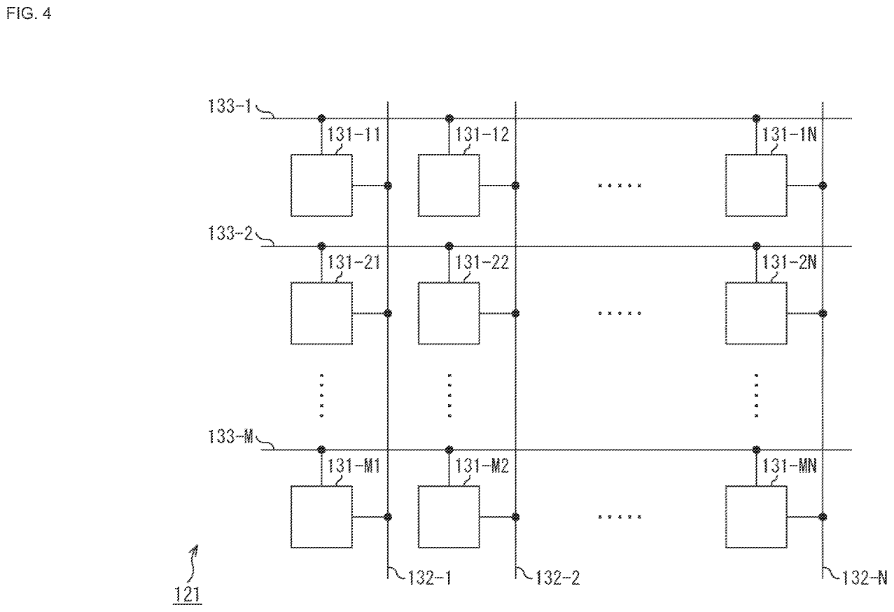

A plurality of pixels 131 (FIG. 4) each having a photoelectric conversion element such as a photodiode are arranged in the pixel array 121 vertically and horizontally.

The A/D conversion unit 122 performs A/D conversion on, for example, an analog signal read from each pixel 131 of the pixel array 121, and outputs a resultant digital pixel signal.

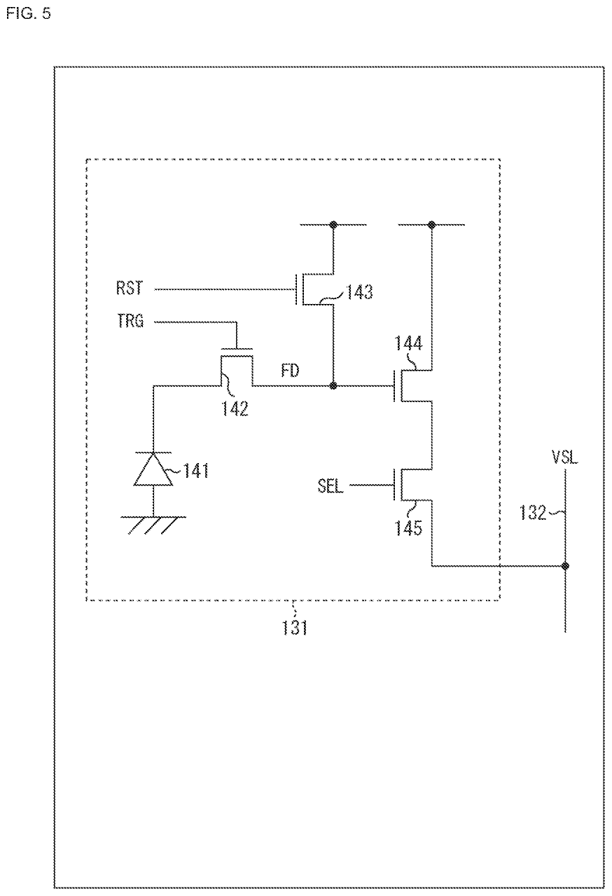

The vertical scanning unit 123 controls an operation of a transistor (such as a transfer transistor 142 in FIG. 5) of each pixel 131 of the pixel array 121. That is, charge accumulated in each pixel 131 of the pixel array 121 is controlled and read out by the vertical scanning unit 123, supplied as a pixel signal to the A/D conversion unit 122 via a signal line 132 (FIG. 4) for each column of a unit pixel, and subjected to A/D conversion.

The A/D conversion unit 122 supplies a result of the A/D conversion (digital pixel signal) to a logic circuit (not illustrated) formed in the digital processing unit 112 for each column of the pixel 131.

FIG. 4 is a diagram illustrating a detailed configuration example of the pixel array 121. Pixels 131-11 to 131-MN are formed in the pixel array 121 (M and N are arbitrary natural numbers). That is, the pixels 131 in M rows and N columns are arranged in a matrix (array) in the pixel array 121. Hereinafter, the pixels 131-11 to 131-MN will be referred to as a pixel 131 when it is not necessary for the pixels 131-11 to 131-MN to be individually distinguished.

Signal lines 132-1 to 132-N and control lines 133-1 to 133-M are formed in the pixel array 121. Hereinafter, when it is not necessary to individually distinguish the signal lines 132-1 to 132-N, the signal lines 132-1 to 132-N are referred to as a signal line 132, and when it is not necessary to individually distinguish the control lines 133-1 to 133-M, the control lines 133-1 to 133-M are referred to as a control line 133.

The signal line 132 corresponding to each column is connected to the pixels 131 for each column. Further, the control line 133 corresponding to each row is connected to the pixels 131 for each row. A control signal from the vertical scanning unit 123 is transmitted to the pixels 131 via the control line 133.

An analog pixel signal is output from the pixel 131 to the A/D conversion unit 122 via the signal line 132.

Next, FIG. 5 is a circuit diagram illustrating a configuration example of the pixel 131. The pixel 131 includes a photodiode 141 as a photoelectric conversion element, the transfer transistor 142, a reset transistor 143, an amplification transistor 144, and a selection transistor 145.

The photodiode 141 photoelectrically converts the received light into a photocharge (here, photoelectrons) having a charge amount corresponding to an amount of the light, and accumulates the photocharge. An anode electrode of the photodiode 141 is connected to GND, and a cathode electrode thereof is connected to a floating diffusion (FD) via the transfer transistor 142. Of course, the cathode electrode of the photodiode 141 may be connected to the power supply, the anode electrode may be connected to the floating diffusion via the transfer transistor 142, and the photocharge may be read out as photoholes.

The transfer transistor 142 controls the readout of photocharge from the photodiode 141. The transfer transistor 142 has a drain electrode connected to the floating diffusion and a source electrode connected to the cathode electrode of the photodiode 141. Further, a transfer control line for transferring a transfer control signal TRG supplied from the vertical scanning unit 123 (FIG. 3) is connected to a gate electrode of the transfer transistor 142. When the transfer control signal TRG (that is, a gate potential of the transfer transistor 142) is in an OFF state, the photocharge is not transferred from the photodiode 141 (the photocharge is accumulated in the photodiode 141). When the transfer control signal TRG (that is, the gate potential of the transfer transistor 142) is in an ON state, the photocharge accumulated in the photodiode 141 is transferred to the floating diffusion.

The reset transistor 143 resets a potential of the floating diffusion. The reset transistor 143 has a drain electrode connected to a power supply potential and a source electrode connected to the floating diffusion. Further, a reset control line for transferring a reset control signal RST supplied from the vertical scanning unit 123 is connected to a gate electrode of the reset transistor 143. When the reset control signal RST (that is, a gate potential of the reset transistor 143) is in an OFF state, the floating diffusion is disconnected from the power supply potential. When the reset control signal RST (that is, the gate potential of the reset transistor 143) is in an ON state, the charge of the floating diffusion is discharged to the power supply potential, and the floating diffusion is reset.

The amplification transistor 144 outputs an electrical signal (an analog signal) according to a voltage of the floating diffusion (causes a current to flow). The amplification transistor 144 has a gate electrode connected to the floating diffusion, a drain electrode connected to a (source follower) power supply voltage, and a source electrode connected to a drain electrode of the selection transistor 145. For example, the amplification transistor 144 outputs a reset signal (a reset level) serving as an electrical signal according to the voltage of the floating diffusion reset by the reset transistor 143 to the selection transistor 145 as a pixel signal. Further, the amplification transistor 144 outputs a light accumulation signal (a signal level) serving as an electrical signal according to the voltage of the floating diffusion to which the photocharge has been transferred by the transfer transistor 142, to the selection transistor 145, as a pixel signal.

The selection transistor 145 controls the output of the electrical signal supplied from the amplification transistor 144 to the signal line (VSL) 132 (that is, the A/D conversion unit 122). The selection transistor 145 has a drain electrode connected to the source electrode of the amplification transistor 144, and a source electrode connected to the signal line 132. A select control line for transferring a select control signal SEL supplied from the vertical scanning unit 123 is connected to a gate electrode of the selection transistor 145. When the select control signal SEL (that is, a gate potential of the selection transistor 145) is in an OFF state, the amplification transistor 144 and the signal line 132 are electrically disconnected. Therefore, in this state, the reset signal or the light accumulation signal serving as a pixel signal is not output from the pixel 131. When the select control signal SEL (that is, a gate potential of the selection transistor 145) is in an ON state, the pixel 131 enters a selected state. That is, the amplification transistor 144 and the signal line 132 are electrically connected, and the reset signal or the light accumulation signal serving as the pixel signal output is supplied from the amplification transistor 144 to the A/D conversion unit 122 via the signal line 132. That is, the reset signal or the light accumulation signal serving as the pixel signal is read out from the pixel 131.

A configuration of the pixel 131 is arbitrary and is not limited to the example of FIG. 5.

In the pixel and analog processing unit 111 configured as described above, when the pixel 131 is selected as a target of readout of an analog signal serving as a pixel signal, various victim conductor loops (loop-shaped (annular) conductors) are formed by the control line 133 for controlling the various transistors described above, the signal line 132, a power supply wiring (an analog power supply wiring or a digital power supply wiring), or the like. An induced electromotive force occurs due to a magnetic flux generated from wirings or the like near the victim conductor loop passing through the inside of the loop surface of the victim conductor loop.

A part of at least one of the control line 133 and the signal line 132 may be included as the victim conductor loop. Further, the victim conductor loop including a part of the control line 133 and the victim conductor loop including a part of the signal line 132 may be present as independent victim conductor loops. Further, a part or all of the victim conductor loop may be included in the second semiconductor substrate 102. Further, the victim conductor loop may have a variable loop path or may have a fixed loop path.

It is preferable for wiring directions of the control lines 133 and the signal lines 132 forming the victim conductor loop to be substantially orthogonal to each other, but the control lines 133 and the signal lines 132 may be substantially parallel to each other.

A conductor loop present near another conductor loop can be a victim conductor loop. For example, a conductor loop that is not influenced by a magnetic field intensity changing due to change in the current flowing in an aggressor loop near the conductor loop can also be a victim conductor loop.

In the victim conductor loop, when a high-frequency signal flows in a wiring (aggressor conductor loop) present near the victim conductor loop and a magnetic field intensity around the aggressor conductor loop changes, an induced electromotive force may be generated in the victim conductor loop due to an influence of the change, and noise may occur in the victim conductor loop. In particular, when wirings in which currents flow in the same direction are densely present near the victim conductor loop, the change in magnetic field intensity increases, and the induced electromotive force (that is, noise) generated in the victim conductor loop also increases.

Therefore, in the present disclosure, a direction of the magnetic flux generated from the loop surface of the aggressor conductor loop is adjusted so that the magnetic field does not pass through the aggressor conductor loop.

<3. Structure for Shielding Emitted Hot Carrier Light>

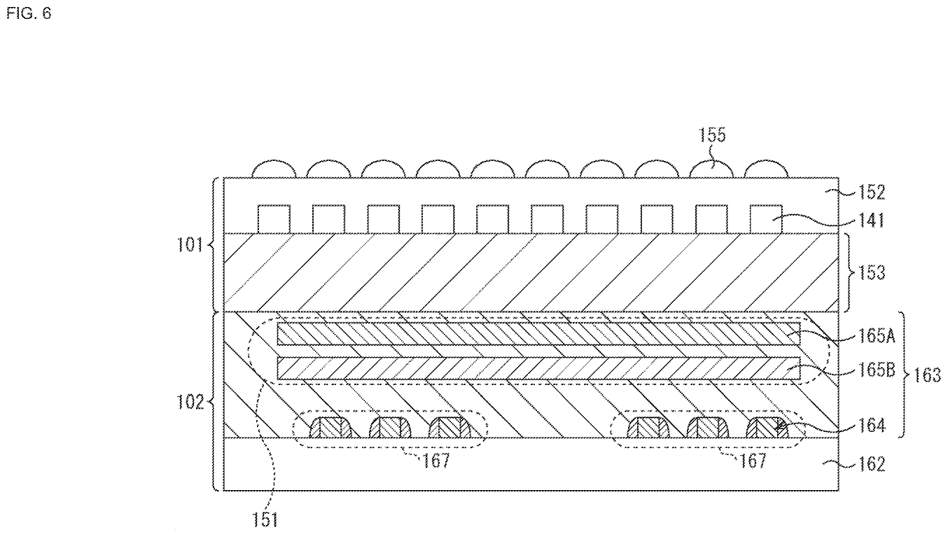

FIG. 6 is a diagram illustrating an example of a cross-sectional structure of the solid-state imaging device 100.

As described above, the solid-state imaging device 100 has a configuration in which the first semiconductor substrate 101 and the second semiconductor substrate 102 are stacked.

A pixel array in which a plurality of pixel units each including the photodiode 141 serving as a photoelectric conversion unit and a plurality of pixel transistors (the transfer transistor 142 to the selection transistor 145 in FIG. 5) are two-dimensionally arranged, for example, is formed on the first semiconductor substrate 101.

The photodiode 141 is formed, for example, with an n-type semiconductor region and a p-type semiconductor region on the substrate front surface side (a lower side in FIG. 6) in a well region formed in the semiconductor substrate 152. A plurality of pixel transistors (the transfer transistor 142 to the selection transistor 145 in FIG. 5) are formed on the semiconductor substrate 152.

A multilayer wiring layer 153 in which wirings of a plurality of layers are arranged with an interlayer insulating film therebetween is formed on the front surface side of the semiconductor substrate 152. The wiring is formed of, for example, copper wiring. In the pixel transistor, the vertical scanning unit 123, and the like, wirings of different wiring layers are connected to each other at a required location by connection conductors penetrating the wiring layers. An antireflection film, a light shielding film that shields light in a predetermined region, and an optical member 155 such as a color filter or a microlens provided at a position corresponding to each photodiode 141, for example, are formed on a back surface (an upper surface in FIG. 6) of the semiconductor substrate 152.

On the other hand, a logic circuit as the digital processing unit 112 (FIG. 2) is formed in the second semiconductor substrate 102. The logic circuit includes, for example, a plurality of MOS transistors 164 formed in a p-type semiconductor well region of the semiconductor substrate 162.

Further, a multilayer wiring layer 163 including a plurality of wiring layers in which wirings are arranged with an interlayer insulating film therebetween is formed on the semiconductor substrate 162. FIG. 6 illustrates two wiring layers (a wiring layer 165A and a wiring layer 165B) among the plurality of wiring layers forming the multilayer wiring layer 163.

In the solid-state imaging device 100, a light shielding structure 151 is formed by the wiring layer 165A and the wiring layer 165B.

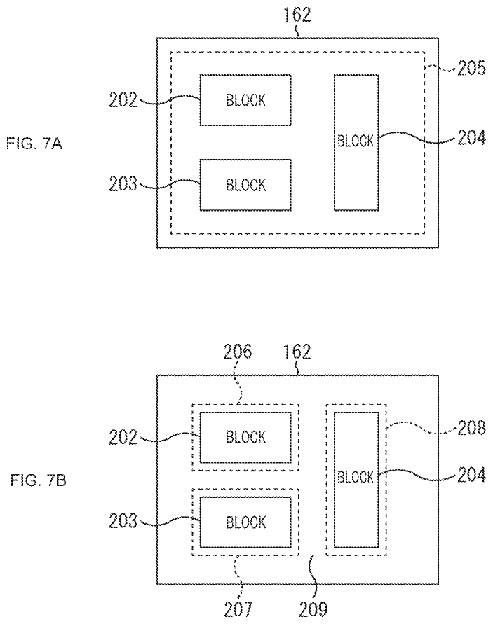

Here, in the second semiconductor substrate 102, a region in which active elements such as the MOS transistor 164 are formed is an active element group 167. In the second semiconductor substrate 102, for example, a circuit for realizing one function by combining a plurality of active elements such as nMOS transistors or pMOS transistors is configured. A region in which the active element group 167 has been formed is a circuit block (corresponding to circuit blocks 202 to 204 in FIG. 7). Active elements formed in the second semiconductor substrate 102 can include, for example, a diode, in addition to the MOS transistor 164.

In the multilayer wiring layer 163 of the second semiconductor substrate 102, the light shielding structure 151 including the wiring layer 165A and the wiring layer 165B is present between the active element group 167 and the photodiode 141, thereby curbing leakage of hot carrier light generated from the active element group 167 into the photodiode 141 (details will be described below).

Hereinafter, the wiring layer 165A closer to the first semiconductor substrate 101 on which the photodiode 141 and the like have been formed among the wiring layer 165A and the wiring layer 165B forming the light shielding structure 151 is referred to as a conductor layer A (a first conductor layer). Further, the wiring layer 165B close to the active element group 167 is referred to as a conductor layer B (second conductor layer).

However, the wiring layer 165A close to the first semiconductor substrate 101 on which the photodiode 141 and the like have been formed may be the conductor layer B, and the wiring layer 165B close to the active element group 167 may be the conductor layer A. Further, an insulating layer, a semiconductor layer, another conductor layer, or the like may be provided between the conductor layers A and B. An insulating layer, a semiconductor layer, another conductor layer, or the like may be provided in a region other than a region between the conductor layers A and B.

It is preferable for the conductor layer A and the conductor layer B to be conductor layers in which current flows most easily in the circuit board, the semiconductor substrate, and the electronic device, but the present technology is not limited thereto.

It is preferable for one of the conductor layer A and the conductor layer B to be a conductor layer in which it is most easy for a current to flow in the circuit board, the semiconductor substrate, and the electronic device, and for the other to be a conductor layer in which it is second-most easy for a current to flow in the circuit board, the semiconductor substrate, and the electronic device, but the present technology is not limited thereto.

It is preferable for one of the conductor layers A and B not to be a conductor layer in which it is most difficult for a current to flow in the circuit board, the semiconductor substrate, and the electronic device, but the present technology is not limited thereto. It is preferable for both of the conductor layers A and B not to be conductor layers in which it is most difficult for a current to flow in the circuit board, the semiconductor substrate, and the electronic device, but the present technology is not limited thereto.

For example, one of the conductor layers A and B may be a conductor layer in which it is easy for a current to flow first in the first semiconductor substrate 101, and the other may be a conductor layer in which it is easy for a current to flow second in the first semiconductor substrate 101.

For example, one of the conductor layers A and B is a conductor layer in which it is easy for a current to flow first in the second semiconductor substrate 102, and the other is a conductor layer in which it is easy for a current to flow second in the second semiconductor substrate 102.

For example, one of the conductor layers A and B is a conductor layer in which it is easy for a current to flow first in the first semiconductor substrate 101, and the other is a conductor layer in which it is easy for a current to flow first in the second semiconductor substrate 102.

For example, one of the conductor layers A and B is a conductor layer in which it is easy for a current to flow first in the first semiconductor substrate 101, and the other is a conductor layer in which it is easy for a current to flow second in the second semiconductor substrate 102.

For example, one of the conductor layer A and the conductor layer B is a conductor layer in which it is easy for a current to flow second in the first semiconductor substrate 101, and the other is a conductor layer in which it is easy for a current to flow first in the second semiconductor substrate 102.

For example, one of the conductor layer A and the conductor layer B is a conductor layer in which it is easy for a current to flow second in the first semiconductor substrate 101, and the other is a conductor layer in which it is easy for a current to flow second in the second semiconductor substrate 102.

For example, one of the conductor layer A and the conductor layer B may not be a conductor layer in which it is most difficult for a current to flow in the first semiconductor substrate 101 or the second semiconductor substrate 102.

For example, both the conductor layer A and the conductor layer B may not be conductor layers in which it is most difficult for a current to flow in the first semiconductor substrate 101 or the second semiconductor substrate 102.

The above-described first can be replaced with third, fourth or N-th (N is a positive number), and the above-described second can also be replaced with third, fourth or N-th (N is a positive number).

The conductor layer in which it is easy for a current to flow in the circuit board, the semiconductor substrate, or the electronic device described above may be considered to be one of a conductor layer in which it is easy for a current to flow in the circuit board, a conductor layer in which it is easy for a current to flow in the semiconductor substrate, and a conductor layer in which it is easy for a current to flow in the electronic device. Further, the conductor layer in which it is difficult for a current to flow in the circuit board, the semiconductor substrate, or the electronic device described above may be considered to be one of a conductor layer in which it is difficult for a current to flow in the circuit board, a conductor layer in which it is difficult for a current to flow in the semiconductor substrate, and a conductor layer in which it is difficult for a current to flow in the electronic device. Further, the conductor layer in which it is easy for a current to flow can be replaced with a conductor layer having a low sheet resistance, and the conductor layer in which it is difficult for a current to flow can be replaced with a conductor layer having high sheet resistance.

A metal such as copper, aluminum, tungsten, chromium, nickel, tantalum, molybdenum, titanium, gold, silver, or iron, or a mixture, compound, or alloy containing at least one of these may be mainly used as a material of the conductor used for the conductor layers A and B. Further, a semiconductor such as silicon, germanium, a compound semiconductor, and an organic semiconductor may be included. Further, an insulating material such as cotton, paper, polyethylene, polyvinyl chloride, natural rubber, polyester, epoxy resin, melamine resin, phenol resin, polyurethane, synthetic resin, mica, asbestos, glass fiber, or porcelain may be included.

The conductor layers A and B forming the light shielding structure 151 can be formed of aggressor conductor loops when a current is passed.

Next, a region shielded by the light shielding structure 151 (a light shielding target region) will be described.

FIG. 7 is a schematic configuration diagram illustrating a planar arrangement example of circuit blocks including a region in which the active element group 167 has been formed in the semiconductor substrate 162.

A of FIG. 7 illustrates an example in which a plurality of circuit blocks 202 to 204 are collectively set as a light shielding target region of the light shielding structure 151, and a region 205 including all of the circuit blocks 202, 203, and 204 is a light shielding target region.

B of FIG. 7 illustrates an example in which the plurality of circuit blocks 202 to 204 are individually set as light shielding target regions of the light shielding structure 151, respective regions 206, 207, and 208 including the circuit blocks 202, 203, and 204 are individual light shielding target regions, and a region 209 other than the regions 206 to 208 is a non-light shielding target region.

In the case of the example illustrated in B of FIG. 7, it is possible to avoid limitation of a degree of freedom in a layout of the conductor layers A and B forming the light shielding structure 151. However, since the layout of the conductor layers A and B becomes complicated, a great amount of labor is required to design the layout of the conductor layers A and B.

In order to easily design the layout of the conductor layers A and B forming the light shielding structure 151, it is preferable for the example illustrated in A of FIG. 7 to be adopted and for the plurality of circuit blocks to be collectively set as the light shielding target region.

Therefore, the present disclosure proposes a structure of the conductor layers A and B of which a layout can be easily designed while avoiding limitation of a degree of freedom in layout of the conductor layers A and B.

Further, in the light shielding target region in the present embodiment, a buffer region is provided so that the vicinity of the circuit blocks is a light shielding target region, in addition to the circuit blocks indicating a region of the active element group 167 serving as a light emitting source for the emitted hot carrier light. By providing the buffer region around the circuit blocks, it is possible to curb leakage of the hot carrier light emitted obliquely from the circuit block into the photodiode 141.

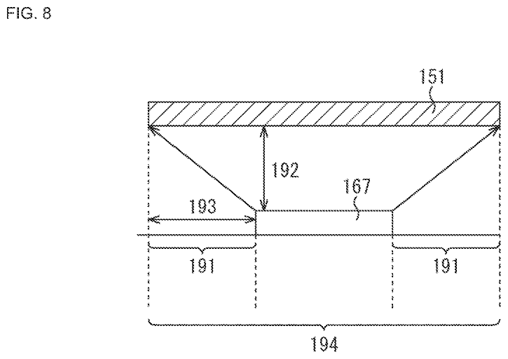

FIG. 8 is a diagram illustrating an example of a positional relationship between the light shielding target region of the light shielding structure 151, a region of the active element group, and the buffer region.

In the example illustrated in FIG. 8, the region in which the active element group 167 has been formed and a buffer region 191 around the active element group 167 are light shielding target regions 194, and the light shielding structure 151 is formed to face the light shielding target region 194.

Here, a length from the active element group 167 to the light shielding structure 151 is an interlayer distance 192. Further, a length from an end portion of the active element group 167 to an end portion of the light shielding structure 151 formed of a wiring is defined as a buffer region width 193.

The light shielding structure 151 is formed so that the buffer region width 193 is larger than the interlayer distance 192. This makes it possible to shield an oblique component of the emitted hot carrier light generated as a point light source.

An appropriate value of the buffer region width 193 changes depending on the interlayer distance 192 between the light shielding structure 151 and the active element group 167. For example, when the interlayer distance 192 is long, it is necessary for the large buffer region 191 to be provided so that it is possible to sufficiently shield the oblique component of the hot carrier light emitted from the active element group 167. On the other hand, when the interlayer distance 192 is short, it is possible to sufficiently shield the hot carrier light emitted from the active element group 167 without providing the large buffer region 191. Therefore, when the light shielding structure 151 is formed by using the wiring layer close to the active element group 167 among the plurality of wiring layers forming the multilayer wiring layer 163, a degree of freedom in the layout of the conductor layers A and B can be improved. However, it is often difficult to form the light shielding structure 151 using the wiring layer close to the active element group 167 due to, for example, a layout constraint of the wiring layer close to the active element group 167. In the present technology, a high degree of freedom in a layout can be obtained even when the light shielding structure 151 is formed using a wiring layer far from the active element group 167.

<4. Configuration Examples of Conductor Layers A and B>

Hereinafter, a configuration example of the conductor layer A (wiring layer 165A) and the conductor layer B (wiring layer 165B) forming the light shielding structure 151, which can be an aggressor conductor loop in the solid-state imaging device 100 to which the present technology has been applied will be described, but a comparative example to be compared with the configuration example will be described first.

### FIRST COMPARATIVE EXAMPLE

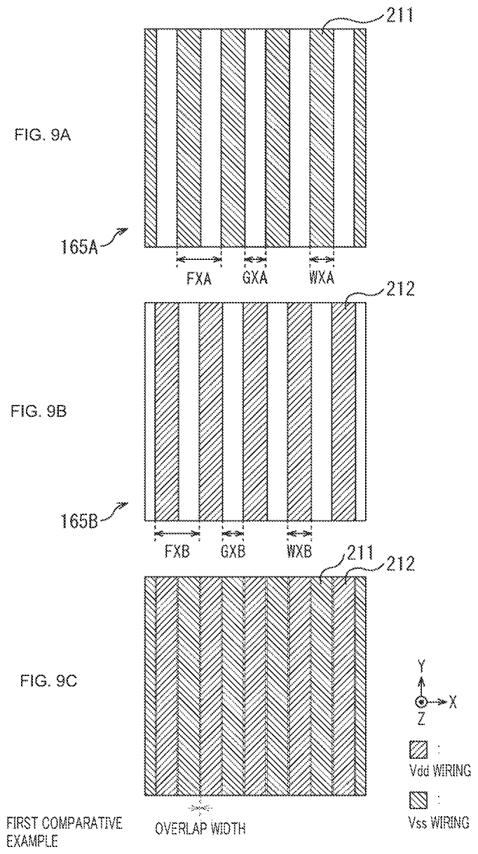

FIG. 9 is a plan view illustrating a first comparative example for comparison with a plurality of configuration examples of the conductor layers A and B forming the light shielding structure 151, which will be described below. A of FIG. 9 illustrates the conductor layer A, and B of FIG. 9 illustrates the conductor layer B. In a coordinate system in FIG. 9, a horizontal direction indicates an X-axis, a vertical direction indicates a Y-axis, and a direction orthogonal to an XY plane indicates a Z-axis.

In the conductor layer A in the first comparative example, straight conductors 211 that are long in the Y direction are periodically arranged in the X direction in a conductor period FXA. The conductor period FXA is a sum of a conductor width WXA in the X direction and a gap width GXA in the X direction. Each straight conductor 211 is, for example, a wiring (Vss wiring) connected to GND or a negative power supply.

In the conductor layer B in the first comparative example, straight conductors 212 that are long in the Y direction are periodically arranged in the X direction in a conductor period FXB. The conductor period FXB=conductor width WXB in the X direction+gap width GXB in the X direction. Each straight conductor 212 is, for example, a wiring (Vdd wiring) connected to a positive power supply. Here, conductor period FXB=conductor period FXA.

Connection destinations of the conductor layers A and B may be exchanged so that each straight conductor 211 is a Vdd wiring and each straight conductor 212 is a Vss wiring.

C of FIG. 9 illustrates a state in which the conductor layers A and B illustrated in A and B of FIG. 9, respectively, are viewed from the photodiode 141 side (back surface side). In the case of the first comparative example, since the straight conductors 211 and 212 are formed so that an overlapping portion in which conductor portions overlap each other is formed when the straight conductor 211 forming the conductor layer A and the straight conductor 212 forming the conductor layer B are arranged in an overlapping manner as illustrated in C of FIG. 9, it is possible to sufficiently shield the hot carrier light emitted from the active element group 167. A width of the overlapping portion is also referred to as an overlap width.

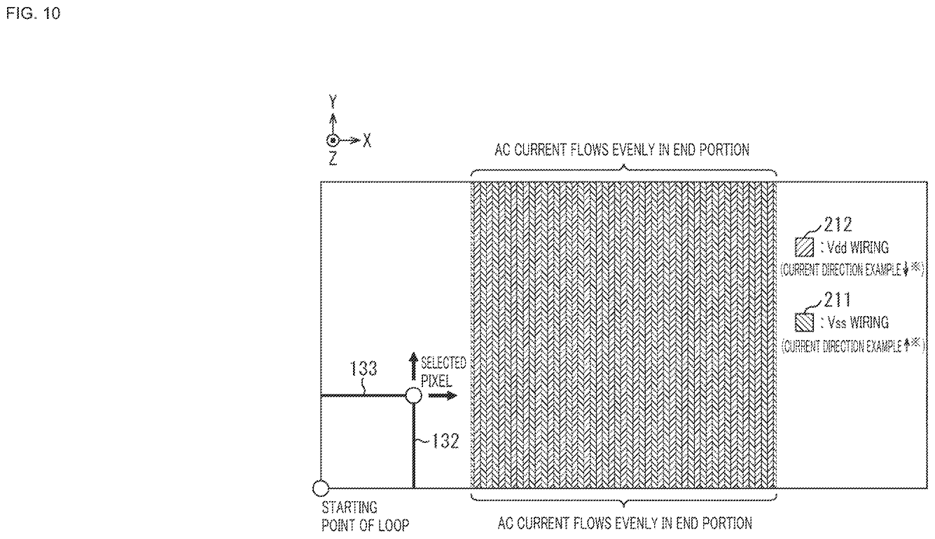

FIG. 10 is a diagram illustrating conditions of a current flowing in the first comparative example (FIG. 9).

It is assumed that an AC current flows evenly in end portions of the straight conductor 211 forming the conductor layer A and the straight conductor 212 forming the conductor layer B. However, it is assumed that a current direction changes with time and, for example, when a current flows through the straight conductor 212 that is the Vdd wiring from the upper side to the lower side of FIG. 10, a current flows through the straight conductor 211 that is the Vss wiring from the lower side to the upper side of FIG. 10.

In the first comparative example, when a current flows as illustrated in FIG. 10, it is easy for a magnetic flux substantially in a Z direction to be generated by a conductor loop having a loop surface substantially parallel to the XY plane, which is formed to include the adjacent straight conductors 211 and 212 in the plan view of FIG. 10, between the straight conductor 211 that is the Vss wiring and the straight conductor 212 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane, as illustrated in FIG. 10. In the victim conductor loop formed on the XY plane, an induced electromotive force is easily generated by the magnetic flux in a Z direction, and when the change in induced electromotive force becomes greater, the image output from the solid-state imaging device 100 deteriorates (inductive noise increases).

Further, since the induced electromotive force is proportional to a dimension of the victim conductor loop depending on a configuration of the aggressor conductor loop, when an effective dimension of the victim conductor loop including the signal line 132 and the control line 133 is changed due to a movement of the selected pixel in the pixel array 121, the change in induced electromotive force becomes significant.

In the case of the first comparative example, since the direction (generally the Z direction) of the magnetic flux generated from the loop surface of the aggressor conductor loop of the light shielding structure 151 including the conductor layers A and B and the direction (the Z direction) of the magnetic flux in which the induced electromotive force is easily generated in the victim conductor loop are substantially the same, deterioration of the image output from the solid-state imaging device 100 (occurrence of inductive noise) is expected.

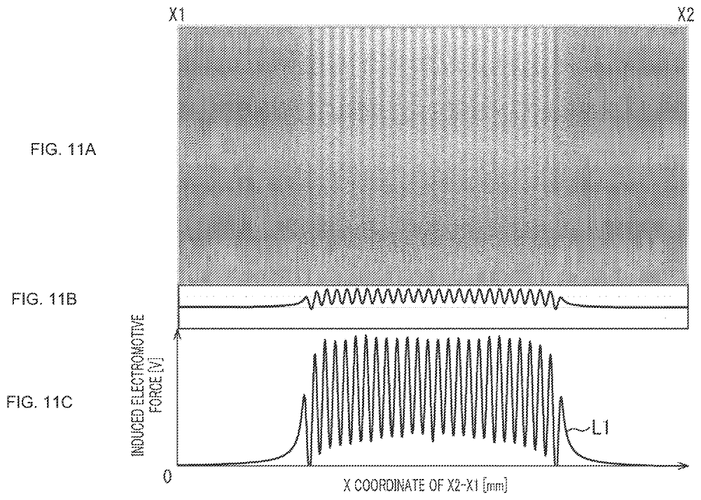

FIG. 11 illustrates results of simulation of inductive noise occurring when the first comparative example is applied to the solid-state imaging device 100.

A of FIG. 11 illustrates an image output from the solid-state imaging device 100, in which inductive noise occurs. B of FIG. 11 illustrates change in pixel signal in a line segment X1-X2 of the image illustrated in A of FIG. 11. C of FIG. 11 illustrates a solid line L1 indicating an induced electromotive force that causes the inductive noise in the image. A horizontal axis in C of FIG. 11 indicates an X-axis coordinate of the image, and a vertical axis indicates a magnitude of the induced electromotive force.

Hereinafter, the solid line L1 illustrated in C of FIG. 11 is used for a comparison with results of simulation of inductive noise occurring when the configuration example of the conductor layers A and B forming the light shielding structure 151 has been applied to the solid-state imaging device 100.

### FIRST CONFIGURATION EXAMPLE

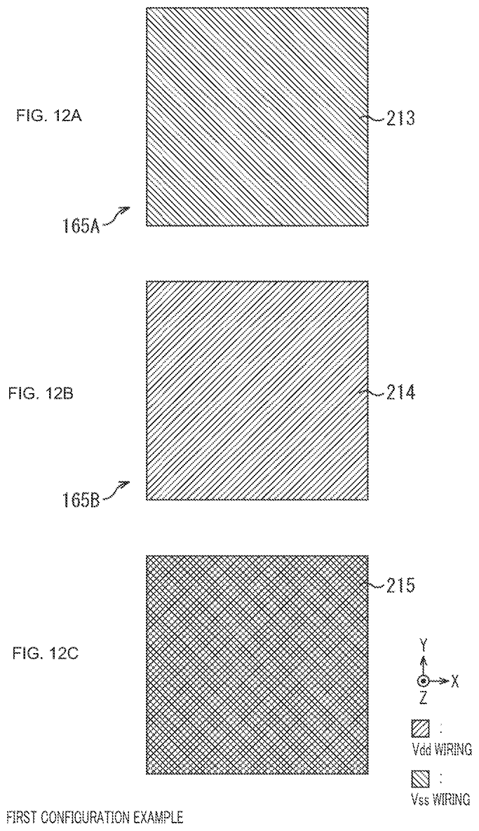

FIG. 12 illustrates a first configuration example of the conductor layers A and B. A of FIG. 12 illustrates the conductor layer A, and B of FIG. 12 illustrates the conductor layer B. In a coordinate system in FIG. 12, a horizontal direction indicates an X-axis, a vertical direction indicates a Y-axis, and a direction orthogonal to an XY plane indicates a Z-axis.

The conductor layer A in the first configuration example includes a planar conductor 213. The planar conductor 213 is, for example, a wiring (Vss wiring) connected to GND or a negative power supply.

The conductor layer B in the first comparative example includes the planar conductor 214. The planar conductor 214 is, for example, a wiring (Vdd wiring) connected to a positive power supply.

Connection destinations of the conductor layers A and B may be exchanged so that the planar conductor 213 is a Vdd wiring and the planar conductor 214 is a Vss wiring. The same applies to each of configuration examples that will be described below.

C of FIG. 12 illustrates a state in which the respective conductor layers A and B illustrated in A and B of FIG. 12 are viewed from the photodiode 141 side (back surface side). However, a hatched region 215 in C of FIG. 12 in which diagonal lines intersect indicates a region in which the planar conductor 213 of the conductor layer A and the planar conductor 214 of the conductor layer B overlap. Therefore, in the case in C of FIG. 12, it is shown that an entire surface of the planar conductor 213 of the conductor layer A and an entire surface of the planar conductor 214 of the conductor layer B overlap. In the case of the first configuration example, since the entire surface of the planar conductor 213 of the conductor layer A and the entire surface of the planar conductor 214 of the conductor layer B overlap each other, it is possible to reliably shield the hot carrier light emitted from the active element group 167.

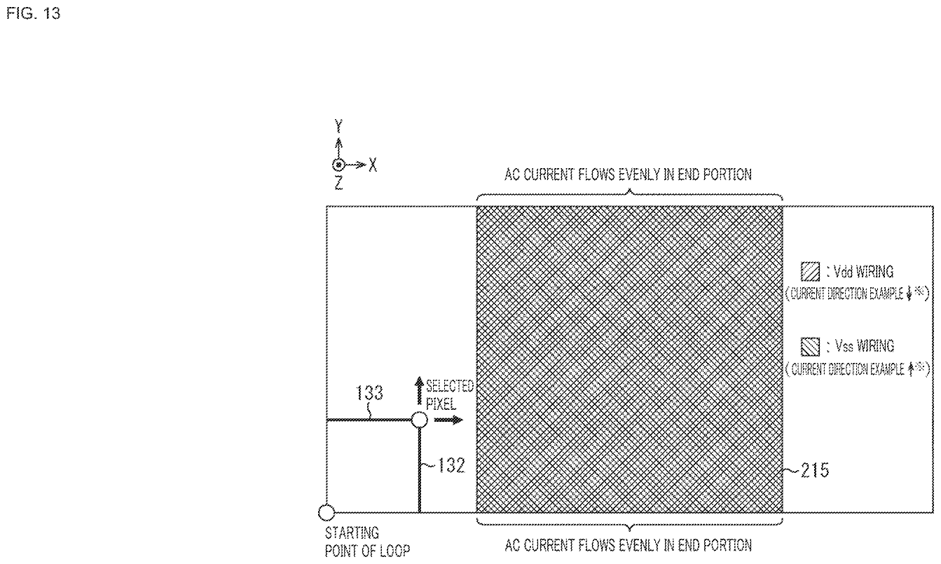

FIG. 13 is a diagram illustrating conditions of a current flowing in the first configuration example (FIG. 12).

It is assumed that an AC current flows evenly in end portions of the planar conductor 213 forming the conductor layer A and the planar conductor 214 forming the conductor layer B. However, it is assumed that a current direction changes with time and, for example, when a current flows through the planar conductor 214 that is the Vdd wiring from the upper side to the lower side of FIG. 13, a current flows through the planar conductor 213 that is the Vss wiring from the lower side to the upper side of FIG. 13.

In the first configuration example, when a current flows as illustrated in FIG. 13, a magnetic flux in substantially an X direction and substantially a Y direction is easily generated by a conductor loop having a loop surface substantially orthogonal to the X-axis and a conductor loop having a loop surface substantially orthogonal to the Y-axis, which are formed to include (cross-sections of) the planar conductors 213 and 214 in a cross-section on which the planar conductors 213 and 214 are arranged between the planar conductor 213 that is the Vss wiring and the planar conductor 214 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane, as illustrated in FIG. 13. In the victim conductor loop formed on the XY plane, an induced electromotive force is easily generated by the magnetic flux in the Z direction, and when the change in induced electromotive force becomes greater, the image output from the solid-state imaging device 100 deteriorates (inductive noise increases).

Further, when the effective dimension of the victim conductor loop including the signal line 132 and the control line 133 is changed due to the movement of the selected pixel in the pixel array 121, the change in induced electromotive force becomes significant.

In the case of the first configuration example, the direction (generally the X direction or generally the Y direction) of the magnetic flux generated from the loop surface of the aggressor conductor loop of the light shielding structure 151 including the conductor layers A and B and the direction (the Z direction) of the magnetic flux that generates the induced electromotive force in the victim conductor loop are substantially orthogonal to each other and differ by about 90 degrees. In other words, the direction of the loop surface on which the magnetic flux occurs from the aggressor conductor loop and the direction of the loop surface on which the induced electromotive force occurs in the victim conductor loop differ by about 90 degrees. Thus, the deterioration of the image output from the solid-state imaging device 100 (occurrence of inductive noise) is expected to be less than that in the case of the first comparative example.

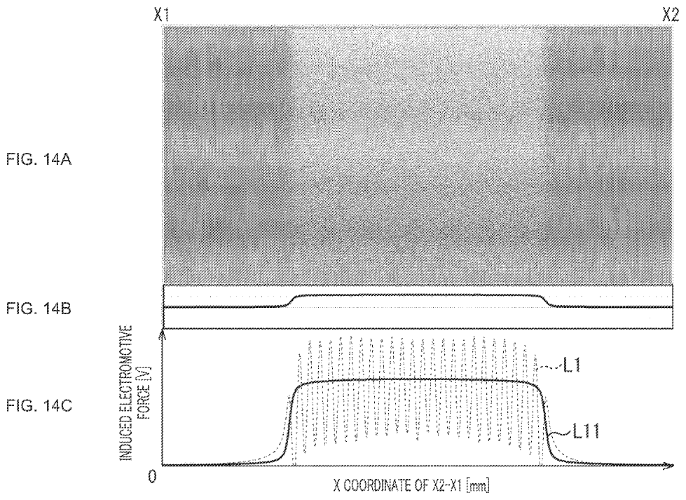

FIG. 14 illustrates results of simulation of inductive noise occurring when the first configuration example (FIG. 12) is applied to the solid-state imaging device 100.

A of FIG. 14 illustrates an image output from the solid-state imaging device 100, in which inductive noise can occur. B of FIG. 14 illustrates change in pixel signal in a line segment X1-X2 of the image illustrated in A of FIG. 14. C of FIG. 14 illustrates a solid line L11 indicating an induced electromotive force that causes the inductive noise in the image. A horizontal axis in C of FIG. 14 indicates an X-axis coordinate of the image, and a vertical axis indicates a magnitude of the induced electromotive force. A dotted line L1 in C of FIG. 14 corresponds to the first comparative example (FIG. 9).

As is clear from a comparison of the solid line L11 with the dotted line L1 illustrated in C of FIG. 14, in the first configuration example, it is possible to curb change in the induced electromotive force generated in the victim conductor loop, as compared with the first comparative example. Therefore, it is possible to curb the occurrence of inductive noise in the image output from the solid-state imaging device 100.

### SECOND CONFIGURATION EXAMPLE

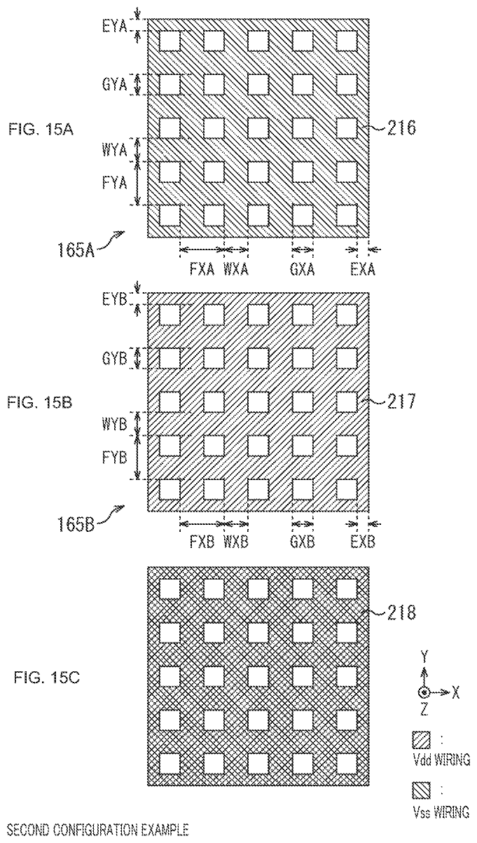

FIG. 15 illustrates a second configuration example of the conductor layers A and B. A of FIG. 15 illustrates the conductor layer A, and B of FIG. 15 illustrates the conductor layer B. In a coordinate system in FIG. 15, a horizontal direction indicates an X-axis, a vertical direction indicates a Y-axis, and a direction orthogonal to an XY plane indicates a Z-axis.

The conductor layer A in the second configuration example includes a mesh conductor 216. In the mesh conductor 216, a conductor width in the X direction is WXA, a gap width is GXA, a conductor period is FXA (=conductor width WXA+gap width GXA), and an end portion width is EXA (=conductor width WXA/2). Further, in the mesh conductor 216, a conductor width in the Y direction is WYA, a gap width is GYA, a conductor period is FYA (=conductor width WYA+gap width GYA), and an end portion width is EYA (=conductor width WYA/2). The mesh conductor 216 is, for example, a wiring (Vss wiring) connected to GND or a negative power supply.

The conductor layer B in the second configuration example includes a mesh conductor 217. In the mesh conductor 217, a conductor width in the X direction is WXB, a gap width is GXB, a conductor period is FXB (=conductor width WXB+gap width GXB), and an end portion width is EXB (=conductor width WXB/2). Further, in the mesh conductor 217, a conductor width in the Y direction is WYB, a gap width is GYB, a conductor period is FYB (=conductor width WYB+gap width GYB), and an end portion width is EYB (=conductor width WYB/2). The mesh conductor 217 is, for example, a wiring (Vdd wiring) connected to a positive power supply.

It is preferable for the mesh conductor 216 and the mesh conductor 217 to satisfy the following relationships.

conductor width WXA=conductor width WYA=conductor width WXB=conductor width WYB

gap width GXA=gap width GYA=gap width GXB=gap width GYB end portion width EXA=end portion width EYA=end portion width EXB=end portion width EYB

conductor period FXA=conductor period FYA=conductor period FXB=conductor period FYB

C of FIG. 15 illustrates a state in which the respective conductor layers A and B illustrated in A and B of FIG. 15 are viewed from the photodiode 141 side (back surface side). However, a hatched region 218 in C of FIG. 15 in which diagonal lines intersect indicates a region in which the mesh conductor 216 of the conductor layer A and the mesh conductor 217 of the conductor layer B overlap. In the case of the second configuration example, since a gap between the mesh conductors 216 forming the conductor layer A and a gap between the mesh conductors 217 forming the conductor layer B match, it is not possible to sufficiently shield the hot carrier light emitted from the active element group 167. However, it is possible to curb the occurrence of inductive noise, as described below.

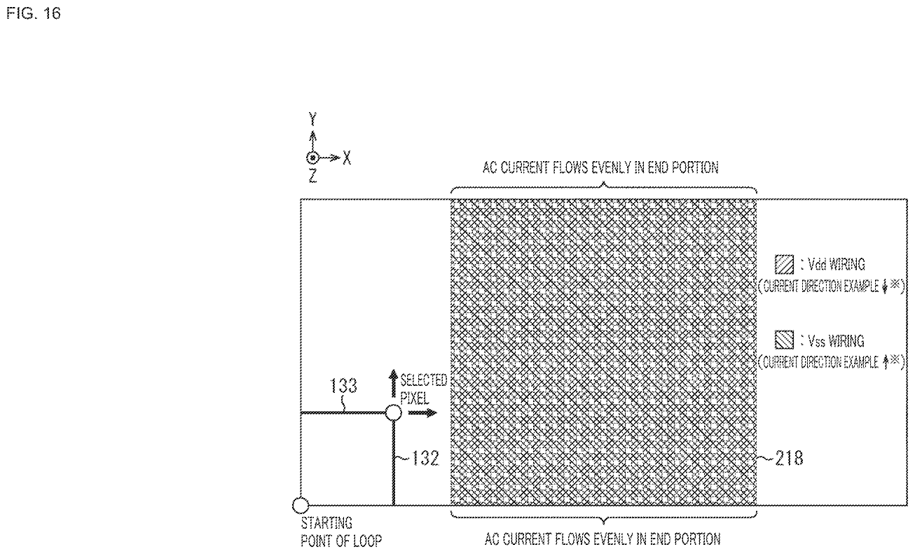

FIG. 16 is a diagram illustrating conditions of a current flowing in the second configuration example (FIG. 15).

It is assumed that an AC current flows evenly in end portions of the mesh conductor 216 forming the conductor layer A and the mesh conductor 217 forming the conductor layer B. However, it is assumed that a current direction changes with time and, for example, when a current flows through the mesh conductor 217 that is the Vdd wiring from the upper side to the lower side of FIG. 16, a current flows through the mesh conductor 216 that is the Vss wiring from the lower side to the upper side of FIG. 16.

In the second configuration example, when a current flows as illustrated in FIG. 16, a magnetic flux in a substantially X direction and substantially a Y direction is easily generated by a conductor loop having a loop surface substantially orthogonal to the X-axis and a conductor loop having a loop surface substantially orthogonal to the Y-axis, which are formed to include (cross-sections of) the mesh conductors 216 and 217 in a cross-section on which the mesh conductors 216 and 217 are arranged between the mesh conductor 216 that is the Vss wiring and the mesh conductor 217 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane, as illustrated in FIG. 16. In the victim conductor loop formed on the XY plane, an induced electromotive force is easily generated by the magnetic flux in the Z direction, and when the change in induced electromotive force becomes greater, the image output from the solid-state imaging device 100 deteriorates (inductive noise increases).

Further, when the effective dimension of the victim conductor loop including the signal line 132 and the control line 133 is changed due to the movement of the selected pixel in the pixel array 121, the change in induced electromotive force becomes significant.

In the case of the second configuration example, the direction (generally the X direction or generally the Y direction) of the magnetic flux generated from the loop surface of the aggressor conductor loop of the light shielding structure 151 including the conductor layers A and B and the direction (the Z direction) of the magnetic flux that generates the induced electromotive force in the victim conductor loop are substantially orthogonal to each other and differ by about 90 degrees. In other words, the direction of the loop surface on which the magnetic flux occurs from the aggressor conductor loop and the direction of the loop surface on which the induced electromotive force occurs in the victim conductor loop differ by about 90 degrees. Thus, the deterioration of the image output from the solid-state imaging device 100 (occurrence of inductive noise) is expected to be less than that in the case of the first comparative example.

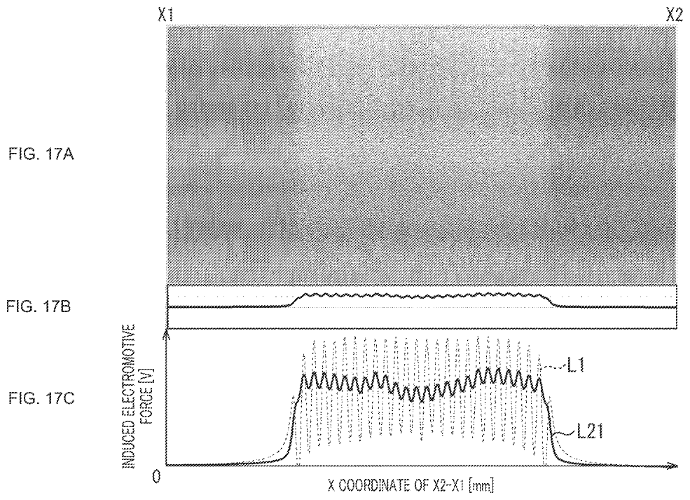

FIG. 17 illustrates results of simulation of inductive noise occurring when the second configuration example (FIG. 15) is applied to the solid-state imaging device 100.

A of FIG. 17 illustrates an image output from the solid-state imaging device 100, in which inductive noise can occur. B of FIG. 17 illustrates change in pixel signal in a line segment X1-X2 of the image illustrated in A of FIG. 17. C of FIG. 17 illustrates a solid line L21 indicating an induced electromotive force that causes the inductive noise in the image. A horizontal axis in C of FIG. 17 indicates an X-axis coordinate of the image, and a vertical axis indicates a magnitude of the induced electromotive force. A dotted line L1 in C of FIG. 17 corresponds to the first comparative example (FIG. 9).

As is clear from a comparison of the solid line L21 with the dotted line L1 illustrated in C of FIG. 17, in the second configuration example, it is possible to curb change in the induced electromotive force generated in the victim conductor loop, as compared with the first comparative example. Therefore, it is possible to curb the occurrence of inductive noise in the image output from the solid-state imaging device 100.

### SECOND COMPARATIVE EXAMPLE

In the second configuration example (FIG. 15), conductor period FXA=conductor period FYA=conductor period FXB =conductor period FYB is satisfied as a relationship between the mesh conductor 216 forming the conductor layer A and the mesh conductor 217 forming the conductor layer B.

Thus, when the conductor period FXA of the conductor layer A in the X direction, the conductor period FYA of the conductor layer A in the Y direction, the conductor period FXB of the conductor layer B in the X direction, and the conductor period FYB of the conductor layer B in the X direction match, it is possible to curb the occurrence of inductive noise.

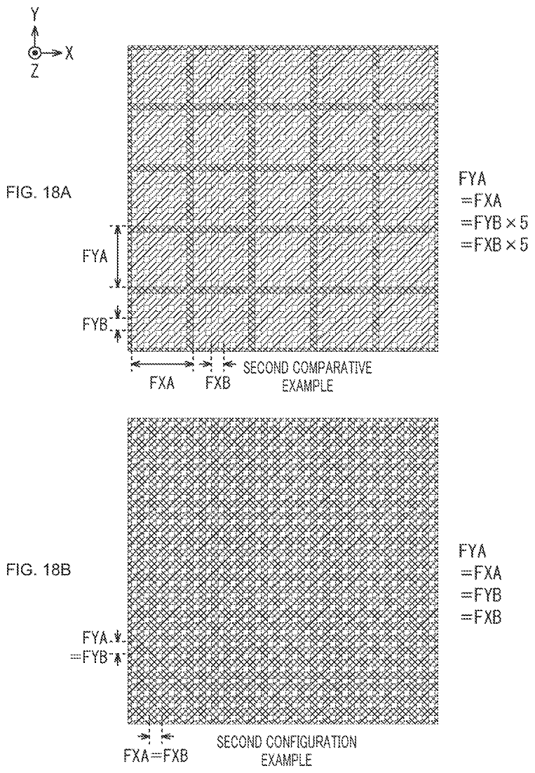

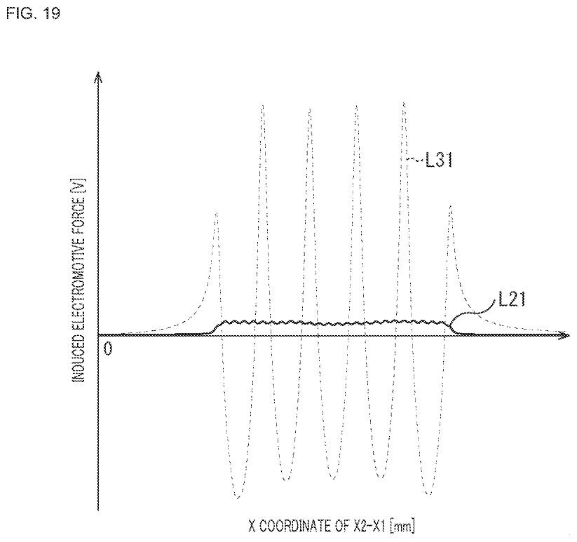

FIGS. 18 and 19 are diagrams illustrating that it is possible to curb the occurrence of inductive noise when the conductor periods of both the conductor layer A and the conductor layer B match.

A of FIG. 18 illustrates a second comparative example which is a modification of the second configuration example for comparison with the second configuration example illustrated in FIG. 15, and in the second comparative example, the gap width GXA in the X direction and the gap width GYA in the Y direction of the mesh conductor 216 forming the conductor layer A in the second configuration example are increased, and the conductor period FXA in the X direction and the conductor period FYA in the Y direction are five times those in the second configuration example. It is assumed that the mesh conductor 217 forming the conductor layer B in the second comparative example is the same as that in the second configuration example. B of FIG. 18 illustrates the second configuration example illustrated in C of FIG. 15 at the same magnification as in A of FIG. 18.

FIG. 19 illustrates change in induced electromotive force that causes inductive noise in an image, as results of simulation when the second comparative example (A of FIG. 18) and the second configuration example (B of FIG. 18) are applied to the solid-state imaging device 100. Conditions of a current flowing in the second comparative example are the same as those illustrated in FIG. 16. A horizontal axis of FIG. 19 indicates an X-axis coordinate of the image, and a vertical axis indicates a magnitude of the induced electromotive force.

The solid line L21 in FIG. 19 corresponds to the second configuration example, and a dotted line L31 corresponds to the second comparative example.

As is clear from a comparison of the solid line L21 with the dotted line L31, it can be seen that in the second configuration example, it is possible to curb change in the induced electromotive force generated in the victim conductor loop and to curb the inductive noise, as compared with the second comparative example.

### THIRD COMPARATIVE EXAMPLE

Incidentally, even when the conductor width of the mesh conductor forming the conductor layer A in the second comparative example is widened, it is possible to curb the occurrence of inductive noise.

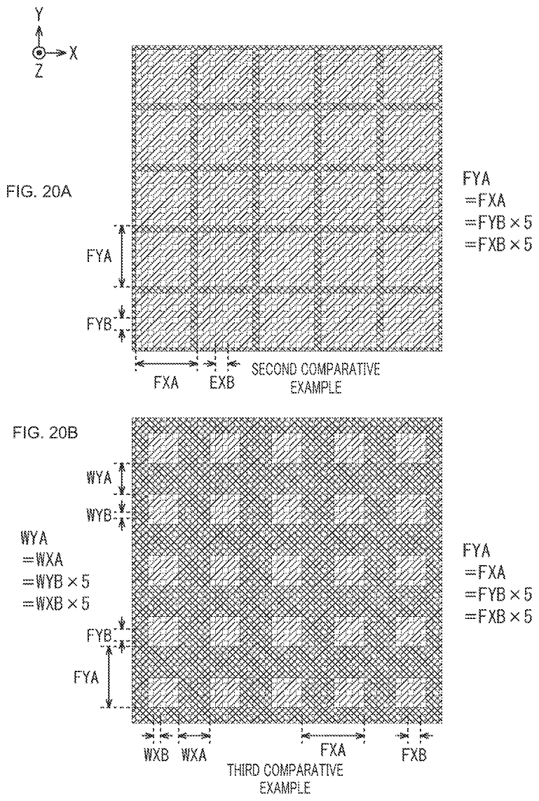

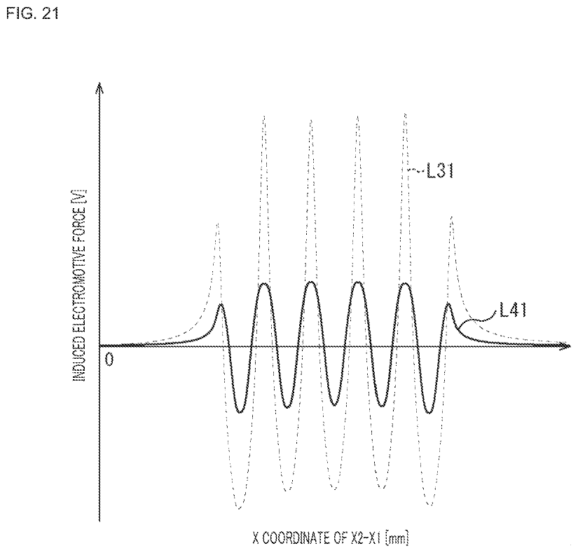

FIGS. 20 and 21 are diagrams illustrating that it is possible to curb the occurrence of inductive noise when the conductor width of the mesh conductor forming the conductor layer A is widened.

A of FIG. 20 illustrates the second comparative example illustrated in A of FIG. 18 again.

B of FIG. 20 illustrates a third comparative example which is a modification example of the second configuration example for comparison with the second comparative example, and in the third comparative example, conductor widths WXA and WYA in an X direction and a Y direction of the mesh conductor 216 forming the conductor layer A in the second configuration example are increased to five times those in the second configuration example. The mesh conductor 217 forming the conductor layer B in the third comparative example is the same as that in the second configuration example.

FIG. 21 illustrates change in induced electromotive force that causes inductive noise in an image, as results of simulation when the third comparative example and the second configuration example are applied to the solid-state imaging device 100. Conditions of a current flowing in the third comparative example are the same as those illustrated in FIG. 16. A horizontal axis of FIG. 21 indicates an X-axis coordinate of the image, and a vertical axis indicates a magnitude of the induced electromotive force.

A solid line L41 in FIG. 21 corresponds to the third comparative example, and a dotted line L31 corresponds to the second comparative example.

As is clear from a comparison of the solid line L41 with the dotted line L31, it can be seen that in the third configuration example, it is possible to curb change in the induced electromotive force generated in the victim conductor loop and to curb the inductive noise, as compared with the second comparative example.

### THIRD CONFIGURATION EXAMPLE

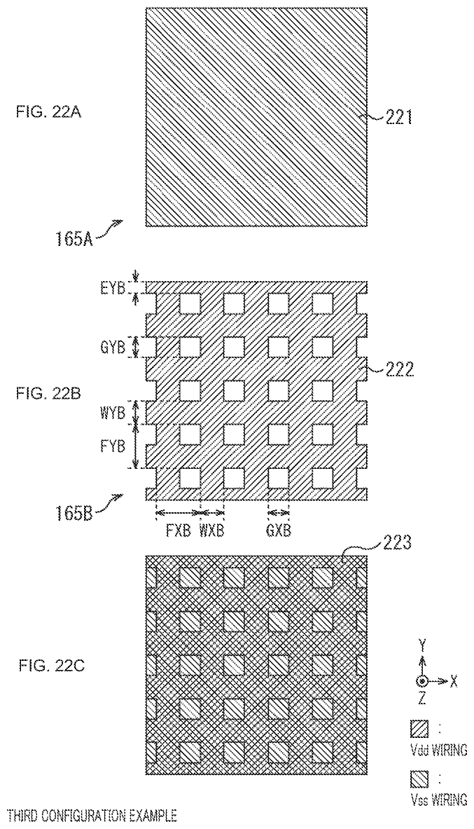

Next, FIG. 22 illustrates a third configuration example of the conductor layers A and B. A of FIG. 22 illustrates the conductor layer A, and B of FIG. 22 illustrates the conductor layer B. In a coordinate system in FIG. 22, a horizontal direction indicates an X-axis, a vertical direction indicates a Y-axis, and a direction orthogonal to an XY plane indicates a Z-axis.

The conductor layer A in the third configuration example includes a planar conductor 221. The planar conductor 221 is, for example, a wiring (Vss wiring) connected to GND or a negative power supply.

The conductor layer B in the third configuration example includes a mesh conductor 222. It is assumed that a conductor width in the X direction of the mesh conductor 222 is WXB, a gap width is GXB, and a conductor period is FXB (=conductor width WXB+gap width GXB). Further, it is assumed that a conductor width in the Y direction of the mesh conductor 222 is WYB, a gap width is GYB, a conductor period is FYB (=conductor width WYB+gap width GYB), and an end portion width is EYB. The mesh conductor 222 is, for example, a wiring (Vdd wiring) connected to a positive power supply.

It is preferable for the mesh conductor 222 to satisfy the following relationships.

conductor width WXB=conductor width WYB

gap width GXB=gap width GYB

end portion width EYB=conductor width WYB/2

conductor period FXB=conductor period FYB

A wiring resistance and a wiring impedance of the mesh conductor 222 become uniform in the X and Y directions by aligning the conductor width, the conductor period, and the gap width in the X and Y directions as in the relationship described above and thus, it is possible to make a magnetic field resistance or a voltage drop even in the X direction and the Y direction.

Further, it is possible to curb the induced electromotive force generated in the victim conductor loop due to a magnetic field generated around an end portion of the mesh conductor 222 by setting the end portion width EYB to ½ of the conductor width WYB.

C of FIG. 22 illustrates a state in which the respective conductor layers A and B illustrated in A and B of FIG. 22 are viewed from the photodiode 141 side (back surface side). However, a hatched region 223 in C of FIG. 22 in which diagonal lines intersect indicates a region in which the planar conductor 221 of the conductor layer A and the mesh conductor 222 of the conductor layer B overlap. In the case of the third configuration example, since the active element group 167 is covered with at least one of the conductor layer A and the conductor layer B, it is possible to shield the hot carrier light emitted from the active element group 167.

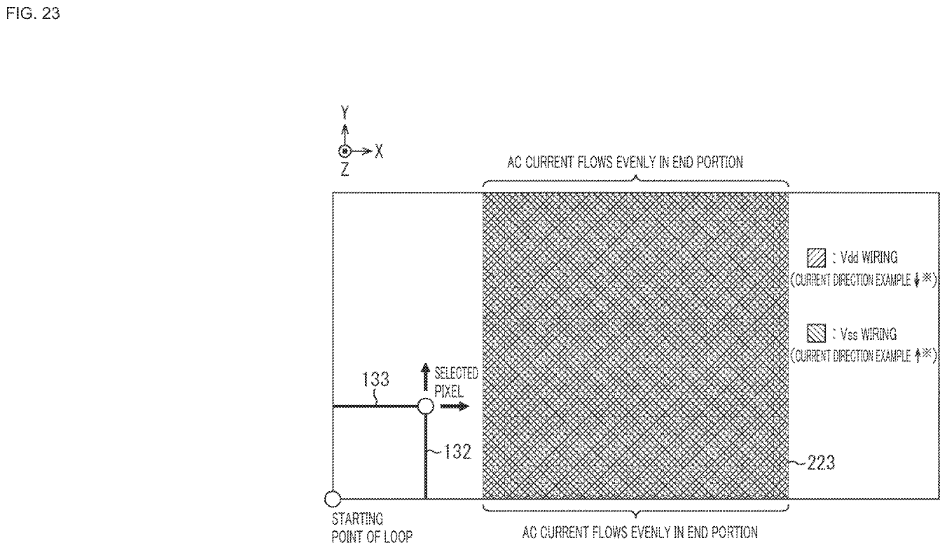

FIG. 23 is a diagram illustrating conditions of a current flowing in the third configuration example (FIG. 22).

It is assumed that an AC current flows evenly in end portions of the planar conductor 221 forming the conductor layer A and the mesh conductor 222 forming the conductor layer B. However, it is assumed that a current direction changes with time and, for example, when a current flows through the mesh conductor 222 that is the Vdd wiring from the upper side to the lower side of FIG. 23, a current flows through the planar conductor 221 that is the Vss wiring from the lower side to the upper side of FIG. 23.

In the third configuration example, when a current flows as illustrated in FIG. 23, a magnetic flux in substantially an X direction and substantially a Y direction is easily generated by a conductor loop having a loop surface substantially orthogonal to the X-axis and a conductor loop having a loop surface substantially orthogonal to the Y-axis, which are formed to include (cross-sections of) the planar conductor 221 and the mesh conductor 222 in a cross-section on which the planar conductors 221 and the mesh conductor 222 are arranged between the planar conductor 221 that is the Vss wiring and the mesh conductor 222 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane. In the victim conductor loop formed on the XY plane, an induced electromotive force is easily generated by the magnetic flux in the Z direction, and when the change in induced electromotive force becomes greater, the image output from the solid-state imaging device 100 deteriorates (inductive noise increases).

Further, when the effective dimension of the victim conductor loop including the signal line 132 and the control line 133 is changed due to the movement of the selected pixel in the pixel array 121, the change in induced electromotive force becomes significant.

In the case of the third configuration example, the direction (generally the X direction or generally the Y direction) of the magnetic flux generated from the loop surface of the aggressor conductor loop of the light shielding structure 151 including the conductor layers A and B and the direction (the Z direction) of the magnetic flux that generates the induced electromotive force in the victim conductor loop are substantially orthogonal to each other and differ by about 90 degrees. In other words, the direction of the loop surface on which the magnetic flux occurs from the aggressor conductor loop and the direction of the loop surface on which the induced electromotive force occurs in the victim conductor loop differ by about 90 degrees. Thus, the deterioration of the image output from the solid-state imaging device 100 (occurrence of inductive noise) is expected to be less than that in the case of the first comparative example.

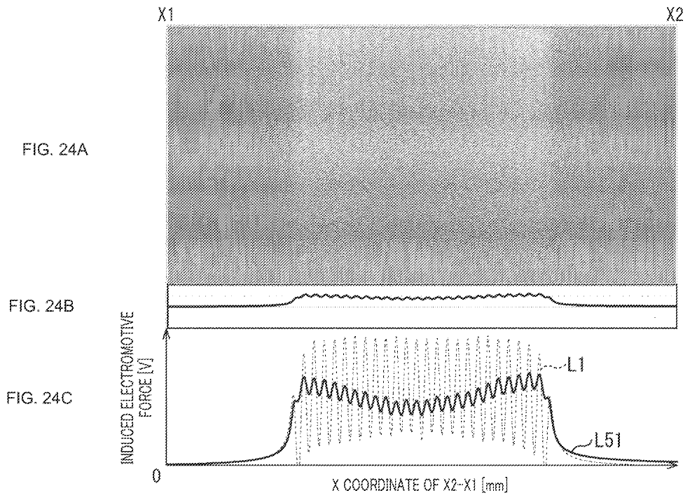

FIG. 24 illustrates results of simulation of inductive noise occurring when the third configuration example (FIG. 22) is applied to the solid-state imaging device 100.

A of FIG. 24 illustrates an image output from the solid-state imaging device 100, in which inductive noise can occur. B of FIG. 24 illustrates change in pixel signal in a line segment X1-X2 of the image illustrated in A of FIG. 24. C of FIG. 24 illustrates a solid line L51 indicating an induced electromotive force that causes the inductive noise in the image. A horizontal axis in C of FIG. 24 indicates an X-axis coordinate of the image, and a vertical axis indicates a magnitude of the induced electromotive force. A dotted line L1 in C of FIG. 24 corresponds to the first comparative example (FIG. 9).

As is clear from a comparison of the solid line L51 with the dotted line L1 illustrated in C of FIG. 24, in the third configuration example, it is possible to curb change in the induced electromotive force generated in the victim conductor loop, as compared with the first comparative example. Therefore, it is possible to curb the occurrence of inductive noise in the image output from the solid-state imaging device 100.

### FOURTH CONFIGURATION EXAMPLE

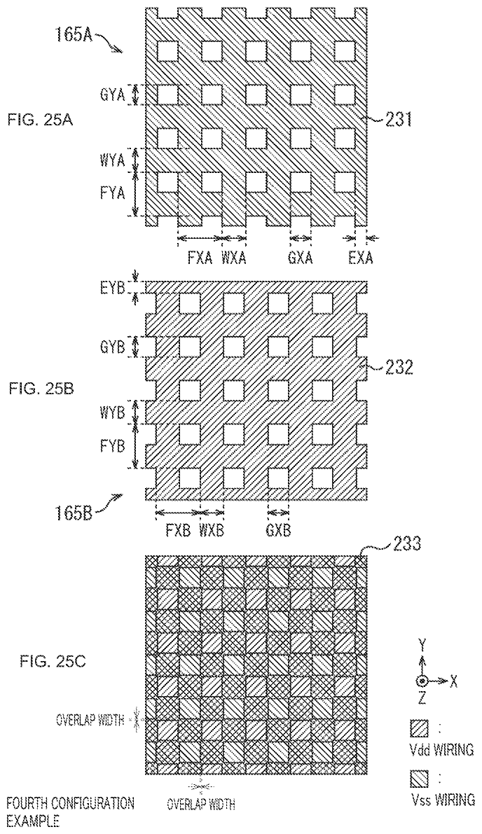

Next, FIG. 25 illustrates a fourth configuration example of the conductor layers A and B. A of FIG. 25 illustrates the conductor layer A, and B of FIG. 25 illustrates the conductor layer B. In a coordinate system in FIG. 25, a horizontal direction indicates an X-axis, a vertical direction indicates a Y-axis, and a direction orthogonal to an XY plane indicates a Z-axis.

The conductor layer A in the fourth configuration example includes the mesh conductor 231. In the mesh conductor 231, a conductor width in an X direction is WXA, a gap width is GXA, a conductor period is FXA (=conductor width WXA+gap width GXA), and an end portion width is EXA (=conductor width WXA/2). A conductor width in the Y direction of the mesh conductor 231 is WYA, a gap width is GYA, and a conductor period is FYA (=conductor width WYA+gap width GYA). The mesh conductor 231 is, for example, a wiring (Vss wiring) connected to GND or a negative power supply.

The conductor layer B in the fourth configuration example includes a mesh conductor 232. It is assumed that a conductor width in the X direction of the mesh conductor 232 is WXB, a gap width is GXB, and a conductor period is FXB (=conductor width WXB+gap width GXB). Further, it is assumed that a conductor width in the Y direction of the mesh conductor 232 is WYB, a gap width is GYB, a conductor period is FYB (=conductor width WYB+gap width GYB), and an end portion width is EYB (=conductor width WYB/2). The mesh conductor 232 is, for example, a wiring (Vdd wiring) connected to a positive power supply.

It is preferable for the mesh conductor 231 and the mesh conductor 232 to satisfy the following relationships.

conductor width WXA=conductor width WYA=conductor width WXB=conductor width WYB

gap width GXA=gap width GYA=gap width GXB=gap width GYB end portion width EXA=end portion width EYB

conductor period FXA=conductor period FYA=conductor period FXB=conductor period FYB

conductor width WYA=2×overlap width+gap width GYA, conductor width WXA=2×overlap width+gap width GXA

conductor width WYB=2×overlap width+gap width GYB, conductor width WXB=2×overlap width+gap width GXB

Here, the overlap width is a width of an overlapping portion in which conductor portions overlap when the mesh conductor 231 of the conductor layer A and the mesh conductor 232 of the conductor layer B are arranged in an overlapping manner.

Since a current distribution of the mesh conductor 231 and a current distribution of the mesh conductor 232 are substantially uniform and have opposite characteristics by aligning both the conductor periods in the X direction and the Y direction of the mesh conductor 231 and the mesh conductor 232 as in the relationship described above, a magnetic field generated by the current distribution of the mesh conductor 231 and a magnetic field generated by the current distribution of the mesh conductor 232 can be effectively offset.

Further, a wiring resistance and a wiring impedance of the mesh conductor 231 and the mesh conductor 232 become uniform in the X and Y directions by aligning the conductor width, the conductor period, and the gap width of the mesh conductor 231 and the mesh conductor 232 in the X and Y directions and thus, it is possible to make a magnetic field resistance or a voltage drop even in the Y direction and the Y direction.

Further, it is possible to curb an induced electromotive force generated in the victim conductor loop due to a magnetic field generated around an end portion of the mesh conductor 231 by setting the end portion width EXA of the mesh conductor 231 to ½ of the conductor width WXA. Further, it is possible to curb an induced electromotive force generated in the victim conductor loop due to a magnetic field generated around an end portion of the mesh conductor 231 by setting the end portion width EYB of the mesh conductor 232 to ½ of the conductor width WYB.

An end portion of the mesh conductor 232 of the conductor layer B in the X direction may be provided instead of the end portion of the mesh conductor 231 of the conductor layer A in the X direction being provided. Further, an end portion of the mesh conductor 231 of the conductor layer A in the Y direction may be provided instead of the end portion of the mesh conductor 232 of the conductor layer B in the Y direction being provided.

C of FIG. 25 illustrates a state in which the respective conductor layers A and B illustrated in A and B of FIG. 25 are viewed from the photodiode 141 side (back surface side). However, a hatched region 233 in C of FIG. 25 in which diagonal lines intersect indicates a region in which the mesh conductor 231 of the conductor layer A and the mesh conductor 232 of the conductor layer B overlap. In the case of the fourth configuration example, since the active element group 167 is covered with at least one of the conductor layer A and the conductor layer B, it is possible to shield the hot carrier light emitted from the active element group 167.

Here, the following relationships must be satisfied in order to completely shield the emitted hot carrier light using the mesh conductor 231 of the conductor layer A and the mesh conductor 232 of the conductor layer B.

conductor width WYA≥Gap width GYA

conductor width WXA≥gap width GXA

conductor width WYB≥gap width GYB

conductor width WXB≥gap width GXB

In this case, the following relationships are satisfied.

conductor width WYA=2×overlap width+gap width GYA

conductor width WXA=2×overlap width+gap width GXA

conductor width WYB=2×overlap width+gap width GYB

conductor width WXB=2×overlap width+gap width GXB

In the fourth configuration example, when a current flows as in the case illustrated in FIG. 23, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 231 and 232 in a cross-section on which the mesh conductors 231 and 232 are arranged between the mesh conductor 231 that is the Vss wiring and the mesh conductor 232 that is the Vdd wiring.

### FIFTH CONFIGURATION EXAMPLE

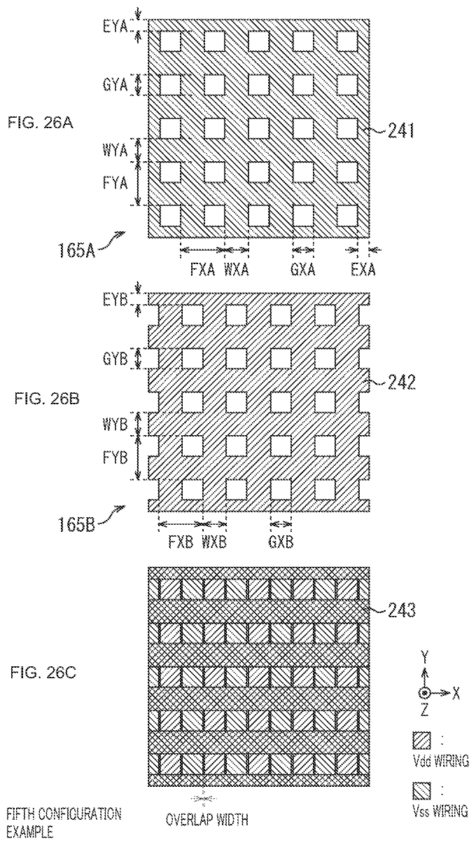

Next, FIG. 26 illustrates a fifth configuration example of the conductor layers A and B. A of FIG. 26 illustrates the conductor layer A, and B of FIG. 26 illustrates the conductor layer B. In a coordinate system in FIG. 26, a horizontal direction indicates an X-axis, a vertical direction indicates a Y-axis, and a direction orthogonal to an XY plane indicates a Z-axis.

The conductor layer A in the fifth configuration example includes a mesh conductor 241. The mesh conductor 241 is obtained by moving the mesh conductor 231 forming the conductor layer A in the fourth configuration example (FIG. 25) by a conductor period FYA/2 in the Y direction. The mesh conductor 241 is, for example, a wiring (Vss wiring) connected to GND or a negative power supply.

The conductor layer B in the fifth configuration example includes a mesh conductor 242. Since the mesh conductor 242 has the same shape as the mesh conductor 232 forming the conductor layer B in the fourth configuration example (FIG. 25), description thereof will be omitted. The mesh conductor 242 is, for example, a wiring (Vdd wiring) connected to a positive power supply.

It is preferable for the mesh conductor 241 and the mesh conductor 242 to satisfy the following relationships.

conductor width WXA=conductor width WYA=conductor width WXB=conductor width WYB

gap width GXA=gap width GYA=gap width GXB=gap width GYB end portion width EXA=end portion width EYB

conductor period FXA=conductor period FYA=conductor period FXB=conductor period FYB

conductor width WYA=2×overlap width+gap width GYA, conductor width WXA=2×overlap width+gap width GXA

conductor width WYB=2×overlap width+gap width GYB, conductor width WXB=2×overlap width+gap width GXB

Here, the overlap width is a width of an overlapping portion in which conductor portions overlap when the mesh conductor 241 of the conductor layer A and the mesh conductor 242 of the conductor layer B are arranged in an overlapping manner.

C of FIG. 26 illustrates a state in which the respective conductor layers A and B illustrated in A and B of FIG. 26 are viewed from the photodiode 141 side (back surface side). However, a hatched region 243 in C of FIG. 26 in which diagonal lines intersect indicates a region in which the mesh conductor 241 of the conductor layer A and the mesh conductor 242 of the conductor layer B overlap. In the case of the fifth configuration example, since the active element group 167 is covered with at least one of the conductor layer A and the conductor layer B, it is possible to shield the hot carrier light emitted from the active element group 167.

Further, in the case of the fifth configuration example, a region 243 in which the mesh conductor 241 and the mesh conductor 242 overlap is continuous in the X direction. In the region 243 in which the mesh conductor 241 and the mesh conductor 242 overlap, since currents having different polarities flow through the mesh conductor 241 and the mesh conductor 242, magnetic fields generated from the region 243 are offset. Therefore, it is possible to curb the occurrence of inductive noise near the region 243.

In the fifth configuration example, when a current flows as in the case illustrated in FIG. 23, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 241 and 242 in a cross-section on which the mesh conductors 241 and 242 are arranged between the mesh conductor 241 that is the Vss wiring and the mesh conductor 242 that is the Vdd wiring.

### SIXTH CONFIGURATION EXAMPLE

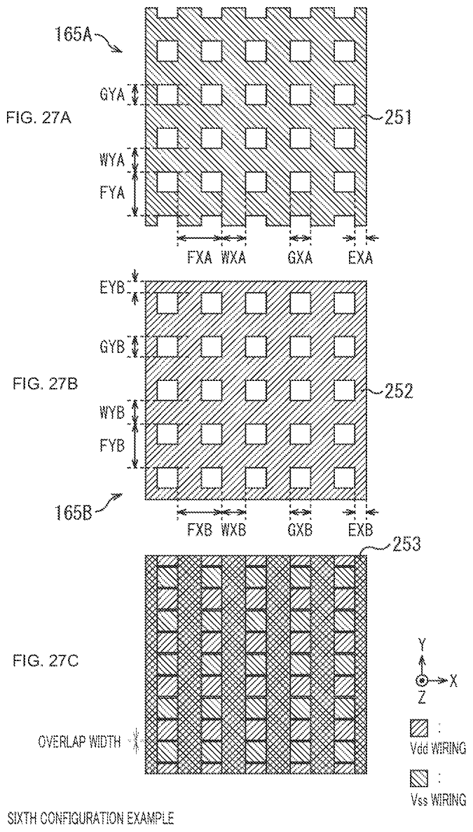

Next, FIG. 27 illustrates a sixth configuration example of the conductor layers A and B. A of FIG. 27 illustrates the conductor layer A, and B of FIG. 27 illustrates the conductor layer B. In a coordinate system in FIG. 27, a horizontal direction indicates an X-axis, a vertical direction indicates a Y-axis, and a direction orthogonal to an XY plane indicates a Z-axis.

The conductor layer A in the sixth configuration example includes a mesh conductor 251. Since the mesh conductor 251 has the same shape as the mesh conductor 231 forming the conductor layer A in the fourth configuration example (FIG. 25), description thereof will be omitted. The mesh conductor 251 is, for example, a wiring (Vss wiring) connected to GND or a negative power supply.

The conductor layer B in the sixth configuration example includes a mesh conductor 252. The mesh conductor 252 is obtained by moving the mesh conductor 232 forming the conductor layer B in the fourth configuration example (FIG. 25) by a conductor period FXB/2 in the X direction. The mesh conductor 252 is, for example, a wiring (Vdd wiring) connected to a positive power supply.

It is preferable for the mesh conductor 251 and the mesh conductor 252 to satisfy the following relationships.

conductor width WXA=conductor width WYA=conductor width WXB=conductor width WYB

gap width GXA=gap width GYA=gap width GXB=gap width GYB end portion width EXA=end portion width EYB

conductor period FXA=conductor period FYA=conductor period FXB=conductor period FYB

conductor width WYA=2×overlap width+gap width GYA, conductor width WXA=2×overlap width+gap width GXA

conductor width WYB=2×overlap width+gap width GYB, conductor width WXB=2×overlap width+gap width GXB

Here, the overlap width is a width of an overlapping portion in which conductor portions overlap when the mesh conductor 251 of the conductor layer A and the mesh conductor 252 of the conductor layer B are arranged in an overlapping manner.

C of FIG. 27 illustrates a state in which the respective conductor layers A and B illustrated in A and B of FIG. 27 are viewed from the photodiode 141 side (back surface side). However, a hatched region 253 in C of FIG. 27 in which diagonal lines intersect indicates a region in which the mesh conductor 251 of the conductor layer A and the mesh conductor 252 of the conductor layer B overlap. In the case of the sixth configuration example, since the active element group 167 is covered with at least one of the conductor layer A and the conductor layer B, it is possible to shield the hot carrier light emitted from the active element group 167.

In the sixth configuration example, when a current flows as in the case illustrated in FIG. 23, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 251 and 252 in a cross-section on which the mesh conductors 251 and 252 are arranged between the mesh conductor 251 that is the Vss wiring and the mesh conductor 252 that is the Vdd wiring.

Further, in the case of the sixth configuration example, a region 253 in which the mesh conductor 251 and the mesh conductor 252 overlap is continuous in the Y direction. In the region 253 in which the mesh conductor 251 and the mesh conductor 252 overlap, since currents having different polarities flow through the mesh conductor 251 and the mesh conductor 252, magnetic fields generated from the region 253 are offset. Therefore, it is possible to curb the occurrence of inductive noise near the region 253.

### SIMULATION RESULTS OF FOURTH TO SIXTH CONFIGURATION EXAMPLES

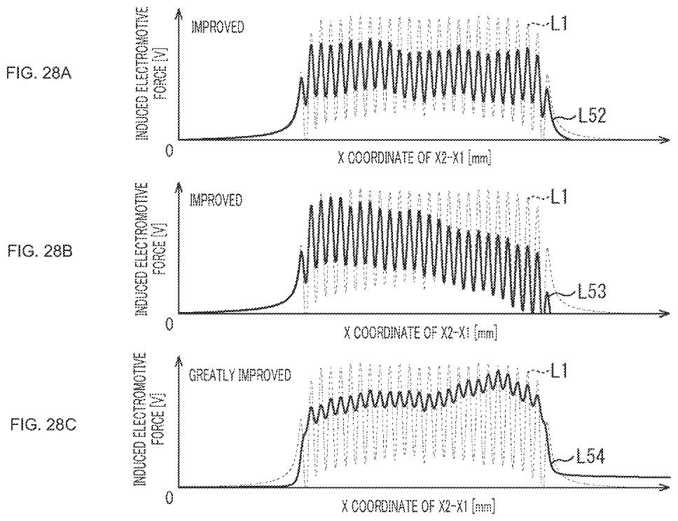

FIG. 28 illustrates change in the induced electromotive force that causes the inductive noise in the image as results of simulation when the fourth to sixth configuration examples (FIGS. 25 to 27) are applied to the solid-state imaging device 100. Conditions of a current flowing in the fourth to sixth configuration examples are the same as those illustrated in FIG. 23. A horizontal axis of FIG. 28 indicates an X-axis coordinate of the image, and a vertical axis indicates a magnitude of the induced electromotive force.

A solid line L52 in A of FIG. 28 corresponds to the fourth configuration example (FIG. 25), and a dotted line L1 corresponds to the first comparative example (FIG. 9). As is clear from a comparison of the solid line L52 with the dotted line L1, it can be seen that in the fourth configuration example, it is possible to curb change in the induced electromotive force generated in the victim conductor loop and to curb the inductive noise, as compared with the first comparative example.

A solid line L53 in B of FIG. 28 corresponds to the fifth configuration example (FIG. 26), and a dotted line L1 corresponds to the first comparative example (FIG. 9). As is clear from a comparison of the solid line L53 with the dotted line L1, it can be seen that in the fifth configuration example, it is possible to curb change in the induced electromotive force generated in the victim conductor loop and to curb the inductive noise, as compared with the first comparative example.

A solid line L54 in C of FIG. 28 corresponds to the sixth configuration example (FIG. 27), and a dotted line L1 corresponds to the first comparative example (FIG. 9). As is clear from a comparison of the solid line L54 with the dotted line L1, it can be seen that in the sixth configuration example, it is possible to curb change in the induced electromotive force generated in the victim conductor loop and to curb the inductive noise, as compared with the first comparative example.

Further, as is clear from a comparison of the solid lines L52 to L54, it can be seen that in the sixth configuration example, it is possible to further curb change in the induced electromotive force generated in the victim conductor loop and further curb the inductive noise, as compared with the fourth configuration example and the fifth configuration example.

### SEVENTH CONFIGURATION EXAMPLE

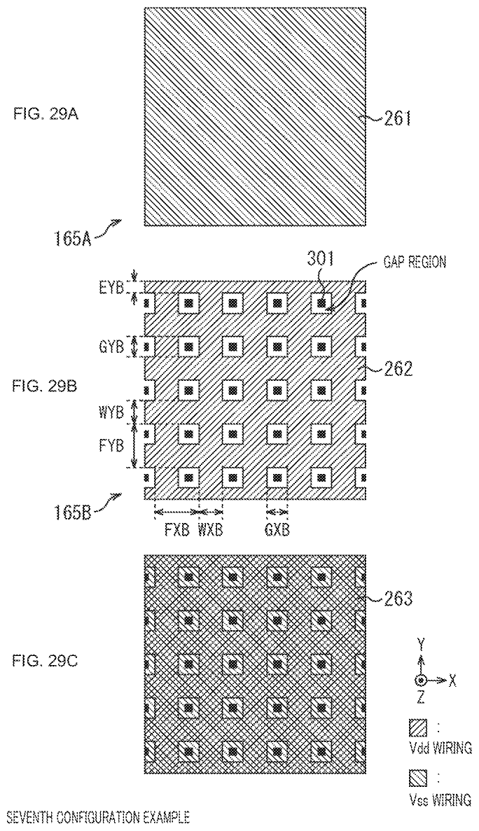

Next, FIG. 29 illustrates a seventh configuration example of the conductor layers A and B. A of FIG. 29 illustrates the conductor layer A, and B of FIG. 29 illustrates the conductor layer B. In a coordinate system in FIG. 29, a horizontal direction indicates an X-axis, a vertical direction indicates a Y-axis, and a direction orthogonal to an XY plane indicates a Z-axis.

The conductor layer A in the seventh configuration example includes the planar conductor 261. The planar conductor 261 is, for example, a wiring (Vss wiring) connected to GND or a negative power supply.

The conductor layer B in the seventh configuration example includes a mesh conductor 262 and a relay conductor 301. Since the mesh conductor 262 has the same shape as the mesh conductor 222 of the conductor layer B in the third configuration example (FIG. 22), description thereof will be omitted. The mesh conductor 262 is, for example, a wiring (Vdd wiring) connected to a positive power supply.

The relay conductor (other conductor) 301 is arranged in a gap region other than that of a conductor of the mesh conductor 262, is electrically insulated from the mesh conductor 262, and is connected to Vss to which the planar conductor 261 of the conductor layer A is connected.

The relay conductor 301 has any shape, and a symmetrical circle or polygon such as rotationally symmetrical circle or polygon or a mirror-symmetrical circle or polygon is preferable. The relay conductor 301 can be arranged at a center of the gap region of the mesh conductor 262 or any other position. The relay conductor 301 may be connected to the conductor layer serving as the Vss wiring different from the conductor layer A. The relay conductor 301 may be connected to a conductor layer serving as the Vss wiring on the side closer to the active element group 167 than to the conductor layer B. The relay conductor 301 can be connected to, for example, a conductor layer different from the conductor layer A or a conductor layer on the side closer to the active element group 167 than to the conductor layer B, by a conductor via extending in the Z direction.

C of FIG. 29 illustrates a state in which the respective conductor layers A and B illustrated in A and B of FIG. 29 are viewed from the photodiode 141 side (back surface side). However, a hatched region 263 in C of FIG. 29 in which diagonal lines intersect indicates a region in which the planar conductor 261 of the conductor layer A and the mesh conductor 262 of the conductor layer B overlap. In the case of the seventh configuration example, since the active element group 167 is covered with at least one of the conductor layer A and the conductor layer B, it is possible to shield the hot carrier light emitted from the active element group 167.

Further, in the case of the seventh configuration example, the planar conductor 261 that is the Vss wiring can be connected to the active element group 167 at a substantially shortest distance or a short distance by providing the relay conductor 301. It is possible to reduce the voltage drop, the energy loss, or the inductive noise between the planar conductor 261 and the active element group 167 by connecting the planar conductor 261 to the active element group 167 at a substantially shortest distance or a short distance.

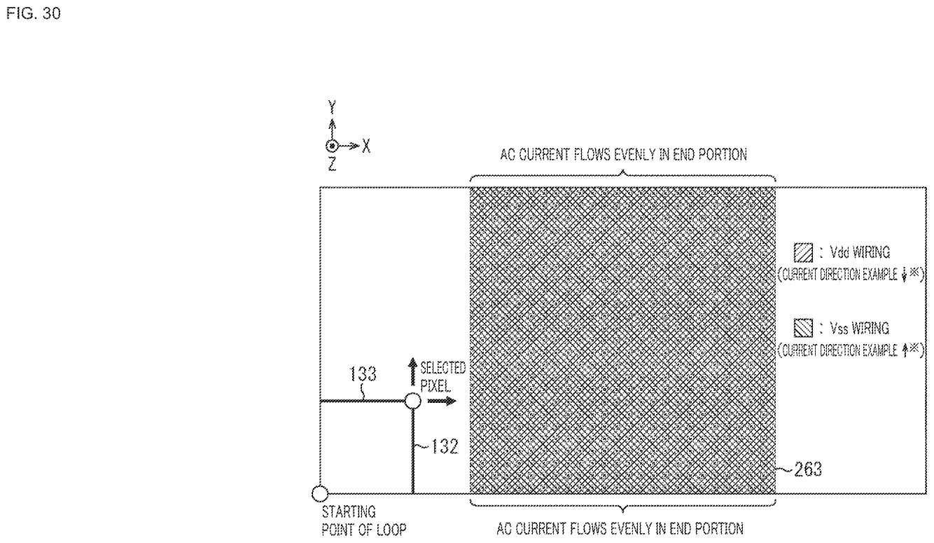

FIG. 30 is a diagram illustrating conditions of a current flowing in the seventh configuration example (FIG. 29).

It is assumed that an AC current flows evenly in end portions of the planar conductor 261 forming the conductor layer A and the mesh conductor 262 forming the conductor layer B. However, it is assumed that a current direction changes with time and, for example, when a current flows through the mesh conductor 262 that is the Vdd wiring from the upper side to the lower side of FIG. 30, a current flows through the planar conductor 261 that is the Vss wiring from the lower side to the upper side of FIG. 30.

In the seventh configuration example, when a current flows as illustrated in FIG. 30, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the planar conductor 261 and the mesh conductor 262 in a cross-section on which the planar conductor 261 and the mesh conductor 262 are arranged between the planar conductor 261 that is the Vss wiring and the mesh conductor 262 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane. In the victim conductor loop formed on the XY plane, an induced electromotive force is easily generated by the magnetic flux in the Z direction, and when the change in induced electromotive force becomes greater, the image output from the solid-state imaging device 100 deteriorates (inductive noise increases).

Further, when the effective dimension of the victim conductor loop including the signal line 132 and the control line 133 is changed due to the movement of the selected pixel in the pixel array 121, the change in induced electromotive force becomes significant.

In the case of the seventh configuration example, the direction (generally the X direction or generally the Y direction) of the magnetic flux generated from the loop surface of the aggressor conductor loop of the light shielding structure 151 including the conductor layers A and B and the direction (the Z direction) of the magnetic flux that generates the induced electromotive force in the victim conductor loop are substantially orthogonal to each other and differ by about 90 degrees. In other words, the direction of the loop surface on which the magnetic flux occurs from the aggressor conductor loop and the direction of the loop surface on which the induced electromotive force occurs in the victim conductor loop differ by about 90 degrees. Thus, the deterioration of the image output from the solid-state imaging device 100 (occurrence of inductive noise) is expected to be less than that in the case of the first comparative example.

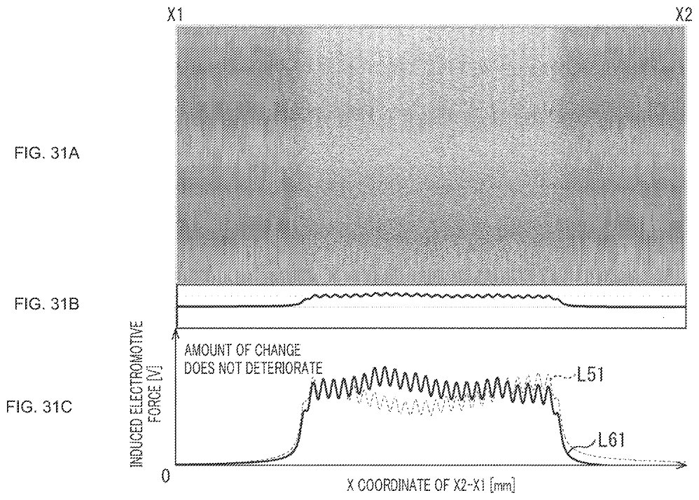

FIG. 31 illustrates results of simulation of inductive noise occurring when the seventh configuration example (FIG. 29) is applied to the solid-state imaging device 100.

A of FIG. 31 illustrates an image output from the solid-state imaging device 100, in which inductive noise can occur. B of FIG. 31 illustrates change in pixel signal in a line segment X1-X2 of the image illustrated in A of FIG. 31. C of FIG. 31 illustrates a solid line L61 indicating an induced electromotive force that causes the inductive noise in the image. A horizontal axis in C of FIG. 31 indicates an X-axis coordinate of the image, and a vertical axis indicates a magnitude of the induced electromotive force. A dotted line L51 in C of FIG. 31 corresponds to the third configuration example (FIG. 22).

As is clear from a comparison of the solid line L61 with the dotted line L51 illustrated in C of FIG. 31, it can be seen that in the seventh configuration example, change in induced electromotive force generated in the victim conductor loop does not deteriorate, as compared with the third configuration example. That is, even in the seventh configuration example in which the relay conductor 301 is arranged in a gap between the mesh conductors 262 of the conductor layer B, it is possible to curb occurrence of inductive noise in the image output from the solid-state imaging device 100 to the same degree as in the third configuration example. However, these results of the simulation are results of simulation when the planar conductor 261 is not connected to the active element group 167 and the mesh conductor 262 is not connected to the active element group 167. For example, when at least parts of the planar conductor 261 and the active element group 167 are connected to each other at a substantially shortest distance or a short distance by a conductor via or the like or when at least a part of the mesh conductor 262 and the active element group 167 are connected to each other at a substantially shortest distance or a short distance by a conductor via or the like, an amount of current flowing through the planar conductor 261 or the mesh conductor 262 gradually decreases depending on a position. In such a case, there is a condition that the voltage drop, energy loss, or inductive noise can be greatly reduced to ½ or less by providing the relay conductor 301.

### CIGHTH CONFIGURATION EXAMPLE

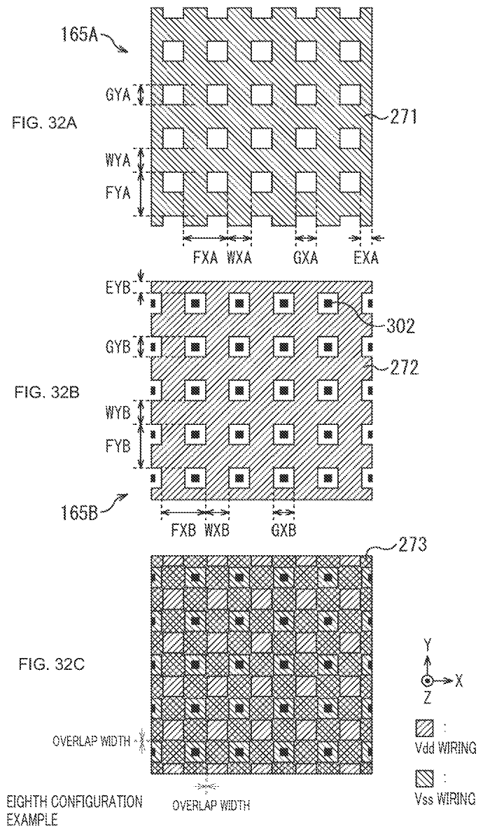

Next, FIG. 32 illustrates an eighth configuration example of the conductor layers A and B. A of FIG. 32 illustrates the conductor layer A, and B of FIG. 32 illustrates the conductor layer B. In a coordinate system in FIG. 32, a horizontal direction indicates an X-axis, a vertical direction indicates a Y-axis, and a direction orthogonal to an XY plane indicates a Z-axis.

The conductor layer A in the eighth configuration example includes a mesh conductor 271. Since the mesh conductor 271 has the same shape as the mesh conductor 231 of the conductor layer A in the fourth configuration example (FIG. 25), description thereof will be omitted. The mesh conductor 271 is, for example, a wiring (Vss wiring) connected to GND or a negative power supply.

The conductor layer B in the eighth configuration example includes a mesh conductor 272 and a relay conductor 302. Since the mesh conductor 272 has the same shape as the mesh conductor 232 of the conductor layer B in the fourth configuration example (FIG. 25), description thereof will be omitted. The mesh conductor 232 is, for example, a wiring (Vdd wiring) connected to a positive power supply.

The relay conductor (other conductor) 302 is arranged in a gap region which is not a conductor of the mesh conductor 272, is electrically insulated from the mesh conductor 272, and is connected to Vss to which the mesh conductor 271 of the conductor layer A has been connected.

The relay conductor 302 has any shape, and a symmetrical circle or polygon such as rotationally symmetrical circle or polygon or a mirror-symmetrical circle or polygon is preferable. The relay conductor 302 can be arranged at a center of the gap region of the mesh conductor 272 or any other position. The relay conductor 302 may be connected to the conductor layer serving as the Vss wiring different from the conductor layer A. The relay conductor 302 may be connected to a conductor layer serving as the Vss wiring on the side closer to the active element group 167 than to the conductor layer B. The relay conductor 302 can be connected to, for example, a conductor layer different from the conductor layer A or a conductor layer on the side closer to the active element group 167 than to the conductor layer B, by a conductor via extending in the Z direction.

C of FIG. 32 illustrates a state in which the respective conductor layers A and B illustrated in A and B of FIG. 32 are viewed from the photodiode 141 side (back surface side). However, a hatched region 273 in C of FIG. 32 in which diagonal lines intersect indicates a region in which the mesh conductor 271 of the conductor layer A and the mesh conductor 272 of the conductor layer B overlap. In the case of the eighth configuration example, since the active element group 167 is covered with at least one of the conductor layer A and the conductor layer B, it is possible to shield the hot carrier light emitted from the active element group 167.

In the eighth configuration example, when a current flows as in the case illustrated in FIG. 30, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 271 and 272 in a cross-section on which the mesh conductors 271 and 272 are arranged between the mesh conductor 271 that is the Vss wiring and the mesh conductor 272 that is the Vdd wiring.

Further, in the case of the eighth configuration example, the mesh conductor 271 that is the Vss wiring can be connected to the active element group 167 at a substantially shortest distance or a short distance by providing the relay conductor 302. It is possible to reduce the voltage drop, the energy loss, or the inductive noise between the mesh conductor 271 and the active element group 167 by connecting the mesh conductor 271 to the active element group 167 at a substantially shortest distance or a short distance.

### NINTH CONFIGURATION EXAMPLE

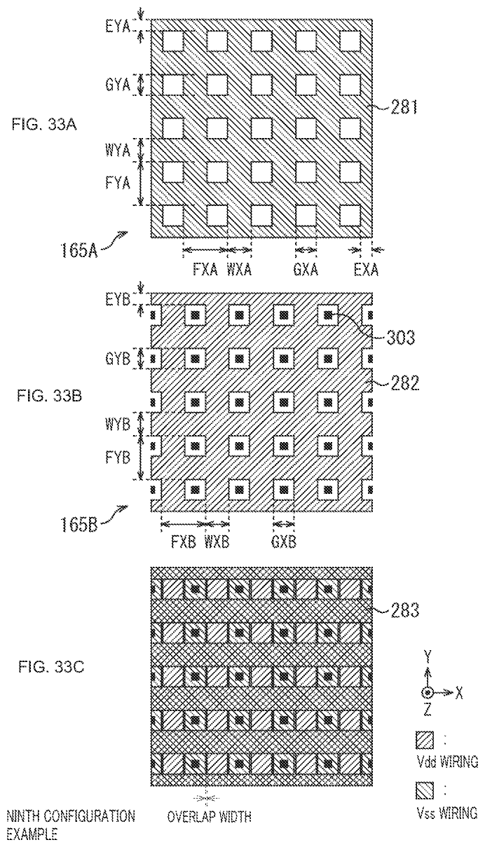

Next, FIG. 33 illustrates a ninth configuration example of the conductor layers A and B. A of FIG. 33 illustrates the conductor layer A, and B of FIG. 33 illustrates the conductor layer B. In a coordinate system in FIG. 33, a horizontal direction indicates an X-axis, a vertical direction indicates a Y-axis, and a direction orthogonal to an XY plane indicates a Z-axis.

The conductor layer A in the ninth configuration example includes a mesh conductor 281. Since the mesh conductor 281 has the same shape as the mesh conductor 241 of the conductor layer A in the fifth configuration example (FIG. 26), description thereof will be omitted. The mesh conductor 281 is, for example, a wiring (Vss wiring) connected to GND or a negative power supply.

The conductor layer B in the ninth configuration example includes a mesh conductor 282 and a relay conductor 303. Since the mesh conductor 282 has the same shape as the mesh conductor 242 of the conductor layer B in the fifth configuration example (FIG. 26), description thereof will be omitted. The mesh conductor 282 is, for example, a wiring (Vdd wiring) connected to a positive power supply.

The relay conductor (other conductor) 303 is arranged in a gap region which is not a conductor of the mesh conductor 282, is electrically insulated from the mesh conductor 282, and is connected to Vss to which the mesh conductor 281 of the conductor layer A has been connected.

The relay conductor 303 has any shape, and a symmetrical circle or polygon such as rotationally symmetrical circle or polygon or a mirror-symmetrical circle or polygon is preferable. The relay conductor 303 can be arranged at a center of the gap region of the mesh conductor 282 or any other position. The relay conductor 303 may be connected to the conductor layer serving as the Vss wiring different from the conductor layer A. The relay conductor 303 may be connected to a conductor layer serving as the Vss wiring on the side closer to the active element group 167 than to the conductor layer B. The relay conductor 303 can be connected to, for example, a conductor layer different from the conductor layer A or a conductor layer on the side closer to the active element group 167 than to the conductor layer B, by a conductor via extending in the Z direction.

C of FIG. 33 illustrates a state in which the respective conductor layers A and B illustrated in A and B of FIG. 33 are viewed from the photodiode 141 side (back surface side). However, a hatched region 283 in C of FIG. 33 in which diagonal lines intersect indicates a region in which the mesh conductor 281 of the conductor layer A and the mesh conductor 282 of the conductor layer B overlap. In the case of the ninth configuration example, since the active element group 167 is covered with at least one of the conductor layer A and the conductor layer B, it is possible to shield the hot carrier light emitted from the active element group 167.

In the ninth configuration example, when a current flows as in the case illustrated in FIG. 30, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 281 and 282 in a cross-section on which the mesh conductors 281 and 282 are arranged between the mesh conductor 281 that is the Vss wiring and the mesh conductor 282 that is the Vdd wiring.

Further, in the case of the ninth configuration example, the mesh conductor 281 that is the Vss wiring can be connected to the active element group 167 at a substantially shortest distance or a short distance by providing the relay conductor 303. It is possible to reduce the voltage drop, the energy loss, or the inductive noise between the mesh conductor 281 and the active element group 167 by connecting the mesh conductor 281 to the active element group 167 at a substantially shortest distance or a short distance.

### TENTH CONFIGURATION EXAMPLE

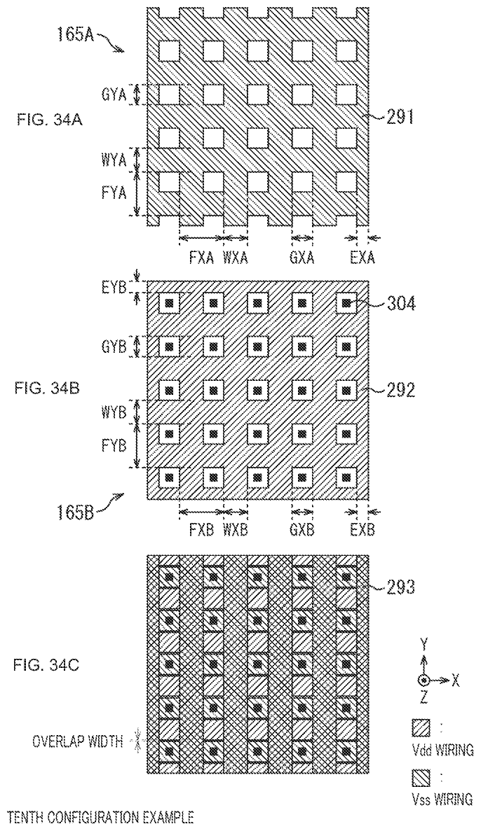

Next, FIG. 34 illustrates a tenth configuration example of the conductor layers A and B. A of FIG. 34 illustrates the conductor layer A, and B of FIG. 34 illustrates the conductor layer B. In a coordinate system in FIG. 34, a horizontal direction indicates an X-axis, a vertical direction indicates a Y-axis, and a direction orthogonal to an XY plane indicates a Z-axis.

The conductor layer A in the tenth configuration example includes a mesh conductor 291. Since the mesh conductor 291 has the same shape as the mesh conductor 251 of the conductor layer A in the sixth configuration example (FIG. 27), description thereof will be omitted. The mesh conductor 291 is, for example, a wiring (Vss wiring) connected to GND or a negative power supply.

The conductor layer B in the tenth configuration example includes a mesh conductor 292 and a relay conductor 304. Since the mesh conductor 292 has the same shape as the mesh conductor 252 of the conductor layer B in the sixth configuration example (FIG. 27), description thereof will be omitted. The mesh conductor 292 is, for example, a wiring (Vdd wiring) connected to a positive power supply.

The relay conductor (other conductor) 304 is arranged in a gap region which is not a conductor of the mesh conductor 292, is electrically insulated from the mesh conductor 292, and is connected to Vss to which the mesh conductor 291 of the conductor layer A has been connected.

The relay conductor 304 has any shape, and a symmetrical circle or polygon such as rotationally symmetrical circle or polygon or a mirror-symmetrical circle or polygon is preferable. The relay conductor 304 can be arranged at a center of the gap region of the mesh conductor 292 or any other position. The relay conductor 304 may be connected to the conductor layer serving as the Vss wiring different from the conductor layer A. The relay conductor 304 may be connected to a conductor layer serving as the Vss wiring on the side closer to the active element group 167 than to the conductor layer B. The relay conductor 304 can be connected to, for example, a conductor layer different from the conductor layer A or a conductor layer on the side closer to the active element group 167 than to the conductor layer B, by a conductor via extending in the Z direction.

C of FIG. 34 illustrates a state in which the respective conductor layers A and B illustrated in A and B of FIG. 34 are viewed from the photodiode 141 side (back surface side). However, a hatched region 293 in C of FIG. 34 in which diagonal lines intersect indicates a region in which the mesh conductor 291 of the conductor layer A and the mesh conductor 292 of the conductor layer B overlap. In the case of the tenth configuration example, since the active element group 167 is covered with at least one of the conductor layer A and the conductor layer B, it is possible to shield the hot carrier light emitted from the active element group 167.

In the tenth configuration example, when a current flows as in the case illustrated in FIG. 30, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 291 and 292 in a cross-section on which the mesh conductors 291 and 292 are arranged between the mesh conductor 291 that is the Vss wiring and the mesh conductor 292 that is the Vdd wiring.

Further, in the case of the tenth configuration example, the mesh conductor 291 that is the Vss wiring can be connected to the active element group 167 at a substantially shortest distance or a short distance by providing the relay conductor 304. It is possible to reduce the voltage drop, the energy loss, or the inductive noise between the mesh conductor 291 and the active element group 167 by connecting the mesh conductor 291 to the active element group 167 at a substantially shortest distance or a short distance.

### SIMULATION RESULTS OF EIGHTH TO TENTH CONFIGURATION EXAMPLES

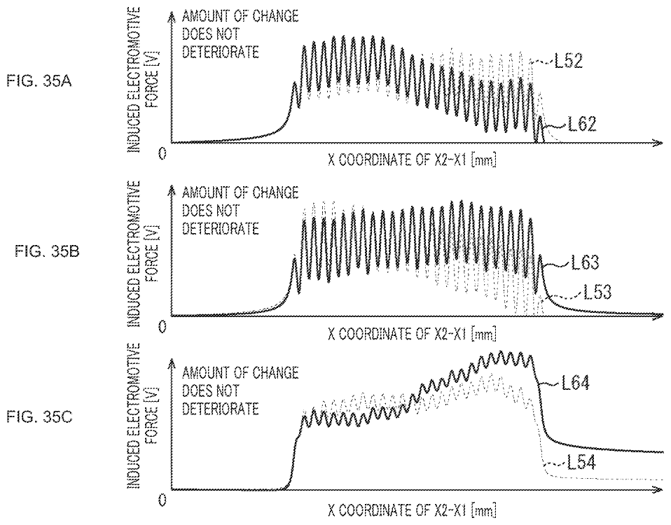

FIG. 35 illustrates change in the induced electromotive force that causes the inductive noise in the image as results of simulation when the eighth to tenth configuration examples (FIGS. 32 to 34) are applied to the solid-state imaging device 100. Conditions of a current flowing in the eighth to tenth configuration examples are the same as those illustrated in FIG. 30. A horizontal axis of FIG. 35 indicates an X-axis coordinate of the image, and a vertical axis indicates a magnitude of the induced electromotive force.

A solid line L62 in A of FIG. 35 corresponds to the eighth configuration example (FIG. 32), and a dotted line L52 corresponds to the fourth configuration example (FIG. 25) As is clear from a comparison of the solid line L62 with the dotted line L52, it can be seen that in the eighth configuration example, change in induced electromotive force generated in the victim conductor loop does not deteriorate, as compared with the fourth configuration example. That is, even in the eighth configuration example in which the relay conductor 302 is arranged in a gap between the mesh conductors 272 of the conductor layer B, it is possible to curb occurrence of inductive noise in the image output from the solid-state imaging device 100 to the same degree as in the fourth configuration example. However, the results of the simulations are results of simulation when the mesh conductor 271 is not connected to the active element group 167 and the mesh conductor 272 is not connected to the active element group 167. For example, when at least parts of the mesh conductor 271 and the active element group 167 are connected to each other at a substantially shortest distance or a short distance by a conductor via or the like or when at least a part of the mesh conductor 272 and the active element group 167 are connected to each other at a substantially shortest distance or a short distance by a conductor via or the like, an amount of current flowing through the mesh conductor 271 or the mesh conductor 272 gradually decreases depending on a position. In such a case, there is a condition that the voltage drop, energy loss, or inductive noise can be greatly reduced to ½ or less by providing the relay conductor 302.

A solid line L63 in B of FIG. 35 corresponds to the ninth configuration example (FIG. 33), and a dotted line L53 corresponds to the fifth configuration example (FIG. 26). As is clear from a comparison of the solid line L63 with the dotted line L53, it can be seen that in the ninth configuration example, change in induced electromotive force generated in the victim conductor loop does not deteriorate, as compared with the fifth configuration example. That is, even in the ninth configuration example in which the relay conductor 303 is arranged in a gap between the mesh conductors 282 of the conductor layer B, it is possible to curb occurrence of inductive noise in the image output from the solid-state imaging device 100 to the same degree as in the fifth configuration example. However, the results of the simulations are results of simulation when the mesh conductor 281 is not connected to the active element group 167 and the mesh conductor 282 is not connected to the active element group 167. For example, when at least parts of the mesh conductor 281 and the active element group 167 are connected to each other at a substantially shortest distance or a short distance by a conductor via or the like or when at least a part of the mesh conductor 282 and the active element group 167 are connected to each other at a substantially shortest distance or a short distance by a conductor via or the like, an amount of current flowing through the mesh conductor 281 or the mesh conductor 282 gradually decreases depending on a position. In such a case, there is a condition that the voltage drop, energy loss, or inductive noise can be greatly reduced to ½ or less by providing the relay conductor 303.

A solid line L64 in C of FIG. 35 corresponds to the tenth configuration example (FIG. 34), and a dotted line L54 corresponds to the sixth configuration example (FIG. 27). As is clear from a comparison of the solid line L64 with the dotted line L54, it can be seen that in the tenth configuration example, change in induced electromotive force generated in the victim conductor loop does not deteriorate, as compared with the sixth configuration example. That is, even in the tenth configuration example in which the relay conductor 304 is arranged in a gap between the mesh conductors 292 of the conductor layer B, it is possible to curb occurrence of inductive noise in the image output from the solid-state imaging device 100 to the same degree as in the sixth configuration example. However, the results of the simulations are results of simulation when the mesh conductor 291 is not connected to the active element group 167 and the mesh conductor 292 is not connected to the active element group 167. For example, when at least parts of the mesh conductor 291 and the active element group 167 are connected to each other at a substantially shortest distance or a short distance by a conductor via or the like or when at least a part of the mesh conductor 292 and the active element group 167 is connected to each other at a substantially shortest distance or a short distance by a conductor via or the like, an amount of current flowing through the mesh conductor 291 or the mesh conductor 292 gradually decreases depending on a position. In such a case, there is a condition that the voltage drop, energy loss, or inductive noise can be greatly reduced to ½ or less by providing the relay conductor 304.

Further, as is clear from a comparison of the solid lines L62 to L64, it can be seen that in the tenth configuration example, it is possible to further curb change in the induced electromotive force generated in the victim conductor loop and further curb the inductive noise, as compared with the eighth configuration example and the ninth configuration example.

### ELEVENTH CONFIGURATION EXAMPLE

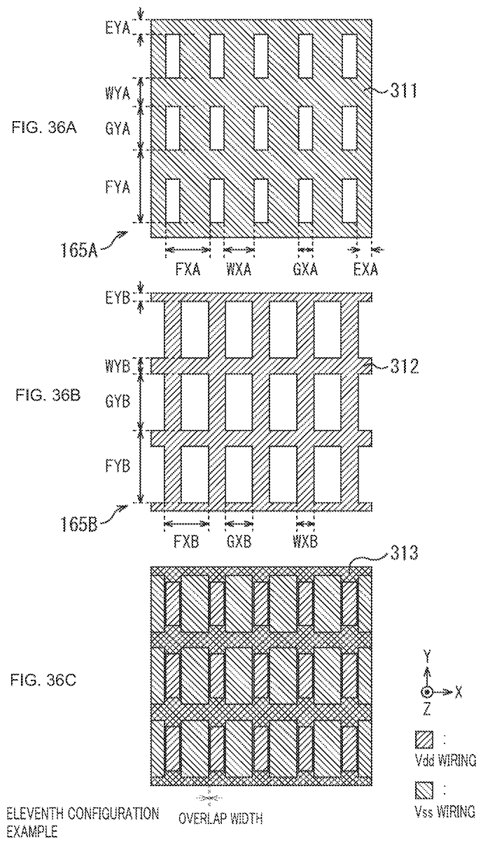

Next, FIG. 36 illustrates an eleventh configuration example of the conductor layers A and B. A of FIG. 36 illustrates the conductor layer A, and B of FIG. 36 illustrates the conductor layer B. In a coordinate system in FIG. 36, a horizontal direction indicates an X-axis, a vertical direction indicates a Y-axis, and a direction orthogonal to an XY plane indicates a Z-axis.

The conductor layer A in the eleventh configuration example includes a mesh conductor 311 of which a resistance value in the X direction (first direction) differs from a resistance value in the Y direction (second direction). The mesh conductor 311 is, for example, a wiring (Vss wiring) connected to GND or a negative power supply.

A conductor width in the X direction of the mesh conductor 311 is WXA, a gap width is GXA, a conductor period is FXA (=conductor width WXA+gap width GXA), and an end portion width is EXA (=conductor width WXA/2). Further, it is assumed that a conductor width in the Y direction of the mesh conductor 311 is WYA, a gap width is GYA, a conductor period is FYA (=conductor width WYA+gap width GYA), and an end portion width is EYA (=conductor width WYA/2). In the mesh conductor 311, the gap width GYA >gap width GXA is satisfied. Therefore, a gap region of the mesh conductor 311 has a shape in which a region in the Y direction is longer than a region in the X direction, a resistance value differs in the X direction and the Y direction, and the resistance value in the Y direction is smaller than the resistance value in the X direction.

The conductor layer B in the eleventh configuration example includes a mesh conductor 312 having different resistance values in the X direction and the Y direction. The mesh conductor 312 is, for example, a wiring (Vdd wiring) connected to a positive power supply.

It is assumed that a conductor width in the X direction of the mesh conductor 312 is WXB, a gap width is GXB, and a conductor period is FXB (=conductor width WXB+gap width GXB). Further, it is assumed that a conductor width in the Y direction of the mesh conductor 312 is WYB, a gap width is GYB, a conductor period is FYB (=conductor width WYB+gap width GYB), and an end portion width is EYB (=conductor width WYB/2). In the mesh conductor 312, the gap width GYB>gap width GXB is satisfied. Therefore, a gap region of the mesh conductor 312 has a shape in which a region in the Y direction is longer than a region in the X direction, a resistance value differs in the X direction and the Y direction, and the resistance value in the Y direction is smaller than the resistance value in the X direction.

When a sheet resistance value of the mesh conductor 311 is larger than a sheet resistance value of the mesh conductor 312, it is preferable for the mesh conductor 311 and the mesh conductor 312 to satisfy the following relationships.

conductor width WYA≥conductor width WYB

conductor width WXA≥conductor width WXB

gap width GXA≤gap width GXB

gap width GYA≤Gap width GYB

On the other hand, when the sheet resistance value of the mesh conductor 311 is smaller than the sheet resistance value of the mesh conductor 312, it is preferable for the mesh conductor 311 and the mesh conductor 312 to satisfy the following relationships.

conductor width WYA≤conductor width WYB

conductor width WXA≤conductor width WXB

gap width GXA≥gap width GXB

gap width GYA≥gap width GYB

Further, it is preferable for the sheet resistance values and the conductor widths of the mesh conductors 311 and 312 to satisfy the following relationships.

(sheet resistance value of mesh conductor 311)/(sheet resistance value of mesh conductor 312)≈conductor width WYA/conductor width WYB

(sheet resistance value of mesh conductor 311)/(sheet resistance value of mesh conductor 312)≈conductor width WXA/conductor width WXB

A dimensional relationship disclosed in the present specification is not necessarily limited, and it is preferable for a current distribution of the mesh conductor 311 and a current distribution of the mesh conductor 312 to be substantially equal, substantially the same, or substantially similar current distributions, and to be current distributions having inverse characteristics.

For example, it is preferable for a ratio of a wiring resistance of the mesh conductor 311 in the X direction to a wiring resistance of the mesh conductor 311 in the Y direction to be substantially the same as a ratio of a wiring resistance of the mesh conductor 312 in the X direction to a wiring resistance of the mesh conductor 312 in the Y direction.

Further, it is preferable for a ratio of wiring inductance of the mesh conductor 311 in the X direction to wiring inductance of the mesh conductor 311 in the Y direction to be substantially the same as a ratio of wiring inductance of the mesh conductor 312 in the X direction to the wiring inductance of the mesh conductor 312 in the Y direction.

Further, it is preferable for a ratio of wiring capacitance of the mesh conductor 311 in the X direction to wiring capacitance of the mesh conductor 311 in the Y direction to be substantially the same as a ratio of wiring capacitance of the mesh conductor 312 in the X direction to wiring capacitance of the mesh conductor 312 in the Y direction.

Further, it is preferable for a ratio of the wiring impedance of the mesh conductor 311 in the X direction to wiring impedance of the mesh conductor 311 in the Y direction to be substantially the same as a ratio of wiring impedance of the mesh conductor 312 in the X direction to wiring impedance of the mesh conductor 312 in the Y direction.

In other words, it is preferable for any one of relationships of (wiring resistance of mesh conductor 311 in X direction×wiring resistance of mesh conductor 312 in Y direction)≈(wiring resistance of mesh conductor 312 in X direction x wiring resistance of mesh conductor 311 in Y direction), (wiring inductance of mesh conductor 311 in X direction x wiring inductance of mesh conductor 312 in Y direction)≈(wiring inductance of mesh conductor 312 in X direction x wiring inductance of mesh conductor 311 in Y direction), (wiring capacitance of mesh conductor 311 in X direction x wiring capacitance of mesh conductor 312 in Y direction)≈(wiring capacitance of mesh conductor 312 in X direction x wiring capacitance of mesh conductor 311 in Y direction), and (wiring impedance of mesh conductor 311 in X direction x wiring impedance of mesh conductor 312 in Y direction)≈(wiring impedance of mesh conductor 312 in X direction x wiring impedance of mesh conductor 311 in Y direction) to be satisfied, but the relationship is not essential.

The wiring resistance, wiring inductance, wiring capacitance, and wiring impedance described above can be replaced with conductor resistance, conductor inductance, conductor capacitance, and conductor impedance, respectively.

Impedance Z, resistance R, inductance L, and capacitance C described above have a relationship of Z=R+jωL+1÷(jωC) depending on an angular frequency ω and an imaginary unit j.

The relationship between the ratios may be satisfied as a whole of the mesh conductor 311 and the mesh conductor 312, may be satisfied within a partial range of the mesh conductor 311 and the mesh conductor 312, or may be satisfied within any range.

Further, a circuit may be provided to adjust the current distributions to be substantially equal, substantially the same, or substantially similar, and have reverse characteristics.

Since the current distribution of the mesh conductor 311 and the current distribution of the mesh conductor 312 are substantially uniform and have opposite characteristics by satisfying the above-described relationship, a magnetic field generated by the current distribution of the mesh conductor 311 and a magnetic field generated by the current distribution of the mesh conductor 312 can be effectively offset.

C of FIG. 36 illustrates a state in which the respective conductor layers A and B illustrated in A and B of FIG. 36 are viewed from the photodiode 141 side (back surface side). However, a hatched region 313 in C of FIG. 36 in which diagonal lines intersect indicates a region in which the mesh conductor 311 of the conductor layer A and the mesh conductor 312 of the conductor layer B overlap. In the eleventh configuration example, since the active element group 167 is covered with at least one of the conductor layer A and the conductor layer B, it is possible to shield the hot carrier light emitted from the active element group 167.

Further, in the case of the eleventh configuration example, a region 313 in which the mesh conductor 311 and the mesh conductor 312 overlap is continuous in the X direction. In the region 313 in which the mesh conductor 311 and the mesh conductor 312 overlap, since currents having different polarities flow through the mesh conductor 311 and the mesh conductor 312, magnetic fields generated from the region 313 are offset. Therefore, it is possible to curb the occurrence of inductive noise near the region 313.

In the eleventh configuration example, the gap width GYA in the Y direction and the gap width GXA in the X direction of the mesh conductor 311 differ from each other, and the gap width GYB in the Y direction and the gap width GXB in the X direction of the mesh conductor 312 differ from each other.

Thus, by forming the mesh conductors 311 and 312 with a difference between the gap widths in the X direction and the Y direction, it is possible to keep constraints of a dimension of the wiring region, a dimension of the gap region, an occupation rate of the wiring region in each conductor layer, or the like when conductor layers are actually designed and manufactured, and it is possible to increase a degree of freedom in a design of the wiring layout. Further, it is possible to design the wirings in a layout advantageous in terms of a voltage drop (IR-Drop), inductive noise, or the like, as compared with a case in which no difference is provided in gap width.

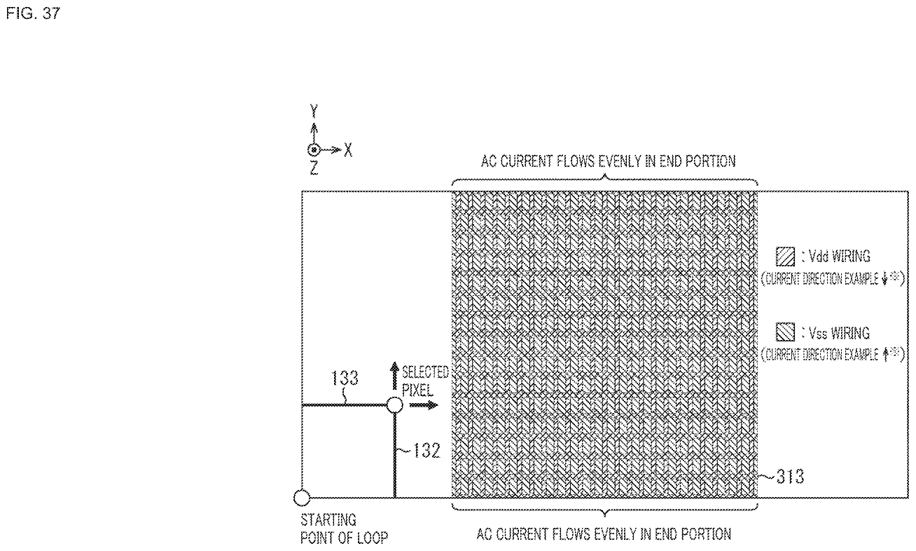

FIG. 37 is a diagram illustrating conditions of a current flowing in the eleventh configuration example (FIG. 36).

It is assumed that an AC current flows evenly in end portions of the mesh conductor 311 forming the conductor layer A and the mesh conductor 312 forming the conductor layer B. However, it is assumed that a current direction changes with time and, for example, when a current flows through the mesh conductor 312 that is the Vdd wiring from the upper side to the lower side of FIG. 37, a current flows through the mesh conductor 311 that is the Vss wiring from the lower side to the upper side of FIG. 37.

In the eleventh configuration example, when a current flows as in the case illustrated in FIG. 37, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 311 and 312 in a cross-section on which the mesh conductors 311 and 312 are arranged between the mesh conductor 311 that is the Vss wiring and the mesh conductor 312 that is the Vdd wiring.

On the other hand, in the pixel array 121 of the first semiconductor substrate 101 stacked on the second semiconductor substrate 102 in which the light shielding structure 151 including the conductor layers A and B is formed, the victim conductor loop including the signal line 132 and the control line 133 is formed in the XY plane. In the victim conductor loop formed on the XY plane, an induced electromotive force is easily generated by the magnetic flux in the Z direction, and when the change in induced electromotive force is greater, the image output from the solid-state imaging device 100 deteriorates (inductive noise increases).

Further, when the effective dimension of the victim conductor loop including the signal line 132 and the control line 133 is changed due to the movement of the selected pixel in the pixel array 121, the change in induced electromotive force becomes significant.

In the case of the eleventh configuration example, the direction (generally the X direction or generally the Y direction) of the magnetic flux generated from the loop surface of the aggressor conductor loop of the light shielding structure 151 including the conductor layers A and B and the direction (the Z direction) of the magnetic flux that generates the induced electromotive force in the victim conductor loop are substantially orthogonal to each other and differ by about 90 degrees. In other words, the direction of the loop surface on which the magnetic flux occurs from the aggressor conductor loop and the direction of the loop surface on which the induced electromotive force occurs in the victim conductor loop differ by about 90 degrees. Thus, the deterioration of the image output from the solid-state imaging device 100 (occurrence of inductive noise) is expected to be less than that in the case of the first comparative example.

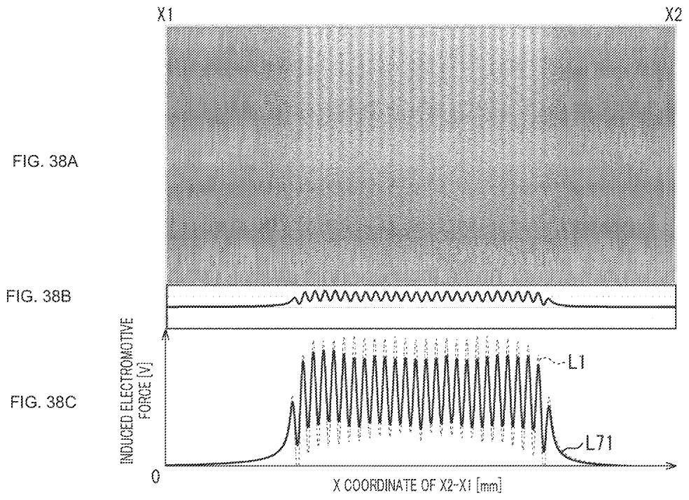

FIG. 38 illustrates results of simulation of inductive noise occurring when the eleventh configuration example (FIG. 36) is applied to the solid-state imaging device 100.

A of FIG. 38 illustrates an image output from the solid-state imaging device 100, in which inductive noise can occur. B of FIG. 38 illustrates change in pixel signal in a line segment X1-X2 of the image illustrated in A of FIG. 38. C of FIG. 38 illustrates a solid line L71 indicating an induced electromotive force that causes the inductive noise in the image. A horizontal axis in C of FIG. 38 indicates an X-axis coordinate of the image, and a vertical axis indicates a magnitude of the induced electromotive force. A dotted line L1 in C of FIG. 38 corresponds to the first comparative example (FIG. 9).

As is clear from a comparison of the solid line L71 with the dotted line L1 illustrated in C of FIG. 38, it can be seen that in the eleventh configuration example, it is possible to curb change in the induced electromotive force generated in the victim conductor loop and to curb the inductive noise, as compared with the first comparative example.

The eleventh configuration example may be rotated at 90 degrees in the XY plane and used. Further, the eleventh configuration example may be rotated at any angle instead of 90 degrees and used. For example, the eleventh configuration example may be configured obliquely with respect to the X-axis and the Y-axis.

### TWELFTH CONFIGURATION EXAMPLE

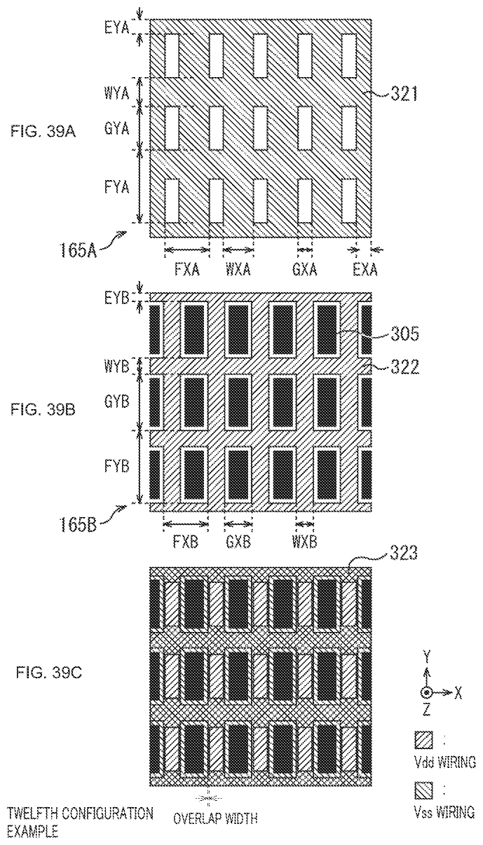

Next, FIG. 39 illustrates a twelfth configuration example of the conductor layers A and B. A of FIG. 39 illustrates the conductor layer A, and B of FIG. 39 illustrates the conductor layer B. In a coordinate system in FIG. 39, a horizontal direction indicates an X-axis, a vertical direction indicates a Y-axis, and a direction orthogonal to an XY plane indicates a Z-axis.

The conductor layer A in the twelfth configuration example includes a mesh conductor 321. Since the mesh conductor 321 has the same shape as the mesh conductor 311 of the conductor layer A in the eleventh configuration example (FIG. 36), description thereof will be omitted. The mesh conductor 321 is, for example, a wiring (Vss wiring) connected to GND or a negative power supply.

The conductor layer B in the twelfth configuration example includes a mesh conductor 322 and a relay conductor 305. Since the mesh conductor 322 has the same shape as the mesh conductor 312 of the conductor layer B in the eleventh configuration example (FIG. 36), description thereof will be omitted. The mesh conductor 322 is, for example, a wiring (Vdd wiring) connected to a positive power supply.

The relay conductor (other conductor) 305 is arranged in a rectangular gap region long in the Y direction that is not a conductor of the mesh conductor 322, is electrically insulated from the mesh conductor 322, and is connected to Vss to which the mesh conductor 321 of the conductor layer A has been connected.

The relay conductor 305 has any shape, and a symmetrical circle or polygon such as rotationally symmetrical circle or polygon or a mirror-symmetrical circle or polygon is preferable. The relay conductor 305 can be arranged at a center of the gap region of the mesh conductor 322 or any other position. The relay conductor 305 may be connected to the conductor layer serving as the Vss wiring different from the conductor layer A. The relay conductor 305 may be connected to a conductor layer serving as the Vss wiring on the side closer to the active element group 167 than to the conductor layer B. The relay conductor 305 can be connected to, for example, a conductor layer different from the conductor layer A or a conductor layer on the side closer to the active element group 167 than to the conductor layer B, by a conductor via extending in the Z direction.

C of FIG. 39 illustrates a state in which the respective conductor layers A and B illustrated in A and B of FIG. 39 are viewed from the photodiode 141 side (back surface side). However, a hatched region 323 in C of FIG. 39 in which diagonal lines intersect indicates a region in which the mesh conductor 321 of the conductor layer A and the mesh conductor 322 of the conductor layer B overlap. In the case of the twelfth configuration example, since the active element group 167 is covered with at least one of the conductor layer A and the conductor layer B, it is possible to shield the hot carrier light emitted from the active element group 167.

In the twelfth configuration example, when a current flows as in the case illustrated in FIG. 37, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 321 and 322 in a cross-section on which the mesh conductors 321 and 322 are arranged between the mesh conductor 321 that is the Vss wiring and the mesh conductor 322 that is the Vdd wiring.

Further, in the case of the twelfth configuration example, a region 323 in which the mesh conductor 321 and the mesh conductor 322 overlap is continuous in the X direction. In the region 323 in which the mesh conductor 321 and the mesh conductor 322 overlap, since currents having different polarities flow through the mesh conductor 321 and the mesh conductor 322, magnetic fields generated from the region 323 are offset. Therefore, it is possible to curb the occurrence of inductive noise near the region 323.

Further, in the case of the twelfth configuration example, the mesh conductor 321 that is the Vss wiring can be connected to the active element group 167 at a substantially shortest distance or a short distance by providing the relay conductor 305. It is possible to reduce the voltage drop, the energy loss, or the inductive noise between the mesh conductor 321 and the active element group 167 by connecting the mesh conductor 321 to the active element group 167 at a substantially shortest distance or a short distance.

The twelfth configuration example may be rotated at 90 degrees in the XY plane and used. Further, the twelfth configuration example may be rotated at any angle instead of 90 degrees and used. For example, the twelfth configuration example may be configured obliquely with respect to the X-axis and the Y-axis.

### THIRTEENTH CONFIGURATION EXAMPLE

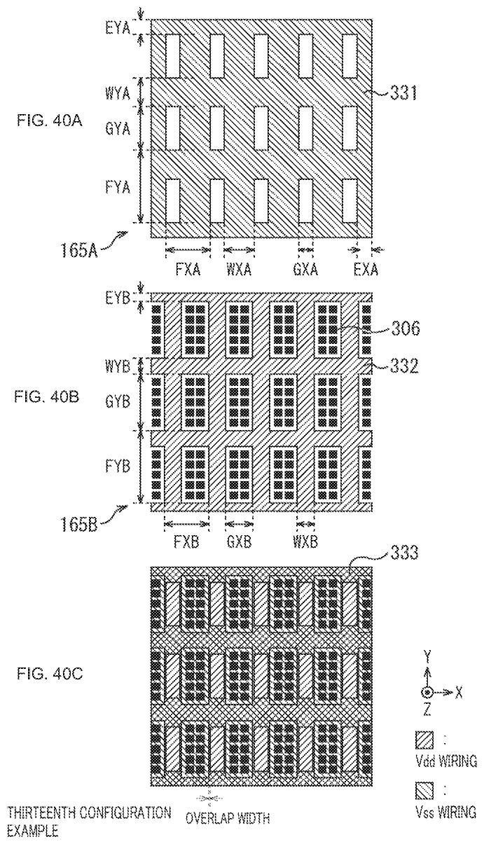

Next, FIG. 40 illustrates a thirteenth configuration example of the conductor layers A and B. A of FIG. 40 illustrates the conductor layer A, and B of FIG. 40 illustrates the conductor layer B. In a coordinate system in FIG. 40, a horizontal direction indicates an X-axis, a vertical direction indicates a Y-axis, and a direction orthogonal to an XY plane indicates a Z-axis.

The conductor layer A in the thirteenth configuration example includes a mesh conductor 331. Since the mesh conductor 331 has the same shape as the mesh conductor 311 of the conductor layer A in the eleventh configuration example (FIG. 36), description thereof will be omitted. The mesh conductor 331 is, for example, a wiring (Vss wiring) connected to GND or a negative power supply.

The conductor layer B in the thirteenth configuration example includes a mesh conductor 332 and a relay conductor 306. Since the mesh conductor 332 has the same shape as the mesh conductor 312 of the conductor layer B in the eleventh configuration example (FIG. 36), description thereof will be omitted. The mesh conductor 332 is, for example, a wiring (Vdd wiring) connected to a positive power supply.

The relay conductor (other conductor) 306 is obtained by dividing the relay conductor 305 in the twelfth configuration example (FIG. 39) into a plurality of conductors (10 in the case of FIG. 40) at intervals. The relay conductor 306 is arranged in a rectangular gap region that is long in a Y direction of the mesh conductor 332, is electrically insulated from the mesh conductor 332, and is connected to Vss to which the mesh conductor 331 of the conductor layer A is connected. The number of divisions of the relay conductor and the presence or absence of connection to Vss may be different depending on the region. In this case, since the current distribution can be finely adjusted at the time of design, it is possible to curb inductive noise and reduce voltage drop (IR-Drop).

The relay conductor 306 has any shape, and a symmetrical circle or polygon such as rotationally symmetrical circle or polygon or a mirror-symmetrical circle or polygon is preferable. The number of divisions of the relay conductor 306 can be arbitrarily changed. The relay conductor 306 can be arranged at a center of the gap region of the mesh conductor 332 or any other position. The relay conductor 306 may be connected to the conductor layer serving as the Vss wiring different from the conductor layer A. The relay conductor 306 may be connected to a conductor layer serving as the Vss wiring on the side closer to the active element group 167 than to the conductor layer B. The relay conductor 306 can be connected to, for example, a conductor layer different from the conductor layer A or a conductor layer on the side closer to the active element group 167 than to the conductor layer B, by a conductor via extending in the Z direction.

C of FIG. 40 illustrates a state in which the respective conductor layers A and B illustrated in A and B of FIG. 40 are viewed from the photodiode 141 side (back surface side). However, a hatched region 333 in C of FIG. 40 in which diagonal lines intersect indicates a region in which the mesh conductor 331 of the conductor layer A and the mesh conductor 332 of the conductor layer B overlap. In the case of the thirteenth configuration example, since the active element group 167 is covered with at least one of the conductor layer A and the conductor layer B, it is possible to shield the hot carrier light emitted from the active element group 167.

In the thirteenth configuration example, when a current flows as in the case illustrated in FIG. 37, a magnetic flux in a substantially X direction and a substantially Y direction is easily generated by a conductor loop having a loop surface substantially orthogonal to the X-axis and a conductor loop having a loop surface substantially orthogonal to the Y-axis, which are formed to include (cross-sections of) the mesh conductors 331 and 332 in a cross-section on which the mesh conductors 331 and 332 are arranged between the mesh conductor 331 that is the Vss wiring and the mesh conductor 332 that is the Vdd wiring.

Further, in the case of the thirteenth configuration example, a region 333 in which the mesh conductor 331 and the mesh conductor 332 overlap is continuous in the X direction. In the region 333, since currents having different polarities flow through the mesh conductor 331 and the mesh conductor 332, magnetic fields generated from the region 333 are offset. Therefore, it is possible to curb the occurrence of inductive noise near the region 333.

Further, in the case of the thirteenth configuration example, the mesh conductor 331 that is the Vss wiring can be connected to the active element group 167 at a substantially shortest distance or a short distance by providing the relay conductor 306. It is possible to reduce the voltage drop, the energy loss, or the inductive noise between the mesh conductor 331 and the active element group 167 by connecting the mesh conductor 331 to the active element group 167 at a substantially shortest distance or a short distance.

Further, in the thirteenth configuration example, since the current distribution in the conductor layer A and the current distribution in the conductor layer B can be substantially uniform and have opposite polarities by dividing the relay conductor 306 into a plurality of parts, it is possible to offset the magnetic field generated from the conductor layer A and the magnetic field generated from the conductor layer B. Therefore, in the thirteenth configuration example, it is possible to make it difficult to cause a difference in current distribution between the Vdd wiring and the Vss wiring due to an external factor. Therefore, the sixteenth configuration example is suitable for a case in which the current distribution on the XY plane is complicated or a case in which impedance of the conductors connected to the mesh conductors 331 and 332 differs between the Vdd wiring and the Vss wiring.

The thirteenth configuration example may be rotated at 90 degrees in the XY plane and used. Further, the thirteenth configuration example may be rotated at any angle instead of 90 degrees and used. For example, the thirteenth configuration example may be configured obliquely with respect to the X-axis and the Y-axis.

### SIMULATION RESULTS OF TWELFTH AND THIRTEENTH CONFIGURATION EXAMPLES

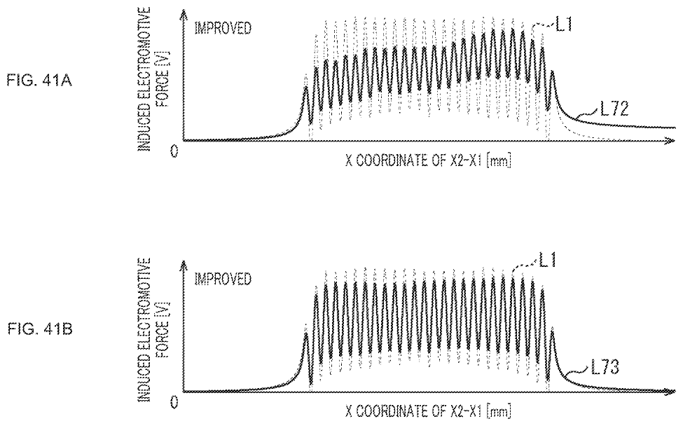

FIG. 41 illustrates change in the induced electromotive force that causes the inductive noise in the image as results of simulation when the twelfth configuration examples (FIG. 39) and the thirteenth configuration examples (FIG. 40) are applied to the solid-state imaging device 100. Conditions of a current flowing in the twelfth and thirteenth configuration examples are the same as those illustrated in FIG. 37. A horizontal axis of FIG. 41 indicates an X-axis coordinate of the image, and a vertical axis indicates a magnitude of the induced electromotive force.

A solid line L72 in A of FIG. 41 corresponds to the twelfth configuration example (FIG. 39), and the dotted line L1 corresponds to the first comparative example (FIG. 9). As is clear from a comparison of the solid line L72 with the dotted line L1, it can be seen that, in the twelfth configuration example, the induced electromotive force generated in the victim conductor loop is not changed, as compared with the first comparative example. Therefore, in the twelfth configuration example, it is possible to curb inductive noise in the image output from the solid-state imaging device 100, as compared with the first comparative example. However, the results of the simulations are results of simulation when the mesh conductor 321 is not connected to the active element group 167 and the mesh conductor 322 is not connected to the active element group 167. For example, when the mesh conductor 321 and at least a part of the active element group 167 are connected to each other at a substantially shortest distance or a short distance by a conductor via or the like or when the mesh conductor 322 and at least a part of the active element group 167 are connected to each other at a substantially shortest distance or a short distance by a conductor via or the like, an amount of current flowing through the mesh conductor 321 or the mesh conductor 322 gradually decreases according to a position. In such a case, there is a condition that the voltage drop, energy loss, or inductive noise can be greatly reduced to ½ or less by providing the relay conductor 305.

A solid line L73 in B of FIG. 41 corresponds to the thirteenth configuration example (FIG. 40), and a dotted line L1 corresponds to the first comparative example (FIG. 9). As is clear from a comparison of the solid line L73 with the dotted line L1, it can be seen that the thirteenth configuration example does not change the induced electromotive force generated in the victim conductor loop, as compared with the first comparative example. Therefore, the thirteenth configuration example can curb inductive noise in the image output from the solid-state imaging device 100, as compared with the first comparative example. However, the results of the simulations are results of simulation when the mesh conductor 331 is not connected to the active element group 167 and the mesh conductor 332 is not connected to the active element group 167. For example, when the mesh conductor 331 and at least a part of the active element group 167 are connected to each other at a substantially shortest distance or a short distance by a conductor via or the like or when the mesh conductor 332 and at least a part of the active element group 167 are connected to each other at a substantially shortest distance or a short distance by a conductor via or the like, an amount of current flowing through the mesh conductor 331 or the mesh conductor 332 gradually decreases according to a position. In such a case, there is a condition that the voltage drop, energy loss, or inductive noise can be greatly reduced to ½ or less by providing the relay conductor 306.

<5. Arrangement Examples of Electrodes on Semiconductor Substrate on which Conductor Layers A and B are Formed>Next, arrangement of electrodes in a semiconductor substrate on which conductors having different resistance values in the X direction and the Y direction are formed, as in the eleventh to thirteenth configuration examples of the conductor layers A and B described above, will be described.

Hereinafter, a case in which the thirteenth configuration example (FIG. 40) including conductor layers A and B including conductors (mesh conductors 331 and 332) having a resistance value in the Y direction smaller than the resistance value in the X direction is formed on a semiconductor substrate will be described by way of example. However, the same applies to a case in which the eleventh and twelfth configuration examples of the conductor layers A and B including conductors having a resistance value in the Y direction smaller than the resistance value in the X direction are formed on the semiconductor substrate.

In the thirteenth configuration example of the conductor layers A and B formed on the semiconductor substrate, since the resistance value of the conductors (the mesh conductors 331 and 332) in the Y direction is smaller than the resistance value in the X direction, it is easy for a current to flow in the Y direction. Therefore, in order to minimize the voltage drop (IR-Drop) in the conductors of the conductor layers A and B in the thirteenth configuration example, it is preferable for a plurality of pads (electrodes) arranged on the semiconductor substrate to be densely arranged in the X direction that is a direction in which the resistance value is large rather than a Y direction that is a direction in which the resistance value is small, but the pads may be arranged densely in the Y direction rather than in the X direction.

<First Arrangement Example of Pads on Semiconductor Substrate>

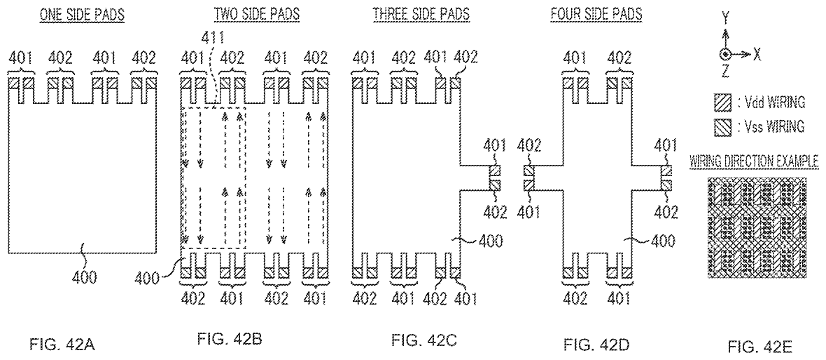

FIG. 42 is a plan view illustrating a first arrangement example in which pads are arranged more densely in the X direction rather than in the Y direction on the semiconductor substrate. In a coordinate system in FIG. 42, a horizontal direction indicates an X-axis, a vertical direction indicates a Y-axis, and a direction orthogonal to an XY plane indicates a Z-axis.

A of FIG. 42 illustrates a case in which pads are arranged on one side of a wiring region 400 in which a plurality of the thirteenth configuration examples (FIG. 40) including the conductor layers A and B are formed. B of FIG. 42 illustrates a case in which pads are arranged on two sides facing in a Y direction of the wiring region 400 in which a plurality of the thirteenth configuration examples (FIG. 40) including the conductor layers A and B are formed. A dotted arrow in FIG. 42 indicates an example of a direction of a current flowing therethrough, and a current loop 411 is generated by the current indicated by the dotted arrow. A direction of the current shown by the dotted arrow changes from moment to moment.

C of FIG. 42 illustrates a case in which pads are arranged on three sides of the wiring region 400 in which a plurality of the thirteenth configuration examples (FIG. 40) including the conductor layers A and B are formed. D of FIG. 42 illustrates a case in which pads are arranged on four sides of the wiring region 400 in which a plurality of the thirteenth configuration examples (FIG. 40) including the conductor layers A and B are formed. E of FIG. 42 illustrates a direction of a plurality of the thirteenth configuration examples of the conductor layers A and B formed in the wiring region 400.

The pad 401 arranged in the wiring region 400 is connected to the Vdd wiring, and the pad 402 is, for example, a wiring (Vss wiring) connected to GND or a negative power supply.

In the case of the first arrangement example illustrated in FIG. 42, each of the pads 401 and 402 includes one or a plurality of (two in the case of FIG. 42) pads arranged to be adjacent to each other. The pads 401 and 402 are arranged to be adjacent to each other. The pad 401 including one pad and the pad 402 including the one pad are arranged to be adjacent to each other, and the pad 401 including two pads and the pad 402 including the two pads are arranged to be adjacent to each other. Polarities of the pads 401 and 402 (a connection destination is the Vdd wiring or the Vss wiring) are opposite polarities. The number of pads 401 arranged in the wiring region 400 is substantially the same as the number of pads 402.

Accordingly, since distributions of current flowing in the respective conductor layers A and B formed in the wiring region 400 can be substantially uniform and have opposite polarities, it is possible to effectively offset magnetic fields generated from the conductor layers A and B and induced electromotive force based on the magnetic fields.

Further, as illustrated in B, C, and D of FIG. 42, when pads are formed on two or more sides of the wiring region 400, the polarities of the pads facing each other on the facing sides are opposite to each other. Accordingly, as indicated by a dotted arrow in B of FIG. 42, it is easy for currents in the same direction to be distributed at positions in which the wiring region 400 has common X coordinates and different Y coordinates.

<Second Arrangement Example of Pads on Semiconductor Substrate>

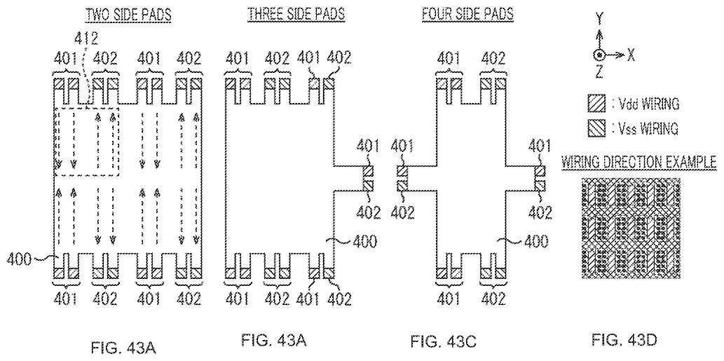

Next, FIG. 43 is a plan view illustrating a second arrangement example in which pads are arranged more densely in the X direction rather than the Y direction on the semiconductor substrate. In the coordinate system in FIG. 43, a horizontal direction indicates an X-axis, a vertical direction indicates a Y-axis, and a direction orthogonal to an XY plane indicates a Z-axis.

A of FIG. 43 illustrates a case in which the pads are arranged on two sides facing in the Y direction of the wiring region 400 in which the plurality of the thirteenth configuration examples (FIG. 40) including the conductor layers A and B are formed. A dotted arrow in FIG. 43 indicates a direction of a current flowing therethrough, and a current loop 412 is generated by the current indicated by the dotted arrow. A direction of the current shown by the dotted arrow changes from moment to moment.

B of FIG. 43 illustrates a case in which pads are arranged on three sides of the wiring region 400 in which a plurality of the thirteenth configuration examples (FIG. 40) including the conductor layers A and B are formed. C of FIG. 43 illustrates a case in which pads are arranged on four sides of the wiring region 400 in which a plurality of the thirteenth configuration examples (FIG. 40) including the conductor layers A and B are formed. D of FIG. 43 illustrates a direction of a plurality of the thirteenth configuration examples of the conductor layers A and B formed in the wiring region 400.

The pad 401 arranged in the wiring region 400 is connected to the Vdd wiring, and the pad 402 is, for example, a wiring (Vss wiring) connected to GND or a negative power supply.

In the case of the second arrangement example illustrated in FIG. 43, each of the pads 401 and 402 includes a plurality of (two in the case of FIG. 43) pads arranged to be adjacent to each other. The pads 401 and 402 are arranged to be adjacent to each other. The pad 401 including one pad and the pad 402 including the one pad are arranged to be adjacent to each other, and the pad 401 including two pads and the pad 402 including the two pads are arranged to be adjacent to each other. Polarities of the pads 401 and 402 (a connection destination is the Vdd wiring or the Vss wiring) are opposite polarities. The number of pads 401 arranged in the wiring region 400 is substantially the same as the number of pads 402.

Accordingly, since distributions of current flowing in the respective conductor layers A and B formed in the wiring region 400 can be substantially uniform and have opposite polarities, it is possible to effectively offset magnetic fields generated from the conductor layers A and B and induced electromotive force based on the magnetic fields.

Further, in the second arrangement example, the polarities of the pads facing each other on the facing sides are the same polarities. However, some of the pads facing each other on the facing sides may have opposite polarities. Accordingly, the current loop 412 smaller than the current loop 411 illustrated in B of FIG. 42 is generated in the wiring region 400. A size of the current loop affects a distribution range of the magnetic field, and when an electric field loop is smaller, the distribution range of the magnetic field becomes narrow. Therefore, in the second arrangement example, the distribution range of the magnetic field is narrower than in the first arrangement example. Therefore, the second arrangement example can reduce induced electromotive force to be generated and inductive noise based on the induced electromotive force, as compared with the first arrangement example.

<Third Arrangement Example of Pads on Semiconductor Substrate>

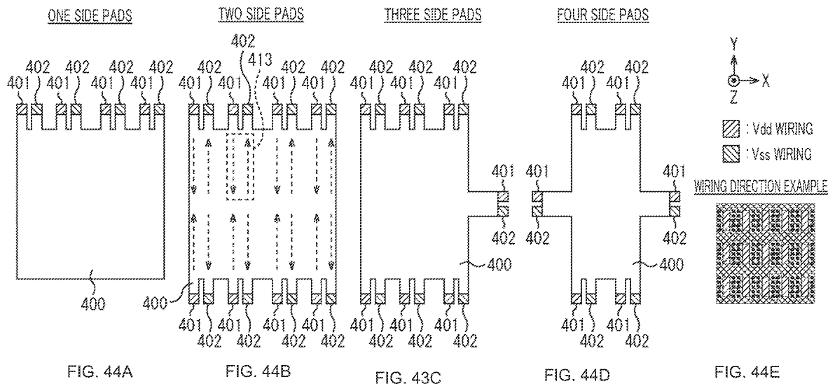

Next, FIG. 44 is a plan view illustrating a third arrangement example in which pads are arranged more densely in the X direction rather than the Y direction on the semiconductor substrate. In the coordinate system in FIG. 44, a horizontal direction indicates an X-axis, a vertical direction indicates a Y-axis, and a direction orthogonal to an XY plane indicates a Z-axis.

A of FIG. 44 illustrates a case in which pads are arranged on one side of the wiring region 400 in which the plurality of the thirteenth configuration examples (FIG. 40) including the conductor layers A and B are formed. B of FIG. 44 illustrates a case in which pads are arranged on the two sides facing in the Y direction of the wiring region 400 in which the plurality of the thirteenth configuration examples (FIG. 40) including the conductor layers A and B are formed. A dotted arrow in FIG. 44 indicates a direction of a current flowing therethrough, and a current loop 413 is generated by the current indicated by the dotted arrow.

C of FIG. 44 illustrates a case in which pads are arranged on the three sides of the wiring region 400 in which the plurality of the thirteenth configuration examples (FIG. 40) including the conductor layers A and B are formed. D of FIG. 44 illustrates a case in which pads are arranged on the four sides of the wiring region 400 in which the plurality of the thirteenth configuration examples (FIG. 40) including the conductor layers A and B are formed. E of FIG. 44 illustrates a direction of a plurality of the thirteenth configuration examples of the conductor layers A and B formed in the wiring region 400.

The pad 401 arranged in the wiring region 400 is connected to the Vdd wiring, and the pad 402 is, for example, a wiring (Vss wiring) connected to GND or a negative power supply.

In the case of the third arrangement example illustrated in FIG. 44, polarities of respective pads (of which a connection destination is the Vdd wiring or the Vss wiring) forming a pad group consisting of a plurality of (two in the case of FIG. 44) pads arranged to be adjacent to each other are opposite polarities. The number of pads 401 arranged on one side or all sides of the wiring region 400 is substantially the same as the number of pads 402.

Further, in the third arrangement example, the polarities of the pads facing each other on the facing sides are the same polarities. However, some of the pads facing each other on the facing sides may have opposite polarities.

Accordingly, the current loop 413 smaller than the current loop 412 illustrated in A of FIG. 43 is generated in the wiring region 400. Therefore, in the third arrangement example, a distribution range of the magnetic field is narrower than in the second arrangement example. Therefore, the third arrangement example can reduce induced electromotive force to be generated and inductive noise based on the induced electromotive force, as compared with the second arrangement example.

<Example of Conductor of which Resistance Value in Y Direction and Resistance Value in X Direction Differ>

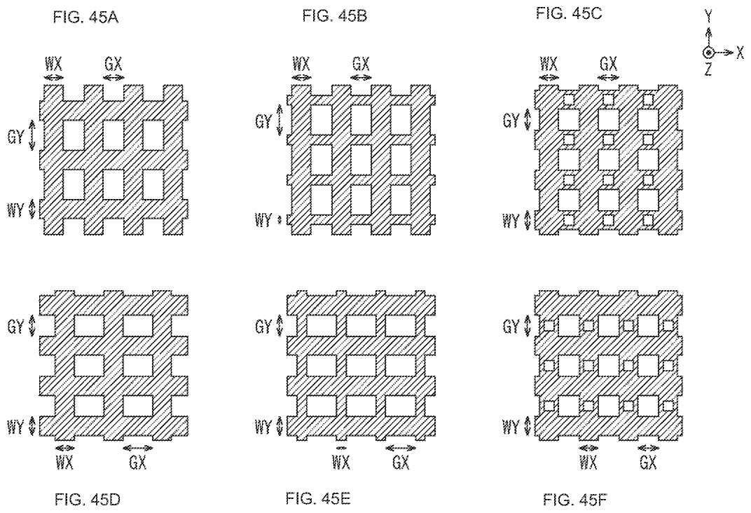

FIG. 45 is a plan view illustrating other examples of the conductors forming the conductor layers A and B. That is, FIG. 45 is a plan view illustrating examples of conductors of which a resistance value in the Y direction differs from a resistance value in the X direction. A to C of FIG. 45 illustrate examples in which the resistance value in the Y direction is smaller than the resistance value in the X direction, and D to F in FIG. 45 illustrate examples in which the resistance value in the X direction is smaller than the resistance value in the Y direction.

A of FIG. 45 illustrates a mesh conductor in which the conductor width WX in the X direction is equal to the conductor width WY in the Y direction, and the gap width GX in the X direction is smaller than the gap width GY in the Y direction. B of FIG. 45 illustrates a mesh conductor in which the conductor width WX in the X direction is larger than the conductor width WY in the Y direction and the gap width GX in the X direction is narrower than the gap width GY in the Y direction. C of FIG. 45 illustrates a mesh conductor in which the conductor width WX in the X direction is equal to the conductor width WY in the Y direction, the gap width GX in the X direction is equal to the gap width GY in the Y direction, and holes are provided in a region in which a portion having the conductor width WY and being long in the X direction does not intersect with a portion having the conductor width WX and being long in the Y direction.

D of FIG. 45 illustrates a mesh conductor in which the conductor width WX in the X direction is equal to the conductor width WY in the Y direction, and the gap width GX in the X direction is larger than the gap width GY in the Y direction. E of FIG. 45 illustrates a mesh conductor in which the conductor width WX in the X direction is smaller than the conductor width WY in the Y direction and the gap width GX in the X direction is larger than the gap width GY in the Y direction. F of FIG. 45 illustrates a mesh conductor in which the conductor width WX in the X direction is equal to the conductor width WY in the Y direction, the gap width GX in the X direction is equal to the gap width GY in the Y direction, and holes are provided in a region in which a portion having the conductor width WY and being long in the X direction does not intersect with a portion having the conductor width WX and being long in the Y direction.

In the first to third arrangement examples of the pads in the wiring region 400 illustrated in FIGS. 42 to 44, the resistance value in the Y direction as illustrated in A to C of FIG. 45 is smaller than the resistance value in the X direction, and when a conductor in which it is easy for a current to flow in the Y direction is formed in the wiring region 400, there is an effect of curbing a voltage drop (IR-Drop) in the conductor.

In the first to third arrangement examples of the pads in the wiring region 400 illustrated in FIGS. 42 to 44, the resistance value in the X direction as illustrated in D to F in FIG. 45 is smaller than the resistance value in the Y direction, and when a conductor in which it is easy for a current to flow in the X direction is formed in the wiring region 400, it is easy for the current to diffuse in the X direction and it is difficult for the magnetic field near the pads arranged on the sides of the wiring region 400 to concentrate and thus, an effect of curbing the occurrence of inductive noise can be expected.

<6. Modification Examples of Configuration Examples of Conductor Layers A and B>

Next, modification examples of some of the first to thirteenth configuration examples of the conductor layers A and B described above will be described.

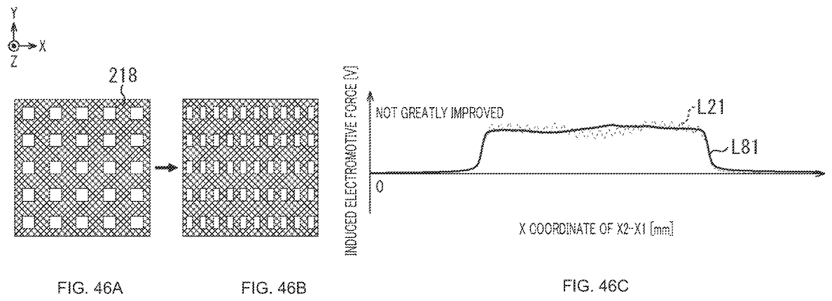

FIG. 46 is a diagram illustrating a modification example in which the conductor period in the X direction of the second configuration example (FIG. 15) of the conductor layers A and B is halved, and effects thereof. A of FIG. 46 illustrates a second configuration example of the conductor layers A and B, and B of FIG. 46 illustrates a modification example of the second configuration example of the conductor layers A and B.

C of FIG. 46 illustrates change in induced electromotive force that causes inductive noise in an image, as results of simulation when the modification example illustrated in B of FIG. 46 is applied to the solid-state imaging device 100. Conditions of a current flowing in the modification example are the same as those illustrated in FIG. 13. A horizontal axis of FIG. 46 indicates an X-axis coordinate of the image, and a vertical axis indicates a magnitude of the induced electromotive force.

A solid line L81 in C of FIG. 46 corresponds to the modification example illustrated in B of FIG. 46, and a dotted line L21 corresponds to the second configuration example (FIG. 15). As is clear from a comparison of the solid line L81 with the dotted line L21, change in the induced electromotive force generated in the victim conductor loop is slightly smaller in this modification example than in the second configuration example. Therefore, it can be seen that this modification example can slightly curb the inductive noise, as compared with the second configuration example.

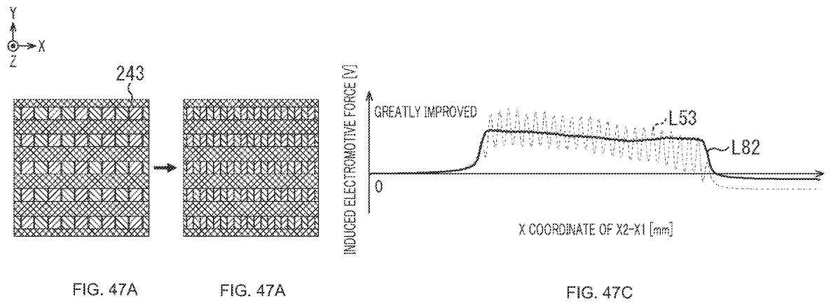

FIG. 47 is a diagram illustrating a modification example in which the conductor period in the X direction of the fifth configuration example (FIG. 26) of the conductor layers A and B is halved, and effects thereof. A of FIG. 47 illustrates a fifth configuration example of the conductor layers A and B, and B of FIG. 47 illustrates a modification example of the fifth configuration example of the conductor layers A and B.

C of FIG. 47 illustrates change in induced electromotive force that causes inductive noise in an image, as results of simulation when the modification example illustrated in B of FIG. 47 is applied to the solid-state imaging device 100. Conditions of a current flowing in the modification example are the same as those illustrated in FIG. 23. A horizontal axis of FIG. 47 indicates an X-axis coordinate of the image, and a vertical axis indicates a magnitude of the induced electromotive force.

A solid line L82 in C of FIG. 47 corresponds to the modification example illustrated in B of FIG. 47, and a dotted line L53 corresponds to the fifth configuration example (FIG. 26). As is clear from a comparison of the solid line L82 with the dotted line L53, the change in the induced electromotive force generated in the victim conductor loop in this modification example is much smaller than that in the fifth configuration example. Therefore, it can be seen that this modification example can further curb the inductive noise, as compared with the fifth configuration example.

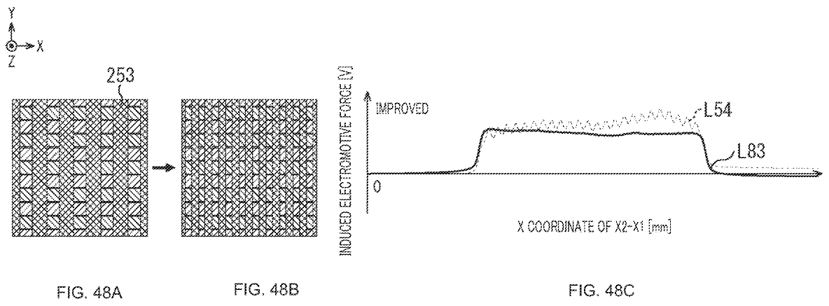

FIG. 48 is a diagram illustrating a modification example in which the conductor period in the X direction of the sixth configuration example (FIG. 27) of the conductor layers A and B is halved, and effects thereof. A of FIG. 48 illustrates a sixth configuration example of the conductor layers A and B, and B of FIG. 48 illustrates a modification example of the sixth configuration example of the conductor layers A and B.

C of FIG. 48 illustrates change in induced electromotive force that causes inductive noise in an image, as results of simulation when the modification example illustrated in B of FIG. 48 is applied to the solid-state imaging device 100. Conditions of a current flowing in the modification example are the same as those illustrated in FIG. 23. A horizontal axis of FIG. 48 indicates an X-axis coordinate of the image, and a vertical axis indicates a magnitude of the induced electromotive force.

A solid line L83 in C of FIG. 48 corresponds to the modification example illustrated in B of FIG. 48, and a dotted line L54 corresponds to the sixth configuration example (FIG. 27). As is clear from a comparison of the solid line L83 with the dotted line L54, change in the induced electromotive force generated in the victim conductor loop in this modification example is smaller than that in the sixth configuration example. Therefore, it can be seen that in this modification example, it is possible to further curb inductive noise, as compared with the sixth configuration example.

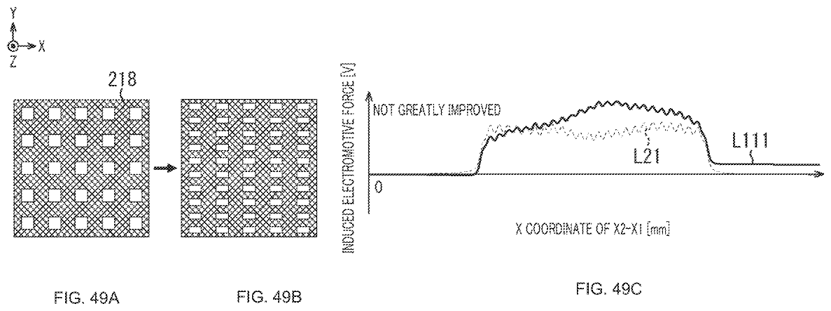

FIG. 49 is a diagram illustrating a modification example in which the conductor period in the Y direction of the second configuration example (FIG. 15) of the conductor layers A and B is halved, and effects thereof. A of FIG. 49 illustrates a second configuration example of the conductor layers A and B, and B of FIG. 49 illustrates a modification example of the second configuration example of the conductor layers A and B.

C of FIG. 49 illustrates change in induced electromotive force that causes inductive noise in an image, as results of simulation when the modification example illustrated in B of FIG. 49 is applied to the solid-state imaging device 100. Conditions of a current flowing in the modification example are the same as those illustrated in FIG. 13. A horizontal axis of FIG. 49 indicates an X-axis coordinate of the image, and a vertical axis indicates a magnitude of the induced electromotive force.

A solid line L111 in C of FIG. 49 corresponds to the modification example illustrated in B of FIG. 49, and a dotted line L21 corresponds to the second configuration example. As is clear from a comparison of the solid line L111 with the dotted line L21, the change in the induced electromotive force generated in the victim conductor loop in this modification example is slightly smaller than that in the second configuration example. Therefore, it can be seen that this modification example can slightly curb the inductive noise, as compared with the second configuration example.

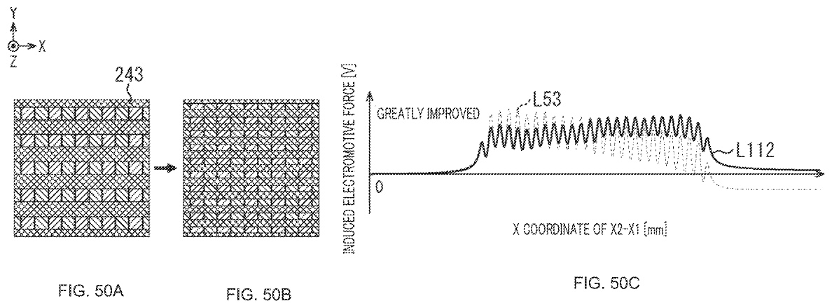

FIG. 50 is a diagram illustrating a modification example in which the conductor period in the Y direction of the fifth configuration example (FIG. 26) of the conductor layers A and B is halved, and effects thereof. A of FIG. 50 illustrates a fifth configuration example of the conductor layers A and B, and B of FIG. 50 illustrates a modification example of the fifth configuration example of the conductor layers A and B.

C of FIG. 50 illustrates change in induced electromotive force that causes inductive noise in an image, as results of simulation when the modification example illustrated in B of FIG. 50 is applied to the solid-state imaging device 100. Conditions of a current flowing in the modification example are the same as those illustrated in FIG. 23. A horizontal axis of FIG. 50 indicates an X-axis coordinate of the image, and a vertical axis indicates a magnitude of the induced electromotive force.

A solid line L112 in C of FIG. 50 corresponds to the modification example illustrated in B of FIG. 50, and a dotted line L53 corresponds to the fifth configuration example. As is clear from a comparison of the solid line L112 with the dotted line L53, change in induced electromotive force generated in the victim conductor loop in this modification example is much smaller than that in the fifth configuration example. Therefore, it can be seen that this modification example can further curb the inductive noise, as compared with the fifth configuration example.

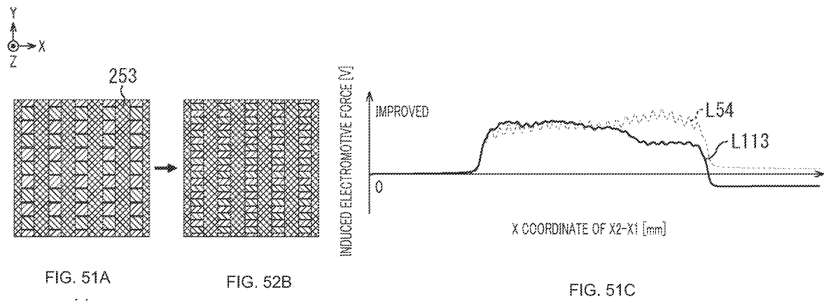

FIG. 51 is a diagram illustrating a modification example in which the conductor period in the Y direction of the sixth configuration example (FIG. 27) of the conductor layers A and B is halved, and effects thereof. Further, A of FIG. 51 illustrates a sixth configuration example of the conductor layers A and B, and B of FIG. 51 illustrates a modification example of the sixth configuration example of the conductor layers A and B.

C of FIG. 51 illustrates change in induced electromotive force that causes inductive noise in an image, as results of simulation when the modification example illustrated in B of FIG. 51 is applied to the solid-state imaging device 100. Conditions of a current flowing in the modification example are the same as those illustrated in FIG. 23. A horizontal axis of FIG. 51 indicates an X-axis coordinate of the image, and a vertical axis indicates a magnitude of the induced electromotive force.

A solid line L113 in C of FIG. 51 corresponds to the modification example illustrated in B of FIG. 51, and a dotted line L54 corresponds to the sixth configuration example. As is clear from a comparison of the solid line L113 with the dotted line L54, change in the induced electromotive force generated in the victim conductor loop this modification example is smaller than that in the sixth configuration example. Therefore, it can be seen that in this modification example, it is possible to further curb inductive noise, as compared with the sixth configuration example.

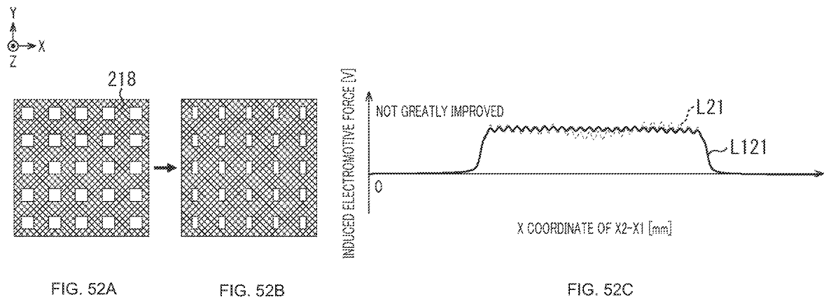

FIG. 52 is a diagram illustrating a modification example in which the conductor width in the X direction of the second configuration example (FIG. 15) of the conductor layers A and B is doubled, and effects thereof. A of FIG. 52 illustrates a second configuration example of the conductor layers A and B, and B of FIG. 52 illustrates a modification example of the second configuration example of the conductor layers A and B.

C of FIG. 52 illustrates change in induced electromotive force that causes inductive noise in an image, as results of simulation when the modification example illustrated in B of FIG. 52 is applied to the solid-state imaging device 100. Conditions of a current flowing in the modification example are the same as those illustrated in FIG. 13. A horizontal axis of FIG. 52 indicates an X-axis coordinate of the image, and a vertical axis indicates a magnitude of the induced electromotive force.

A solid line L121 in C of FIG. 52 corresponds to the modification example illustrated in B of FIG. 52, and a dotted line L21 corresponds to the second configuration example. As is clear from a comparison of the solid line L121 with the dotted line L21, change in the induced electromotive force generated in the victim conductor loop in this modification example is slightly smaller than that in the second configuration example. Therefore, it can be seen that this modification example can slightly curb the inductive noise, as compared with the second configuration example.

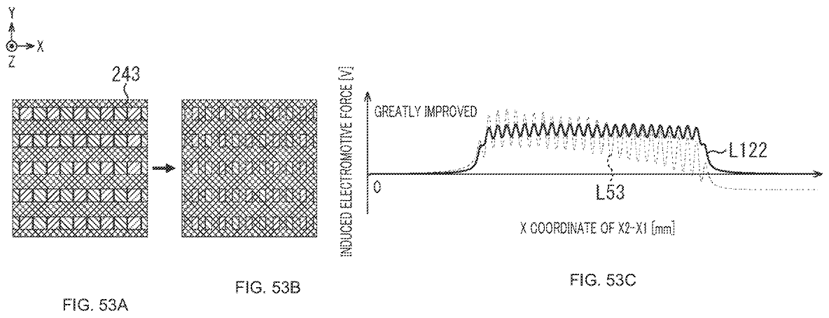

FIG. 53 is a diagram illustrating a modification example in which the conductor width in the X direction of the fifth configuration example (FIG. 26) of the conductor layers A and B is doubled, and effects thereof. A of FIG. 53 illustrates a fifth configuration example of the conductor layers A and B, and B of FIG. 53 illustrates a modification example of the fifth configuration example of the conductor layers A and B.

C of FIG. 53 illustrates change in induced electromotive force that causes inductive noise in an image, as results of simulation when the modification example illustrated in B of FIG. 53 is applied to the solid-state imaging device 100. Conditions of a current flowing in the modification example are the same as those illustrated in FIG. 23. A horizontal axis of FIG. 53 indicates an X-axis coordinate of the image, and a vertical axis indicates a magnitude of the induced electromotive force.

A solid line L122 in C of FIG. 53 corresponds to the modification example illustrated in B of FIG. 53, and a dotted line L53 corresponds to the fifth configuration example. As is clear from a comparison of the solid line L122 with the dotted line L53, change in the induced electromotive force generated in the victim conductor loop in this modification example is much smaller than that in the fifth configuration example. Therefore, it can be seen that this modification example can further curb the inductive noise, as compared with the fifth configuration example.

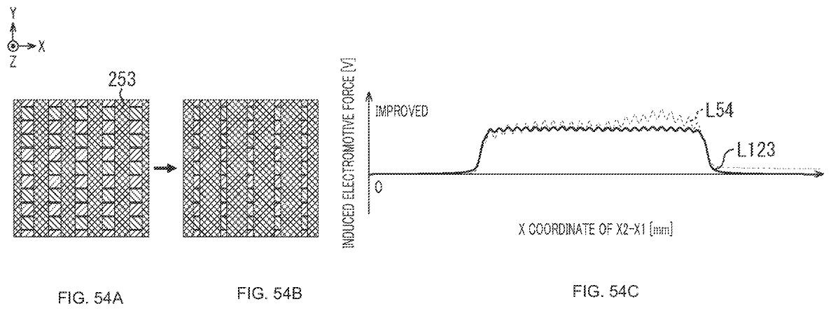

FIG. 54 is a diagram illustrating a modification example in which the conductor width in the X direction of the sixth configuration example (FIG. 27) of the conductor layers A and B is doubled, and effects thereof. A of FIG. 54 illustrates a sixth configuration example of the conductor layers A and B, and B of FIG. 54 illustrates a modification example of the sixth configuration example of the conductor layers A and B.

C of FIG. 54 illustrates change in induced electromotive force that causes inductive noise in an image, as results of simulation when the modification example illustrated in B of FIG. 54 is applied to the solid-state imaging device 100. Conditions of a current flowing in the modification example are the same as those illustrated in FIG. 23. A horizontal axis of FIG. 54 indicates an X-axis coordinate of the image, and a vertical axis indicates a magnitude of the induced electromotive force.

A solid line L123 in C of FIG. 54 corresponds to the modification example illustrated in B of FIG. 54, and a dotted line L54 corresponds to the sixth configuration example. As is clear from a comparison of the solid line L123 with the dotted line L54, change in the induced electromotive force generated in the victim conductor loop in this modification example is smaller than that in the sixth configuration example. Therefore, it can be seen that in this modification example, it is possible to further curb inductive noise, as compared with the sixth configuration example.

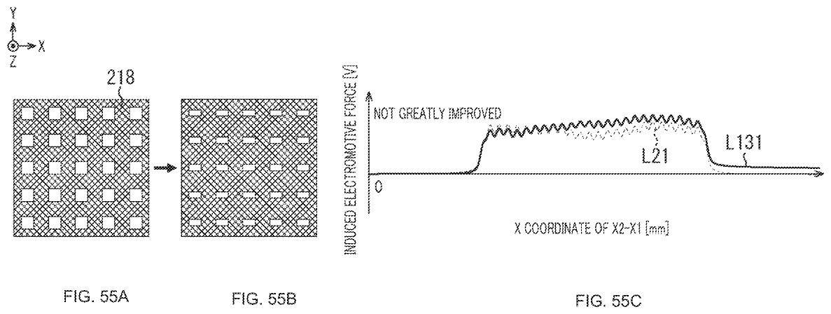

FIG. 55 is a diagram illustrating a modification example in which the conductor width in the Y direction of the second configuration example (FIG. 15) of the conductor layers A and B is doubled, and effects thereof. A of FIG. 55 illustrates a second configuration example of the conductor layers A and B, and B of FIG. 55 illustrates a modification example of the second configuration example of the conductor layers A and B.

C of FIG. 55 illustrates change in induced electromotive force that causes inductive noise in an image, as results of simulation when the modification example illustrated in B of FIG. 55 is applied to the solid-state imaging device 100. Conditions of a current flowing in the modification example are the same as those illustrated in FIG. 13. A horizontal axis of FIG. 55 indicates an X-axis coordinate of the image, and a vertical axis indicates a magnitude of the induced electromotive force.

A solid line L131 in C of FIG. 55 corresponds to the modification example illustrated in B of FIG. 55, and a dotted line L21 corresponds to the second configuration example. As is clear from a comparison of the solid line L131 with the dotted line L21, change in the induced electromotive force generated in the victim conductor loop in this modification example is slightly smaller than in the second configuration example. Therefore, it can be seen that this modification example can slightly curb the inductive noise, as compared with the second configuration example.

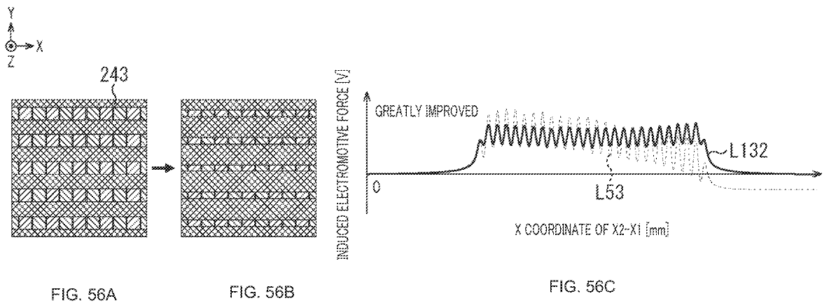

FIG. 56 is a diagram illustrating a modification example in which the conductor width in the Y direction of the fifth configuration example (FIG. 26) of the conductor layers A and B is doubled, and effects thereof. A of FIG. 56 illustrates a fifth configuration example of the conductor layers A and B, and B of FIG. 56 illustrates a modification example of the fifth configuration example of the conductor layers A and B.

C of FIG. 56 illustrates change in induced electromotive force that causes inductive noise in an image, as results of simulation when the modification example illustrated in B of FIG. 56 is applied to the solid-state imaging device 100. Conditions of a current flowing in the modification example are the same as those illustrated in FIG. 23. A horizontal axis of FIG. 56 indicates an X-axis coordinate of the image, and a vertical axis indicates a magnitude of the induced electromotive force.

A solid line L132 in C of FIG. 56 corresponds to the modification example illustrated in B of FIG. 56, and a dotted line L53 corresponds to the fifth configuration example. As is clear from a comparison of the solid line L132 with the dotted line L53, change in the induced electromotive force generated in the victim conductor loop in this modification example is much smaller than that in the fifth configuration example. Therefore, it can be seen that this modification example can further curb the inductive noise, as compared with the fifth configuration example.

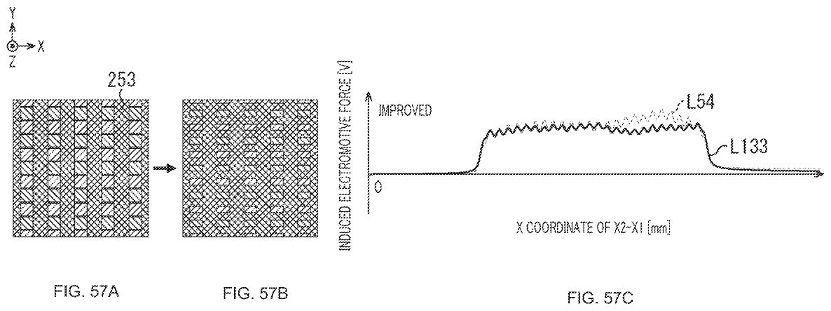

FIG. 57 is a diagram illustrating a modification example in which the conductor width in the Y direction of the sixth configuration example (FIG. 27) of the conductor layers A and B is doubled, and effects thereof. A of FIG. 57 illustrates a sixth configuration example of the conductor layers A and B, and B of FIG. 57 illustrates a modification example of the sixth configuration example of the conductor layers A and B.

C of FIG. 57 illustrates change in induced electromotive force that causes inductive noise in an image, as results of simulation when the modification example illustrated in B of FIG. 57 is applied to the solid-state imaging device 100. Conditions of a current flowing in the modification example are the same as those illustrated in FIG. 23. A horizontal axis of FIG. 57 indicates an X-axis coordinate of the image, and a vertical axis indicates a magnitude of the induced electromotive force.

A solid line L133 in C of FIG. 57 corresponds to the modification example illustrated in B of FIG. 57, and a dotted line L54 corresponds to the sixth configuration example. As is clear from a comparison of the solid line L133 with the dotted line L54, change in the induced electromotive force generated in the victim conductor loop in this modification example is smaller than that in the sixth configuration example. Therefore, it can be seen that in this modification example, it is possible to further curb inductive noise, as compared with the sixth configuration example.

<7. Modification Examples of Mesh Conductor>

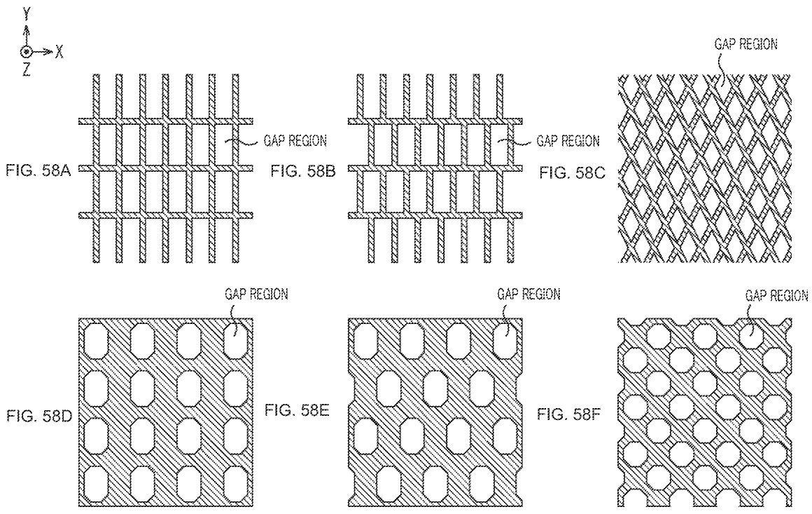

Next, FIG. 58 is a plan view illustrating a modification example of the mesh conductor that can be applied to each of configuration examples of the conductor layers A and B described above.

A of FIG. 58 is a simplified diagram of a shape of a mesh conductor adopted in each of configuration examples of the conductor layers A and B described above. In the mesh conductor adopted in each of the configuration examples of the conductor layers A and B described above, gap regions have a rectangular shape, and the respective rectangular gap regions are arranged in a straight shape in the X direction and the Y direction.

B of FIG. 58 is a simplified diagram illustrating a first modification example of the mesh conductor. In the first modification example of the mesh conductor, gap regions have rectangular shape, and the respective gap regions are arranged in a straight shape in the X direction and are arranged to be displaced in each stage in the Y direction.

C of FIG. 58 is a simplified diagram illustrating a second modification example of the mesh conductor. In the second modification example of the mesh conductor, gap regions have a diamond shape and the gap regions are arranged in a straight shape in an oblique direction.

D of FIG. 58 is a simplified diagram of a third modification example of the mesh conductor. In the third modification example of the mesh conductor, gap regions have a circular shape or a polygonal shape (octagon in the case of D in FIG. 58) other than the rectangular shape, and the respective gap regions are arranged in a straight shape in the X direction and the Y direction.

E of FIG. 58 is a simplified diagram of a fourth modification example of the mesh conductor. In the fourth modification example of the mesh conductor, the gap regions have a circular shape or a polygonal shape (octagon in the case of E in FIG. 58) other than the rectangular shape, and the respective gap regions are arranged in a straight shape in the X direction and are arranged to be displaced in each stage in the Y direction.

F of FIG. 58 is a simplified diagram of a fifth modification example of the mesh conductor. In the fifth modification example of the mesh conductor, gap regions have a circular shape or a polygonal shape (octagon in the case of F in FIG. 58) other than the rectangular shape, and the respective gap regions are arranged in a straight shape in an oblique direction.

A shape of the mesh conductor that can be applied to the respective configuration examples of the conductor layers A and B is not limited to the modification examples illustrated in FIG. 58 and may be any mesh shape.

<8. Various Effects>

<Improvement of Degree of Freedom in Layout Design>

As described above, in each of the configuration examples of the conductor layers A and B, the planar conductor or the mesh conductor is adopted. Generally, a mesh conductor (lattice conductor) has a wiring structure that is periodic in the X and Y directions. Therefore, when a mesh conductor having a basic periodic structure that is a unit of the periodic structure (for one period) is designed, the basic periodic structure is repeatedly arranged in the X direction or the Y direction such that the layout of the wirings can be simply designed as compared with the case in which the straight conductor is used. In other words, when the mesh conductor is used, the degree of freedom in a layout is improved as compared with the case in which the straight conductor is used. Therefore, the man-hours, time, or cost required for layout design can be reduced.

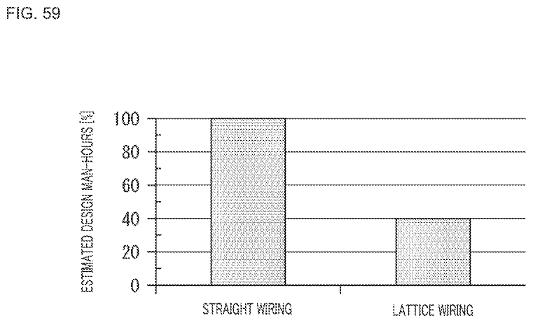

FIG. 59 is a diagram illustrating a result of a simulation of design man-hours when a layout of circuit wirings satisfying predetermined conditions is designed using the straight conductor and design man-hours when the layout of circuit wirings is designed using the mesh conductor (lattice conductor).

In the case of FIG. 59, when the design man-hours when the layout is designed using the straight conductor is 100%, the design man-hours when the layout is designed using the mesh conductor (lattice conductor) is about 40% and the design man-hours can be greatly reduced.

<Reduction of Voltage Drop (IR-Drop)>

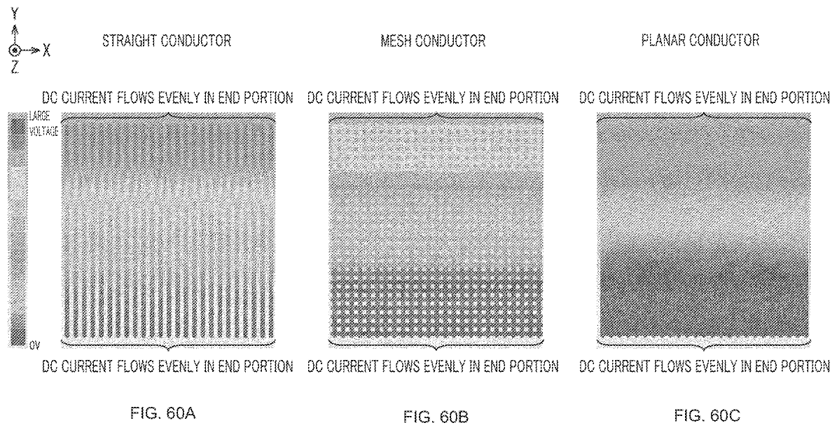

FIG. 60 is a diagram illustrating voltage change when a DC current flows in the Y direction under the same conditions for conductors having the same material and different shapes arranged on the XY plane.

A of FIG. 60 corresponds to a straight conductor, B of FIG. 60 corresponds to a mesh conductor, and C of FIG. 60 corresponds to a planar conductor, and shade of color represents a voltage. When A, B, and C of FIG. 60 are compared with each other, it can be seen that the voltage change is largest in the straight conductor, and is next largest in an order of the mesh conductor and the planar conductor.

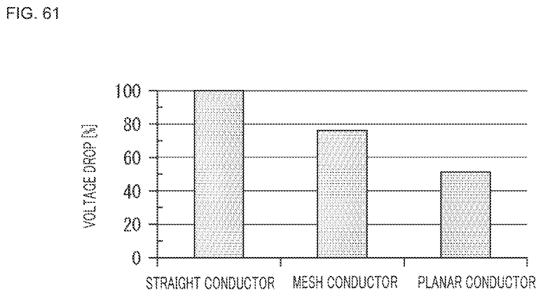

FIG. 61 is a diagram illustrating voltage drops of the mesh conductor and the planar conductor in a relative graph, in which a voltage drop of the straight conductor illustrated in A of FIG. 60 is 100%.

As is clear from FIG. 61, it can be seen that the planar conductor and the mesh conductor can reduce a voltage drop (IR-Drop) that can be a fatal obstacle for driving of a semiconductor device, as compared with the straight conductor.

However, it is known that the planar conductor cannot be manufactured in current semiconductor substrate processing. Therefore, it is practical to adopt a configuration example in which a mesh conductor is used for both the conductor layers A and B. However, this does not apply when the semiconductor substrate processing has evolved so that the planar conductor can be manufactured. For the uppermost layer metal or the lowermost layer metal among metal layers, the planar conductor cannot be manufactured in some cases.

<Reduction of Capacitive Noise>

It is conceivable that the conductor (planar conductor or mesh conductor) forming the conductor layers A and B causes not only inductive noise but also capacitive noise for the victim conductor loop including the signal line 132 and the control line 133.

Here, the capacitive noise means that, when a voltage is applied to the conductors forming the conductor layers A and B, a voltage is generated in the signal line 132 or the control line 133 due to capacitive coupling between the conductor and the signal line 132 or the control line 133, and voltage noise occurs in the signal line 132 or the control line 133 due to change in the applied voltage. This voltage noise becomes noise of the pixel signal.

It is conceivable that a magnitude of the capacitive noise is substantially proportional to capacitance or a voltage between the conductor forming the conductor layers A and B and a wiring such as the signal line 132 or the control line 133. Regarding the capacitance, when an overlapping area of two conductors (one may be a conductor and the other may be a wiring) is S, the two conductors are arranged in parallel at an interval d, and a dielectric of permittivity ϵ is uniformly filled between the conductors, capacitance C between the two conductors is C=ϵ*S/d. Therefore, it can be seen that the capacitive noise increases when the overlapping area S of the two conductors is larger.

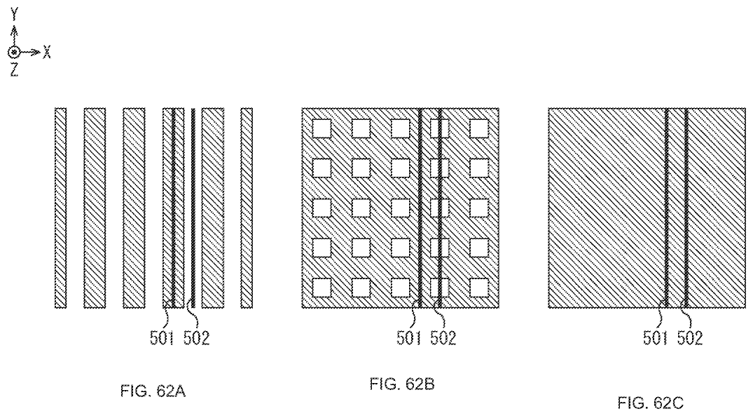

FIG. 62 is a diagram illustrating a difference in capacitance between a conductor and another conductor (wiring) having the same material and different shapes arranged on an XY plane.

A of FIG. 62 shows a straight conductor long in the Y direction, and wirings 501 and 502 (corresponding to the signal line 132 or the control line 133) formed in a straight shape in the Y direction at an interval in the Z direction from the straight conductor. However, the entire wiring 501 overlaps a conductor region of the straight conductor, but the entire wiring 502 overlaps a gap region of the straight conductor and does not have an area overlapping the conductor region.

B of FIG. 62 illustrates the mesh conductor and the wirings 501 and 502 formed in a straight shape in the Y direction at an interval from the mesh conductor in the Z direction. Here, the entire wiring 501 overlaps a conductor region of the mesh conductor, but substantially a half of the wiring 502 overlaps the conductor region of the mesh conductor.

C of FIG. 62 illustrates the planar conductor and the wirings 501 and 502 formed in a straight shape in the Y direction at an interval from the planar conductor in the Z direction. Here, the entire wirings 501 and 502 overlap the conductive region of the planar conductor.

When differences between capacitance between the conductor (straight conductor, mesh conductor, or planar conductor) and the wiring 501 in A, B, and C of FIG. 62 and capacitance of the conductor (straight conductor, mesh conductor, or planar conductor) and the wiring 502 are compared with each other, the straight conductor has the largest capacitance and the mesh conductor and the planar conductor have the next largest capacitance in this order.

That is, in the straight conductor, a difference in capacitance between the straight conductor and the wiring due to a difference between XY coordinates of the wiring is large, and occurrence of capacitive noise also greatly differs. Therefore, the capacitive noise is likely to be noise of a pixel signal with high visibility in an image.

On the other hand, in the mesh conductor or the planar conductor, the difference in capacitance between the conductor and the wiring due to the difference between the XY coordinates of the wiring is small as compared with the straight conductor and thus, it is possible to further reduce occurrence of the capacitive noise. Therefore, it is possible to curb the noise of the pixel signal caused by the capacitive noise.

<Reduction of Radiative Noise>

In the configuration examples other than the first configuration example among the respective configuration examples of the conductor layers A and B, the mesh conductor is used as described above. With the mesh conductor, an effect of reducing radiative noise can be expected. Here, the radiative noise is assumed to include radiative noise from the inside of the solid-state imaging device 100 to the outside (unnecessary radiation) and radiative noise from the outside of the solid-state imaging device 100 to the inside (delivered noise).

Since the radiative noise from the outside of the solid-state imaging device 100 to the inside can cause voltage noise in the signal line 132 or noise in the pixel signal, an effect of curbing voltage noise or pixel signal noise can be expected when the configuration example using the mesh conductor in at least one of the conductor layer A and the conductor layer B is adopted.

Since the conductor period of the mesh conductor affects a frequency band of radiative noise that can be reduced by the mesh conductor, it is possible to reduce the radiative noise in a broader frequency band as compared with a case in which mesh conductors having the same conductor frequency are used for the layers A and B, when mesh conductors having different conductor periods are used for the respective conductor layers A and B.

The above-described effects are merely examples and are not limited, and there may be other effects.

<9. Configuration Examples in which Lead Portions Differ>

Incidentally, for example, when the wiring layer 165A that is the conductor layer A or the wiring layer 165B that is the conductor layer B is connected to the pad 401 or 402, a wiring lead portion for connection to the pad 401 or 402 is provided, as illustrated in FIGS. 42 to 44. The wiring lead portion is usually formed to have a narrow wiring width according to a size of the pad.

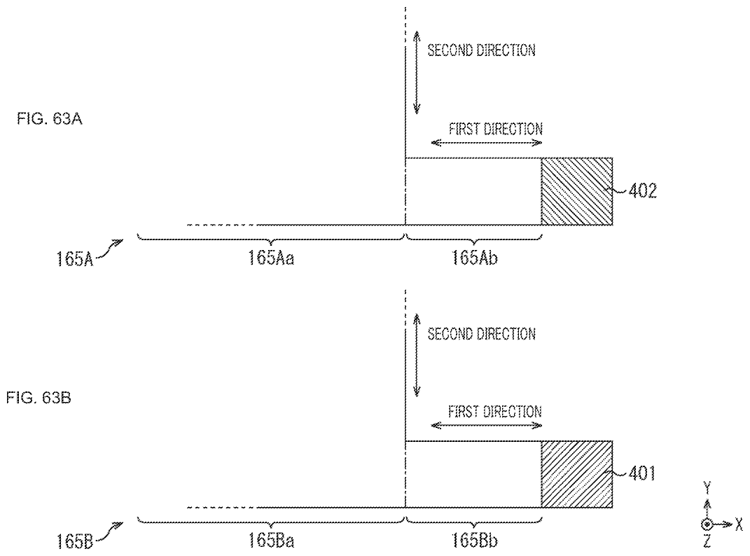

Therefore, for example, the wiring layer 165A (conductor layer A) divided into a main conductor portion 165Aa and a lead conductor portion 165Ab, as illustrated in A of FIG. 63, is considered. The main conductor portion 165Aa is a portion of which a main purpose is to shield the hot carrier light emitted from the active element group 167 and curb occurrence of inductive noise, and has a larger area than the lead conductor portion 165Ab. The lead conductor portion 165Ab is a portion of which a main purpose is to connect the main conductor portion 165Aa to the pad 402 and supply a predetermined voltage such as GND or a negative power supply (V_{SS}) to the main conductor portion 165Aa. In the lead conductor portion 165Ab, at least one length (width) in the X direction (first direction) or Y direction (second direction) is shorter (narrower) than a length (width) of the main conductor portion 165Aa. A connection portion between the main conductor portion 165Aa and the lead conductor portion 165Ab that is indicated by an alternate long and short dash line in A of FIG. 63 is referred to as a bonding portion.

Similarly, the wiring layer 165B (conductor layer B) divided into a main conductor portion 165Ba and a lead conductor portion 165Bb, as illustrated in B of FIG. 63, is considered. The main conductor portion 165Ba is a portion of which a main purpose is to shield the hot carrier light emitted from the active element group 167 and curb occurrence of inductive noise, and has a larger area than the lead conductor portion 165Bb. The lead conductor portion 165Bb is a portion of which a main purpose is to connect the main conductor portion 165Ba to the pad 401 and supply a predetermined voltage such as a positive power supply (Vdd) to the main conductor portion 165Ba. In the lead conductor portion 165Bb, at least one length (width) in the X direction (first direction) or Y direction (second direction) is shorter (narrower) than a length (width) of the main conductor portion 165Ba. A connection portion between the main conductor portion 165Ba and the lead conductor portion 165Bb that is indicated by an alternate long and short dash line in B of FIG. 63 is referred to as a bonding portion.

When the main conductor portion 165Aa and the main conductor portion 165Ba are collectively referred to without distinguishing between the wiring layer 165A (conductor layer A) and the wiring layer 165B (conductor layer B), and when the lead conductor portion 165Ab and the lead conductor portion 165Bb are collectively referred to, the main conductor portions and the lead conductor portions are referred to as a main conductor portion 165a and a lead conductor portion 165b, respectively.

Although the description has been given using an example in which the lead conductor portion 165Ab and the lead conductor portion 165Bb are connected to the pad 401 or 402 for easy understanding in FIG. 63, the lead conductor portion 165Ab and the lead conductor portion 165Bb are not necessarily connected to the pad 401 or 402 and may be connected to another wiring or electrode.

Further, FIG. 63 illustrates an example in which the pad 401 and the pad 402 have substantially the same shape and are arranged at substantially the same position, but the present technology is not limited thereto. For example, the pad 401 and the pad 402 may have different shapes and may be arranged at different positions. Further, the pad 401 and the pad 402 may be configured to have a smaller size than that in the example illustrated in FIG. 63, may be configured not to contact each other in the wiring layer 165A, or may be configured not to contact each other in the wiring layer 165B, or a plurality of the pads may be provided.

Further, an example in which end portion positions in the Y direction substantially match in the main conductor portion 165Aa and the lead conductor portion 165Ab is illustrated in FIG. 63, but the present technology is not limited thereto. For example, the end portion positions may not match in the main conductor portion 165Aa and the lead conductor portion 165Ab. Similarly, an example in which end portion positions in the Y direction substantially match in the main conductor portion 165Ba and the lead conductor portion 165Bb is illustrated in FIG. 63, but the present technology is not limited thereto. For example, the end portion positions may not match in the main conductor portion 165Ba and the lead conductor portion 165Bb. The same applies to each of configuration examples that will be described below, for the shapes and positions of the main conductor portion 165a and the lead conductor portion 165b, and a relationship with the pads 401 and 402.

In the first to thirteenth configuration examples described above, both the main conductor portion 165Aa and the lead conductor portion 165Ab in the wiring layer 165A are formed with the same wiring pattern such as planar conductors or mesh conductors without particularly distinguishing between the main conductor portion 165Aa and the lead conductor portion 165Ab.

Both the main conductor portion 165Ba and the lead conductor portion 165Bb in the wiring layer 165B are formed with the same wiring pattern such as planar conductors or mesh conductors without particularly distinguishing between the main conductor portion 165Ba and the lead conductor portion 165Bb.

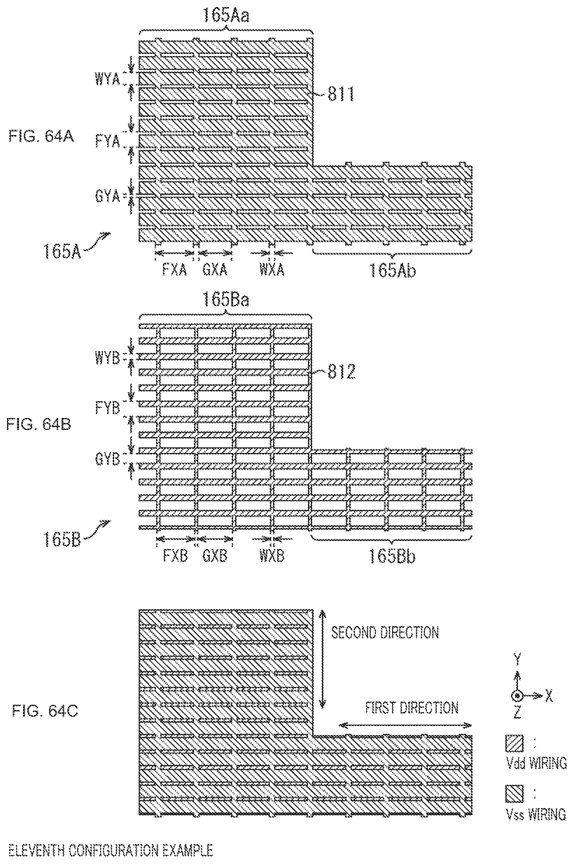

FIG. 64 illustrates an example in which the eleventh configuration example illustrated in FIG. 36 is applied to the wiring layer 165A and the wiring layer 165B using different wiring patterns, as an example of the first to thirteenth configuration examples described above.

A of FIG. 64 illustrates the conductor layer A (wiring layer 165A), and B of FIG. 64 illustrates the conductor layer B (wiring layer 165B). In a coordinate system in FIG. 64, a horizontal direction indicates an X-axis, a vertical direction indicates a Y-axis, and a direction orthogonal to an XY plane indicates a Z-axis.

In the eleventh configuration example illustrated in FIG. 36, the mesh conductor 311 of the conductor layer A illustrated in A of FIG. 36 has, for example, a shape in which the conductor width WXA in the X direction is wider than the gap width GXA, whereas a mesh conductor 811 of the conductor layer A illustrated in A of FIG. 64 has a shape in which the conductor width WXA in the X direction is narrower than the gap width GXA. Further, in the Y direction, the mesh conductor 311 illustrated in A of FIG. 36 has, for example, a shape in which the conductor width WYA is narrower than the gap width GYA, whereas the mesh conductor 811 of the conductor layer A illustrated in A of FIG. 64 has a shape in which the conductor width WYA is wider than the gap width GYA. The mesh conductor 311 of the conductor layer A illustrated in A of FIG. 36 has, for example, a shape in which the conductor width WYA and the conductor width WXA are substantially the same, whereas the mesh conductor 811 of the conductor layer A illustrated in A of FIG. 64 has a shape in which the conductor width WYA is wider than the conductor width WXA. In the mesh conductor 811 of the conductor layer A of FIG. 64, the same pattern is periodically arranged in the conductor period FXA in the X direction and the same pattern is periodically arranged in the conductor period FYA in the Y direction in both the main conductor portion 165Aa and the lead conductor portion 165Ab.

The conductor layer B has a shape in which a ratio of the gap width GXB to the conductor width WXB in the X direction of the mesh conductor 812 of the conductor layer B in B of FIG. 64 (gap width GXB/conductor width WXB) is higher than a ratio of the gap width GXB to the conductor width WXB in the X direction of the mesh conductor 312 of the conductor layer B in B of FIG. 36 (gap width GXB/conductor width WXB). In other words, in the mesh conductor 812 of the conductor layer B illustrated in B of FIG. 64, a difference between the conductor width WXB and the gap width GXB becomes larger than that of the mesh conductor 312 of the conductor layer B illustrated in B of FIG. 36. In the Y direction, a ratio of the gap width GYB to the conductor width WYB of the mesh conductor 812 of the conductor layer B in B of FIG. 64 (gap width GYB/conductor width WYB) is lower than a ratio of the gap width GYB to the conductor width WYB of the mesh conductor 312 of the conductor layer B illustrated in B of FIG. 36 (gap width GYB/conductor width WYB). The mesh conductor 312 of the conductor layer B illustrated in B of FIG. 36 is an example in which the conductor width WYB and the conductor width WXB have substantially the same shape, whereas the mesh conductor 812 of the conductor layer B in B of FIG. 64 has a shape in which the conductor width WYB is wider than the conductor width WXB. In the mesh conductor 812 of the conductor layer B in B of FIG. 64, the same pattern is periodically arranged in the conductor period FXB in the X direction and the same pattern is periodically arranged in the conductor period FYB in the Y direction in both the main conductor portion 165Ba and the lead conductor portion 165Bb.

C of FIG. 64 illustrates a state in which the respective conductor layers A and B illustrated in A and B of FIG. 64 are viewed from the conductor layer A side (photodiode 141 side). In C of FIG. 64, a region of the conductor layer B that is hidden due to overlapping with the conductor layer A is not illustrated.

As illustrated in C of FIG. 64, in the eleventh configuration example, since the active element group 167 is covered with at least one of the conductor layer A and the conductor layer B, it is possible to shield the hot carrier light emitted from the active element group 167 and to curb the occurrence of inductive noise.

Thus, the first to thirteenth configuration examples described above are example in which, in the wiring layer 165A (conductor layer A), the main conductor portion 165Aa and the lead conductor portion 165Ab are formed in the same wiring pattern without any particular distinguishment and, similarly, in the wiring layer 165B (conductor layer B), the main conductor portion 165Ba and the lead conductor portion 165Bb are formed in the same wiring pattern without any particular distinguishment.

However, since the lead conductor portion 165b is formed with an area smaller than that of the main conductor portion 165a, the lead conductor portion 165b is a portion on which a current is concentrated, and it is preferable for the lead conductor portion 165b to be configured to reduce the wiring resistance or make it easy for a current to diffuse in the main conductor portion 165a.

Therefore, hereinafter, a configuration example in which in the wiring layer 165A (conductor layer A), a wiring pattern of the lead conductor portion 165Ab is set as a wiring pattern different from that of the main conductor portion 165Aa, and in the wiring layer 165B (conductor layer B), a wiring pattern of the lead conductor portion 165Bb is set as a wiring pattern different from that of the main conductor portion 165Ba will be described.

### FOURTEENTH CONFIGURATION EXAMPLE

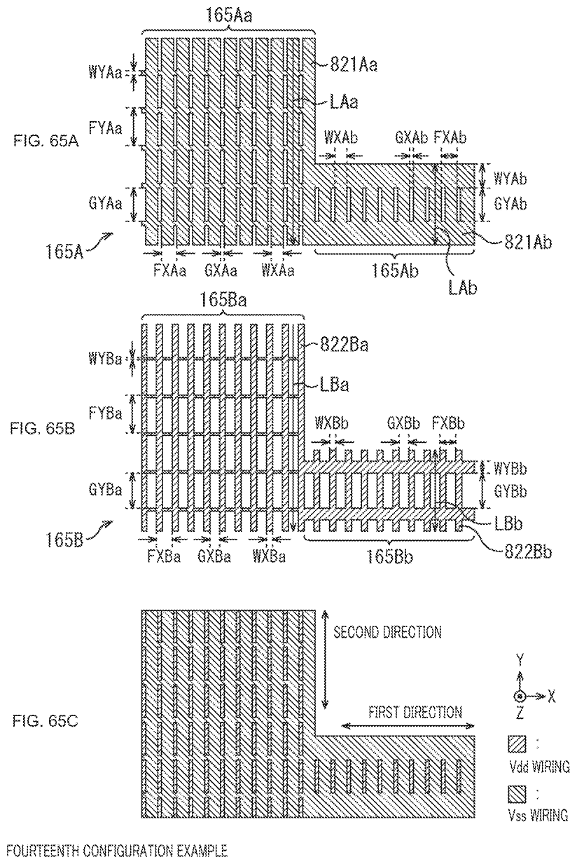

FIG. 65 illustrates a fourteenth configuration example of the conductor layers A and B. A of FIG. 65 illustrates the conductor layer A, and B of FIG. 65 illustrates the conductor layer B. In a coordinate system in FIG. 65, a horizontal direction indicates an X-axis, a vertical direction indicates a Y-axis, and a direction orthogonal to an XY plane indicates a Z-axis.

As illustrated in A of FIG. 65, the conductor layer A in the fourteenth configuration example includes a mesh conductor 821Aa of the main conductor portion 165Aa and a mesh conductor 821Ab of the lead conductor portion 165Ab. The mesh conductor 821Aa and the mesh conductor 821Ab are wirings (Vss wirings) connected to GND or a negative power supply, for example.

The mesh conductor 821Aa of the main conductor portion 165Aa has a conductor width WXAa and a gap width GXAa in the X direction and is configured with the same patterns periodically arranged in a conductor period FXAa, and has a conductor width WYAa and a gap width GYAa in the Y direction and is configured with the same patterns periodically arranged in a conductor period FYAa. Therefore, the mesh conductor 821Aa has a shape including a repetitive pattern in which a predetermined basic pattern is repeatedly arranged in a conductor period in at least one of the X direction and the Y direction.

The mesh conductor 821Ab of the lead conductor portion 165Ab has a conductor width WXAb and a gap width GXAb in the X direction and is configured with the same patterns periodically arranged in a conductor period FXAb, and has a conductor width WYAb and a gap width GYAb in the Y direction. Therefore, the mesh conductor 821Ab has a shape including a repetitive pattern in which a predetermined basic pattern is repeatedly arranged in a conductor period in at least one of the X direction and the Y direction.

Further, when the corresponding conductor widths WXA, gap widths GXA, conductor widths WYA, and gap widths GYA of the mesh conductor 821Aa of the main conductor portion 165Aa and the mesh conductor 821Ab of the lead conductor portion 165Ab are compared with each other, at least one of them has a different value, and a repetitive pattern of the mesh conductor 821Ab of the lead conductor portion 165Ab differs from a repetitive pattern of the mesh conductor 821Aa of the main conductor portion 165Aa.

When a total length LAa of the mesh conductor 821Aa of the main conductor portion 165Aa in the Y direction and is compared with a total length LAb of the mesh conductor 821Ab of the lead conductor portion 165Ab in the Y direction, the total length LAa of the mesh conductor 821Aa is longer than the total length LAb of the mesh conductor 821Ab. Therefore, in the mesh conductor 821Ab of the lead conductor portion 165Ab, a current is locally concentrated as compared with the mesh conductor 821Aa of the main conductor portion 165Aa and thus, a voltage drop (particularly IR-Drop) is larger.

Here, the repetitive pattern of the mesh conductor 821Ab of the lead conductor portion 165Ab has a shape in which a current flows at least in a first direction, which is an X direction toward the main conductor portion 165Aa, and a conductor width (wiring width) WYAb in a second direction (Y direction) orthogonal to the first direction is larger than a conductor width (wiring width) WYAa of the mesh conductor 821Aa of the main conductor portion 165Aa in the second direction. Accordingly, wiring resistance of the mesh conductor 821Ab of the lead conductor portion 165Ab, which is a current concentration location, can be reduced and thus, it is possible to further reduce the voltage drop. Although the example in which the conductor width WYAb is larger than the conductor width WYAa has been described, the present technology is not limited thereto and, for example, the conductor width WXAb may be larger than the conductor width WXAa.

Accordingly, the wiring resistance of the mesh conductor 821Ab can be reduced and thus, it is possible to further reduce the voltage drop.

Further, at least a part of the mesh conductor 821Aa of the main conductor portion 165Aa has a pattern (shape) in which it is easy for a current to flow in the Y direction (second direction) rather than the X direction (first direction). Specifically, since at least one of the wiring width (conductor width WXAa and conductor width WYAa) and wiring interval (gap width GXAa and gap width GYAa) differs, the wiring resistance in the Y direction is smaller than that in the X direction. Accordingly, in the main conductor portion 165Aa having the total length LAa longer than the total length LAb of the mesh conductor 821Ab, since it is easy for the current to be diffused in the Y direction, it is possible to mitigate electrode concentration around a bonding portion of the main conductor portion 165Aa and the lead conductor portion 165Ab and to further reduce the inductive noise.

The conductor layer B in the fourteenth configuration example includes a mesh conductor 822Ba of the main conductor portion 165Ba and a mesh conductor 822Bb of the lead conductor portion 165Bb, as illustrated in B of FIG. 65. The mesh conductor 822Ba and the mesh conductor 822Bb are, for example, wirings (Vdd wirings) connected to a positive power supply.

The mesh conductor 822Ba of the main conductor portion 165Ba has a conductor width WXBa and a gap width GXBa in the X direction and is configured with the same patterns periodically arranged in a conductor period FXBa, and has a conductor width WYBa and a gap width GYBa in the Y direction and is configured with the same patterns periodically arranged in a conductor period FYBa. Therefore, the mesh conductor 822Ba has a shape including a repetitive pattern in which a predetermined basic pattern is repeatedly arranged in a conductor period in at least one of the X direction and the Y direction.

The mesh conductor 822Bb of the lead conductor portion 165Bb has a conductor width WXBb and a gap width GXBb in the X direction and is configured with the same patterns periodically arranged in a conductor period FXBb, and has the conductor width WYBb and the gap width GYBb in the Y direction. Therefore, the mesh conductor 822Bb has a shape including a repetitive pattern in which a predetermined basic pattern is repeatedly arranged in a conductor period in at least one of the X direction and the Y direction.

Further, when the corresponding conductor widths WXB, gap widths GXB, conductor widths WYB, and gap widths GYB of the mesh conductor 822Ba of the main conductor portion 165Ba and the mesh conductor 822Bb of the lead conductor portion 165Bb are compared with each other, at least one of them has a different value, and a repetitive pattern of the mesh conductor 822Bb of the lead conductor portion 165Bb differs from the repetitive pattern of the mesh conductor 822Ba of the main conductor portion 165Ba.

When a total length LBa of the mesh conductor 822Ba of the main conductor portion 165Ba in the Y direction is compared with a total length LBb of the mesh conductor 822Bb of the lead conductor portion 165Bb in the Y direction, the total length LBa of the mesh conductor 822Ba is larger than the total length LBb of the mesh conductor 822Bb. Therefore, in the mesh conductor 822Bb of the lead conductor portion 165Bb, a current is locally concentrated as compared with the mesh conductor 822Ba of the main conductor portion 165Ba and thus, a voltage drop (particularly IR-Drop) is larger.

Here, the repetitive pattern of the mesh conductor 822Bb of the lead conductor portion 165Bb has a shape in which a current flows at least in a first direction, which is an X direction toward the main conductor portion 165Ba, and a conductor width (wiring width) WYBb in a second direction (Y direction) orthogonal to the first direction is larger than a conductor width (wiring width) WYBa of the mesh conductor 822Ba of the main conductor portion 165Ba in the second direction. Accordingly, wiring resistance of the mesh conductor 822Bb of the lead conductor portion 165Bb, which is a current concentration location, can be reduced and thus, it is possible to further reduce the voltage drop. Although the example in which the conductor width WYBb is larger than the conductor width WYBa has been described, the present technology is not limited thereto and, for example, the conductor width WXBb may be larger than the conductor width WXBa. Accordingly, the wiring resistance of the mesh conductor 822Bb can be reduced and thus, it is possible to further reduce the voltage drop.

Further, at least a part of the mesh conductor 822Ba of the main conductor portion 165Ba has a pattern (shape) in which it is easy for a current to flow in the Y direction (second direction) rather than the X direction (first direction). Specifically, since at least one of the wiring width (conductor width WXBa and conductor width WYBa) and wiring interval (gap width GXBa and gap width GYBa) differs, the wiring resistance in the Y direction is smaller than that in the X direction. Accordingly, in the main conductor portion 165Ba having the total length LBa longer than the total length LBb of the mesh conductor 822Bb, since it is easy for the current to be diffused in the Y direction, it is possible to mitigate electrode concentration around a bonding portion of the main conductor portion 165Ba and the lead conductor portion 165Bb and to further reduce the inductive noise.

As described above, according to the fourteenth configuration example, in the wiring layer 165A (conductor layer A), the repetitive pattern of the mesh conductor 821Ab of the lead conductor portion 165Ab is formed as a pattern different from the repetitive pattern of the mesh conductor 821Aa of the main conductor portion 165Aa and the main conductor portion 165Aa is electrically connected to the lead conductor portion 165Ab and thus, it is possible to reduce the wiring resistance of the lead conductor portion 165Ab and to further reduce the voltage drop. Similarly, in the wiring layer 165B (conductor layer B), the repetitive pattern of the mesh conductor 822Bb of the lead conductor portion 165Bb is formed as a pattern different from the repetitive pattern of the mesh conductor 822Ba of the main conductor portion 165Ba and the main conductor portion 165Ba is electrically connected to the lead conductor portion 165Bb and thus, it is possible to reduce the wiring resistance of the lead conductor portion 165Bb and to further reduce the voltage drop.

Further, the active element group 167 is covered with at least one of the conductor layer A and the conductor layer B in a state in which the conductor layer A and the conductor layer B are overlapped, as illustrated in C of FIG. 65. That is, the main conductor portion 165Aa of the wiring layer 165A and the main conductor portion 165Ba of the wiring layer 165B form a light shielding structure, and the lead conductor portion 165Ab of the wiring layer 165A and the lead conductor portion 165Bb of the wiring layer 165B form a light shielding structure. Thereby, it is possible to shield the hot carrier light emitted from the active element group 167 also in the fourteenth configuration example, similar to the first to thirteenth configuration examples described above.

### MODIFICATION EXAMPLES OF FOURTEENTH CONFIGURATION EXAMPLE

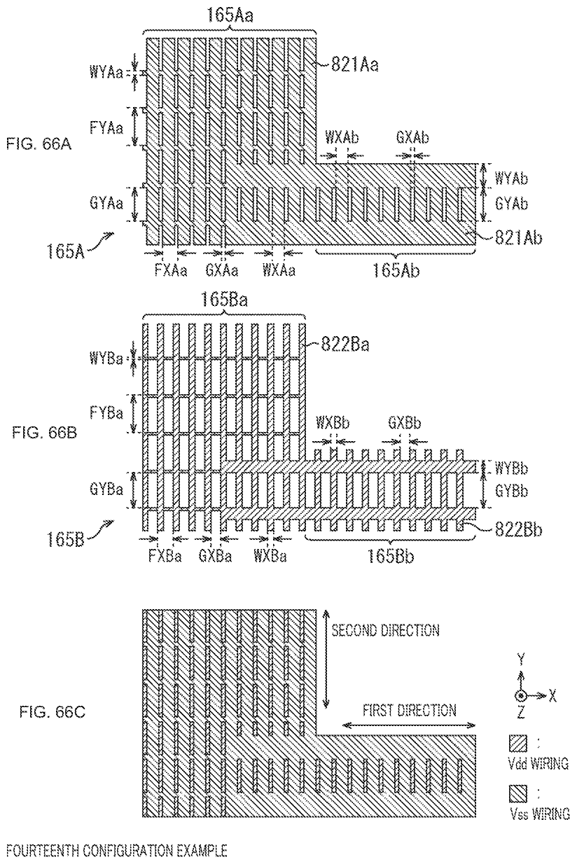

FIGS. 66 to 68 illustrate first to third modification examples of the fourteenth configuration example. A to C of FIGS. 66 to 68 correspond to A to C of FIG. 65 and are denoted by the same reference signs, description of common parts will be appropriately omitted, and different portions will be described.

In the fourteenth configuration example illustrated in FIG. 65, in the wiring layer 165A (conductor layer A), a bonding portion between the main conductor portion 165Aa and the lead conductor portion 165Ab is arranged on a side of a rectangle surrounding an outer periphery of the main conductor portion 165Aa, but the present technology is not limited thereto.

For example, the main conductor portion 165Aa and the lead conductor portion 165Ab are connected so that the mesh conductor 821Ab of the lead conductor portion 165Ab enters the rectangle surrounding the outer periphery of the main conductor portion 165Aa, as illustrated in A of FIG. 66.

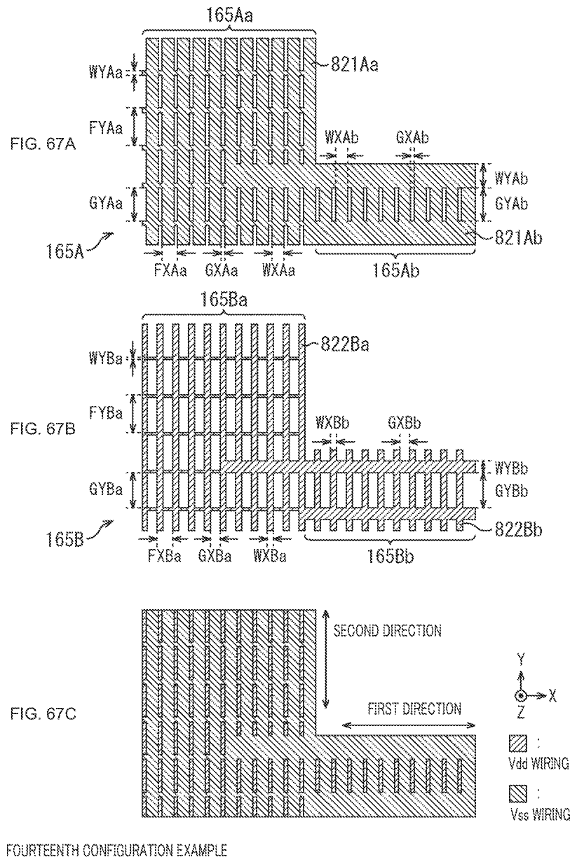

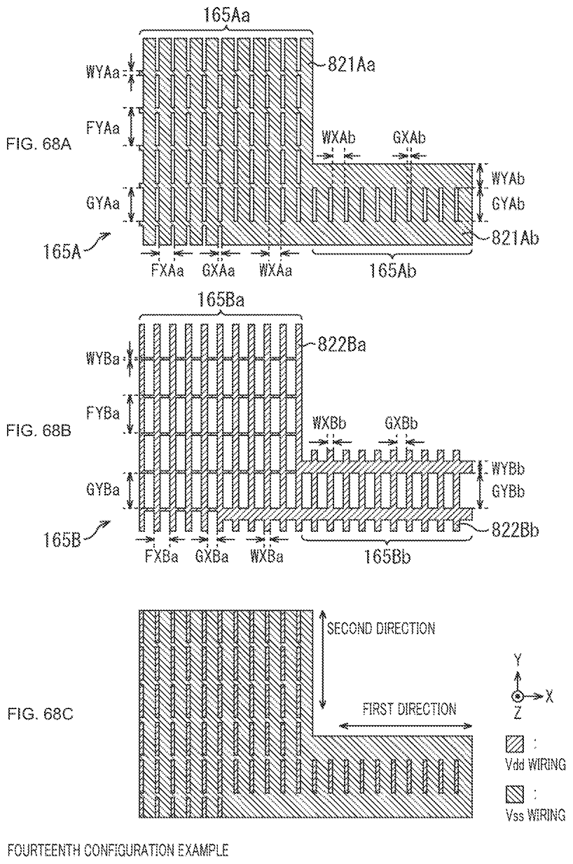

Further, for example, The main conductor portion 165Aa and the lead conductor portion 165Ab may be connected so that only some of the plurality of wirings of the conductor width WYAb extending toward the main conductor portion 165Aa of the mesh conductor 821Ab of the lead conductor portion 165Ab enter the rectangle surrounding the outer periphery of the main conductor portion 165Aa, as illustrated in A of FIG. 67 and A of FIG. 68. The mesh conductor 821Ab of the lead conductor portion 165Ab in C of FIG. 67 extends so that an upper wiring between the two wirings having the conductor width WYAb enters the rectangle surrounding the outer periphery of the main conductor portion 165Aa, and the mesh conductor 821Ab of the lead conductor portion 165Ab in A of FIG. 68 extends so that a lower wiring enters the rectangle surrounding the outer periphery of the main conductor portion 165Aa.

The same applies to the wiring layer 165B (conductor layer B). That is, in the fourteenth configuration example illustrated in FIG. 65, a bonding portion between the main conductor portion 165Ba and the lead conductor portion 165Bb is arranged on the side of the rectangle surrounding the outer periphery of the main conductor portion 165Ba, but the present technology is not limited thereto.

For example, the main conductor portion 165Ba and the lead conductor portion 165Bb are connected so that the mesh conductor 822Bb of the lead conductor portion 165Bb enters the rectangle surrounding the outer periphery of the main conductor portion 165Ba, as illustrated in B of FIG. 66.

Further, for example, The main conductor portion 165Ba and the lead conductor portion 165Bb may be connected so that only some of the plurality of wirings of the conductor width WYBb extending toward the main conductor portion 165Ba of the mesh conductor 822Bb of the lead conductor portion 165Bb enter the rectangle surrounding the outer periphery of the main conductor portion 165Ba, as illustrated in B of FIG. 67 and B of FIG. 68. The mesh conductor 822Bb of the lead conductor portion 165Bb in B of FIG. 67 extends so that an upper wiring between the two wirings having the conductor width WYBb enters the rectangle surrounding the outer periphery of the main conductor portion 165Ba, and the mesh conductor 822Bb of the lead conductor portion 165Bb in B of FIG. 68 extends so that a lower wiring enters the rectangle surrounding the outer periphery of the main conductor portion 165Ba.

As illustrated in FIGS. 66 to 68, a shape of a portion in which the main conductor portion 165a and the lead conductor portion 165b are connected may be configured in a complicated manner.

Although the main conductor portion 165Aa and the lead conductor portion 165Ab are connected so that the mesh conductor 821Ab of the lead conductor portion 165Ab enters the rectangle surrounding the outer periphery of the main conductor portion 165Aa in the first to third modification examples of the fourteenth configuration example illustrated in FIGS. 66 to 68, the mesh conductor 821Aa of the main conductor portion 165Aa may project to the outside of the rectangle surrounding the outer periphery of the main conductor portion 165Aa and enter the lead conductor portion 165Ab side. Further, the mesh conductor 822Ba of the main conductor portion 165Ba may project outside the rectangle surrounding the outer periphery of the main conductor portion 165Ba and enter the lead conductor portion 165Bb side.

### FIFTEENTH CONFIGURATION EXAMPLE

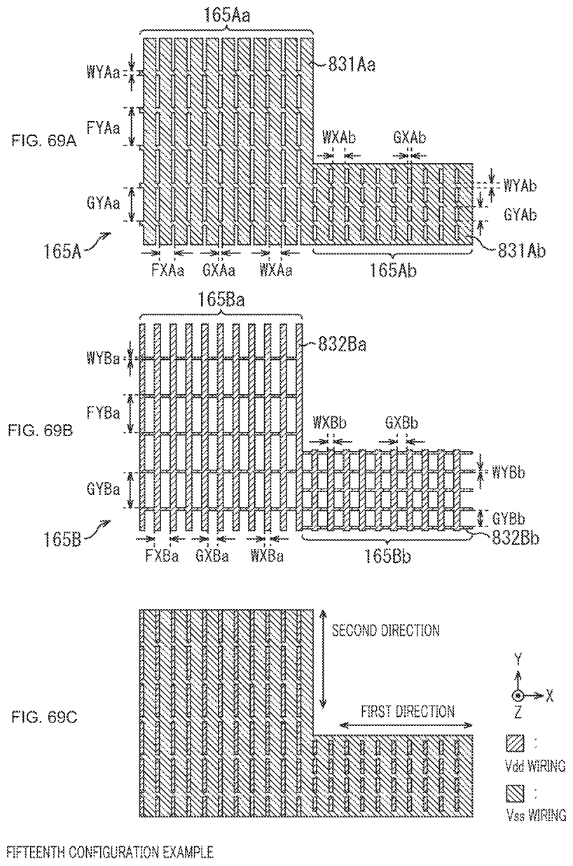

FIG. 69 illustrates a fifteenth configuration example of the conductor layers A and B. A of FIG. 69 illustrates the conductor layer A, and B of FIG. 69 illustrates the conductor layer B. In a coordinate system in FIG. 69, a horizontal direction indicates an X-axis, a vertical direction indicates a Y-axis, and a direction orthogonal to an XY plane indicates a Z-axis.

The conductor layer A in the fifteenth configuration example includes a mesh conductor 831Aa of the main conductor portion 165Aa and a mesh conductor 831Ab of the lead conductor portion 165Ab, as illustrated in A of FIG. 69. The mesh conductor 831Aa and the mesh conductor 831Ab are, for example, wirings (Vss wiring) connected to GND or a negative power supply.

The mesh conductor 831Aa of the main conductor portion 165Aa is the same as the mesh conductor 821Aa of the main conductor portion 165Aa in the fourteenth configuration example illustrated in FIG. 65. On the other hand, the mesh conductor 831Ab of the lead conductor portion 165Ab differs from the mesh conductor 821Ab of the lead conductor portion 165Ab in the fourteenth configuration example illustrated in FIG. 65.

Specifically, the gap width GYAb of the mesh conductor 831Ab of the lead conductor portion 165Ab in the Y direction is smaller than the gap width GYAa of the mesh conductor 831Aa of the main conductor portion 165Aa in the Y direction. In the fourteenth configuration example illustrated in FIG. 65, the gap width GYAb of the mesh conductor 821Ab of the lead conductor portion 165Ab in the Y direction is the same as the gap width GYAa of the mesh conductor 821Aa of the main conductor portion 165Aa in the Y direction.

Thus, the gap width GYAb of the mesh conductor 831Ab of the lead conductor portion 165Ab in the Y direction is smaller than the gap width GYAa of the mesh conductor 831Aa of the main conductor portion 165Aa in the Y direction and thus, it is possible to reduce the wiring resistance of the mesh conductor 831Ab of the lead conductor portion 165Ab that is a current concentration location and to further reduce the voltage drop. The example in which the gap width GYAb is smaller than the gap width GYAa has been described, but the present technology is not limited thereto and, for example, the gap width GXAb may be smaller than the gap width GXAa. Accordingly, it is possible to reduce the wiring resistance of the mesh conductor 831Ab and thus, it is possible to further reduce the voltage drop.

As illustrated in B of FIG. 69, the conductor layer B in the fifteenth configuration example includes a mesh conductor 832Ba of the main conductor portion 165Ba and a mesh conductor 832Bb of the lead conductor portion 165Bb. The mesh conductor 832Ba and the mesh conductor 832Bb are, for example, wirings (Vdd wirings) connected to a positive power supply.

The mesh conductor 832Ba of the main conductor portion 165Ba is the same as the mesh conductor 822Ba of the main conductor portion 165Ba in the fourteenth configuration example illustrated in FIG. 65. On the other hand, the mesh conductor 832Bb of the lead conductor portion 165Bb differs from the mesh conductor 822Bb of the lead conductor portion 165Bb in the fourteenth configuration example illustrated in FIG. 65.

Specifically, the gap width GYBb of the mesh conductor 832Bb of the lead conductor portion 165Bb in the Y direction is smaller than the gap width GYBa of the mesh conductor 832Ba of the main conductor portion 165Ba in the Y direction. In the fourteenth configuration example illustrated in FIG. 65, the gap width GYBb of the mesh conductor 822Bb of the lead conductor portion 165Bb in the Y direction is the same as the gap width GYBa of the mesh conductor 822Ba of the main conductor portion 165Ba in the Y direction.

Thus, the gap width GYBb of the mesh conductor 832Bb of the lead conductor portion 165Bb in the Y direction is smaller than the gap width GYBa of the mesh conductor 832Ba of the main conductor portion 165Ba in the Y direction and thus, it is possible to reduce the wiring resistance of the mesh conductor 832Bb of the lead conductor portion 165Bb that is a current concentration location and to further reduce the voltage drop. The example in which the gap width GYBb is smaller than the gap width GYBa has been described, but the present technology is not limited thereto and, for example, the gap width GXBb may be smaller than the gap width GXBa. Accordingly, it is possible to reduce the wiring resistance of the mesh conductor 832Bb and thus, it is possible to further reduce the voltage drop.

Further, the active element group 167 is covered with at least one of the conductor layer A and the conductor layer B in a state in which the conductor layer A and the conductor layer B are overlapped, as illustrated in C of FIG. 69. That is, the main conductor portion 165Aa of the wiring layer 165A and the main conductor portion 165Ba of the wiring layer 165B form a light shielding structure, and the lead conductor portion 165Ab of the wiring layer 165A and the lead conductor portion 165Bb of the wiring layer 165B form a light shielding structure. Thereby, also in the fifteenth configuration example, it is possible to shield the hot carrier light emitted from the active element group 167.

### FIRST MODIFICATION EXAMPLE OF FIFTEENTH CONFIGURATION EXAMPLE

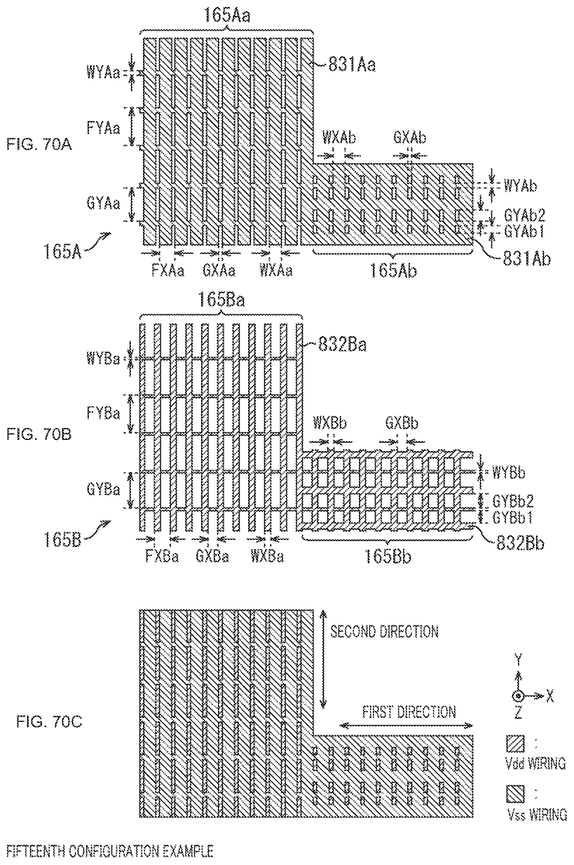

FIG. 70 illustrates a first modification example of the fifteenth configuration example. Further, A of FIG. 70 illustrates the conductor layer A, and B of FIG. 70 illustrates the conductor layer B. C of FIG. 70 illustrates a state in which the respective conductor layers A and B illustrated in A and B of FIG. 70 are viewed from the conductor layer A side. In a coordinate system in FIG. 70, a horizontal direction indicates an X-axis, a vertical direction indicates a Y-axis, and a direction orthogonal to an XY plane indicates a Z-axis.

The first modification example of the fifteenth configuration example differs from the fifteenth configuration example illustrated in FIG. 69 in that all the gap widths GYAb in the Y direction of the lead conductor portion 165Ab of the wiring layer 165A are not uniform. Specifically, the mesh conductor 831Ab of the lead conductor portion 165Ab of the wiring layer 165A has two kinds of gap widths GYAb including a small gap width GYAb1 and a large gap width GYAb2, as illustrated in A of FIG. 70.

Further, the first modification example of the fifteenth configuration example differs from the fifteenth configuration example illustrated in FIG. 69 in that all the gap widths GYBb in the Y direction of the lead conductor portion 165Bb of the wiring layer 165B are not uniform. Specifically, the mesh conductor 832Bb of the lead conductor portion 165Bb of the wiring layer 165B has two kinds of gap widths GYBb including a small the gap width GYBb1 and a large the gap width GYBb2, as illustrated in B of FIG. 70.

In the first modification example of the fifteenth configuration example, the lead conductor portion 165Ab of the wiring layer 165A and the lead conductor portion 165Bb of the wiring layer 165B form a light shielding structure in a state in which the conductor layer A and the conductor layer B are overlapped, as illustrated in C of FIG. 70.

### SECOND MODIFICATION EXAMPLES OF FIFTEENTH CONFIGURATION EXAMPLE

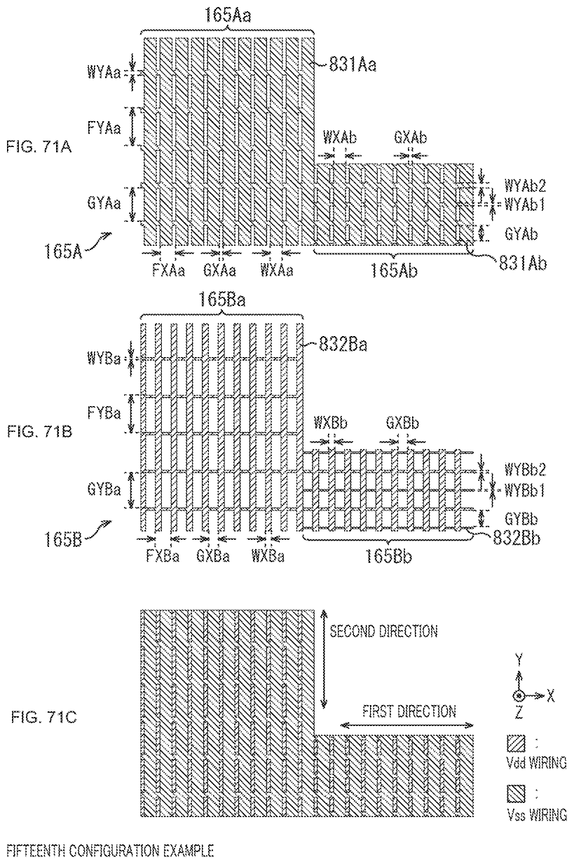

FIG. 71 illustrates a second modification example of the fifteenth configuration example. A of FIG. 71 illustrates the conductor layer A, and B of FIG. 71 illustrates the conductor layer B. C of FIG. 71 illustrates a state in which the respective conductor layers A and B illustrated in A and B of FIG. 71 are viewed from the conductor layer A side. In a coordinate system in FIG. 71, a horizontal direction indicates an X-axis, a vertical direction indicates a Y-axis, and a direction orthogonal to an XY plane indicates a Z-axis.

The second modification example of the fifteenth configuration example differs from the fifteenth configuration example illustrated in FIG. 69 in that all the conductor widths WYAb of the lead conductor portion 165Ab of the wiring layer 165A in the Y direction are not equal. Specifically, the mesh conductor 831Ab of the lead conductor portion 165Ab of the wiring layer 165A has two kinds of conductor widths WYAb including a small conductor width WYAb1 and a large conductor width WYAb2, as illustrated in A of FIG. 71.

Further, the second modification example differ from the fifteenth configuration example illustrated in FIG. 69 in that all the conductor widths WYBb of the lead conductor portion 165Bb of the wiring layer 165B in the Y direction do not equal. Specifically, the mesh conductor 832Bb of the lead conductor portion 165Bb of the wiring layer 165B has two kinds of conductor widths WYBb including a small conductor width WYBb1 and a large conductor width WYBb2, as illustrated in B of FIG. 71.

In the second modification example of the fifteenth configuration example, the lead conductor portion 165Ab of the wiring layer 165A and the lead conductor portion 165Bb of the wiring layer 165B form a light shielding structure in a state in which the conductor layer A and the conductor layer B are overlapped, as illustrated in C of FIG. 71.

The gap width GYAb or the conductor width WYAb of the lead conductor portion 165Ab of the wiring layer 165A is not equal to the gap width GYBb or the conductor width WYBb of the lead conductor portion 165Bb of the wiring layer 165B as in the first modification example and the second modification example of the fifteenth configuration example, such that a degree of freedom in wirings can be increased. In each conductor layer, generally, there is a constraint of an occupation rate of the conductor region, but a wiring resistance of the lead conductor portions 165Ab and 165Bb can be minimized within the constraint of the occupation rate due to an increase in the degree of freedom in wirings and thus, it is possible to further reduce the voltage drop. The description has been given using an example in which all the gap widths GYAb are not equal, an example in which all the gap widths GYBb are not equal, an example in which all the conductor widths WYAb are not equal, and an example in which all the conductor widths WYBb are not equal, but the present technology is not limited thereto. For example, all the gap widths GXAb in the X direction, all the gap widths GXBb in the X direction, all the conductor widths WXAb in the X direction, or all the conductor widths WXBb in the X direction may not equal. In these cases, similarly, it is possible to increase a degree of freedom in wirings and thus, it is possible to further reduce the voltage drop for the same reason as above.

### SIXTEENTH CONFIGURATION EXAMPLE

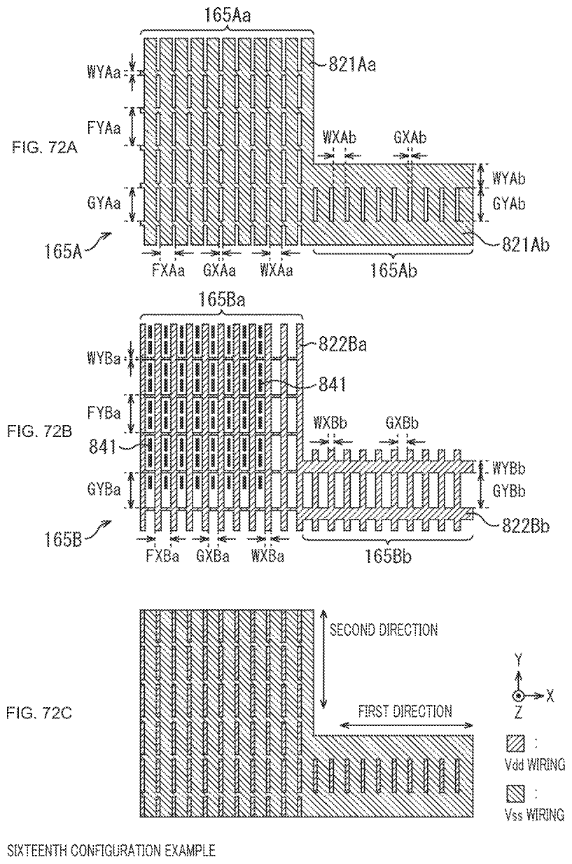

FIG. 72 illustrates a sixteenth configuration example of the conductor layers A and B. A of FIG. 72 illustrates the conductor layer A, and B of FIG. 72 illustrates the conductor layer B. In a coordinate system in FIG. 72, a horizontal direction indicates an X-axis, a vertical direction indicates a Y-axis, and a direction orthogonal to an XY plane indicates a Z-axis.

Since the conductor layer A of the sixteenth configuration example illustrated in A of FIG. 72 is the same as the conductor layer A of the fourteenth configuration example illustrated in FIG. 65, description thereof will be omitted.

The conductor layer B of the sixteenth configuration example illustrated in B of FIG. 72 has a configuration in which a relay conductor 841 is further added to the conductor layer B of the fourteenth configuration example illustrated in FIG. 65. More specifically, the main conductor portion 165Ba includes a mesh conductor 822Ba and a plurality of relay conductors 841, and the lead conductor portion 165Bb includes a mesh conductor 822Bb as in the fourteenth configuration example.

In the main conductor portion 165Ba, the relay conductor 841 is arranged in a rectangular gap region that is not a conductor of the mesh conductor 822Ba and is long in the Y direction, is electrically insulated from the mesh conductor 822Ba, and is connected to the Vss wiring to which the mesh conductor 821Aa of the conductor layer A has been connected. One or a plurality of relay conductors 841 are arranged in a gap region of the mesh conductor 822Ba. B of FIG. 72 illustrates an example in which two relay conductors 841 in total in 2 rows and 1 column are arranged in the gap region of the mesh conductor 822Ba.

In B of FIG. 72, the relay conductor 841 is arranged only in a gap region of a part of the mesh conductor 822Ba in the entire region of the main conductor portion 165Ba.

However, the relay conductor 841 may be arranged in a gap region of the entire region of the main conductor portion 165Ba. Further, in the conductor layer B of the sixteenth configuration example, the relay conductor 841 is not arranged in a gap region of the mesh conductor 822Bb of the lead conductor portion 165Bb, but the relay conductor 841 may be arranged in the gap region of the mesh conductor 822Bb.

### FIRST MODIFICATION EXAMPLE OF SIXTEENTH CONFIGURATION EXAMPLE

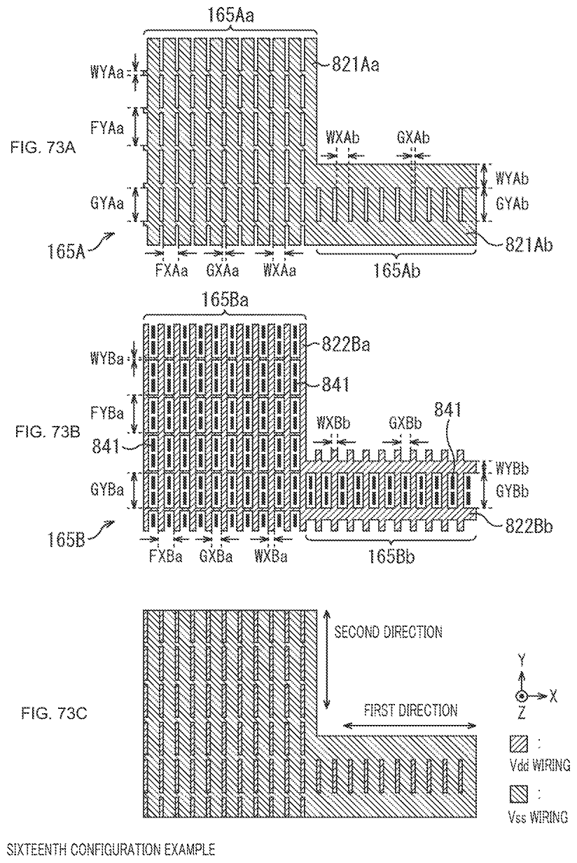

FIG. 73 illustrates a first modification example of the sixteenth configuration example.

In the first modification example of the sixteenth configuration example of FIG. 73, the relay conductor 841 is arranged in the gap region of the entire region of the main conductor portion 165Ba of the conductor layer B, and the relay conductor 841 is also arranged in the gap region of the mesh conductor 822Bb of the lead conductor portion 165Bb. Other configurations in the first modification example of FIG. 73 are the same as those of the sixteenth configuration example illustrated in FIG. 72.

SECOND MODIFICATION EXAMPLE OF SIXTEENTH CONFIGURATION EXAMPLE

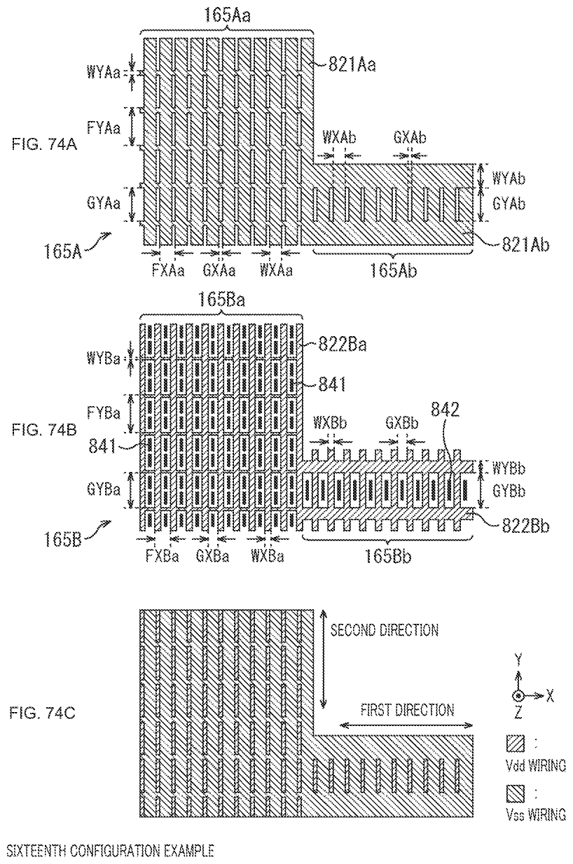

FIG. 74 illustrates a second modification example of the sixteenth configuration example.

The second modification example of the sixteenth configuration example of FIG. 74 is the same as the first modification example in that the relay conductor 841 is arranged in the gap region of the entire region of the main conductor portion 165Ba of the conductor layer B. On the other hand, the second modification example of the sixteenth configuration example differs from the first modification example in that a relay conductor 842 different from the relay conductor 841 is arranged in the gap region of the mesh conductor 822Bb of the lead conductor portion 165Bb. Other configurations of the second modification example of FIG. 74 are the same as those of the sixteenth configuration example illustrated in FIG. 72.

As in the second modification example, the relay conductor 841 arranged in the gap region of the mesh conductor 822Ba of the main conductor portion 165Ba of the conductor layer B and the relay conductor 842 arranged in the gap region of the mesh conductor 822Bb of the lead conductor portion 165Bb may differ in the number or shape.

When the relay conductor 841 is not arranged in the gap region of the mesh conductor 822Bb of the lead conductor portion 165Bb as in the conductor layer B of the sixteenth configuration example illustrated in FIG. 72, it is possible to increase a degree of freedom in wirings (the mesh conductor 822Bb). In each conductor layer, generally, there is a constraint of an occupation rate of the conductor region, but a wiring resistance of the lead conductor portion 165Bb can be minimized within the constraint of the occupation rate due to an increase in the degree of freedom in wirings and thus, it is possible to further reduce the voltage drop.

On the other hand, when the relay conductor 841, the relay conductor 842, or the like is arranged in the gap region of the mesh conductor 822Bb of the lead conductor portion 165Bb, and active elements such as MOS transistors or diodes are arranged in a region of the lead conductor portion 165Bb or in upper and lower layers at the same plane positions as that of the lead conductor portion 165Bb, it is possible to further reduce the voltage drop.

Further, since the relay conductor 841 arranged in the gap region of the mesh conductor 822Ba of the main conductor portion 165Ba of the conductor layer B and the relay conductor 842 arranged in the gap region of the mesh conductor 822Bb of the lead conductor portion 165Bb differ in the number or shape, it is possible to maximize utilization of an occupancy rate of a conductor region of each conductor layer in the main conductor portion 165Ba and the lead conductor portion 165Bb, and thus, it is possible to reduce the wiring resistance and further reduce the voltage drop.

The relay conductor 841 has any shape, and a symmetrical circle or polygon such as rotationally symmetrical circle or polygon or a mirror-symmetrical circle or polygon is preferable. The relay conductor 841 can be arranged at a center of the gap region of the mesh conductor 822Ba or any other position. The relay conductor 841 may be connected to the conductor layer serving as the Vss wiring different from the conductor layer A. The relay conductor 841 may be connected to a conductor layer serving as the Vss wiring on the side closer to the active element group 167 than to the conductor layer B. The relay conductor 841 can be connected to, for example, a conductor layer different from the conductor layer A or a conductor layer on the side closer to the active element group 167 than to the conductor layer B, by a conductor via extending in the Z direction. The same applies to the relay conductor 842.

Although the example in which the relay conductor 841 or 842 is arranged in the gap region of the mesh conductors 822Ba and 822Bb of the conductor layer B in the sixteenth configuration example of FIGS. 72 to 74, the same or different relay conductors may be arranged in the gap region of the mesh conductor 821Aa and 821Ab of the conductor layer A.

### SEVENTEENTH CONFIGURATION EXAMPLE

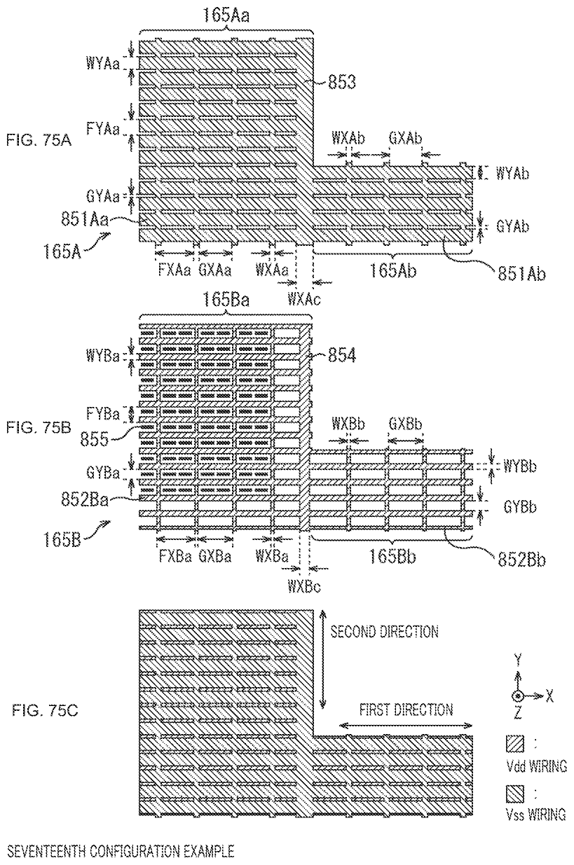

FIG. 75 illustrates a seventeenth configuration example of the conductor layers A and B. A of FIG. 75 illustrates the conductor layer A, and B of FIG. 75 illustrates the conductor layer B. In a coordinate system in FIG. 75, a horizontal direction indicates an X-axis, a vertical direction indicates a Y-axis, and a direction orthogonal to an XY plane indicates a Z-axis.

When the conductor layer A in the seventeenth configuration example illustrated in A of FIG. 75 is compared with the conductor layer A of the fourteenth configuration example illustrated in A of FIG. 65, a shape of the mesh conductor 851Aa of the main conductor portion 165Aa differs from a shape of the mesh conductor 851Ab of the lead conductor portion 165Ab.

In other words, the gap region of the mesh conductor 821Aa in the fourteenth configuration example illustrated in A of FIG. 65 has a vertically long rectangular shape, whereas a gap region of the mesh conductor 851Aa in the seventeenth configuration example illustrated in A of FIG. 75 is a horizontally long rectangular shape. Further, a gap region of the mesh conductor 821Ab in A of FIG. 65 has a vertically long rectangular shape, whereas a gap region of the mesh conductor 851Ab in A of FIG. 75 has a horizontally long rectangular shape.

The mesh conductor 851Ab of the lead conductor portion 165Ab in A of FIG. 75 is the same as the mesh conductor 821Ab in the fourteenth configuration example in A of FIG. 65 in that it is easy for a current to flow in the X direction (first direction) rather than the Y direction (second direction) orthogonal to the X direction toward the main conductor portion 165Aa.

On the other hand, the mesh conductor 851Aa of the main conductor portion 165Aa in A of FIG. 75 has a shape in which it is easy for a current to flow in the X direction than in the Y direction, whereas the mesh conductor 821Aa of the main conductor portion 165Aa in the fourteenth configuration example in A of FIG. 65 has a shape in which it is easy for a current to flow in the Y direction.

That is, the conductor layer A in the seventeenth configuration example illustrated in A of FIG. 75 differs from the conductor layer A of the fourteenth configuration example in A of FIG. 65 in a direction in which it is easy for a current to flow in the main conductor portion 165Aa.

Further, the main conductor portion 165Aa of the conductor layer A in the seventeenth configuration example includes a reinforcing conductor 853 reinforced so that it is easy for a current to flow in the Y direction rather than the X direction.

It is preferable for the conductor width WXAc of the reinforcing conductor 853 to be formed to be larger than one or both of the conductor width WXAa in the X direction and the conductor width WYAa in the Y direction of the mesh conductor 851Aa. The conductor width WXAc of the reinforcing conductor 853 is formed to be larger than the smaller of the conductor width WXAa in the X direction and the conductor width WYAa in the Y direction of the mesh conductor 851Aa. In the example of FIG. 75, a position in the X direction in which the reinforcing conductor 853 is formed is a position closest to the lead conductor portion 165Ab in a region of the main conductor portion 165Aa, but may be a position near the bonding portion.

Since the mesh conductor 851Aa of the main conductor portion 165Aa can be formed in a shape in which it is easy for a current to flow in the X direction, a layout can be created with a minimum number of basic pattern repetitions, and thus, a degree of freedom in a design of a wiring layout is increased. Further, it is possible to further reduce the voltage drop depending on the arrangement of active elements such as MOS transistors or diodes.

By providing the reinforcing conductor 853 reinforced so that it is easy for a current to flow in the Y direction, it becomes easy for the current to diffuse in the Y direction in the main conductor portion 165Aa and thus, it is possible to mitigate current concentration in the vicinity of the bonding portion between the main conductor portion 165Aa and the lead conductor portion 165Ab. When the current is locally concentrated, the inductive noise increases due to a concentration place, but it is possible to further reduce the inductive noise since the current concentration can be mitigated.

When the conductor layer B in the seventeenth configuration example illustrated in B of FIG. 75 is compared with the conductor layer B of the fourteenth configuration example illustrated in B of FIG. 65, a shape of the mesh conductor 852Ba of the main conductor portion 165Ba differs from a shape of the mesh conductor 852Bb of the lead conductor portion 165Bb.

In other words, the gap region of the mesh conductor 822Ba in the fourteenth configuration example illustrated in B of FIG. 65 has a vertically long rectangular shape, whereas a gap region of the mesh conductor 852Ba in the seventeenth configuration example illustrated in B of FIG. 75 is a horizontally long rectangular shape. Further, a gap region of the mesh conductor 822Bb in B of FIG. 65 has a vertically long rectangular shape, whereas a gap region of the mesh conductor 852Bb in B of FIG. 75 has a horizontally long rectangular shape.

The mesh conductor 852Bb of the lead conductor portion 165Bb in B of FIG. 75 is the same as the mesh conductor 822Bb in the fourteenth configuration example in B of FIG. 65 in that it is easy for a current to flow in the X direction (first direction) rather than the Y direction (second direction) orthogonal to the X direction toward the main conductor portion 165Ba.

On the other hand, the mesh conductor 852Ba of the main conductor portion 165Ba in B of FIG. 75 has a shape in which it is easy for a current to flow in the X direction than in the Y direction, whereas the mesh conductor 822Ba of the main conductor portion 165Ba in the fourteenth configuration example in B of FIG. 65 has a shape in which it is easy for a current to flow in the Y direction.

That is, the conductor layer B in the seventeenth configuration example illustrated in B of FIG. 75 differs from the conductor layer B of the fourteenth configuration example in B of FIG. 65 in a direction in which it is easy for a current to flow in the main conductor portion 165Ba.

Further, the main conductor portion 165Ba of the conductor layer B in the seventeenth configuration example includes a reinforcing conductor 854 reinforced so that it is easy for a current to flow in the Y direction rather than the X direction. It is preferable for the conductor width WXBc of the reinforcing conductor 854 to be formed to be larger than one or both of the conductor width WXBa in the X direction and the conductor width WYBa in the Y direction of the mesh conductor 852Ba. The conductor width WXBc of the reinforcing conductor 854 is formed to be larger than the smaller of the conductor width WXBa in the X direction and the conductor width WYBa in the Y direction of the mesh conductor 852Ba. In the example of FIG. 75, a position in the X direction in which the reinforcing conductor 854 is formed is a position closest to the lead conductor portion 165Bb in a region of the main conductor portion 165Ba, but may be a position near the bonding portion.

As illustrated in C of FIG. 75, the reinforcing conductor 853 of the conductor layer A and the reinforcing conductor 854 of the conductor layer B are formed at an overlapping position. Since the active element group 167 is covered with at least one of the conductor layer A and the conductor layer B in a state in which the conductor layer A and the conductor layer B overlap each other, it is possible to shield the hot carrier light emitted from the active element group 167 also in the seventeenth configuration example. For example, when light shielding near the reinforcing conductor 853 or the reinforcing conductor 854 is not necessary, the reinforcing conductor 853 and the reinforcing conductor 854 may not be formed at the overlapping position. Further, at least one of the reinforcing conductor 853 and the reinforcing conductor 854 may not be provided, for example, depending on the current distribution of the main conductor portion 165a.

Since the mesh conductor 852Ba of the main conductor portion 165Ba can be formed in a shape in which it is easy for a current to flow in the X direction, a layout can be created with a minimum number of basic pattern repetitions, and thus, a degree of freedom in a design of a wiring layout is increased. Further, it is possible to further reduce the voltage drop depending on the arrangement of active elements such as MOS transistors or diodes.

Since it is possible to make it easy for the current to diffuse in the second direction in the main conductor portion 165Ba by providing the reinforcing conductor 854 reinforced so that it is easy for a current to flow in the Y direction, it is possible to mitigate current concentration around the bonding portion between the main conductor portion 165Ba and the lead conductor portion 165Bb. When the current is locally concentrated, the inductive noise increases due to a concentration place, but it is possible to further reduce the inductive noise since the current concentration can be mitigated.

Further, the conductor layer B in the seventeenth configuration example illustrated in B of FIG. 75 differs from the conductor layer B of the fourteenth configuration example in B of FIG. 65 in that a relay conductor 855 is arranged in the gap region of at least a part of the mesh conductor 852Ba of the main conductor portion 165Ba. This relay conductor 855 may or may not be arranged.

### FIRST MODIFICATION EXAMPLE OF SEVENTEENTH CONFIGURATION EXAMPLE

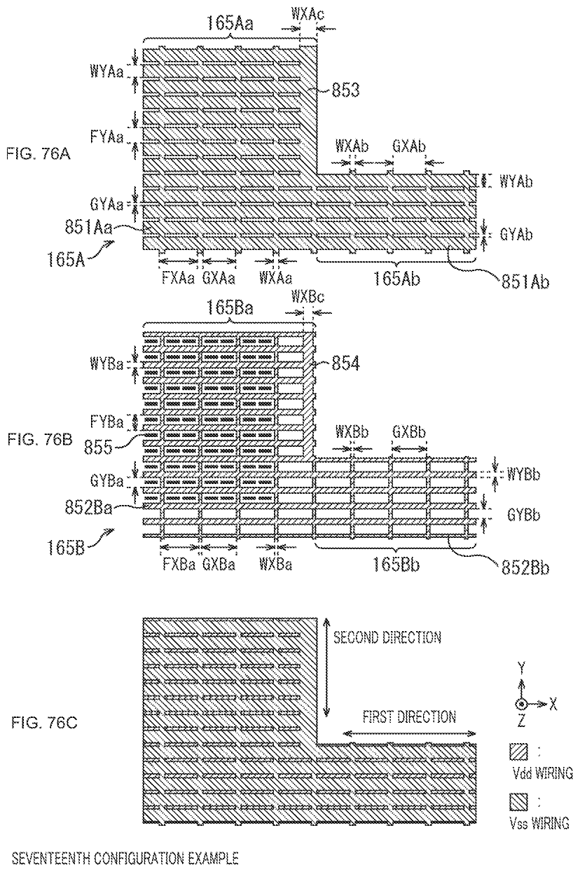

FIG. 76 illustrates a first modification example of the seventeenth configuration example.

The conductor layer A of the first modification example of the seventeenth configuration example differs from the conductor layer A of the seventeenth configuration example illustrated in A of FIG. 75 in that the reinforcing conductor 853 of the conductor layer A illustrated in A of FIG. 76 is not formed over a total length of the main conductor portion 165Aa in the Y direction, but is formed in a partial length of the main conductor portion 165Aa in the Y direction. More specifically, in the first modification example of FIG. 76, the reinforcing conductor 853 of the conductor layer A is formed at a position in the Y direction other than a position in the Y direction of the bonding portion. Other configurations of the conductor layer A in the first modification example are the same as those of the conductor layer A in the seventeenth configuration example illustrated in A of FIG. 75.

Similarly, the conductor layer B differs from the conductor layer B of the seventeenth configuration example illustrated in B of FIG. 75 in that the reinforcing conductor 854 of the conductor layer B illustrated in B of FIG. 76 is not formed over a total length of the main conductor portion 165Ba in the Y direction, but is formed in a partial length in the Y direction. More specifically, in the first modification example of FIG. 76, the reinforcing conductor 854 of the conductor layer B is formed at a position in the Y direction other than a position in the Y direction of the bonding portion. Other configurations of the conductor layer B in the first modification example are the same as those of the conductor layer B in the seventeenth configuration example illustrated in A of FIG. 75.

### SECOND MODIFICATION EXAMPLE OF SEVENTEENTH CONFIGURATION EXAMPLE

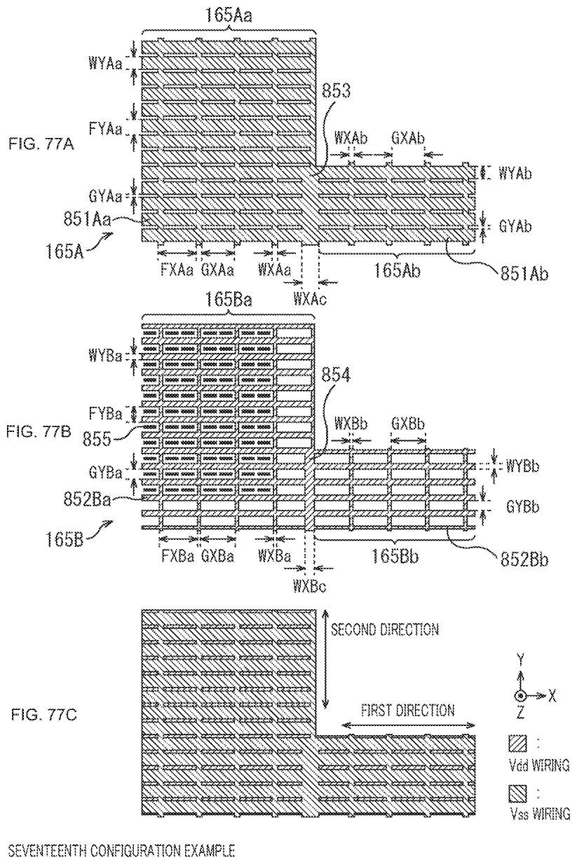

FIG. 77 illustrates a second modification example of the seventeenth configuration example.

The conductor layer A of the second modification example of the seventeenth configuration example differs from the conductor layer A of the seventeenth configuration example illustrated in A of FIG. 75 in that the reinforcing conductor 853 of the conductor layer A illustrated in A of FIG. 77 is not formed over a total length of the main conductor portion 165Aa in the Y direction, but is formed in a partial length in the Y direction. More specifically, in the second modification example of FIG. 77, the reinforcing conductor 853 of the conductor layer A is formed at only a position in the Y direction of the bonding portion. Other configurations of the conductor layer A in the second modification example are the same as those of the conductor layer A in the seventeenth configuration example illustrated in A of FIG. 75.

Similarly, the conductor layer B differs from the conductor layer B of the seventeenth configuration example illustrated in B of FIG. 75 in that the reinforcing conductor 854 of the conductor layer B illustrated in B of FIG. 77 is not formed over a total length of the main conductor portion 165Ba in the Y direction, but is formed in a partial length in the Y direction. More specifically, in the second modification example of FIG. 77, the reinforcing conductor 854 of the conductor layer B is formed at only a position in the Y direction of the bonding portion. Other configurations of the conductor layer B in the second modification example are the same as those of the conductor layer B in the seventeenth configuration example illustrated in A of FIG. 75.

The reinforcing conductor 853 of the conductor layer A and the reinforcing conductor 854 of the conductor layer B are not necessarily formed over a total length of the main conductor portion 165Aa in the Y direction as in the first modification example and the second modification example of the seventeenth configuration example, and may be formed in a predetermined partial region in the Y direction.

### EIGHTEENTH CONFIGURATION EXAMPLE

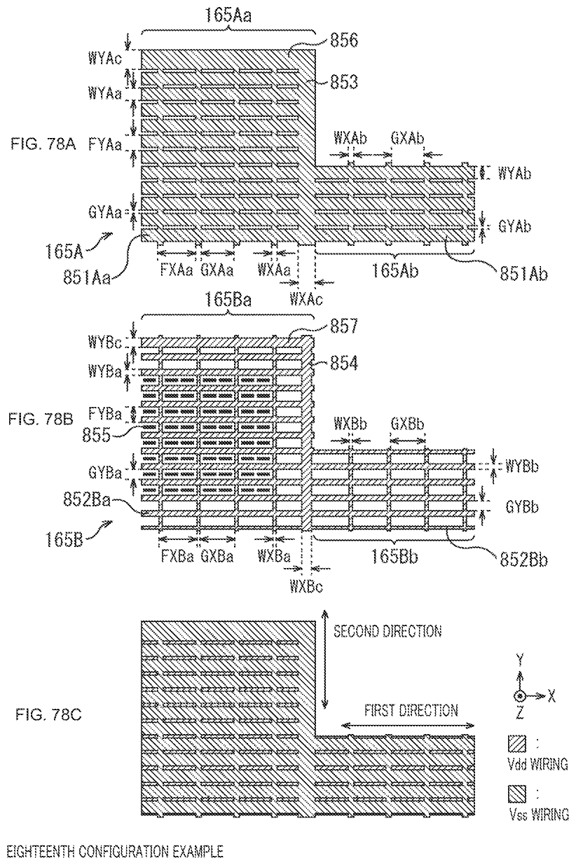

FIG. 78 illustrates an eighteenth configuration example of the conductor layers A and B. A of FIG. 78 illustrates the conductor layer A, and B of FIG. 78 illustrates the conductor layer B. C of FIG. 78 illustrates a state in which the respective conductor layers A and B illustrated in A and B of FIG. 78 are viewed from the conductor layer A side. In a coordinate system in FIG. 78, a horizontal direction indicates an X-axis, a vertical direction indicates a Y-axis, and a direction orthogonal to an XY plane indicates a Z-axis.

The eighteenth configuration example illustrated in FIG. 78 has a configuration in which the seventeenth configuration example illustrated in FIG. 75 is partially modified. In FIG. 78, portions corresponding to those in FIG. 75 are denoted by the same reference signs, and description of the portions will be appropriately omitted.

The conductor layer A of the eighteenth configuration example illustrated in A of FIG. 78 is the same as that of the seventeenth configuration example illustrated in FIG. 75 in that the conductor layer A of the eighteenth configuration example includes a mesh conductor 851Aa having a shape in which it is easy for a current to flow in the X direction, and a reinforcing conductor 853 reinforced so that it is easy for a current to flow in the Y direction.

On the other hand, the conductor layer A of the eighteenth configuration example differs from that of the seventeenth configuration example illustrated in FIG. 75 in that the conductor layer A further includes a reinforcing conductor 856 reinforced so that it is easier for a current to flow in the X direction than in the Y direction. It is preferable for a conductor width WYAc of the reinforcing conductor 856 to be larger than one or both of the conductor width WXAa in the X direction and the conductor width WYAa in the Y direction of the mesh conductor 851Aa. The conductor width WYAc of the reinforcing conductor 856 is larger than a smaller one of the conductor width WXAa in the X direction and the conductor width WYAa in the Y direction of the mesh conductor 851Aa. A plurality of the reinforcing conductors 856 may be arranged in the region of the main conductor portion 165Aa at predetermined intervals in the Y direction, or one reinforcing conductor 856 may be arranged at a predetermined position in the Y direction.

By providing the reinforcing conductor 856 reinforced so that it is easy for a current to flow in the X direction, it is possible to make it easy for the current to flow not only in the Y direction by the reinforcing conductor 853 but also in the X direction, and to mitigate current concentration around the bonding portion between the main conductor portion 165Aa and the lead conductor portion 165Ab. When the current is locally concentrated, the inductive noise increases due to a concentration place, but it is possible to further reduce the inductive noise since the current concentration can be mitigated.

The conductor layer B of the eighteenth configuration example illustrated in B of FIG. 78 is the same as that of the seventeenth configuration example illustrated in FIG. 75 in that the conductor layer B of the eighteenth configuration example includes a mesh conductor 852Ba having a shape in which it is easy for a current to flow in the X direction, and a reinforcing conductor 854 reinforced so that it is easy for a current to flow in the Y direction.

On the other hand, the conductor layer B of the eighteenth configuration example differs from that of the seventeenth configuration example illustrated in FIG. 75 in that the conductor layer B of the eighteenth configuration example further includes a reinforcing conductor 857 reinforced so that it is easy for a current to flow in the X direction than in the Y direction. It is preferable for a conductor width WYBc of the reinforcing conductor 857 to be larger than one or both of the conductor width WXBa in the X direction and the conductor width WYBa in the Y direction of the mesh conductor 852Ba. The conductor width WYBc of the reinforcing conductor 857 is larger than a smaller one of the conductor width WXBa in the X direction and the conductor width WYBa in the Y direction of the mesh conductor 852Ba. A plurality of the reinforcing conductors 857 may be arranged in a region of the main conductor portion 165Ba at predetermined intervals in the Y direction, or one reinforcing conductor 857 may be arranged at a predetermined position in the Y direction.

As illustrated in C of FIG. 78, the reinforcing conductor 856 of the conductor layer A and the reinforcing conductor 857 of the conductor layer B are formed at an overlapping position. Since the active element group 167 is covered with at least one of the conductor layer A and the conductor layer B in a state in which the conductor layer A and the conductor layer B overlap each other, it is possible to shield the hot carrier light emitted from the active element group 167 also in the eighteenth configuration example. For example, when light shielding near the reinforcing conductor 856 or the reinforcing conductor 857 is not necessary, the reinforcing conductor 856 and the reinforcing conductor 857 may not be formed at the overlapping position. Further, at least one of the reinforcing conductor 856 and the reinforcing conductor 857 may not be provided, for example, depending on the current distribution of the main conductor portion 165a.

By providing the reinforcing conductor 857 reinforced so that it is easy for a current to flow in the X direction, it is possible to make it easy for the current to flow not only in the Y direction by the reinforcing conductor 854 but also in the X direction, and to mitigate current concentration around the bonding portion between the main conductor portion 165Ba and the lead conductor portion 165Bb. When the current is locally concentrated, the inductive noise increases due to a concentration place, but it is possible to further reduce the inductive noise since the current concentration can be mitigated.

In the seventeenth configuration example in FIG. 75, a configuration including the reinforcing conductors 853 and 854 reinforced so that it is easy for a current to flow in the Y direction is illustrated, and in the eighteenth configuration example in FIG. 78, a configuration including the reinforcing conductors 856 and 857 reinforced so that it is easy for a current to flow in the X direction, in addition to the reinforcing conductors 853 and 854, is illustrated.

Although illustration is omitted, a configuration in which the conductor layer A does not include the reinforcing conductor 853 and includes the reinforcing conductor 856, and the conductor layer B does not include the reinforcing conductor 854 and includes the reinforcing conductor 857 may be adopted as a modification example of the seventeenth configuration example or the eighteenth configuration example. In other words, a configuration in which only the reinforcing conductors 856 and 857 are included as reinforcing conductors may be adopted.

By providing the reinforcing conductor 856 reinforced so that it is easy for a current to flow in the X direction, the current can be easily diffused in the Y direction depending on a relationship with the wiring resistance even when the reinforcing conductor 853 is not included, and a current concentration around the bonding portion between the main conductor portion 165Aa and the lead conductor portion 165Ab can be mitigated. When the current is locally concentrated, the inductive noise increases due to a concentration place, but it is possible to further reduce the inductive noise since the current concentration can be mitigated.

By providing the reinforcing conductor 857 reinforced so that it is easy for a current to flow in the X direction, the current can be easily diffused in the Y direction depending on a relationship of the wiring resistance even when the reinforcing conductor 854 is not included, and current concentration around the bonding portion between the main conductor portion 165Ba and the lead conductor portion 165Bb can be mitigated. When the current is locally concentrated, the inductive noise increases due to a concentration place, but it is possible to further reduce the inductive noise since the current concentration can be mitigated.

### NINETEENTH CONFIGURATION EXAMPLE

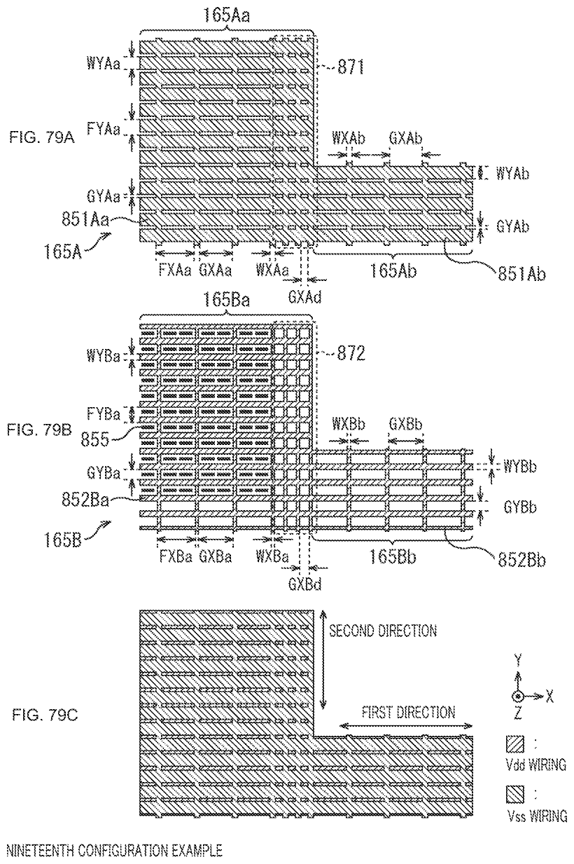

FIG. 79 illustrates a nineteenth configuration example of the conductor layers A and B. A of FIG. 79 illustrates the conductor layer A, and B of FIG. 79 illustrates the conductor layer B. C of FIG. 79 illustrates a state in which the respective conductor layers A and B illustrated in A and B of FIG. 79 are viewed from the conductor layer A side. In a coordinate system in FIG. 79, a horizontal direction indicates an X-axis, a vertical direction indicates a Y-axis, and a direction orthogonal to an XY plane indicates a Z-axis.

The nineteenth configuration example illustrated in FIG. 79 has a configuration obtained by partially modifying the seventeenth configuration example illustrated in FIG. 75. In FIG. 79, portions corresponding to those in FIG. 75 are denoted by the same reference signs, and description of the portions will be appropriately omitted.

The conductor layer A of the nineteenth configuration example illustrated in A of FIG. 79 differs in that the reinforcing conductor 853 of the seventeenth configuration example illustrated in FIG. 75 is replaced with a reinforcing conductor 871, and is the same in other points. The reinforcing conductor 871 includes a plurality of wirings extending in the Y direction. Each wiring forming the reinforcing conductor 871 are evenly spaced and arranged in the X direction with a gap width GXAd. The gap width GXAd is smaller than the gap width GXAa of the mesh conductor 851Aa of the main conductor portion 165Aa.

The conductor layer B of the nineteenth configuration example illustrated in B of FIG. 79 differs in that the reinforcing conductor 854 of the seventeenth configuration example illustrated in FIG. 75 is replaced with a reinforcing conductor 872, and is the same in other points. The reinforcing conductor 872 includes a plurality of wirings extending in the Y direction. Each wiring forming the reinforcing conductor 872 are evenly spaced and arranged in the X direction with a gap width GXBd. The gap width GXBd is smaller than the gap width GXBa of the mesh conductor 852Ba of the main conductor portion 165Ba.

As illustrated in C of FIG. 79, the reinforcing conductor 871 of the conductor layer A and the reinforcing conductor 872 of the conductor layer B are formed at an overlapping position. Since the active element group 167 is covered with at least one of the conductor layer A and the conductor layer B in a state in which the conductor layer A and the conductor layer B overlap each other, it is possible to shield the hot carrier light emitted from the active element group 167 also in the nineteenth configuration example. For example, when light shielding near the reinforcing conductor 871 or the reinforcing conductor 872 is not necessary, the reinforcing conductor 871 and the reinforcing conductor 872 may not be formed at the overlapping position. Further, at least one of the reinforcing conductor 871 and the reinforcing conductor 872 may not be provided, for example, depending on the current distribution of the main conductor portion 165a.

### MODIFICTION EXAMPLES OF NINETEENTH CONFIGURATION EXAMPLE

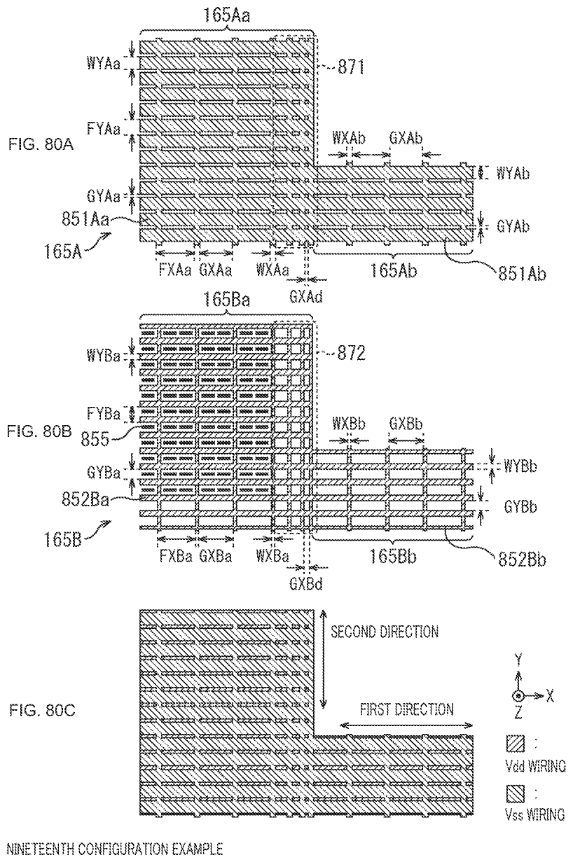

FIG. 80 illustrates a modification example of the nineteenth configuration example.

In the nineteenth configuration example illustrated in FIG. 79, a plurality of wirings forming the reinforcing conductor 871 of the conductor layer A are evenly spaced and arranged in the X direction with the gap width GXAd. A plurality of wirings forming the reinforcing conductor 872 of the conductor layer B are also equally spaced and arranged in the X direction with the gap width GXAd.

On the other hand, in FIG. 80 illustrating a modification example of the nineteenth configuration example, the gap widths GXAd of the adjacent wirings differ from each other in the plurality of wirings forming the reinforcing conductor 871 of the conductor layer A. At least one of the gap widths GXAd is smaller than the gap width GXAa of the mesh conductor 851Aa of the main conductor portion 165Aa. In the plurality of wirings forming the reinforcing conductor 872 of the conductor layer B, the gap widths GXBd of the adjacent wiring differ from each other. At least one of the gap widths GXBd is smaller than the gap width GXBa of the mesh conductor 852Ba of the main conductor portion 165Ba.

In the example of FIG. 80, the plurality of gap widths GXAd and gap widths GXBd are formed to gradually decrease from the left side, but the present technology is not limited thereto, and the gap widths GXAd and gap widths GXBd may be formed to gradually decrease from the right side or may be a random width.

As described above, the modification example of the nineteenth configuration example of FIG. 80 is the same as the nineteenth configuration example illustrated in FIG. 79 except that the gap widths GXAd and GXBd are not equal and are changed.

As in the nineteenth configuration example and the modification example thereof illustrated in FIGS. 79 and 80, the reinforcing conductor 871 of the conductor layer A and the reinforcing conductor 872 of the conductor layer B can be configured of a plurality of wirings arranged with a predetermined gap width GXAd or GXBd.

By providing the reinforcing conductors 871 and 872 reinforced so that it is easy for a current to flow in the Y direction, it becomes easy for the current to diffuse in the Y direction and, thus, it is possible to mitigate the current concentration around the bonding portion. When the current is locally concentrated, the inductive noise increases due to a concentration place, but it is possible to further reduce the inductive noise since the current concentration can be mitigated. In the nineteenth configuration example and the modification example thereof illustrated in FIGS. 79 and 80, a configuration in which at least a gap width smaller than the gap width GXAa or the gap width GXBa in the X direction is included and the reinforcing conductors 871 and 872 reinforced so that it is easy for a current to flow in the Y direction are included is shown, but the present technology is not limited thereto. For example, although not illustrated, a configuration in which at least a gap width smaller than the gap width GYAa or the gap width GYBa in the Y direction is included and reinforcing conductors reinforced so that it is easy for a current to flow in the X direction are included as in the eighteenth configuration example of FIG. 78 may be adopted. Further, any one of a configuration including a reinforcing conductor reinforced so that it is easy for a current to flow in the X direction, a configuration including a reinforcing conductor reinforced so that it is easy for a current to flow in the Y direction, and a configuration including both the reinforcing conductor reinforced so that it is easy for a current to flow in the X direction and the reinforcing conductor reinforced so that it is easy for a current to flow in the Y direction may be adopted. In these cases, since the current concentration can be mitigated depending on the relationship of the wiring resistance, it is possible to further reduce the inductive noise.

### TWENTIETH CONFIGURATION EXAMPLE

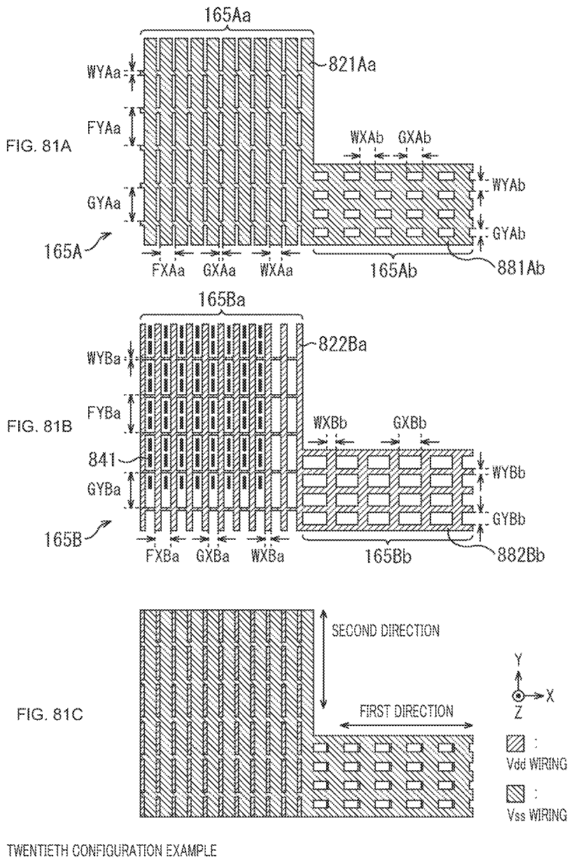

FIG. 81 illustrates a twentieth configuration example of the conductor layers A and B. A of FIG. 81 illustrates the conductor layer A, and B of FIG. 81 illustrates the conductor layer B. C of FIG. 81 illustrates a state in which the respective conductor layers A and B illustrated in A and B of FIG. 81 are viewed from the conductor layer A side. In a coordinate system in FIG. 81, a horizontal direction indicates an X-axis, a vertical direction indicates a Y-axis, and a direction orthogonal to an XY plane indicates a Z-axis.

The twentieth configuration example illustrated in FIG. 81 has a configuration in which the sixteenth configuration example illustrated in FIG. 72 is partially modified. In FIG. 81, portions corresponding to those in FIG. 72 are denoted by the same reference signs, and description of the portions will be appropriately omitted.

The conductor layer A of the twentieth configuration example illustrated in A of FIG. 81 is the same as the conductor layer A of the sixteenth configuration example illustrated in FIG. 72 in that the main conductor portion 165Aa includes the mesh conductor 821Aa. On the other hand, the conductor layer A of the twentieth configuration example differs from the conductor layer A of the sixteenth configuration example illustrated in FIG. 72 in that the lead conductor portion 165Ab includes a mesh conductor 881Ab different from the mesh conductor 821Ab.

The conductor layer B of the twentieth configuration example illustrated in B of FIG. 81 is the same as the conductor layer B of the sixteenth configuration example illustrated in FIG. 72 in that the main conductor portion 165Ba has the mesh conductor 822Ba and the relay conductor 841 arranged in the gap region. The conductor layer B of the twentieth configuration example differs from the conductor layer B of the sixteenth configuration example illustrated in FIG. 72 in that the lead conductor portion 165Bb includes a mesh conductor 882Bb different from the mesh conductor 822Bb.

That is, the twentieth configuration example differs from the sixteenth configuration example illustrated in FIG. 72 in a shape of the repetitive pattern of the lead conductor portion 165b.

A region of a part of the lead conductor portion 165b is an open region in a state in which the conductor layer A and the conductor layer B overlap each other, as illustrated in C of FIG. 81.

Thus, it is not necessary for the light shielding structure to be adopted in regions of both the conductor layer A and the conductor layer B and, for example, light shielding may not be performed in a region in which active elements such as MOS transistors or diodes are not arranged.

Although the twentieth configuration example of FIG. 81 is a configuration in which the region of the part of the lead conductor portion 165b of the conductor layer A and the conductor layer B does not shield light, a region of a part of the main conductor portions 165a of the conductor layer A and the conductor layer B may not shield light. Since the degree of freedom in a design of a wiring layout is further increased by not adopting a light shielding structure for regions in which light shielding is not required, it is possible to adopt a wiring pattern for further reduced inductive noise or voltage drop.

### TWENTY-FIRST CONFIGURATION EXAMPLE

In the fourteenth to twentieth configuration examples described above, the conductor layers of the lead conductor portion 165b connected to the main conductor portion 165a are formed of the mesh conductors.

However, the conductor layer of the lead conductor portion 165b is not limited to the mesh conductor, and may be formed of a planar conductor or a straight conductor, as in the main conductor portion 165a.

Configuration examples in which the conductor layer of the lead conductor portion 165b is formed of a planar conductor or a straight conductor will be described in twenty-first to twenty-fourth configuration examples below.

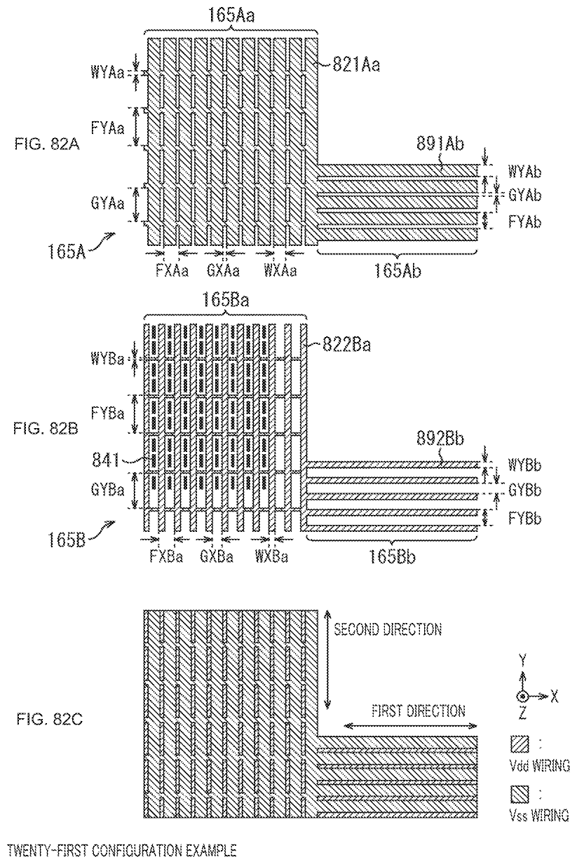

FIG. 82 illustrates a twenty-first configuration example of the conductor layers A and B. A of FIG. 82 illustrates the conductor layer A, and B of FIG. 82 illustrates the conductor layer B. C of FIG. 82 illustrates a state in which the respective conductor layers A and B illustrated in A and B of FIG. 82 are viewed from the conductor layer A side. In a coordinate system in FIG. 82, a horizontal direction indicates an X-axis, a vertical direction indicates a Y-axis, and a direction orthogonal to an XY plane indicates a Z-axis.

The twenty-first configuration example illustrated in FIG. 82 has a configuration in which the conductor layer of the lead conductor portion 165b of the sixteenth configuration example illustrated in FIG. 72 has been changed. In FIG. 82, portions corresponding to those in FIG. 72 are denoted by the same reference signs, and description of the portions will be appropriately omitted.

In the lead conductor portion 165Ab of the conductor layer A of the twenty-first configuration example illustrated in A of FIG. 82, a straight conductor 891Ab long in the X direction is periodically arranged in the conductor period FYAb in the Y direction instead of the mesh conductor 821Ab of the sixteenth configuration example. The conductor period FYAb is equal to a sum of the conductor width WYAb in the Y direction and the gap width GYAb in the Y direction (conductor period FYAb=conductor width WYAb in Y direction+gap width GYAb in Y direction).

In the lead conductor portion 165Bb of the conductor layer B of the twenty-first configuration example illustrated in B of FIG. 82, a straight conductor 892Bb long in the X direction is arranged periodically in a conductor period FYBb in the Y direction, instead of the mesh conductor 822Bb of the sixteenth configuration example. The conductor period FYBb is equal to a sum of the conductor width WYBb in the Y direction and the gap width GYBb in the Y direction (conductor period FYBb=conductor width WYBb in Y direction+gap width GYBb in Y direction).

Since the active element group 167 is covered with at least one of the conductor layer A and the conductor layer B in a state in which the conductor layer A and the conductor layer B overlap each other as illustrated in C of FIG. 82, it is possible to shield the hot carrier light emitted from the active element group 167 also in the twenty-first configuration example.

### TWENTY-SECOND CONFIGURATION EXAMPLE

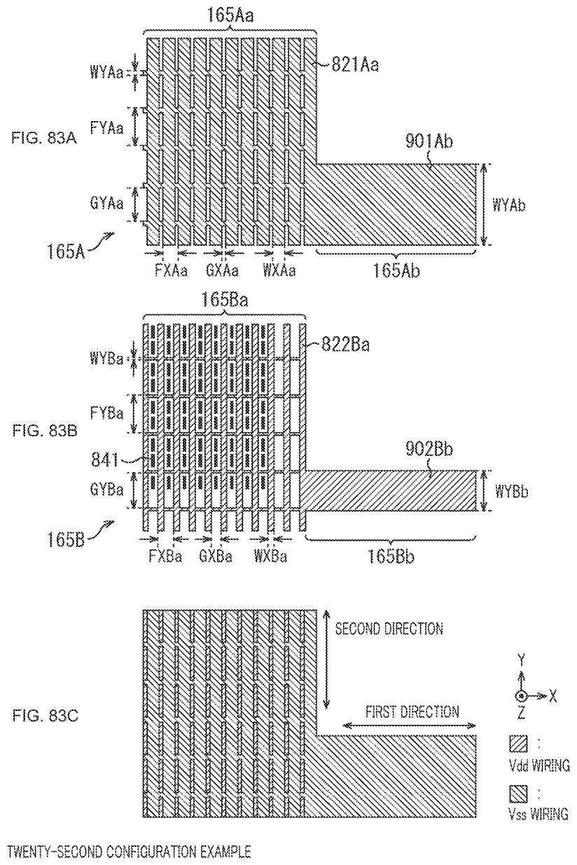

FIG. 83 illustrates a twenty-second configuration example of the conductor layers A and B. A of FIG. 83 illustrates the conductor layer A, and B of FIG. 83 illustrates the conductor layer B. C of FIG. 83 illustrates a state in which the respective conductor layers A and B illustrated in A and B of FIG. 83 are viewed from the conductor layer A side. In a coordinate system in FIG. 83, a horizontal direction indicates an X-axis, a vertical direction indicates a Y-axis, and a direction orthogonal to an XY plane indicates a Z-axis.

The twenty-second configuration example illustrated in FIG. 83 has a configuration in which the conductor layer of the lead conductor portion 165b of the sixteenth configuration example illustrated in FIG. 72 has been changed. In FIG. 83, portions corresponding to those in FIG. 72 are denoted by the same reference signs, and description of the portions will be appropriately omitted.

In the lead conductor portion 165Ab of the conductor layer A of the twenty-second configuration example illustrated in A of FIG. 83, a planar conductor 901Ab is arranged instead of the mesh conductor 821Ab of the sixteenth configuration example. The planar conductor 901Ab has the conductor width WYAb in the Y direction.

In the lead conductor portion 165Bb of the conductor layer B of the twenty-second configuration example illustrated in B of FIG. 83, a planar conductor 902Bb is arranged instead of the mesh conductor 822Bb of the sixteenth configuration example. The planar conductor 902Bb has the conductor width WYBb in the Y direction.

Since the active element group 167 is covered with at least one of the conductor layer A and the conductor layer B in a state in which the conductor layer A and the conductor layer B overlap each other as illustrated in C of FIG. 83, it is possible to shield the hot carrier light emitted from the active element group 167 also in the twenty-second configuration example.

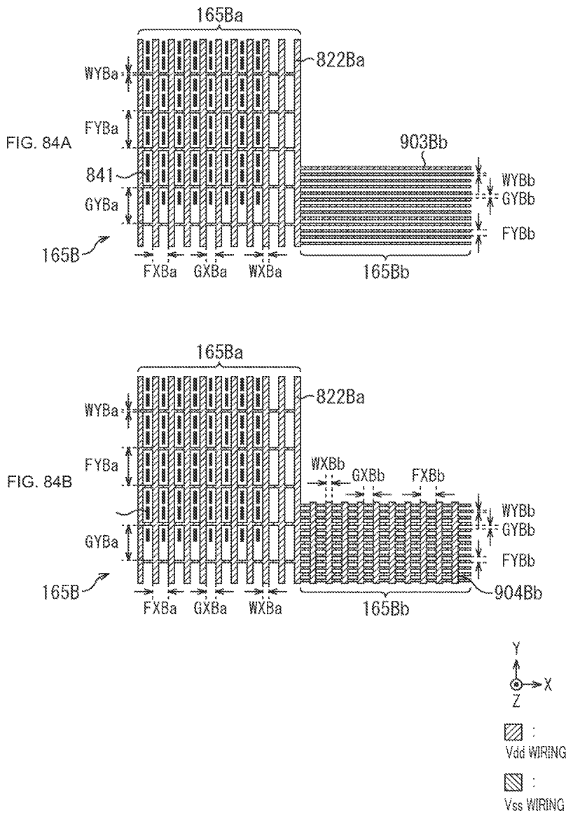

In the twenty-second configuration example, the conductor layer B illustrated in A or B of FIG. 84 may be adopted instead of the conductor layer B illustrated in B of FIG. 83.

The conductor layer B illustrated in A and B of FIG. 84 differs from the conductor layer B illustrated in B of FIG. 83 only in the lead conductor portion 165b.

In the lead conductor portion 165Bb of the conductor layer B illustrated in A of FIG. 84, a straight conductor 903Bb long in the X direction is arranged periodically in the conductor period FYBb in the Y direction, instead of the planar conductor 901Ab illustrated in B of FIG. 83. Conductor period FYBb=conductor width WYBb in Y direction+gap width GYBb in Y direction).

In the lead conductor portion 165Bb of the conductor layer B in B of FIG. 84, a mesh conductor 904Bb is provided instead of the planar conductor 901Ab illustrated in B of FIG. 83. The mesh conductor 904Bb has a conductor width WXBb and a gap width GXBb in the X direction and is configured with the same patterns periodically arranged in a conductor period FXBb, and has the conductor width WYBb and the gap width GYBb in the Y direction and is configured with the same patterns periodically arranged with the conductor period FYBb. Therefore, the mesh conductor 904Bb has a shape including a repetitive pattern in which a predetermined basic pattern is repeatedly arranged in a conductor period in at least one of the X direction and the Y direction.

A plan view in a state in which the conductor layer B of A or B of FIG. 84 and the conductor layer A illustrated in A of FIG. 83 overlap each other is similar to C of FIG. 83.

### TWENTY-THIRD CONFIGURATION EXAMPLE

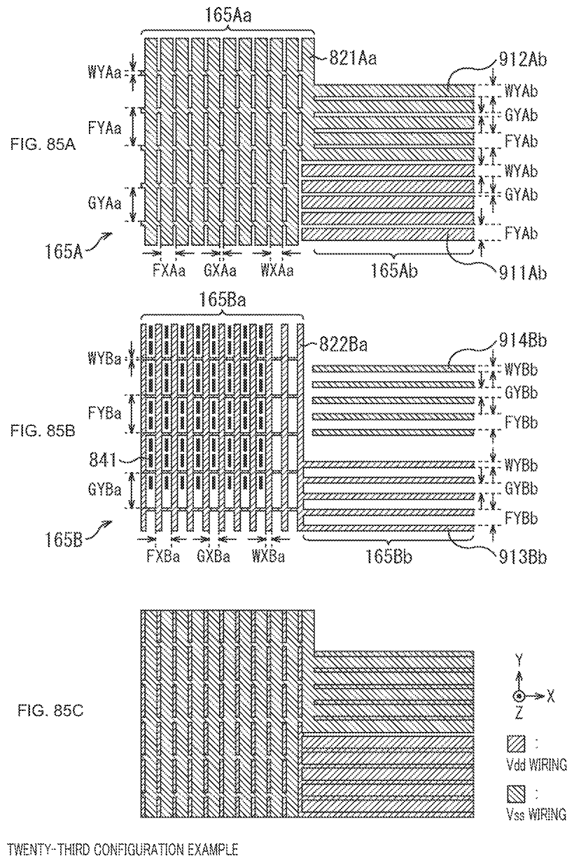

FIG. 85 illustrates a twenty-third configuration example of the conductor layers A and B. A of FIG. 85 illustrates the conductor layer A, and B of FIG. 85 illustrates the conductor layer B. C of FIG. 85 illustrates a state in which the respective conductor layers A and B illustrated in A and B of FIG. 85 are viewed from the conductor layer A side. In a coordinate system in FIG. 85, a horizontal direction indicates an X-axis, a vertical direction indicates a Y-axis, and a direction orthogonal to an XY plane indicates a Z-axis.

The twenty-third configuration example illustrated in FIG. 85 has a configuration in which the conductor layer of the lead conductor portion 165b of the sixteenth configuration example illustrated in FIG. 72 has been changed. In FIG. 85, portions corresponding to those in FIG. 72 are denoted by the same reference signs, and description of the portions will be appropriately omitted.

In the lead conductor portion 165Ab of the conductor layer A of the twenty-third configuration example illustrated in A of FIG. 85, a straight conductor 911Ab long in the X direction is arranged periodically in the conductor period FYAb in the Y direction and a straight conductor 912Ab long in the X direction is arranged periodically in the conductor period FYAb in the Y direction, instead of the mesh conductor 821Ab of the sixteenth configuration example. The straight conductor 911Ab is, for example, a wiring (Vdd wiring) connected to a positive power supply. The straight conductor 912Ab is, for example, a wiring (Vss wiring) connected to GND or a negative power supply. The conductor period FYAb is equal to a sum of the conductor width WYAb in the Y direction and the gap width GYAb in the Y direction (conductor period FYAb=conductor width WYAb+gap width GYAb).

In the lead conductor portion 165Bb of the conductor layer B of the twenty-third configuration example illustrated in B of FIG. 85, a straight conductor 913Bb long in the X direction is arranged periodically in the conductor period FYBb in the Y direction, instead of the mesh conductor 822Bb of the sixteenth configuration example, and a straight conductor 914Bb long in the X direction is arranged periodically in the conductor period FYBb in the Y direction. The straight conductor 913Bb is, for example, a wiring (Vdd wiring) connected to a positive power supply. The straight conductor 914Bb is, for example, a wiring (Vss wiring) connected to GND or a negative power supply. The conductor period FYBb is equal to a sum of the conductor width WYBb in the Y direction and the gap width GYBb in the Y direction (conductor period FYBb=conductor width WYBb+gap width GYBb).

The straight conductor 912Ab of the lead conductor portion 165Ab of the conductor layer A is electrically connected to the mesh conductor 821Aa of the main conductor portion 165Aa, and is electrically connected to the straight conductor 914Bb of the lead conductor portion 165Bb of the conductor layer B, for example, by a conductor via extending in the Z direction.

The straight conductor 913Bb of the lead conductor portion 165Bb of the conductor layer B is electrically connected to the mesh conductor 822Ba of the main conductor portion 165Ba, and is electrically connected to the straight conductor 911Ab of the lead conductor portion 165Ab of the conductor layer A, for example, by a conductor via extending in the Z direction.

Since the active element group 167 is covered with at least one of the conductor layer A and the conductor layer B in a state in which the conductor layer A and the conductor layer B overlap each other as illustrated in C of FIG. 85, it is possible to shield the hot carrier light emitted from the active element group 167 also in the twenty-first configuration example.

Although the Vdd wiring and the Vss wiring having different polarities are arranged to overlap each other in the same planar region in the lead conductor portion 165b in the fourteenth to twenty-second configuration examples described above, the Vdd wiring and the Vss wiring with different polarities may be displaced and arranged in different planar regions so that GND, a negative voltage, and a positive voltage are transferred using both of the conductor layer A and the conductor layer B, as in the twenty-third configuration example of FIG. 85.

The straight conductor 911Ab of the lead conductor portion 165Ab of the conductor layer A may be a dummy wiring without being electrically connected to the straight conductor 913Bb of the lead conductor portion 165Bb of the conductor layer B. The straight conductor 914Bb of the lead conductor portion 165Bb of the conductor layer B may be dummy wiring without being electrically connected to the straight conductor 912Ab of the lead conductor portion 165Ab of the conductor layer A.

Further, the example in which the one group of straight conductors 911Ab and the one group of straight conductors 912Ab are arranged to be adjacent to each other is illustrated in FIG. 85, the present technology is not limited thereto. For example, a plurality of groups of straight conductors 911Ab and a plurality of groups of straight conductors 912Ab may be provided and one group of straight conductors 911Ab and one group of straight conductors 912Ab may be alternately arranged.

Further, the example in which the straight conductor 911Ab including a plurality of straight conductors and the straight conductor 912Ab including a plurality of straight conductors are arranged to be adjacent to each other is illustrated in FIG. 85, the present technology is not limited thereto. For example, one straight conductor 911Ab and one straight conductor 912Ab may be alternately arranged.

Further, the example in which one group of straight conductors 913Bb and one group of straight conductors 914Bb are arranged to be adjacent to each other is illustrated in FIG. 85, but the present technology is not limited thereto. For example, a plurality of groups of straight conductors 913Bb and a plurality of groups of straight conductors 914Bb may be provided and one group of straight conductors 913Bb and one group of straight conductors 914Bb may be alternately arranged.

Further, the example in which the straight conductor 913Bb including a plurality of straight conductors and the straight conductor 914Bb including a plurality of straight conductors are arranged to be adjacent is illustrated in FIG. 85, the present technology is not limited thereto. For example, one straight conductor 913Bb and one straight conductor 914Bb may be alternately arranged.

### TWENTY-FOURTH CONFIGURATION EXAMPLE

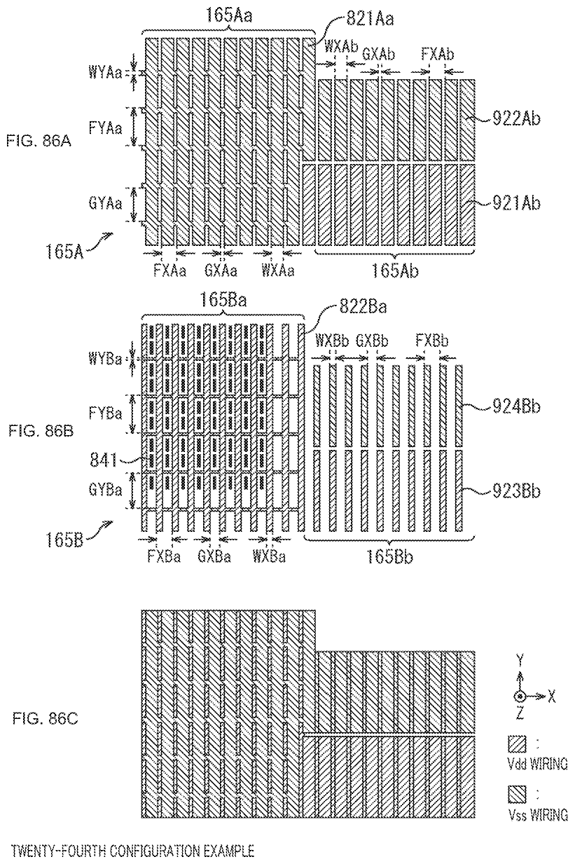

FIG. 86 illustrates a twenty-fourth configuration example of the conductor layers A and B. A of FIG. 86 illustrates the conductor layer A, and B of FIG. 86 illustrates the conductor layer B. C of FIG. 86 illustrates a state in which the respective conductor layers A and B illustrated in A and B of FIG. 86 are viewed from the conductor layer A side. In a coordinate system in FIG. 86, a horizontal direction indicates an X-axis, a vertical direction indicates a Y-axis, and a direction orthogonal to an XY plane indicates a Z-axis.

The twenty-fourth configuration example illustrated in FIG. 86 has a configuration in which the conductor layer of the lead conductor portion 165b of the sixteenth configuration example illustrated in FIG. 72 has been changed. In FIG. 86, portions corresponding to those in FIG. 72 are denoted by the same reference signs, and description of the portions will be appropriately omitted.

In the lead conductor portion 165Ab of the conductor layer A of the twenty-fourth configuration example illustrated in A of FIG. 86, a straight conductor 921Ab long in the Y direction is periodically arranged in the conductor period FXAb in the X direction and a straight conductor 922Ab long in the Y direction is periodically arranged in the conductor period FXAb in the X direction, instead of the mesh conductor 821Ab of the sixteenth configuration example. The straight conductor 921Ab is, for example, a wiring (Vdd wiring) connected to a positive power supply. The straight conductor 922Ab is, for example, a wiring (Vss wiring) connected to GND or a negative power supply. The conductor period FXAb is equal to a sum of the conductor width WXAb in the X direction and the gap width GXAb in the X direction (conductor period FXAb=conductor width WXAb+gap width GXAb).

In the lead conductor portion 165Bb of the conductor layer B of the twenty-fourth configuration example illustrated in B of FIG. 86, a straight conductor 923Bb long in the Y direction is periodically arranged in the conductor period FXBb in the X direction and a straight conductor 924Bb long in the Y direction is periodically arranged in the conductor period FXBb in the X direction, instead of the mesh conductor 822Bb of the sixteenth configuration example. The straight conductor 923Bb is, for example, a wiring (Vdd wiring) connected to the positive power supply. The straight conductor 924Bb is, for example, a wiring (Vss wiring) connected to GND or a negative power supply. The conductor period FXBb is equal to a sum of the conductor width WXBb in the X direction and the gap width GXBb in the X direction (conductor period FXBb=conductor width WXBb+gap width GXBb).

The straight conductor 922Ab of the lead conductor portion 165Ab of the conductor layer A is electrically connected to the straight conductor 924Bb of the lead conductor portion 165Bb of the conductor layer B by, for example, the conductor via extended in the Z direction, and is electrically connected to the mesh conductor 821Aa of the main conductor portion 165Aa via the straight conductor 924Bb.

That is, for example, a GND or a negative voltage is alternately transferred on the straight conductor 922Ab of the conductor layer A and the straight conductor 924Bb of the conductor layer B in the lead conductor portion 165b, and arrives at the mesh conductor 821Aa of the main conductor portion 165Aa.

The straight conductor 923Bb of the lead conductor portion 165Bb of the conductor layer B is electrically connected to the straight conductor 921Ab of the lead conductor portion 165Ab of the conductor layer A by, for example, the conductor via extended in the Z direction, and is electrically connected to the mesh conductor 822Ba of the main conductor portion 165Ba via the straight conductor 921Ab.

That is, for example, a positive voltage is alternately transferred on the straight conductor 921Ab of the conductor layer A and the straight conductor 923Bb of the conductor layer B in the lead conductor portion 165b, and arrives at the mesh conductor 823Ba of the main conductor portion 165Ba.

Since the active element group 167 is covered with at least one of the conductor layer A and the conductor layer B in a state in which the conductor layer A and the conductor layer B overlap each other as illustrated in C of FIG. 86, it is possible to shield the hot carrier light emitted from the active element group 167 also in the twenty-first configuration example.

Although the Vdd wiring and the Vss wiring having different polarities are arranged to overlap each other in the same planar region in the lead conductor portion 165b in the fourteenth to twenty-second configuration examples described above, the Vdd wiring and the Vss wiring with different polarities may be displaced and arranged in different planar regions so that GND, a negative voltage, and a positive voltage are transferred using both of the conductor layer A and the conductor layer B, as in the twenty-fourth configuration example of FIG. 86.

The conductor layer of the lead conductor portion 165b is not limited to the mesh conductor and may be formed of a planar conductor or a straight conductor, as in the twenty-first to twenty-fourth configuration examples illustrated in FIGS. 82 to 86. Further, not only one layer of the conductor layer A or B but also two layers of the conductor layers A and B may be used.

With such a configuration, it is possible to achieve any one of an effect of satisfying a wiring layout constraint, an effect of further improving the degree of freedom in a design of the wiring layout, an effect of further reducing the inductive noise, and an effect of further reducing the voltage drop.

### TWENTY-FIFTH CONFIGURATION EXAMPLE

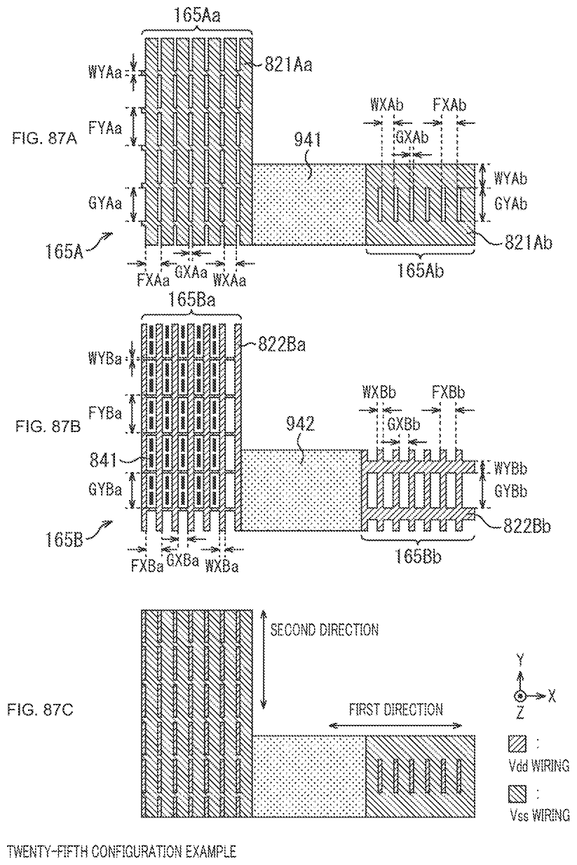

FIG. 87 illustrates a twenty-fifth configuration example of the conductor layers A and B. A of FIG. 87 illustrates the conductor layer A, and B of FIG. 87 illustrates the conductor layer B. C of FIG. 87 illustrates a state in which the respective conductor layers A and B illustrated in A and B of FIG. 87 are viewed from the conductor layer A side. In a coordinate system in FIG. 87, a horizontal direction indicates an X-axis, a vertical direction indicates a Y-axis, and a direction orthogonal to an XY plane indicates a Z-axis.

The twenty-fifth configuration example illustrated in FIG. 87 has a configuration in which some parts are added to the sixteenth configuration example illustrated in FIG. 72. In FIG. 86, portions corresponding to those in FIG. 72 are denoted by the same reference signs, and description of the portions will be appropriately omitted.

The conductor layer A of the twenty-fifth configuration example illustrated in A of FIG. 87 includes a conductor 941 having a shape arbitrarily including a repetitive pattern different from that of the mesh conductor 821Aa of the main conductor portion 165Aa and the mesh conductor 821Ab of the lead conductor portion 165Ab in the sixteenth configuration example illustrated in FIG. 72, which is added between the mesh conductor 821Aa and the mesh conductor 821Ab. Although it is preferable for the conductor 941 to have a shape including a repetitive pattern in order to efficiently design a wiring layout, the conductor 941 may have a shape not including the repetitive pattern. Since the pattern of the conductor 941 can have any shape, the pattern of the conductor 941 in A of FIG. 87 is not particularly specified and is represented by a planar shape. The conductor 941 is electrically connected to both the mesh conductor 821Aa and the mesh conductor 821Ab. In other words, the mesh conductor 821Aa of the main conductor portion 165Aa and the mesh conductor 821Ab of the lead conductor portion 165Ab are electrically connected via the conductor 941.

The conductor layer B of the twenty-fifth configuration example illustrated in B of FIG. 87 includes a conductor 942 having a shape arbitrarily including a repetitive pattern different from that of the mesh conductor 822Ba of the main conductor portion 165Ba and the mesh conductor 822Bb of the lead conductor portion 165Bb in the sixteenth configuration example illustrated in FIG. 72, which is added between the mesh conductor 822Ba and the mesh conductor 822Bb. Although the conductor 942 preferably has a shape including a repetitive pattern in order to efficiently design a wiring layout, the conductor 942 may have a shape not including the repetitive pattern. Since the pattern of the conductor 942 can have any shape, the pattern of the conductor 942 is not particularly specified and is represented by a planar shape in the conductor 942 in B of FIG. 87. The conductor 942 is electrically connected to both the mesh conductor 822Ba and the mesh conductor 822Bb. In other words, the mesh conductor 822Ba of the main conductor portion 165Ba and the mesh conductor 822Bb of the lead conductor portion 165Bb are electrically connected via the conductor 942.

According to the twenty-fifth configuration example, in the conductor layer A, it is possible to further improve the freedom in the wiring layout design and particularly improve a degree of freedom near the pad by connecting the mesh conductor 821Aa of the main conductor portion 165Aa to the mesh conductor 821Ab of the lead conductor portion 165Ab via the predetermined conductor 941.

In the conductor layer B, it is possible to further improve the freedom in the wiring layout design and particularly improve a degree of freedom near the pad by connecting the mesh conductor 822Ba of the main conductor portion 165Ba to the mesh conductor 822Bb of the lead conductor portion 165Bb via the predetermined conductor 942.

### TWENTY-SIXTH CONFIGURATION EXAMPLE

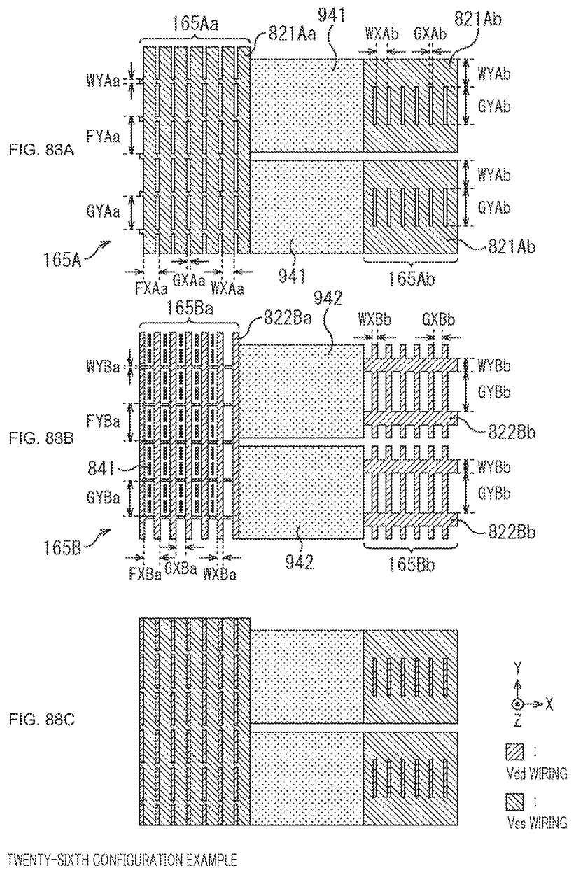

FIG. 88 illustrates a twenty-sixth configuration example of the conductor layers A and B. A of FIG. 88 illustrates the conductor layer A, and B of FIG. 88 illustrates the conductor layer B. C of FIG. 88 illustrates a state in which the respective conductor layers A and B illustrated in A and B of FIG. 88 are viewed from the conductor layer A side. In a coordinate system in FIG. 88, a horizontal direction indicates an X-axis, a vertical direction indicates a Y-axis, and a direction orthogonal to an XY plane indicates a Z-axis.

The twenty-sixth configuration example illustrated in FIG. 88 has a configuration in which the twenty-fifth configuration example illustrated in FIG. 87 is partially modified. In FIG. 86, portions corresponding to those in FIG. 87 are denoted by the same reference signs, and description of the portions will be appropriately omitted.

The conductor layer A of the twenty-sixth configuration example illustrated in A of FIG. 88 includes the same mesh conductor 821Aa as in the twenty-fifth configuration example illustrated in FIG. 87 for the main conductor portion 165Aa. Further, regarding the lead conductor portion 165Ab, the conductor layer A of the twenty-sixth configuration example includes the mesh conductor 821Ab and the conductors 941 that are the same as in the twenty-fifth configuration example as a plurality of ones at predetermined intervals in the Y direction. In other words, the conductor layer A of the twenty-sixth configuration example in A of FIG. 88 has a configuration in which the twenty-fifth configuration example illustrated in FIG. 87 is modified so that the mesh conductor 821Ab of the lead conductor portion 165Ab and the conductor 941 in the twenty-fifth configuration example illustrated in FIG. 87 are provided as a plurality of ones at predetermined intervals in the Y direction. All of the plurality of conductors 941 may be the same or may not be the same.

The conductor layer B of the twenty-sixth configuration example illustrated in B of FIG. 88 includes the same mesh conductor 822Ba as in the twenty-fifth configuration example illustrated in FIG. 87 for the main conductor portion 165Ba. Further, regarding the lead conductor portion 165Bb, the conductor layer B of the twenty-sixth configuration example includes the mesh conductor 822Bb and the conductors 942 that are the same as in the twenty-fifth configuration example as a plurality of ones at predetermined intervals in the Y direction. In other words, the conductor layer B of the twenty-sixth configuration example in B of FIG. 88 has a configuration in which the twenty-fifth configuration example illustrated in FIG. 87 is modified so that the mesh conductor 822Bb of the lead conductor portion 165Bb and the conductor 942 in the twenty-fifth configuration example illustrated in FIG. 87 are provided as a plurality of ones at predetermined intervals in the Y direction. All of the plurality of conductors 942 may be the same or may not be the same.

With such a configuration, it is possible to achieve any one of an effect of satisfying a wiring layout constraint, an effect of further improving the degree of freedom in a design of the wiring layout, an effect of further reducing the inductive noise, and an effect of further reducing the voltage drop.

### TWENTY-SEVENTH CONFIGURATION EXAMPLE

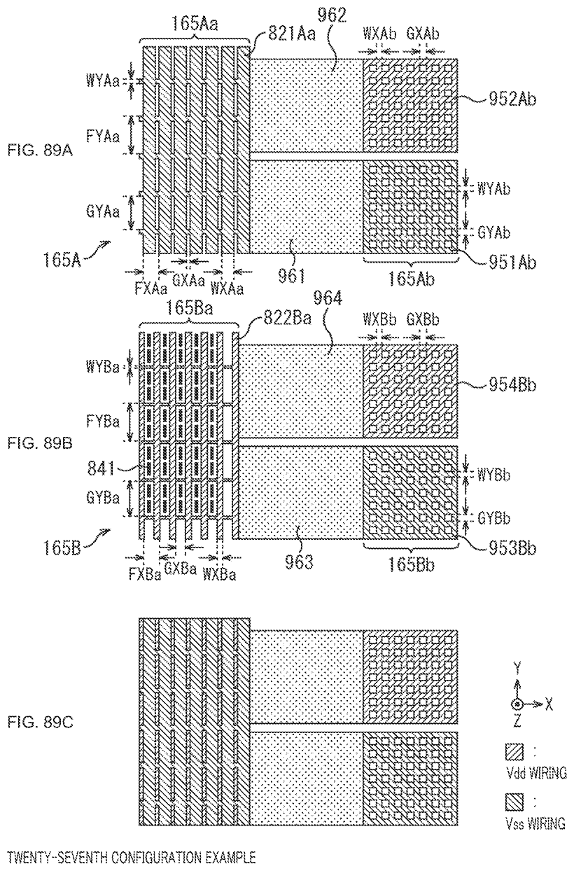

FIG. 89 illustrates a twenty-seventh configuration example of the conductor layers A and B. A of FIG. 89 illustrates the conductor layer A, and B of FIG. 89 illustrates the conductor layer B. C of FIG. 89 illustrates a state in which the respective conductor layers A and B illustrated in A and B of FIG. 89 are viewed from the conductor layer A side. In a coordinate system in FIG. 89, a horizontal direction indicates an X-axis, a vertical direction indicates a Y-axis, and a direction orthogonal to an XY plane indicates a Z-axis.

The twenty-seventh configuration example illustrated in FIG. 89 has a configuration in which the twenty-sixth configuration example illustrated in FIG. 88 is partially modified. In FIG. 89, portions corresponding to those in FIG. 88 are denoted by the same reference signs, and description of the portions will be appropriately omitted.

The main conductor portion 165Aa of the conductor layer A of the twenty-seventh configuration example illustrated in A of FIG. 89 includes the same mesh conductor 821Aa as that in the twenty-sixth configuration example illustrated in FIG. 88. The lead conductor portion 165Ab of the conductor layer A of the twenty-seventh configuration example includes a mesh conductor 951Ab and a mesh conductor 952Ab. Each of shapes of the mesh conductor 951Ab and the mesh conductor 952Ab includes a conductor width WXAb and a gap width GXAb in the X direction, and a conductor width WYAb and a gap width GYAb in the Y direction. However, the mesh conductor 952Ab is, for example, a wiring (Vdd wiring) connected to the positive power supply, and the mesh conductor 951Ab is, for example, a wiring (Vss wiring) connected to the GND or the negative power supply.

A conductor 961 having a shape arbitrarily including a repetitive pattern different from that of the mesh conductor 821Aa of the main conductor portion 165Aa and the mesh conductor 951Ab of the lead conductor portion 165Ab is arranged between the mesh conductor 821Aa of the main conductor portion 165Aa and the mesh conductor 951Ab of the lead conductor portion 165Ab. A conductor 962 having a shape arbitrarily including a repetitive pattern different from that of the mesh conductor 821Aa of the main conductor portion 165Aa and the mesh conductor 952Ab of the lead conductor portion 165Ab is arranged between the mesh conductor 821Aa of the main conductor portion 165Aa and the mesh conductor 952Ab of the lead conductor portion 165Ab. Although it is preferable for the conductor 961 or 962 to have a shape including a repetitive pattern in order to efficiently design a wiring layout, the conductor 961 or 962 may have a shape not including the repetitive pattern. Since the pattern of the conductor 961 or 962 can have any shape, the pattern of the conductor 961 or 962 in A of FIG. 89 is not particularly specified and is represented by a planar shape.

The main conductor portion 165Ba of the conductor layer B of the twenty-seventh configuration example illustrated in B of FIG. 89 includes the mesh conductor 822Ba that is the same as that of the twenty-sixth configuration example illustrated in FIG. 88. The lead conductor portion 165Bb of the conductor layer B of the twenty-seventh configuration example includes a mesh conductor 953Bb and a mesh conductor 954Bb. Each of shapes of the mesh conductor 953Bb and the mesh conductor 954Bb has the conductor width WXBb and the gap width GXBb in the X direction, and the conductor width WYBb and the gap width GYBb in the Y direction. However, the mesh conductor 954Bb is, for example, a wiring (Vdd wiring) connected to the positive power supply, and the mesh conductor 953Bb is, for example, a wiring (Vss wiring) connected to the GND or the negative power supply.

A conductor 963 having a shape arbitrarily including a repetitive pattern different from those of the mesh conductor 822Ba of the main conductor portion 165Ba and the mesh conductor 953Bb of the lead conductor portion 165Bb is arranged between the mesh conductor 822Ba of the main conductor portion 165Ba and the mesh conductor 953Bb of the lead conductor portion 165Bb. A conductor 964 having a shape arbitrarily including a repetitive pattern different from those of the mesh conductor 822Ba of the main conductor portion 165Ba and the mesh conductor 954Bb of the lead conductor portion 165Bb is arranged between the mesh conductor 822Ba of the main conductor portion 165Ba and the mesh conductor 954Bb of the lead conductor portion 165Bb. Although it is preferable for the conductor 963 or 964 to have a shape including a repetitive pattern in order to efficiently design a wiring layout, the conductor 963 or 964 may have a shape not including the repetitive pattern. Since the pattern of the conductor 963 or 964 can have any shape, the pattern of the conductor 963 or 964 in A of FIG. 89 is not particularly specified and is represented by a planar shape.

The conductor 961 of the conductor layer A is electrically connected to at least one of the mesh conductor 821Aa of the main conductor portion 165Aa and the mesh conductor 951Ab or 953Bb of the lead conductor portion 165b directly or, for example, indirectly via a conductor such as at least a part of the conductor 963. In other words, the mesh conductor 821Aa of the main conductor portion 165Aa and at least one of the mesh conductors 951Ab and 953Bb of the lead conductor portion 165b are electrically connected via the conductor 961. Further, the mesh conductor 951Ab of the lead conductor portion 165Ab is electrically connected to the mesh conductor 953Bb of the lead conductor portion 165Bb of the conductor layer B, for example, by the conductor via extended in the Z direction. The conductor 961 and the conductor 963 may also be electrically connected to each other by, for example, the conductor via extended in the Z direction.

The conductor 964 of the conductor layer B is electrically connected to at least one of the mesh conductor 822Ba of the main conductor portion 165Ba and the mesh conductor 952Ab or 954Bb of the lead conductor portion 165b directly or, for example, indirectly via a conductor such as at least a part of the conductor 962. In other words, the mesh conductor 822Ba of the main conductor portion 165Ba and at least one of the mesh conductors 952Ab and 954Bb of the lead conductor portion 165b are electrically connected via the conductor 964. Further, the mesh conductor 952Ab of the lead conductor portion 165Ab is electrically connected to the mesh conductor 954Bb of the lead conductor portion 165Bb of the conductor layer B, for example, by the conductor via extended in the Z direction. The conductor 962 and the conductor 964 may also be electrically connected to each other by, for example, the conductor via extended in the Z direction.

For example, in the twenty-sixth configuration example of FIG. 88 described above, in the case of polarities of the conductor layer A and the conductor layer B at the same plane position for each of the main conductor portion 165a and the lead conductor portion 165b, polarities of the main conductor portion 165Aa of the conductor layer A and the main conductor portion 165Ba of the conductor layer B differ between the Vss wiring and the Vdd wiring, and polarities of the lead conductor portion 165Ab of the conductor layer A and the lead conductor portion 165Bb of the conductor layer B differ.

On the other hand, in the twenty-seventh configuration example of FIG. 89, in the case of polarities of the conductor layer A and the conductor layer B at the same plane position for each of the main conductor portion 165a and the lead conductor portion 165b, polarities of the main conductor portion 165Aa of the conductor layer A and the main conductor portion 165Ba of the conductor layer B differ between the Vss wiring and the Vdd wiring, and polarities of the lead conductor portion 165Ab of the conductor layer A and the lead conductor portion 165Bb of the conductor layer B are the same. When the upper and lower conductor layers A and B are configured by such a polar arrangement, the lead conductor portion 165b electrically connected to the upper and lower conductor layers A and B can be used as a pad (electrode).

According to the twenty-seventh configuration example, it is possible to achieve any one of an effect of satisfying a wiring layout constraint, an effect of further improving the degree of freedom in a design of the wiring layout, an effect of further reducing the inductive noise, and an effect of further reducing the voltage drop.

### TWENTY-EIGHTH CONFIGURATION EXAMPLE

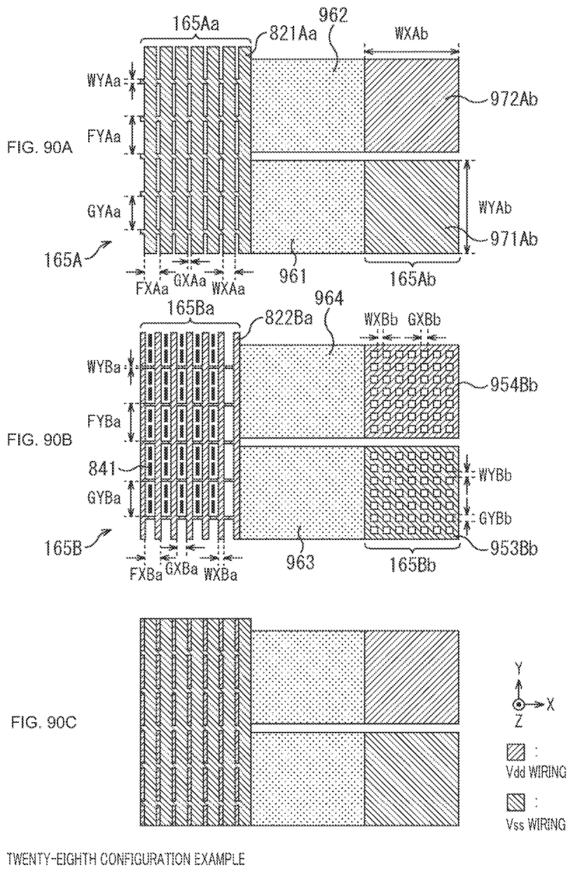

FIG. 90 illustrates a twenty-eighth configuration example of the conductor layers A and B. A of FIG. 90 illustrates the conductor layer A, and B of FIG. 90 illustrates the conductor layer B. C of FIG. 90 illustrates a state in which the respective conductor layers A and B illustrated in A and B of FIG. 90 are viewed from the conductor layer A side. In a coordinate system in FIG. 90, a horizontal direction indicates an X-axis, a vertical direction indicates a Y-axis, and a direction orthogonal to an XY plane indicates a Z-axis.

The twenty-eighth configuration example illustrated in FIG. 90 has a configuration in which the twenty-seventh configuration example illustrated in FIG. 89 is partially modified. In FIG. 90, portions corresponding to those in FIG. 89 are denoted by the same reference signs, and description of the portions will be appropriately omitted.

The twenty-eighth configuration example illustrated in FIG. 90 differs from the twenty-seventh configuration example of FIG. 89 only in a shape of the lead conductor portion 165Ab of the conductor layer A, and is the same as the twenty-seventh configuration example of FIG. 89 in other points.

Specifically, the mesh conductor 951Ab and the mesh conductor 952Ab including a shape of the conductor width WXAb and the gap width GXAb in the X direction and the conductor width WYAb and the gap width GYAb in the Y direction are formed in the lead conductor portion 165Ab of the conductor layer A in the twenty-seventh configuration example of FIG. 89.

On the other hand, a planar conductor 971Ab and a planar conductor 972Ab including a shape of the conductor width WXAb in the X direction and the conductor width WYAb in the Y direction are formed in the lead conductor portion 165Ab of the conductor layer A in the twenty-eighth configuration example of FIG. 90.

In other words, in the twenty-eighth configuration example of FIG. 90, in the lead conductor portion 165Ab of the conductor layer A, the planar conductor 971Ab is provided instead of the mesh conductor 951Ab of the twenty-seventh configuration example of FIG. 89 and the planar conductor 972Ab is provided instead of the mesh conductor 952Ab.

Although the twenty-seventh configuration example illustrated in FIG. 89 is an example in which the lead conductor portions 165b of the upper and lower conductor layers A and B have the same shape, but the lead conductor portions 165b may have different shapes as in the twenty-eighth configuration example of FIG. 90.

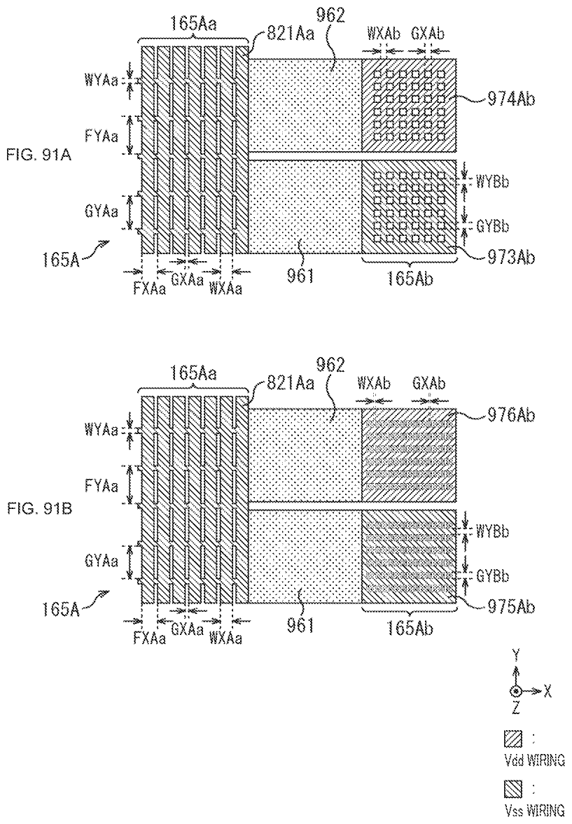

Further, although the lead conductor portion 165Ab of the conductor layer A has a planar shape in the twenty-eighth configuration example of FIG. 90, a configuration in which, even when the lead conductor portion 165Ab has the same mesh shape as the mesh conductor 973Ab and the mesh conductor 974Ab of the lead conductor portion 165Ab of the conductor layer A illustrated in A of FIG. 91, a light shield structure is formed by the mesh conductor 973Ab of the conductor layer A in A of FIG. 91 and the mesh conductor 953Bb of the conductor layer B in B of FIG. 90, and a light shield structure is formed by the mesh conductor 974Ab of the conductor layer A in A of FIG. 91 and the mesh conductor 954Bb of the conductor layer B in B of FIG. 90 may be adopted. Further, the conductor width WXAb or the gap width GXAb in the X direction or the conductor width WYAb or the gap width GYAb in the Y direction may be substantially the same as that of the mesh conductor 953Bb or the mesh conductor 954Bb of the lead conductor portion 165Bb of the conductor layer B.

Alternatively, the conductor width WXAb or the gap width GXAb in the X direction may be smaller than those of the mesh conductor 953Bb or the mesh conductor 954Bb of the lead conductor portion 165Bb of the conductor layer B in B of FIG. 90, as in the mesh conductor 975Ab and the mesh conductor 976Ab of the lead conductor portion 165Ab of the conductor layer A illustrated in B of FIG. 91. Further, the mesh conductor 975Ab of the conductor layer A of B in B of FIG. 91 and the mesh conductor 953Bb of the conductor layer B in B of FIG. 90 may form a light shielding structure, and the mesh conductor 976Ab of the conductor layer A in B of FIG. 91 and the mesh conductor 954Bb of the conductor layer B of FIG. 90 may form a light shielding structure. Further, although not illustrated, the conductor width WYAb or the gap width GYAb in the Y direction of the lead conductor portion 165Ab of the conductor layer A may be smaller than that of the mesh conductor 953Bb or the mesh conductor 954Bb of the lead conductor portion 165Bb of the conductor layer B, and the conductor width WXAb or the gap width GXAb in the X direction or the conductor width WYAb or the gap width GYAb in the Y direction of the lead conductor portion 165Ab of the conductor layer A may be larger than that of the mesh conductor 953Bb or the mesh conductor 954Bb of the lead conductor portion 165Bb of the conductor layer B.

A and B of FIG. 91 illustrate other configuration examples of the conductor layer A in the twenty-eighth configuration example of FIG. 90.

### SUMMARY OF FOURTEENTH TO TWENTY-EIGHTH CONFIGURATION EXAMPLES

In fourteenth to twenty-eighth configuration examples illustrated in FIGS. 65 to 90, repetitive patterns of the main conductor portion 165a and the lead conductor portion 165b in both the conductor layer A and the conductor layer B are different patterns (shapes).

The conductor layer A (a first conductor layer) includes the main conductor portion 165Aa (first conductor portion) including a conductor having a shape in which a pattern in which a plane, straight line, or mesh is repeated (a first basic pattern) is repeatedly arranged on a single plane in the X direction or the Y direction, and the lead conductor portion 165Ab (fourth conductor portion) including a conductor having a shape in which a pattern in which a plane, straight line, or mesh is repeated (a fourth basic pattern) is repeatedly arranged on a single plane in the X direction or the Y direction. Here, the repetitive pattern of the conductor of the main conductor portion 165Aa and the repetitive pattern of the conductor of the lead conductor portion 165Ab may have different shapes, and conductors having a pattern different from patterns of the conductor of the main conductor portion 165Aa and the conductor of the lead conductor portion 165Ab may be present between the conductor of the main conductor portion 165Aa and the conductor of the lead conductor portion 165Ab.

The conductor layer B (a second conductor layer) includes the main conductor portion 165Ba (second conductor portion) including a conductor having a shape in which a pattern in which a plane, straight line, or mesh is repeated (a second basic pattern) is repeatedly arranged on a single plane in the X direction or the Y direction, and the lead conductor portion 165Bb (a third conductor portion) including a conductor having a shape in which a pattern in which a plane, straight line, or mesh is repeated (a third basic pattern) is repeatedly arranged on a single plane in the X direction or the Y direction. Here, the repetitive pattern of the conductor of the main conductor portion 165Ba and the repetitive pattern of the conductor of the lead conductor portion 165Bb may have different shapes, and the patterns and the conductors having different patterns may be present between the conductor of the main conductor portion 165Ba and the conductor of the lead conductor portion 165Bb.

In each configuration example described above, for example, the conductor described as the wiring (Vss wiring) connected to the GND or the negative power supply may be, for example, the wiring (Vdd wiring) connected to the positive power supply and, for example, the conductor described as the wiring (Vdd wiring) connected to the positive power supply may be, for example, the wiring (Vss wiring) connected to the GND or the negative power supply.

Although the total length LAa of the conductor of the main conductor portion 165Aa in the Y direction is longer than the total length LAb of the conductor in the lead conductor portion 165Ab in the Y direction in each of the configuration examples described above, the total length LAa and the total length LAb may be the same or substantially the same, or the total length LAa may be shorter than the total length LAb.

Similarly, although the total length LBa of the main conductor portion 165Ba in the Y direction is longer than the total length LBb of the lead conductor portion 165Bb in the Y direction, the total length LBa and the total length LBb may be the same or substantially the same, or the total length LBa may be shorter than the total length LBb.

In the configuration example in which the repetitive pattern in which it is easy for a current to flow in the Y direction rather than the X direction is used among the configuration examples described above, the example of the repetitive pattern of the main conductor portion 165Aa and the main conductor portion 165Ba may be a repetitive pattern example in which it is easy for a current to flow in the X direction, or on the other hand, in the configuration example in which a repetitive pattern in which it is easy for a current to flow in the X direction rather than the Y direction is used, the example of the repetitive pattern of the main conductor portion 165Aa and the main conductor portion 165Ba may be a repetitive pattern example in which it is easy for a current to flow in the Y direction. Further, an example of a repetitive pattern in which it is easy for a current to flow to the same extent in the X direction and the Y direction may be used.

In each of the configuration examples described above, the patterns of the conductors of the main conductor portion 165Aa of the conductor layer A (wiring layer 165A) and the main conductor portion 165Ba of the conductor layer B (wiring layer 165B) may have a configuration of any one of the patterns described in the first to thirteenth configuration examples. The description has been given using the example in which all conductor periods, all conductor widths, or all gap widths are equal in some of the respective configuration examples described above, but the present technology is not limited thereto. For example, the conductor periods, the conductor widths, or the gap widths may not be equal, or the conductor periods, the conductor widths, or the gap widths may be changed depending on positions. Further, the description has been given using the example in which the conductor periods, the conductor widths, the gap widths, the wiring shapes, the wiring positions, or the numbers of wirings are substantially the same in the Vdd wiring and the Vss wiring in some of the configuration examples described above, but the present technology is not limited thereto. For example, in the Vdd wiring and the Vss wiring, the conductor periods may differ, the conductor widths may differ, the gap widths may differ, the wiring shapes may differ, the wiring positions may differ, the wiring positions may be displaced or misaligned, and the numbers of wirings may differ.

<10. Configuration Examples of Connection to Pad>

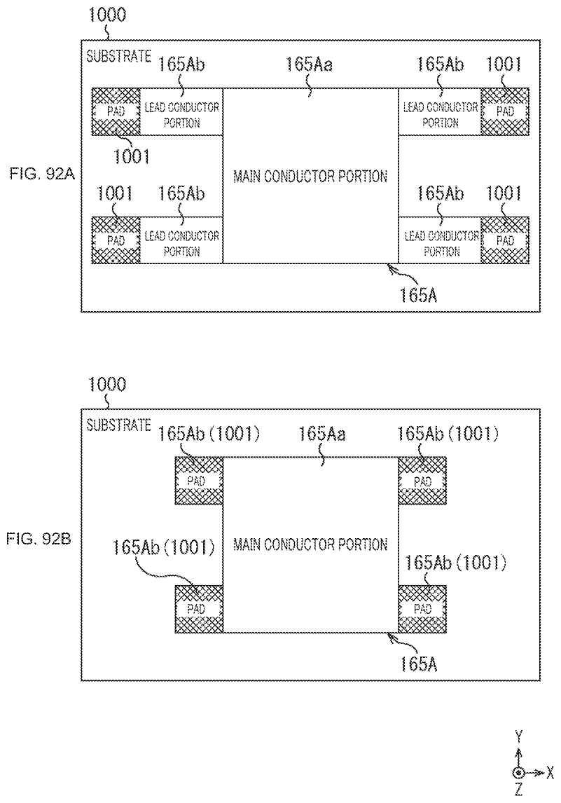

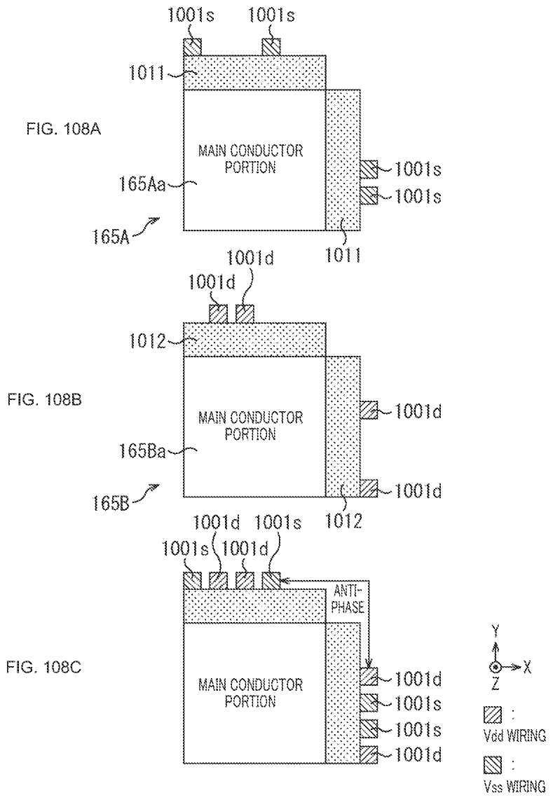

Next, a relationship between the conductor layers A and B and the pad will be described with reference to FIGS. 92 and 108.

FIG. 92 is a plan view illustrating the entire conductor layer A formed on the substrate.

The conductor layer A (wiring layer 165A) includes the main conductor portion 165Aa and the lead conductor portion 165Ab, As described above.

When a pad is provided separately from the conductor layer A, the lead conductor portion 165Ab is provided at a position near the pad 1001 and connects the main conductor portion 165Aa to the pad 1001 as illustrated in A of FIG. 92. On the other hand, the lead conductor portion 165Ab may form the pad 1001, as illustrated in B of FIG. 92.

The main conductor portion 165Aa is formed in a main region of the substrate 1000 such as a central region of the substrate to have a larger area than that of the lead conductor portion 165Ab, and shields light in active elements such as MOMS transistors or diodes formed in a region of the main conductor portion 165Aa or other layers in the Z direction orthogonal to a surface of the region.

FIG. 92 illustrates an example of an arrangement and shape of the conductor layer A, and an arrangement and shape of the conductor layer A are not limited thereto. Therefore, a position and area in the substrate 1000 in which the main conductor portion 165Aa, the lead conductor portion 165Ab, and the pad 1001 are formed are arbitrary, and an active element may not be formed in the region of the main conductor portion 165Aa and the lead conductor portion 165Ab or in another layer in the Z direction orthogonal to a surface of the region. The lead conductor portion 165Ab may not be provided at a position close to the pad 1001. Further, an arrangement of the lead conductor portion 165Ab and the pad 1001 with respect to the main conductor portion 165Aa may be on the side in the Y direction among four sides of the main conductor portion 165Aa rather than the side in the X direction as illustrated in FIG. 92, or may be on both the sides in the X direction and the Y direction. Further, the number of pads 1001 may be one or three or more instead of two on each side, as illustrated in FIG. 92.

FIG. 92 illustrates an example of the conductor layer A (wiring layer 165A), and the same applies to the conductor layer B (wiring layer 165B).

With such a configuration, it is possible to achieve any one of an effect of satisfying a wiring layout constraint, an effect of further improving the degree of freedom in a design of the wiring layout, an effect of further reducing the inductive noise, and an effect of further reducing the voltage drop.

In FIG. 92, it is not particularly distinguished between whether the pad 1001 is an electrode (Vdd electrode) connected to a positive power supply and whether the pad 1001 is an electrode (Vss electrode) connected to GND or a negative power supply, but an arrangement of the pads 1001 when it is distinguished between whether the pad 1001 is an electrode (Vdd electrode) connected to a positive power supply and whether the pad 1001 is an electrode (Vss electrode) connected to GND or a negative power supply will be described below.

<Fourth Arrangement Example of Pads>

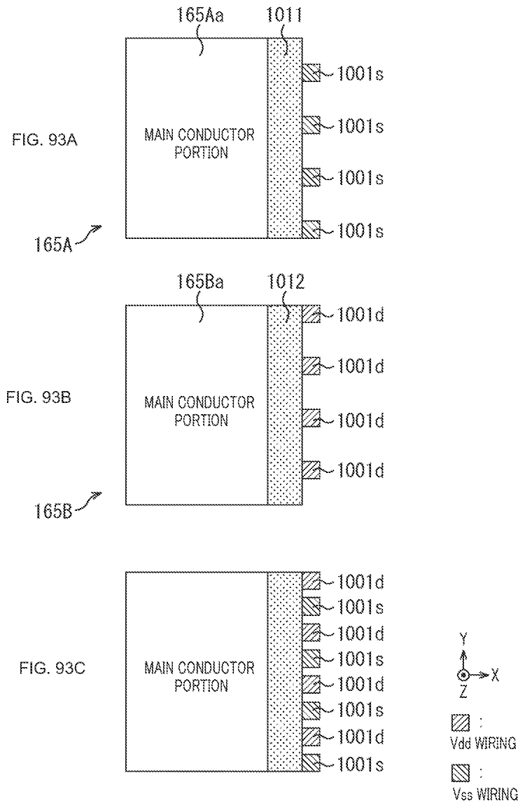

FIG. 93 illustrates a fourth arrangement example of the pads.

A of FIG. 93 is a plan view illustrating an arrangement example of the conductor layer A (wiring layer 165A) and the pads 1001s connected thereto.

B of FIG. 93 is a plan view illustrating an arrangement example of the conductor layer B (wiring layer 165B) and the pads 1001d connected thereto.

C of FIG. 93 is a plan view in a state in which the conductor layers A and B and the pads 1001s and 1001d illustrated in A and B of FIG. 93 are stacked.

In FIG. 93, the pad 1001s indicates the pad 1001 to which, for example, GND or a negative power supply (Vss) is supplied, and the pad 1001d indicates the pad 1001 to which a positive voltage (Vdd) is supplied.

As illustrated in A of FIG. 93, a plurality of pads 1001s are connected to a predetermined side of the main conductor portion 165Aa having a rectangular shape via a conductor 1011 having a shape arbitrarily including a predetermined repetitive pattern at predetermined intervals. Each pad 1001s may be formed of a lead conductor portion 165Ab as in the twenty-seventh configuration example illustrated in FIG. 89, or the conductor 1011 may be formed of a lead conductor portion 165Ab. When the pad 1001s is the lead conductor portion 165Ab, the conductor 1011 may be omitted or may be provided.

As illustrated in B of FIG. 93, the plurality of pads 1001d are connected to a predetermined side of the main conductor portion 165Ba having a rectangular shape, which is the same side as the side in which the pad 1001s is arranged in the conductor layer A, at predetermined intervals via the conductors 1012 having a shape arbitrarily including a predetermined repetitive pattern. Each pads 1001d, for example, may be formed of the lead conductor portion 165Bb as in the twenty-seventh configuration example illustrated in FIG. 89, or the conductor 1012 may be formed of the lead conductor portion 165Bb. When the pad 1001d is the lead conductor portion 165Bb, the conductor 1012 may be omitted or may be provided.

As illustrated in C of FIG. 93, in a state in which the conductor layers A and B are stacked, the arrangement of the pads 1001s and the pad 1001d is an alternate arrangement in which the pads 1001s and the pads 1001d are alternately arranged in the Y direction. In this case, as described with reference to FIGS. 42 to 44, since it is possible to effectively offset the magnetic fields generated from the conductor layers A and B and the induced electromotive force based on the magnetic fields, it is possible to further reduce the inductive noise. However, the pads are not arranged symmetrically in the Y direction and thus, when the pads 1001 are arranged in a wide range, that is, when the main conductor portion 165Aa or 165Ba, the lead conductor portion 165Ab or 165Bb, or the conductor 1011 or 1012 is long in a layout direction of the pads 1001 (when the conductor is longer in the Y direction than in the X direction in FIG. 93), there is a magnetic field that cannot be offset, the magnetic field is accumulated when the victim conductor loop is larger, the induced electromotive force increases, and the inductive noise may increase.

<Fifth Arrangement Example of Pads>

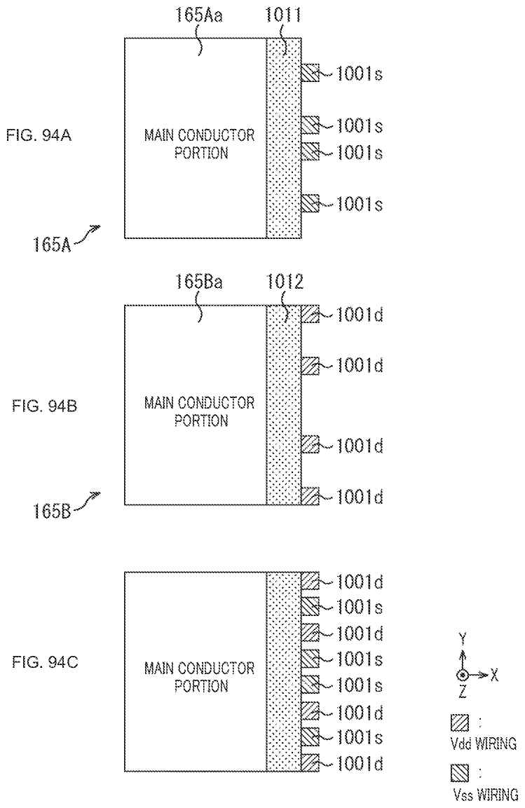

FIG. 94 illustrates a fifth arrangement example of the pads.

A of FIG. 94 is a plan view illustrating an arrangement example of the conductor layer A (wiring layer 165A) and the pads 1001s connected thereto.

B of FIG. 94 is a plan view illustrating an arrangement example of the conductor layer B (wiring layer 165B) and the pads 1001d connected thereto.

C of FIG. 94 is a plan view in a state in which the conductor layers A and B and the pads 1001s and 1001d illustrated in A and B of FIG. 94 are stacked.

In FIG. 94, the pad 1001s indicates the pad 1001 to which, for example, GND or a negative power supply (Vss) is supplied, and the pad 1001d indicates the pad 1001 to which a positive voltage is supplied.

As illustrated in A of FIG. 94, a plurality of pads 1001s are connected to a predetermined side of the main conductor portion 165Aa having a rectangular shape at predetermined intervals via the conductor 1011 having a shape arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 94, the plurality of pads 1001d are connected to a predetermined side of the main conductor portion 165Ba having a rectangular shape, which is the same side as the side in which the pad 1001s is arranged in the conductor layer A, at predetermined intervals via the conductors 1012 having a shape arbitrarily including a predetermined repetitive pattern. Each pad 1001d may be formed of the lead conductor portion 165Bb, or the conductor 1012 may be formed of the lead conductor portion 165Bb. Further, when the pad 1001d is the lead conductor portion 165Bb, the conductor 1012 may be omitted or may be provided.

As illustrated in C of FIG. 94, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. In this case, since magnetic fields generated from the respective conductor layers A and B and the induced electromotive force based on the magnetic fields can be more effectively offset, it is possible to further reduce the inductive noise depending on a layout other than the pads, as compared with the alternate arrangement illustrated in FIG. 93. p <Sixth Arrangement Example of Pads>

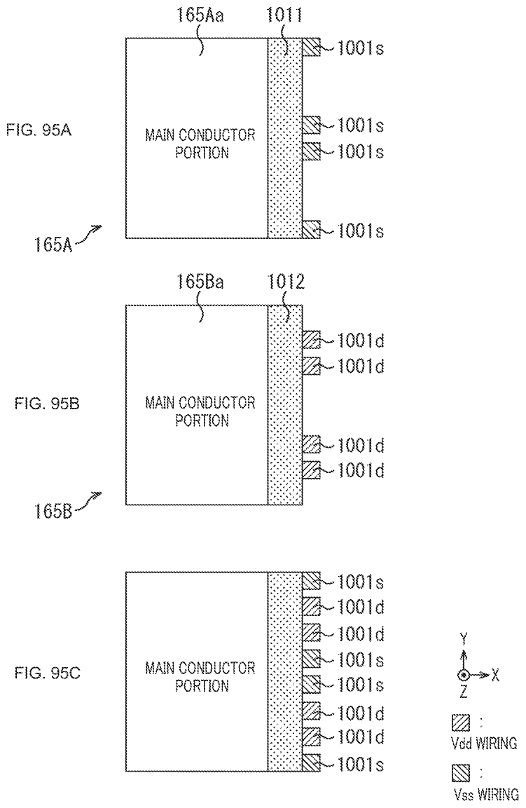

FIG. 95 illustrates a sixth arrangement example of the pads.

A of FIG. 95 is a plan view illustrating an arrangement example of the conductor layer A (wiring layer 165A) and the pads 1001s connected thereto.

B of FIG. 95 is a plan view illustrating an arrangement example of the conductor layer B (wiring layer 165B) and the pads 1001d connected thereto.

C of FIG. 95 is a plan view in a state in which the conductor layers A and B and the pads 1001s and 1001d illustrated in A and B of FIG. 95 are stacked.

In FIG. 95, the pad 1001s indicates the pad 1001 to which, for example, GND or a negative power supply (Vss) is supplied, and the pad 1001d indicates the pad 1001 to which a positive voltage is supplied.

As illustrated in A of FIG. 95, a plurality of pads 1001s are connected to a predetermined side of the main conductor portion 165Aa having a rectangular shape at predetermined intervals via the conductor 1011 having a shape arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 95, the plurality of pads 1001d are connected to a predetermined side of the main conductor portion 165Ba having a rectangular shape, which is the same side as the side in which the pad 1001s is arranged in the conductor layer A, at predetermined intervals via the conductors 1012 having a shape arbitrarily including a predetermined repetitive pattern. Each pad 1001d may be formed of the lead conductor portion 165Bb, or the conductor 1012 may be formed of the lead conductor portion 165Bb. Further, when the pad 1001d is the lead conductor portion 165Bb, the conductor 1012 may be omitted or may be provided.

As illustrated in C of FIG. 95, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. Further, the four pads 1001s and the pads 1001d forming one set also have a mirror-symmetrical arrangement in which two pads 1001 on one side are folded back in the Y direction and arranged with reference to a center line in the Y direction. In the case of such a two-stage configuration of the mirror layout, since a range in which a residual magnetic field is accumulated is narrow, the induced electromotive force can be more effectively offset and it is possible to further reduce the inductive noise depending on a layout other than the pads, as compared with the mirror arrangement of a one-stage configuration illustrated in FIG. 94.

<Seventh Arrangement Example of Pads>

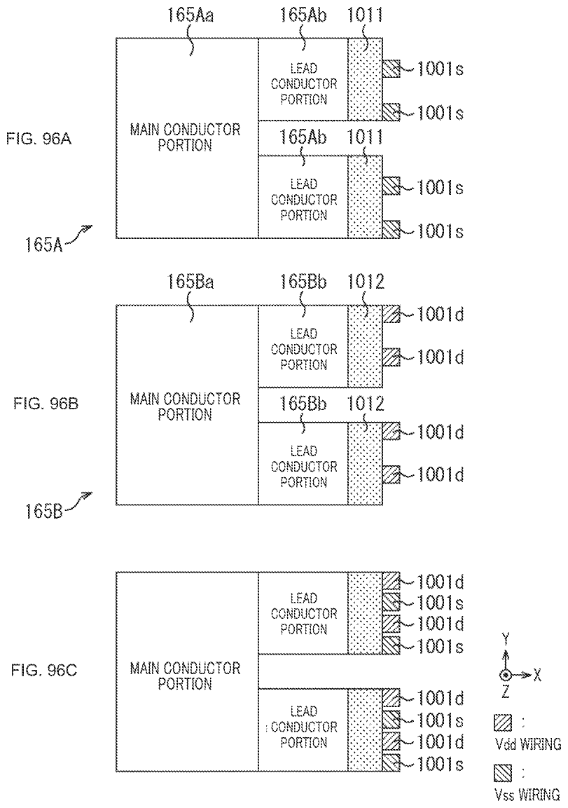

FIG. 96 illustrates a seventh arrangement example of the pads.

A of 96 is a plan view illustrating an arrangement example of the conductor layer A (wiring layer 165A) and the pads 1001s connected thereto.

B of FIG. 96 is a plan view illustrating an arrangement example of the conductor layer B (wiring layer 165B) and the pads 1001d connected thereto.

C of FIG. 96 is a plan view in a state in which the conductor layers A and B and the pads 1001s and 1001d illustrated in A and B of FIG. 96 are stacked.

In FIG. 96, the pad 1001s indicates the pad 1001 to which, for example, GND or a negative power supply (Vss) is supplied, and the pad 1001d indicates the pad 1001 to which a positive voltage is supplied.

As illustrated in A of FIG. 96, the plurality of lead conductor portions 165Ab are connected to a predetermined side of the main conductor portion 165Aa having a rectangular shape, and one pad 1001s are connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 96, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 96, in a state in which the conductor layers A and B are stacked, the arrangement of the pads 1001s and the pad 1001d is an alternate arrangement in which the pads 1001s and the pads 1001d are alternately arranged in the Y direction. In this case, since it is possible to effectively offset the magnetic fields generated from the conductor layers A and B and the induced electromotive force based on the magnetic fields, it is possible to further reduce the inductive noise. However, the pads are not arranged symmetrically in the Y direction and thus, when the pads 1001 are arranged in a wide range, that is, when the main conductor portion 165Aa or 165Ba, the lead conductor portion 165Ab or 165Bb, or the conductor 1011 or 1012 is long in a layout direction of the pads 1001 (when the conductor is longer in the Y direction than in the X direction in FIG. 96), there is a magnetic field that cannot be offset, the magnetic field is accumulated when the victim conductor loop is larger, the induced electromotive force increases, and the inductive noise may increase.

<Eighth Arrangement Example of Pads>

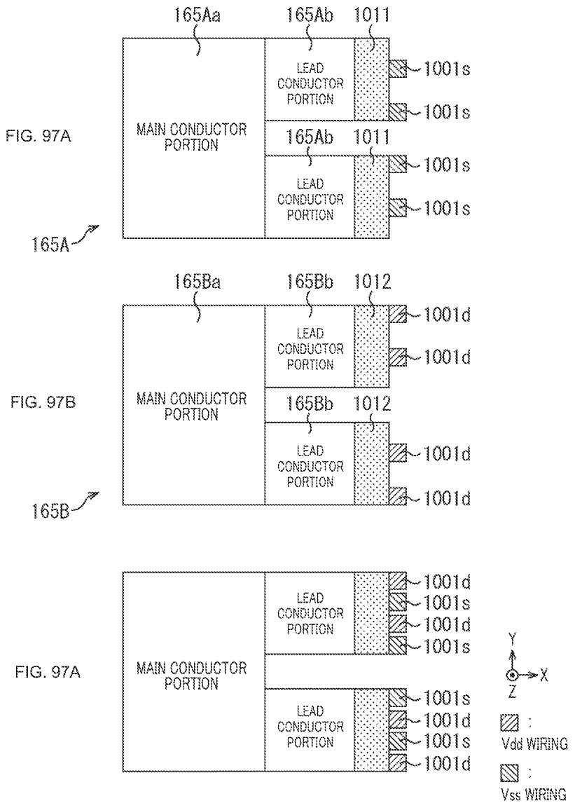

FIG. 97 illustrates an eighth arrangement example of the pads.

A of FIG. 97 is a plan view illustrating an arrangement example of the conductor layer A (wiring layer 165A) and the pads 1001s connected thereto.

B of FIG. 97 is a plan view illustrating an arrangement example of the conductor layer B (wiring layer 165B) and the pads 1001d connected thereto.

C of FIG. 97 is a plan view in a state in which the conductor layers A and B and the pads 1001s and 1001d illustrated in A and B of FIG. 97 are stacked.

In FIG. 97, the pad 1001s indicates the pad 1001 to which, for example, GND or a negative power supply (Vss) is supplied, and the pad 1001d indicates the pad 1001 to which a positive voltage is supplied.

As illustrated in A of FIG. 97, the plurality of lead conductor portions 165Ab are connected to a predetermined side of the main conductor portion 165Aa having a rectangular shape, and one pad 1001s is connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 97, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 97, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. In this case, since magnetic fields generated from the respective conductor layers A and B and the induced electromotive force based on the magnetic fields can be more effectively offset, it is possible to further reduce the inductive noise depending on a layout other than the pads, as compared with the alternate arrangement illustrated in FIG. 96.

<Ninth Arrangement Example of Pads>

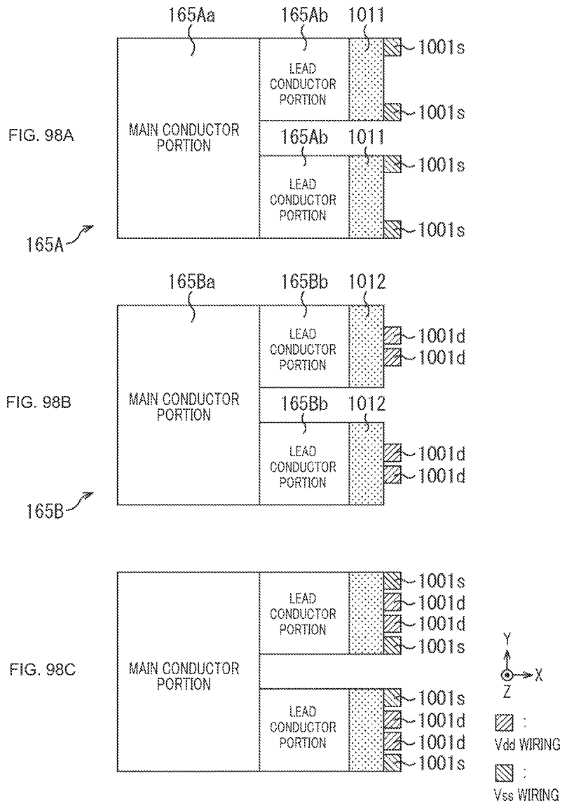

FIG. 98 illustrates a ninth arrangement example of the pads.

A of FIG. 98 is a plan view illustrating an arrangement example of the conductor layer A (wiring layer 165A) and the pads 1001s connected thereto.

B of FIG. 98 is a plan view illustrating an arrangement example of the conductor layer B (wiring layer 165B) and the pads 1001d connected thereto.

C of FIG. 98 is a plan view in a state in which the conductor layers A and B and the pads 1001s and 1001d illustrated in A and B of FIG. 98 are stacked.

In FIG. 98, the pad 1001s indicates the pad 1001 to which, for example, GND or a negative power supply (Vss) is supplied, and the pad 1001d indicates the pad 1001 to which a positive voltage is supplied.

As illustrated in A of FIG. 98, the plurality of lead conductor portions 165Ab are connected to a predetermined side of the main conductor portion 165Aa having a rectangular shape, and one pad 1001s is connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 98, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 98, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. Further, the four pads 1001s and the pads 1001d forming one set also have a mirror-symmetrical arrangement in which two pads 1001 on one side are folded back in the Y direction and arranged with reference to a center line in the Y direction. In the case of such a two-stage configuration of the mirror layout, since a range in which a residual magnetic field is accumulated is narrow, the induced electromotive force can be more effectively offset and it is possible to further reduce the inductive noise depending on a layout other than the pads, as compared with the mirror arrangement of a one-stage configuration illustrated in FIG. 97.

<Tenth ASrrangement Example of Pads>

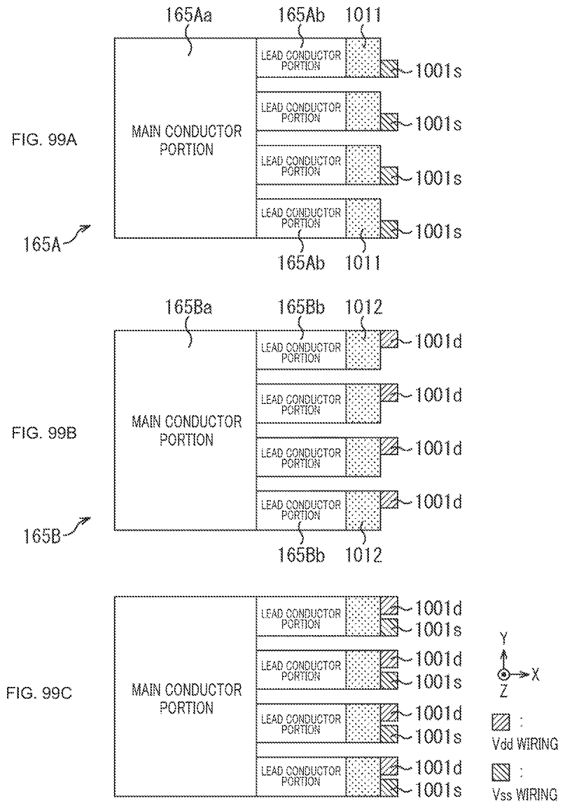

FIG. 99 illustrates a tenth arrangement example of pads.

A of FIG. 99 is a plan view illustrating an arrangement example of the conductor layer A (wiring layer 165A) and the pads 1001s connected thereto.

B of FIG. 99 is a plan view illustrating an arrangement example of the conductor layer B (wiring layer 165B) and the pads 1001d connected thereto.

C of FIG. 99 is a plan view in a state in which the conductor layers A and B and the pads 1001s and 1001d illustrated in A and B of FIG. 99 are stacked.

In FIG. 99, the pad 1001s indicates the pad 1001 to which, for example, GND or a negative power supply (Vss) is supplied, and the pad 1001d indicates the pad 1001 to which a positive voltage is supplied.

As illustrated in A of FIG. 99, the plurality of lead conductor portions 165Ab are connected to a predetermined side of the main conductor portion 165Aa having a rectangular shape, and one pad 1001s is connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 99, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 99, in a state in which the conductor layers A and B are stacked, the arrangement of the pads 1001s and the pad 1001d is an alternate arrangement in which the pads 1001s and the pads 1001d are alternately arranged in the Y direction. In this case, since it is possible to effectively offset the magnetic fields generated from the conductor layers A and B and the induced electromotive force based on the magnetic fields, it is possible to further reduce the inductive noise. However, the pads are not arranged symmetrically in the Y direction and thus, when the pads 1001 are arranged in a wide range, that is, when the main conductor portion 165Aa or 165Ba, the lead conductor portion 165Ab or 165Bb, or the conductor 1011 or 1012 is long in a layout direction of the pads 1001 (when the conductor is longer in the Y direction than in the X direction in FIG. 99), there is a magnetic field that cannot be offset, the magnetic field is accumulated when the victim conductor loop is larger, the induced electromotive force increases, and the inductive noise may increase.

<Eleventh Arrangement Example of Pads>

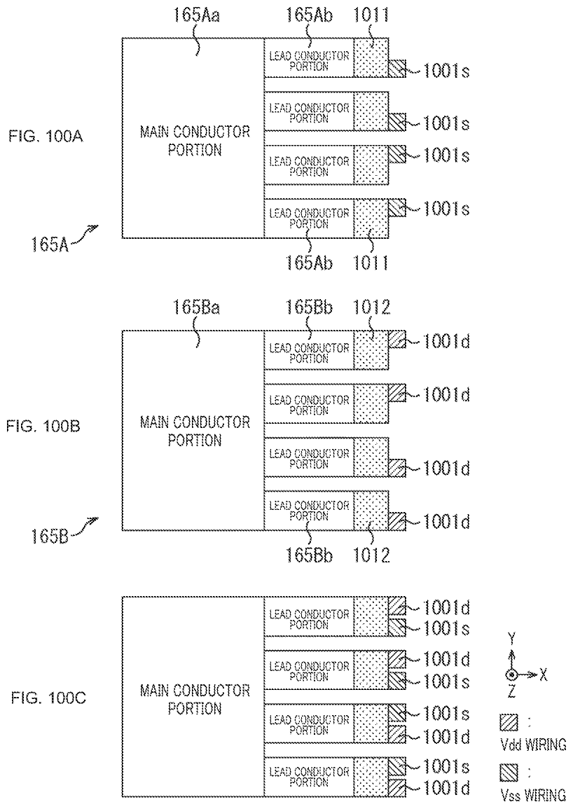

FIG. 100 illustrates an eleventh arrangement example of pads.

A of FIG. 100 is a plan view illustrating an arrangement example of the conductor layer A (wiring layer 165A) and the pads 1001s connected thereto.

B of FIG. 100 is a plan view illustrating an arrangement example of the conductor layer B (wiring layer 165B) and the pads 1001d connected thereto.

C of FIG. 100 is a plan view in a state in which the conductor layers A and B and the pads 1001s and 1001d illustrated in A and B of FIG. 100 are stacked.

In FIG. 100, the pad 1001s indicates the pad 1001 to which, for example, GND or a negative power supply (Vss) is supplied, and the pad 1001d indicates the pad 1001 to which a positive voltage is supplied.

As illustrated in A of FIG. 100, the plurality of lead conductor portions 165Ab are connected to a predetermined side of the main conductor portion 165Aa having a rectangular shape, and one pad 1001s is connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 100, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 100, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. In this case, since magnetic fields generated from the respective conductor layers A and B and the induced electromotive force based on the magnetic fields can be more effectively offset, it is possible to further reduce the inductive noise depending on a layout other than the pads, as compared with the alternate arrangement illustrated in FIG. 99.

<Twelfth Arrangement Example of Pads>

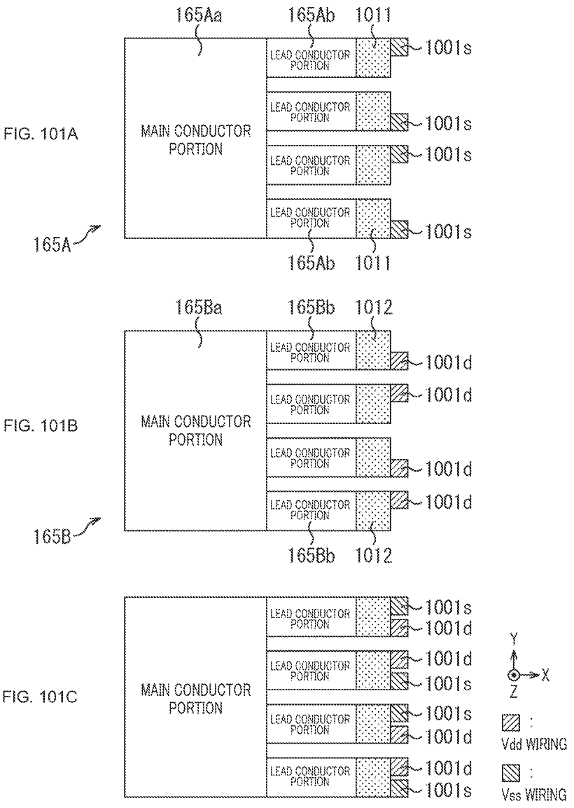

FIG. 101 illustrates a twelfth arrangement example of pads.

A of FIG. 101 is a plan view illustrating an arrangement example of the conductor layer A (wiring layer 165A) and the pads 1001s connected thereto.

B of FIG. 101 is a plan view illustrating an arrangement example of the conductor layer B (wiring layer 165B) and the pads 1001d connected thereto.

C of FIG. 101 is a plan view in a state in which the conductor layers A and B and the pads 1001s and 1001d illustrated in A and B of FIG. 101 are stacked.

In FIG. 101, the pad 1001s indicates the pad 1001 to which, for example, GND or a negative power supply (Vss) is supplied, and the pad 1001d indicates the pad 1001 to which a positive voltage is supplied.

As illustrated in A of FIG. 101, the plurality of lead conductor portions 165Ab are connected to a predetermined side of the main conductor portion 165Aa having a rectangular shape, and one pad 1001s is connected to the outer peripheral portion of each lead conductor portion 165Ab at predetermined intervals via the conductor 1011 having a shape arbitrarily including a predetermined repetitive pattern. The conductor 1011 may be omitted or may be provided. The conductor 1011 may be located between the main conductor portion 165Aa and the lead conductor portion 165Ab.

As illustrated in B of FIG. 101, the plurality of lead conductor portions 165Bb are connected to a predetermined side of the main conductor portion 165Ba having a rectangular shape, and one pad 1001d is connected to the outer peripheral portion of each lead conductor portion 165Bb at predetermined intervals via the conductor 1012 having a shape arbitrarily including a predetermined repetitive pattern. The conductor 1012 may be omitted or may be provided. The conductor 1012 may be located between the main conductor portion 165Ba and the lead conductor portion 165Bb.

As illustrated in C of FIG. 101, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. Further, the four pads 1001s and the pads 1001d forming one set also have a mirror-symmetrical arrangement in which two pads 1001 on one side are folded back in the Y direction and arranged with reference to a center line in the Y direction. In the case of such a two-stage configuration of the mirror layout, since a range in which a residual magnetic field is accumulated is narrow, the induced electromotive force can be more effectively offset and it is possible to further reduce the inductive noise depending on a layout other than the pads, as compared with the mirror arrangement of a one-stage configuration illustrated in FIG. 100.

<Thirteenth Arrangement Example of Pads>

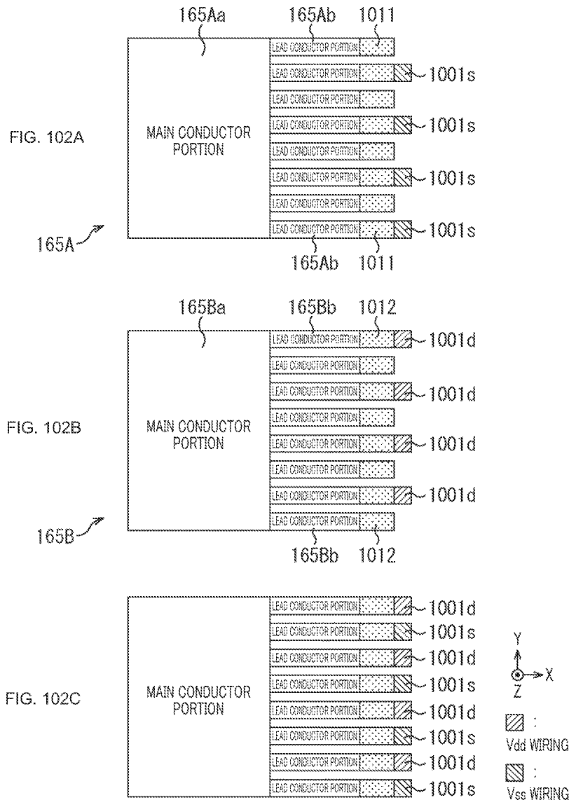

FIG. 102 illustrates a thirteenth arrangement example of pads.

A of FIG. 102 is a plan view illustrating an arrangement example of the conductor layer A (wiring layer 165A) and the pads 1001s connected thereto.

B of FIG. 102 is a plan view illustrating an arrangement example of the conductor layer B (wiring layer 165B) and the pads 1001d connected thereto.

C of FIG. 102 is a plan view in a state in which the conductor layers A and B and the pads 1001s and 1001d illustrated in A and B of FIG. 102 are stacked.

In FIG. 102, the pad 1001s indicates the pad 1001 to which, for example, GND or a negative power supply (Vss) is supplied, and the pad 1001d indicates the pad 1001 to which a positive voltage is supplied.

As illustrated in A of FIG. 102, the plurality of lead conductor portions 165Ab are connected to a predetermined side of the main conductor portion 165Aa having a rectangular shape, and the conductor 1011 having a shape arbitrarily including a predetermined repetitive pattern is connected to the outer peripheral portion of each lead conductor portion 165Ab. Further, one pad 1001s is connected to some of the plurality of lead conductor portions 165Ab via the conductor 1011. The conductor 1011 may be omitted or may be provided. Further, the conductor 1011 may be located between the main conductor portion 165Aa and the lead conductor portion 165Ab.

As illustrated in B of FIG. 102, the plurality of lead conductor portions 165Bb are connected to a predetermined side of the main conductor portion 165Ba having a rectangular shape, and the conductor 1012 having a shape arbitrarily including a predetermined repetitive pattern is connected to the outer peripheral portion of each lead conductor portion 165Bb. Further, one pad 1001d is arranged in some of the plurality of lead conductor portions 165Bb via the conductor 1012. The conductor 1012 may be omitted or may be provided. Further, the conductor 1012 may be located between the main conductor portion 165Ba and the lead conductor portion 165Bb.

As illustrated in C of FIG. 102, in a state in which the conductor layers A and B are stacked, the arrangement of the pads 1001s and the pad 1001d is an alternate arrangement in which the pads 1001s and the pads 1001d are alternately arranged in the Y direction. In this case, since it is possible to effectively offset the magnetic fields generated from the conductor layers A and B and the induced electromotive force based on the magnetic fields, it is possible to further reduce the inductive noise. However, the pads are not arranged symmetrically in the Y direction and thus, when the pads 1001 are arranged in a wide range, that is, when the main conductor portion 165Aa or 165Ba, the lead conductor portion 165Ab or 165Bb, or the conductor 1011 or 1012 is long in a layout direction of the pads 1001 (when the conductor is longer in the Y direction than in the X direction in FIG. 102), there is a magnetic field that cannot be offset, the magnetic field is accumulated when the victim conductor loop is larger, the induced electromotive force increases, and the inductive noise may increase.

<Fourteenth Arrangement Example of Pads>

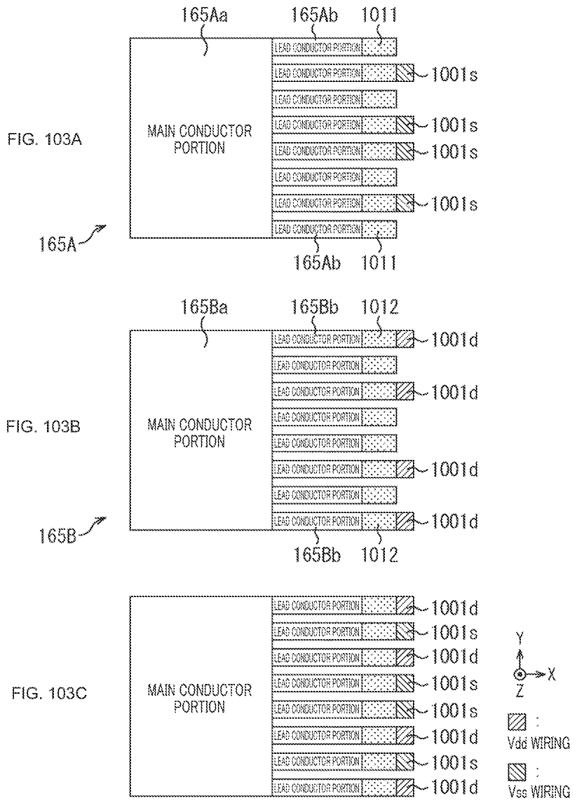

FIG. 103 illustrates a fourteenth arrangement example of pads.

A of FIG. 103 is a plan view illustrating an arrangement example of the conductor layer A (wiring layer 165A) and the pads 1001s connected thereto.

B of FIG. 103 is a plan view illustrating an arrangement example of the conductor layer B (wiring layer 165B) and the pads 1001d connected thereto.

C of FIG. 103 is a plan view in a state in which the conductor layers A and B and the pads 1001s and 1001d illustrated in A and B of FIG. 103 are stacked.

In FIG. 103, the pad 1001s indicates the pad 1001 to which, for example, GND or a negative power supply (Vss) is supplied, and the pad 1001d indicates the pad 1001 to which a positive voltage is supplied.

As illustrated in A of FIG. 103, the plurality of lead conductor portions 165Ab are connected to a predetermined side of the main conductor portion 165Aa having a rectangular shape, and the conductor 1011 having a shape arbitrarily including a predetermined repetitive pattern is connected to the outer peripheral portion of each lead conductor portion 165Ab. Further, one pad 1001s is connected to some of the plurality of lead conductor portions 165Ab via the conductor 1011. The conductor 1011 may be omitted or may be provided. Further, the conductor 1011 may be located between the main conductor portion 165Aa and the lead conductor portion 165Ab.

As illustrated in B of FIG. 103, the plurality of lead conductor portions 165Bb are connected to a predetermined side of the main conductor portion 165Ba having a rectangular shape, and the conductor 1012 having a shape arbitrarily including a predetermined repetitive pattern is connected to the outer peripheral portion of each lead conductor portion 165Bb. Further, one pad 1001d is arranged in some of the plurality of lead conductor portions 165Bb via the conductor 1012. The conductor 1012 may be omitted or may be provided. Further, the conductor 1012 may be located between the main conductor portion 165Ba and the lead conductor portion 165Bb.

As illustrated in C of FIG. 103, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. In this case, since magnetic fields generated from the respective conductor layers A and B and the induced electromotive force based on the magnetic fields can be more effectively offset, it is possible to further reduce the inductive noise depending on a layout other than the pads, as compared with the alternate arrangement illustrated in FIG. 102.

<Fifteenth Arrangement Example of Pads>

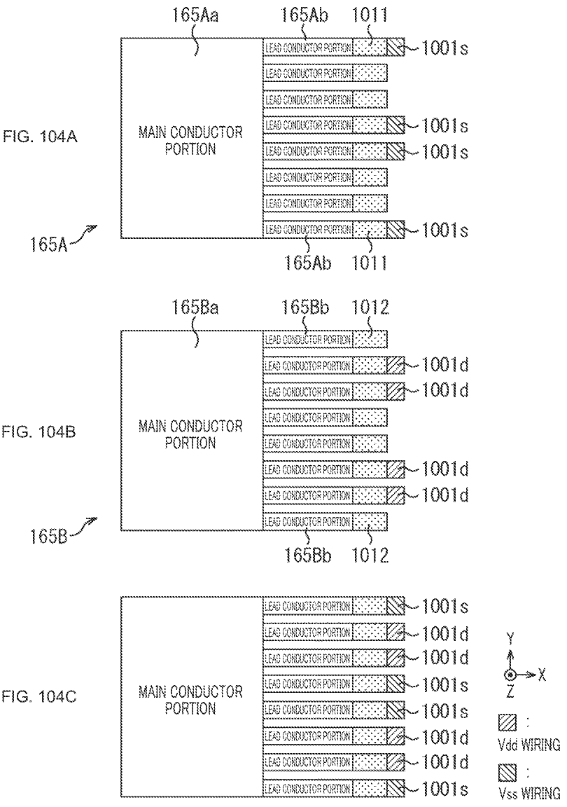

FIG. 104 illustrates a fifteenth arrangement example of pads.

A of FIG. 104 is a plan view illustrating an arrangement example of the conductor layer A (wiring layer 165A) and the pads 1001s connected thereto.

B of FIG. 104 is a plan view illustrating an arrangement example of the conductor layer B (wiring layer 165B) and the pads 1001d connected thereto.

C of FIG. 104 is a plan view in a state in which the conductor layers A and B and the pads 1001s and 1001d illustrated in A and B of FIG. 104 are stacked.

In FIG. 104, the pad 1001s indicates the pad 1001 to which, for example, GND or a negative power supply (Vss) is supplied, and the pad 1001d indicates the pad 1001 to which a positive voltage is supplied.

As illustrated in A of FIG. 104, the plurality of lead conductor portions 165Ab are connected to a predetermined side of the main conductor portion 165Aa having a rectangular shape, and the conductor 1011 having a shape arbitrarily including a predetermined repetitive pattern is connected to the outer peripheral portion of each lead conductor portion 165Ab. Further, one pad 1001s is connected to some of the plurality of lead conductor portions 165Ab via the conductor 1011. The conductor 1011 may be omitted or may be provided. Further, the conductor 1011 may be located between the main conductor portion 165Aa and the lead conductor portion 165Ab.

As illustrated in B of FIG. 104, the plurality of lead conductor portions 165Bb are connected to a predetermined side of the main conductor portion 165Ba having a rectangular shape, and the conductor 1012 having a shape arbitrarily including a predetermined repetitive pattern is connected to the outer peripheral portion of each lead conductor portion 165Bb. Further, one pad 1001d is arranged in some of the plurality of lead conductor portions 165Bb via the conductor 1012. The conductor 1012 may be omitted or may be provided. Further, the conductor 1012 may be located between the main conductor portion 165Ba and the lead conductor portion 165Bb.

As illustrated in C of FIG. 104, in a state in which the conductor layer A and the conductor layer B are overlapped, the arrangement of the pads 1001s and 1001d is a mirror-symmetrical arrangement in which four pads 1001s and 1001d continuous in the Y direction are set as one set, and one set of pads 1001 is folded back in the Y direction and sequentially arranged. Further, the four pads 1001s and the pads 1001d forming one set also have a mirror-symmetrical arrangement in which two pads 1001 on one side are folded back in the Y direction and arranged with reference to a center line in the Y direction. In the case of such a two-stage configuration of the mirror layout, since a range in which a residual magnetic field is accumulated is narrow, the induced electromotive force can be more effectively offset and it is possible to further reduce the inductive noise depending on a layout other than the pads, as compared with the mirror arrangement of a one-stage configuration illustrated in FIG. 103.

In pad arrangement example described with reference to FIGS. 93 to 104, the example in which a total number of pads connected to a predetermined side of the main conductor portion 165a of the conductor layers A and B is eight, and the arrangement of the eight pads 1001 continuous in the Y direction are the alternate arrangement, the mirror arrangement of a one-stage configuration, and the mirror arrangement of a two-stage configuration has been described, the arrangement may be the alternate arrangement, the mirror arrangement of a one-stage configuration, and the mirror arrangement of a two-stage configuration with the total number of pads other than eight. The number of pads in one set in the alternate arrangement or the mirror arrangement is not limited to the above-described two or four, but is arbitrary.

Further, the number of pads connected to one lead conductor portion 165b is not limited to one or two illustrated in FIGS. 93 to 104, and may be three or more.

Further, an example in which the plurality of pads 1001 are connected to only one predetermined side of the main conductor portions 165a of the conductor layers A and B having a rectangular shape is illustrated for simplicity in FIGS. 93 to 104, the plurality of pads 1001 may be connected to one side other than the side illustrated in FIGS. 93 to 104, or may be connected to any two sides, three sides, or four sides.

The case in which the total number of pads is 8 has been described as an example, but the number is not limited thereto. The number of pads may be increased, or the number of pads may be decreased.

Some or all of the respective components shown as a pad arrangement example may be omitted, some or all thereof may be changed, some or all thereof may be modified, some or all thereof may be replaced with other components, and other components may be added to some or all thereof. Further, some or all thereof the respective components shown as a pad arrangement example may be divided into a plurality of parts or may be separated into a plurality of parts, and functions or characteristics may differ in at least some of the plurality of divided or separated components. Further, at least some of the respective components shown as a pad arrangement example may be arbitrarily combined for a different pad layout. Further, at least some of the respective components shown as a pad arrangement example may be moved for a different pad layout. Further, a coupling element or a relay element may be added to a combination of at least some of the respective components shown as a pad arrangement example, for a different pad layout. Further, a switching element or a switching function may be added to a combination of at least some of the respective components shown as a pad arrangement example, for a different pad layout.

<Sixteenth Arrangement Example of Pads>

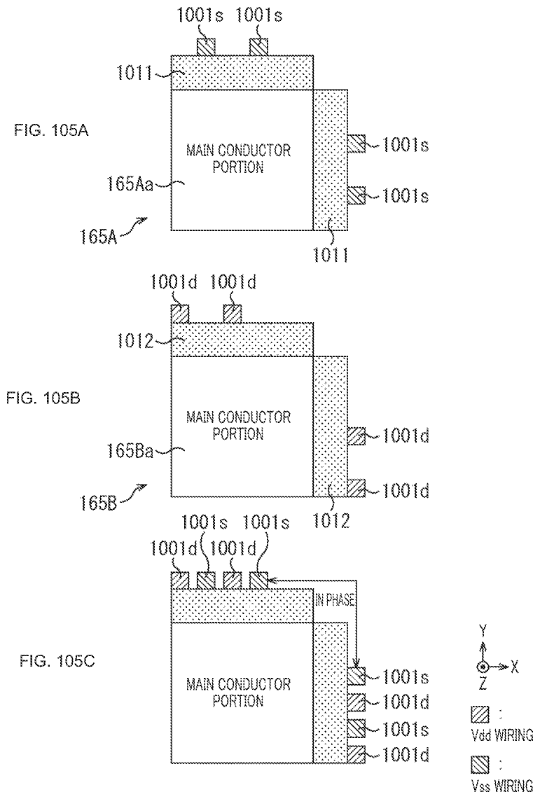

Next, an example of orthogonal pad layout when a plurality of pads 1001 are arranged on two adjacent sides of the main conductor portion 165a having a rectangular shape of the conductor layers A and B will be described with reference to FIGS. 105 to 108.

FIG. 105 illustrates a sixteenth arrangement example of the pads.

A of FIG. 105 is a plan view illustrating an arrangement example of the conductor layer A (wiring layer 165A) and the pads 1001s connected thereto.

B of FIG. 105 is a plan view illustrating an arrangement example of the conductor layer B (wiring layer 165B) and the pads 1001d connected thereto.

C of FIG. 105 is a plan view in a state in which the conductor layers A and B and the pads 1001s and 1001d illustrated in A and B of FIG. 105 are stacked.

In FIG. 105, the pad 1001s indicates the pad 1001 to which, for example, GND or a negative power supply (Vss) is supplied, and the pad 1001d indicates the pad 1001 to which a positive voltage is supplied.

As illustrated in A of FIG. 105, the plurality of pads 1001s are connected to two adjacent sides of the main conductor portion 165Aa having a rectangular shape at predetermined intervals via the conductor 1011 arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 105, the plurality of pads 1001d are connected to two adjacent sides of the main conductor portion 165Ba having a rectangular shape at predetermined intervals via the conductor 1012 arbitrarily including a predetermined repetitive pattern. Each pads 1001d may be formed of a lead conductor portion 165Bb, or the conductor 1012 may be formed of a lead conductor portion 165Bb. When the pad 1001d is the lead conductor portion 165Bb, the conductor 1012 may be omitted or may be provided.

As illustrated in C of FIG. 105, in a state in which the conductor layers A and B are stacked, the arrangement of the pads 1001s and the pad 1001d is the alternate arrangement in which the pads 1001s and the pads 1001d are alternately arranged on two adjacent sides of the main conductor portion 165a having a rectangular shape. Further, all polarities of the pads 1001 in the end portion of each side among the pads 1001s and the pads 1001d on the two sides that are alternately arranged are the pad 1001s connected to the GND or the negative power supply. Thus, among the plurality of pads 1001 on the two sides in which the pads 1001s and the pads 1001d are alternately arranged, the polarities of the pads 1001 at an end portion closest to a corner portion of the substrate 1000 are the same, and are the pads 1001s that are polarities of the side having high ESD (electrostatic discharge) resistance, such that the ESD resistance can be increased.

In consideration of the ESD resistance, it is preferable for the polarities of the pads 1001 at the end portion of the two sides in which the pad 1001s and the pads 1001d are alternately arranged to be, for example, the pads 1001s connected to the GND or the negative power supply, but the polarities may be, for example, the pads 1001d connected to the positive power supply.

<Seventeenth Arrangement Example of Pads>

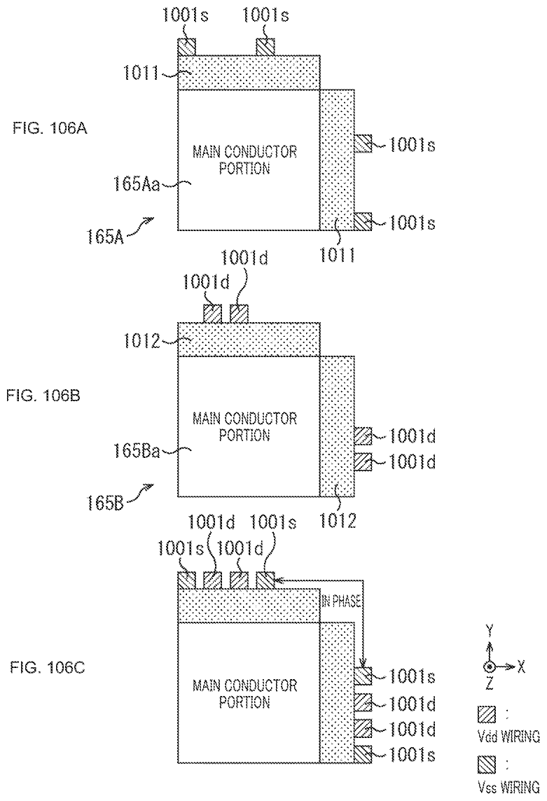

FIG. 106 illustrates a seventeenth arrangement example of pads.

A of FIG. 106 is a plan view illustrating an arrangement example of the conductor layer A (wiring layer 165A) and the pads 1001s connected thereto.

B of FIG. 106 is a plan view illustrating an arrangement example of the conductor layer B (wiring layer 165B) and the pads 1001d connected thereto.

C of FIG. 106 is a plan view in a state in which the conductor layers A and B and the pads 1001s and 1001d illustrated in A and B of FIG. 106 are stacked.

In FIG. 106, the pad 1001s indicates the pad 1001 to which, for example, GND or a negative power supply (Vss) is supplied, and the pad 1001d indicates the pad 1001 to which a positive voltage is supplied.

As illustrated in A of FIG. 106, the plurality of pads 1001s are connected to two adjacent sides of the main conductor portion 165Aa having a rectangular shape at predetermined intervals via the conductor 1011 arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 106, the plurality of pads 1001d are connected to two adjacent sides of the main conductor portion 165Ba having a rectangular shape at predetermined intervals via the conductor 1012 arbitrarily including a predetermined repetitive pattern. Each pads 1001d may be formed of a lead conductor portion 165Bb, or the conductor 1012 may be formed of a lead conductor portion 165Bb. When the pad 1001d is the lead conductor portion 165Bb, the conductor 1012 may be omitted or may be provided.

As illustrated in C of FIG. 106, in a state in which the conductor layers A and B are stacked, the arrangement is a mirror-symmetrical arrangement in which four continuous pads 1001s and 1001d are set as one set, and one set of pads 1001 are folded back in the Y direction and sequentially arranged, as in the pad arrangement example illustrated in C of FIG. 95. Further, all polarities of the pads 1001 in an end portion of each side among the pads 1001s and the pads 1001d on the two sides that are arranged in mirror symmetry are the pad 1001s connected to the GND or the negative power supply. Thus, among the plurality of pads 1001 on the two sides in which the pads 1001s and the pads 1001d are arranged in mirror symmetry, the polarities of the pads 1001 at an end portion closest to a corner portion of the substrate 1000 have the same phase, and are the pads 1001s that are polarities of the side having high electrostatic discharge (ESD) resistance, such that the ESD resistance can be increased. Further, by arranging the pads in mirror symmetry, an impedance difference and a current difference becomes small between the Vss wiring and the Vdd wiring becomes small and thus, it is possible to further reduce the inductive noise, as compared with the sixteenth arrangement example of FIG. 105.

In consideration of the ESD resistance, it is preferable for the polarities of the pads 1001 at the end portion of the two sides in which the pad 1001s and the pads 1001d are arranged in mirror symmetry to be, for example, the pads 1001s connected to the GND or the negative power supply, but the polarities may be, for example, the pads 1001d connected to the positive power supply.

<Eighteenth Arrangement Example of Pads>

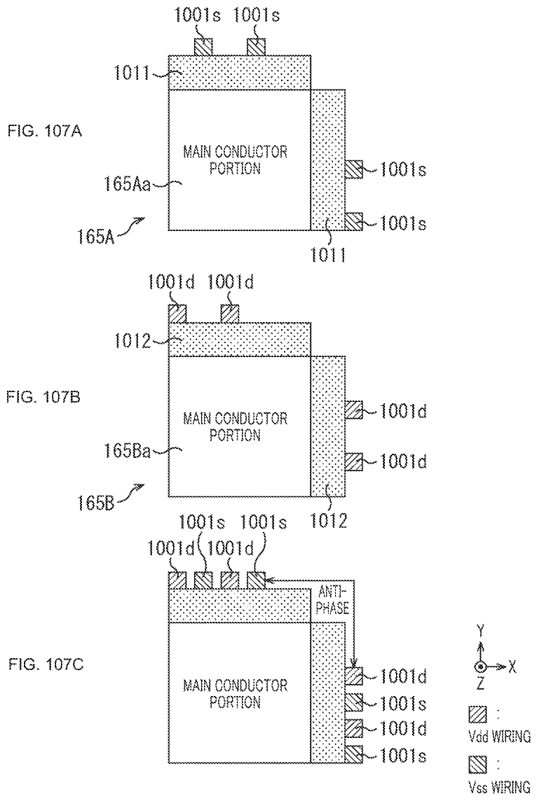

FIG. 107 illustrates an eighteenth arrangement example of pads.

A of FIG. 107 is a plan view illustrating an arrangement example of the conductor layer A (wiring layer 165A) and the pads 1001s connected thereto.

B of FIG. 107 is a plan view illustrating an arrangement example of the conductor layer B (wiring layer 165B) and the pads 1001d connected thereto.

C of FIG. 107 is a plan view in a state in which the conductor layers A and B and the pads 1001s and 1001d illustrated in A and B of FIG. 107 are stacked.

In FIG. 107, the pad 1001s indicates the pad 1001 to which, for example, GND or a negative power supply (Vss) is supplied, and the pad 1001d indicates the pad 1001 to which a positive voltage is supplied.

As illustrated in A of FIG. 107, the plurality of pads 1001s are connected to two adjacent sides of the main conductor portion 165Aa having a rectangular shape at predetermined intervals via the conductor 1011 arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 107, the plurality of pads 1001d are connected to two adjacent sides of the main conductor portion 165Ba having a rectangular shape at predetermined intervals via the conductor 1012 arbitrarily including a predetermined repetitive pattern. Each pads 1001d may be formed of a lead conductor portion 165Bb, or the conductor 1012 may be formed of a lead conductor portion 165Bb. When the pad 1001d is the lead conductor portion 165Bb, the conductor 1012 may be omitted or may be provided.

As illustrated in C of FIG. 107, in a state in which the conductor layers A and B are stacked, the arrangement of the pads 1001s and the pad 1001d is the alternate arrangement in which the pads 1001s and the pads 1001d are alternately arranged, as in the pad arrangement example illustrated in FIG. 105. Here, this pad arrangement example differs from the pad arrangement example illustrated in FIG. 105 in that the polarities of the pads 1001 at the end portion of each side among the pads 1001s and the pads 1001d arranged on the two sides are opposite to those of the pads 1001s and the pads 1001d. Thus, the polarities of the pads 1001 at the end portion closest to a corner portion of the substrate 1000 among the plurality of pads 1001 on the two sides in which the pads 1001s and the pads 1001d are alternately arranged are set to be opposite, such that an impedance difference between the Vss wiring and the Vdd wiring can be further reduced and a current difference between the Vss wiring and the Vdd wiring is further reduced, and thus, it is possible to further reduce the inductive noise, as compared with the seventeenth arrangement example of FIG. 106.

<Nineteenth Arrangement Example of Pads>

FIG. 108 illustrates a nineteenth arrangement example of pads.

A of FIG. 108 is a plan view illustrating an arrangement example of the conductor layer A (wiring layer 165A) and the pads 1001s connected thereto. B of FIG. 108 is a plan view illustrating an arrangement example of the conductor layer B (wiring layer 165B) and the pads 1001d connected thereto.

C of FIG. 108 is a plan view in a state in which the conductor layers A and B and the pads 1001s and 1001d illustrated in A and B of FIG. 108 are stacked.

In FIG. 108, the pad 1001s indicates the pad 1001 to which, for example, GND or a negative power supply (Vss) is supplied, and the pad 1001d indicates the pad 1001 to which a positive voltage is supplied.

As illustrated in A of FIG. 108, the plurality of pads 1001s are connected to two adjacent sides of the main conductor portion 165Aa having a rectangular shape at predetermined intervals via the conductor 1011 arbitrarily including a predetermined repetitive pattern. Each pad 1001s may be formed of a lead conductor portion 165Ab, or the conductor 1011 may be formed of a lead conductor portion 165Ab. When the pad 1001s is the lead conductor portion 165Ab, the conductor 1011 may be omitted or may be provided.

As illustrated in B of FIG. 108, the plurality of pads 1001d are connected to two adjacent sides of the main conductor portion 165Ba having a rectangular shape at predetermined intervals via the conductor 1012 arbitrarily including a predetermined repetitive pattern. Each pads 1001d may be formed of a lead conductor portion 165Bb, or the conductor 1012 may be formed of a lead conductor portion 165Bb. When the pad 1001d is the lead conductor portion 165Bb, the conductor 1012 may be omitted or may be provided.

As illustrated in C of FIG. 108, in a state in which the conductor layers A and B are stacked, the arrangement of the pads 1001s and the pad 1001d is the mirror-symmetrical arrangement in which the pads 1001s and the pads 1001d are arranged in mirror symmetry, as in the pad arrangement example illustrated in FIG. 106. Here, this pad arrangement example differs from the pad arrangement example illustrated in FIG. 106 in that the polarities of the pads 1001 at the end portion of each side among the pads 1001s and the pads 1001d arranged on the two sides are opposite to those of the pads 1001s and the pads 1001d. Thus, the polarities of the pads 1001 at the end portion closest to a corner portion of the substrate 1000 among the plurality of pads 1001 on the two sides in which the pads 1001s and the pads 1001d are arranged in mirror symmetry are set to be opposite, such that an impedance difference between the Vss wiring and the Vdd wiring can be further reduced and a current difference between the Vss wiring and the Vdd wiring is further reduced, and thus, it is possible to further reduce the inductive noise, as compared with the seventeenth arrangement example of FIG. 106.

Although the example in which the plurality of pads 1001 are arranged at predetermined intervals on two adjacent sides of the main conductor portion 165a having a rectangular shape via the conductor 1011 or 1012 has been described in the sixteenth to nineteenth arrangement examples of the pads described with reference to FIGS. 105 to 108, the sides on which the pads 1001 are arranged are not limited to the two sides and may be three sides or four sides.

Further, although the example in which the alternate arrangement in FIG. 93 and the mirror arrangement of a two-stage configuration in FIG. 95 are adopted as forms of the pads 1001 arranged on one side has been shown in the sixteenth to nineteenth arrangement examples of the pads described with reference to FIGS. 105 to 108, the mirror arrangement of a one-stage configuration illustrated in FIG. 94 may be adopted and the polarities of the pads 1001 in the end portion closest to the corner portion may be the same or opposite.

Further, the sixteenth to nineteenth arrangement examples of the pads described with reference to FIGS. 105 to 108 have a form in which the lead conductor portion 165b is omitted, but have the configuration in which the lead conductor portion 165b is included in the side of the main conductor portion 165Aa having a rectangular shape as illustrated in FIGS. 96 to 104, whereas the alternate arrangement of FIG. 93, the mirror arrangement of a one-stage configuration of FIG. 94, or the mirror arrangement of a two-stage configuration of FIG. 95 may be adopted and the polarities of the pads 1001 at the end portion closest to the corner portion may be the same or opposite.

It is preferable for the lead conductor portions 165Ab and 165Bb and the conductors 1011 and 1012 to be configured, for example, so that GND or a negative voltage is supplied from the pad 1001s to the main conductor portion 165Aa and a positive power supply having an opposite polarity is supplied from the pads 1001d to the main conductor portion 165Ba, but the present technology is not limited thereto. In other words, it is preferable for the lead conductor portions 165Ab and 165Bb and the conductors 1011 and 1012 to be configured so that, for example, the GND or the negative power supply and the positive power supply having an opposite polarity are not completely short-circuited, which are supplied from the pad 1001, but the present technology is not limited thereto. The example in which the plurality of pads 1001s are arranged, the example in which the plurality of pads 1001d are arranged, the example in which the plurality of conductors 1011 are arranged, the example in which the plurality of conductors 1012 are arranged, the example in which the plurality of lead conductor portion 165Ab are arranged, and the example in which the plurality of lead conductor portion 165Bb are arranged, for example, are shown in at least some of FIGS. 92 to 108, in the respective figures, all the pads 1001s may be the same, all the pads 1001s may not be the same, all the pads 1001d may be the same, all the pads 1001d may not be the same, all the conductors 1011 may be the same, all the conductors 1011 may not be the same, all the conductors 1012 may be the same, all the conductors 1012 may not be the same, all the lead conductor portions 165Ab may be the same, all the lead conductor portions 165Ab may not be the same, all the lead conductor portions 165Bb may be the same, or all the lead conductor portions 165Bb may not be the same. It is preferable for at least one of a total number of pads 1001s directly or indirectly connected to the main conductor portion 165a in the substrate 1000 being the same or substantially the same as a total number of pads 1001d, a total number of pads 1001s directly or indirectly connected to the main conductor portion 165a in two predetermined adjacent sides of the substrate 1000 being the same or substantially the same as a total number of pads 1001d, a total number of pads 1001s directly or indirectly connected to the main conductor portion 165a in two predetermined opposing sides of the substrate 1000 being the same or substantially the same as a total number of pads 1001d, a total number of pads 1001s directly or indirectly connected to at least main conductor portion 165a in one predetermined side of the substrate 1000 being the same or substantially the same as a total number of pads 1001d, a total number of pads 1001s directly or indirectly connected to at least two lead conductor portions 165b in two predetermined adjacent sides of the substrate 1000 being the same or substantially the same as a total number of pads 1001d, a total number of pads 1001s directly or indirectly connected to at least two lead conductor portions 165b in two predetermined opposing sides of the substrate 1000 being the same or substantially the same as a total number of pads 1001d, a total number of pads 1001s directly or indirectly connected to at least one lead conductor portion 165b in one predetermined side of the substrate 1000 being the same or substantially the same as a total number of pads 1001d, a total number of pads 1001s directly or indirectly connected to at least two sets of conductors 1011 and 1012 in two predetermined adjacent sides of the substrate 1000 being the same or substantially the same as a total number of pads 1001d, a total number of pads 1001s directly or indirectly connected to at least two sets of conductors 1011 and 1012 in two predetermined opposing sides of the substrate 1000 being the same or substantially the same as a total number of pads 1001d, and a total number of pads 1001s directly or indirectly connected to at least one set of conductors 1011 and 1012 in one predetermined side of the substrate 1000 being the same or substantially the same as a total number of pads 1001d to be satisfied, but the present technology is not limited thereto. For example, the total number of pads 1001s may not be the same as the total number of pads 1001d, and the total number of pads 1001s may not be substantially the same as the total number of pads 1001d.

<Example of Substrate Arrangement of Victim Conductor Loop and Aggressor Conductor Loop>

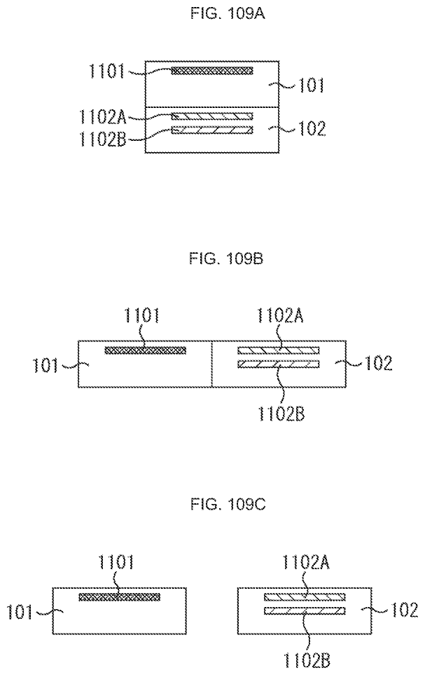

FIG. 109 illustrates an example of substrate arrangement of a victim conductor loop and an aggressor conductor loop.

A of FIG. 109 is a cross-sectional view schematically illustrating a substrate arrangement example of the victim conductor loop and the aggressor conductor loop described above.

In each of the configuration examples described above, the structure in which the victim conductor loop 1101 is included in the first semiconductor substrate 101, the aggressor conductor loops 1102A and 1102B are included in the second semiconductor substrate 102, and the first semiconductor substrate 101 and the second semiconductor substrate 102 are stacked, as illustrated in A of FIG. 109, has been described.

However, the structure may be a structure in which the first semiconductor substrate 101 and the second semiconductor substrate 102 are not stacked and the first semiconductor substrate 101 and the second semiconductor substrate 102 are arranged to be adjacent to each other as illustrated in B of FIG. 109, or the first semiconductor substrate 101 and the second semiconductor substrate 102 may be arranged on a single plane at a predetermined interval as illustrated in C of FIG. 109.

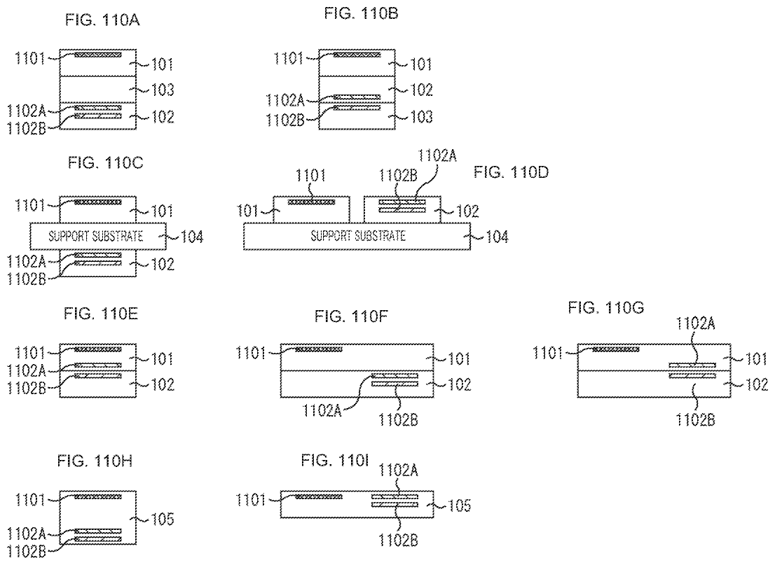

Further, for the substrate arrangement of the victim conductor loop and the aggressor conductor loop, various arrangement configurations as illustrated in A to I of FIG. 110 can be adopted.

A of FIG. 110 illustrates a structure in which the victim conductor loop 1101 is included in the first semiconductor substrate 101, the aggressor conductor loops 1102A and 1102B are included in the second semiconductor substrate 102, a third semiconductor substrate 103 is inserted between the first semiconductor substrate 101 and the second semiconductor substrate 102, and the first semiconductor substrate 101 to the third semiconductor substrate 103 are stacked.

B of FIG. 110 illustrates a structure in which the victim conductor loop 1101 is included in the first semiconductor substrate 101, the aggressor conductor loop 1102A is included in the second semiconductor substrate 102, the aggressor conductor loop 1102B is included in the third semiconductor substrate 103, and the first semiconductor substrate 101 to the third semiconductor substrate 103 are stacked in this order.

C of FIG. 110 illustrates a structure in which the victim conductor loop 1101 is included in the first semiconductor substrate 101, the aggressor conductor loops 1102A and 1102B are included in the second semiconductor substrate 102, a support substrate 104 is inserted the first semiconductor substrate 101 and the second semiconductor substrate 102, and the first semiconductor substrate 101, the support substrate 104, and the second semiconductor substrate 102 are stacked in this order. The support substrate 104 may be omitted, and the first semiconductor substrate 101 and the second semiconductor substrate 102 may be arranged with a predetermined gap.

D of FIG. 110 illustrates a structure in which the victim conductor loop 1101 is included in the first semiconductor substrate 101, the aggressor conductor loops 1102A and 1102B are included in the second semiconductor substrate 102, and the first semiconductor substrate 101 and the second semiconductor substrate 102 are placed on the support substrate 104 and arranged on a single plane with a predetermined gap. The support substrate 104 may be omitted, and the first semiconductor substrate 101 and the second semiconductor substrate 102 may be supported to be arranged on a single plane at different positions.

E of FIG. 110 illustrates a structure in which the victim conductor loop 1101 and the aggressor conductor loop 1102A are included in the first semiconductor substrate 101, the aggressor conductor loop 1102B is included in the second semiconductor substrate 102, and the first semiconductor substrate 101 and the second semiconductor substrate 102 are stacked. Here, a region on the XY plane in which the victim conductor loop 1101 in the first semiconductor substrate 101 has been formed, at least partially, overlaps a region on the XY plane in which the aggressor conductor loops 1102A and 1102B in the second semiconductor substrate 102 have been formed.

F of FIG. 110 illustrates a structure in which the victim conductor loop 1101 is included in the first semiconductor substrate 101, the aggressor conductor loops 1102A and 1102B are included in the second semiconductor substrate 102, and the first semiconductor substrate 101 and the second semiconductor substrate 102 are stacked. Here, the region on the XY plane in which the victim conductor loop 1101 in the first semiconductor substrate 101 has been formed may completely differ from or may at least partially overlap the region on the XY plane in which the aggressor conductor loops 1102A and 1102B in the second semiconductor substrate 102 have been formed.

G of FIG. 110 illustrates a structure in which the victim conductor loop 1101 and the aggressor conductor loop 1102A are included in the first semiconductor substrate 101, the aggressor conductor loop 1102B is included in the second semiconductor substrate 102, and the first semiconductor substrate 101 and the second semiconductor substrate 102 are stacked. Here, the region on the XY plane in which the victim conductor loop 1101 in the first semiconductor substrate 101 has been formed may completely differ from the region on the XY plane in which the aggressor conductor loops 1102A and 1102B have been formed.

H of FIG. 110 illustrates a structure in which the victim conductor loop 1101 and the aggressor conductor loops 1102A and 1102B are included in one semiconductor substrate 105. Here, the region on the XY plane in which the victim conductor loop 1101 has been formed in the one semiconductor substrate 105 may at least partially overlap the region on the XY plane in which the aggressor conductor loops 1102A and 1102B have been formed.

I of FIG. 110 illustrates a structure in which the victim conductor loop 1101 and the aggressor conductor loops 1102A and 1102B are included in one semiconductor substrate 105. Here, the region on the XY plane in which the victim conductor loop 1101 has been formed in the one semiconductor substrate 105 may differ from the region on the XY plane in which the aggressor conductor loops 1102A and 1102B have been formed.

A stacking order of the respective substrates illustrated in A to I of FIG. 110 may be reversed and positions of the victim conductor loop 1101 and the aggressor conductor loops 1102A and 1102B may be reversed upside down.

As described above, the number and arrangement of semiconductor substrates in which the victim conductor loop 1101 and the aggressor conductor loops 1102A and 1102B are included, and the presence/absence of the support substrate can take various structures.

The aggressor conductor loop that generates the magnetic flux passing through the loop surface of the victim conductor loop may or may not overlap the victim conductor loop. Further, the aggressor conductor loop may be formed on a plurality of semiconductor substrates stacked on a semiconductor substrate on which the victim conductor loop is formed, or may be formed on the same semiconductor substrate as the semiconductor substrate on which the victim conductor loop is formed.

Further, the aggressor conductor loop may be formed on various substrates, such as a printed circuit board, a flexible printed circuit board, an interposer substrate, a package substrate, an inorganic substrate, or an organic substrate, instead of a semiconductor substrate, but may be formed on any substrate that includes a conductor or on which a conductor loop can be formed, and the aggressor conductor may be present in a circuit other than the semiconductor substrate, such as a package in which the semiconductor substrate is sealed. Generally, a distance of the aggressor conductor loop from the victim conductor loop becomes shorter in order of a case in which the aggressor conductor loop is formed on the semiconductor substrate, a case in which the aggressor conductor loop is formed on the package, and a case in which the aggressor conductor loop is formed on a printed circuit board. Since it becomes easy for inductive noise or capacitive noise that can occur in the victim conductor loop to increase when the distance of the aggressor conductor loop from the victim conductor loop becomes shorter, the present technology is more effective when the distance of the aggressor conductor loop from the victim conductor loop is shorter. Further, the present invention is not limited to only the substrate, but the present technology can also be applied to a conductor itself representative by a conductor wire or a conductor plate, such as a bonding wire, a lead wire, an antenna wire, a power wire, a GND wire, a coaxial wire, a dummy wire, a sheet metal.

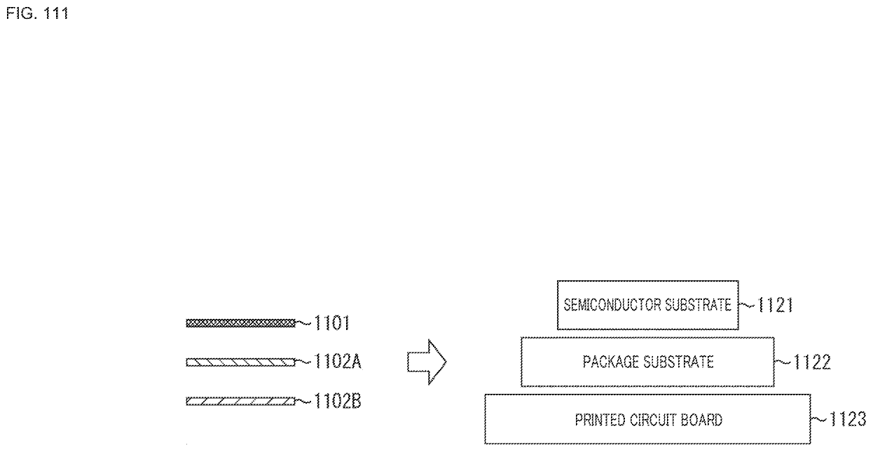

Next, an arrangement example in which a conductor 1101 that is at least a part of the victim conductor loop (hereinafter referred to as a victim conductor loop 1101) and conductors 1102A and 1102B that are at least parts of the aggressor conductor loop (hereinafter referred to as aggressor conductor loops 1102A and 1102B) in a structure in which three types of substrates including a semiconductor substrate 1121, a package substrate 1122, and a printed circuit board 1123 are stacked as illustrated in FIG. 111 will be described. Although not illustrated, the victim conductor loop or Aggressor conductor loop described above may include at least conductors arranged on two or more of the semiconductor substrate 1121, the package substrate 1122, and the printed circuit board 1123. The semiconductor substrate 1121 can be replaced with any one of a package substrate, an interposer substrate, a printed circuit board, a flexible printed circuit board, an inorganic substrate, an organic substrate, a substrate including a conductor, or a substrate on which conductors can be formed. Further, the package substrate 1122 can be replaced with any one of a semiconductor substrate, an interposer substrate, a printed circuit board, a flexible printed circuit board, an inorganic substrate, an organic substrate, a substrate including a conductor, or a substrate on which conductors can be formed. Further, the printed circuit board 1123 can be replaced with any one of a semiconductor substrate, a package substrate, an interposer substrate, a flexible printed circuit board, an inorganic substrate, an organic substrate, a substrate including a conductor, or a substrate on which conductors can be formed.

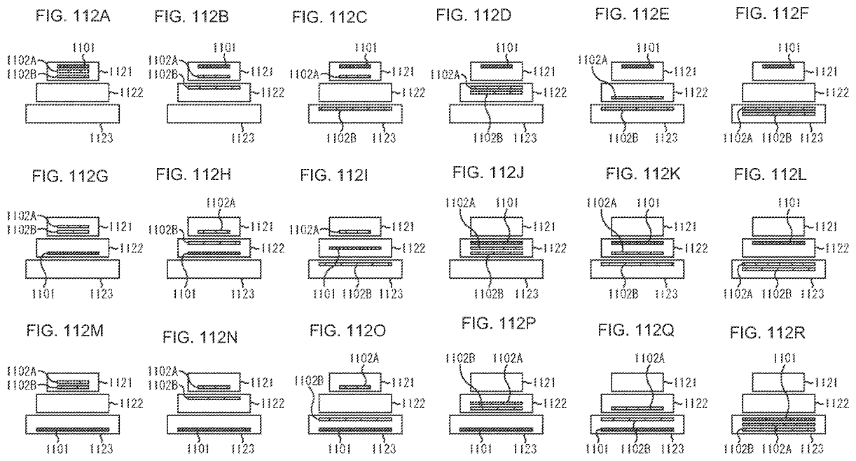

A to R of FIG. 112 illustrate examples of arrangement of victim conductor loops and aggressor conductor loops in the stacked structure in which the three types of substrates illustrated in FIG. 111 are stacked.

A of FIG. 112 illustrates a schematic diagram of a stacked structure in which the victim conductor loop 1101 and the aggressor conductor loops 1102A and 1102B are all included in the semiconductor substrate 1121. The package substrate 1122 and the printed circuit board 1123 in which neither the victim conductor loop 1101 nor the aggressor conductor loops 1102A and 1102B are formed may be omitted.

B of FIG. 112 illustrates a schematic diagram of a stacked structure in which the victim conductor loop 1101 and the aggressor conductor loop 1102A are included in the semiconductor substrate 1121, and the aggressor conductor loop 1102B is included in the package substrate 1122. The printed circuit board 1123 in which neither the victim conductor loop 1101 nor the aggressor conductor loops 1102A and 1102B are formed may be omitted.

C of FIG. 112 illustrates a schematic diagram of a stacked structure in which the victim conductor loop 1101 and the aggressor conductor loop 1102A are included in the semiconductor substrate 1121, and the aggressor conductor loop 1102B is included in the printed circuit board 1123. The package substrate 1122 in which neither the victim conductor loop 1101 nor the aggressor conductor loops 1102A and 1102B are formed may be omitted.

D of FIG. 112 illustrates a schematic diagram of a stacked structure in which the victim conductor loop 1101 is included in the semiconductor substrate 1121 and the aggressor conductor loops 1102A and 1102B are included in the package substrate 1122. The printed circuit board 1123 in which neither the victim conductor loop 1101 nor the aggressor conductor loops 1102A and 1102B are formed may be omitted.

E of FIG. 112 illustrates a schematic diagram of a stacked structure in which the victim conductor loop 1101 is included in the semiconductor substrate 1121, the aggressor conductor loop 1102A is included in the package substrate 1122, and the aggressor conductor loop 1102B is included in the printed circuit board 1123.

F of FIG. 112 illustrates a schematic diagram of a stacked structure in which the victim conductor loop 1101 is included in the semiconductor substrate 1121 and the aggressor conductor loops 1102A and 1102B are included in the printed circuit board 1123. The package substrate 1122 in which neither the victim conductor loop 1101 nor the aggressor conductor loops 1102A and 1102B are formed may be omitted.

G of FIG. 112 illustrates a schematic diagram of a stacked structure in which the aggressor conductor loops 1102A and 1102B are included in the semiconductor substrate 1121 and the victim conductor loop 1101 is included in the package substrate 1122. The printed circuit board 1123 in which neither the victim conductor loop 1101 nor the aggressor conductor loops 1102A and 1102B are formed may be omitted.

H of FIG. 112 illustrates a schematic diagram of a stacked structure in which the aggressor conductor loop 1102A is included in the semiconductor substrate 1121, and the aggressor conductor loop 1102B and the victim conductor loop 1101 are included in the package substrate 1122. The printed circuit board 1123 in which neither the victim conductor loop 1101 nor the aggressor conductor loops 1102A and 1102B are formed may be omitted.

I of FIG. 112 illustrates a schematic diagram of a stacked structure in which the aggressor conductor loop 1102A is included in the semiconductor substrate 1121, the victim conductor loop 1101 is included in the package substrate 1122, and the aggressor conductor loop 1102B is included in the printed circuit board 1123.

J of FIG. 112 illustrates a schematic diagram of a stacked structure in which all of the victim conductor loop 1101 and the aggressor conductor loops 1102A and 1102B are included in the package substrate 1122. The semiconductor substrate 1121 and the printed circuit board 1123 in which neither the victim conductor loop 1101 nor the aggressor conductor loops 1102A and 1102B are formed may be omitted.

K of FIG. 112 illustrates a schematic diagram of a stacked structure in which the victim conductor loop 1101 and the aggressor conductor loop 1102A are included in the package substrate 1122, and the aggressor conductor loop 1102B is included in the printed circuit board 1123. The semiconductor substrate 1121 in which neither the victim conductor loop 1101 nor the aggressor conductor loops 1102A and 1102B are formed may be omitted.

L in FIG. 112 illustrates a schematic diagram of a stacked structure in which the victim conductor loop 1101 is included in the package substrate 1122, and the aggressor conductor loops 1102A and 1102B are included in the printed circuit board 1123. The semiconductor substrate 1121 in which neither the victim conductor loop 1101 nor the aggressor conductor loops 1102A and 1102B are formed may be omitted.

M of FIG. 112 illustrates a schematic diagram of a stacked structure in which the aggressor conductor loops 1102A and 1102B are included in the semiconductor substrate 1121, and the victim conductor loop 1101 are included in the printed circuit board 1123. The package substrate 1122 in which neither the victim conductor loop 1101 nor the aggressor conductor loops 1102A and 1102B are formed may be omitted.

N of FIG. 112 illustrates a schematic diagram of a stacked structure in which the aggressor conductor loop 1102A is included in the semiconductor substrate 1121, the aggressor conductor loop 1102B is included in the package substrate 1122, and the victim conductor loop 1101 is included in the printed circuit board 1123.

O in FIG. 112 illustrates a schematic diagram of a stacked structure in which the aggressor conductor loop 1102A is included in the semiconductor substrate 1121, and the aggressor conductor loop 1102B and the victim conductor loop 1101 are included in the printed circuit board 1123. The package substrate 1122 in which neither the victim conductor loop 1101 nor the aggressor conductor loops 1102A and 1102B are formed may be omitted.

P in FIG. 112 illustrates a schematic diagram of a stacked structure in which the aggressor conductor loops 1102A and 1102B are included in the package substrate 1122 and the victim conductor loop 1101 is included in the printed circuit board 1123. The semiconductor substrate 1121 in which neither the victim conductor loop 1101 nor the aggressor conductor loops 1102A and 1102B are formed may be omitted.

Q of FIG. 112 illustrates a schematic diagram of a stacked structure in which the aggressor conductor loop 1102A is included in the package substrate 1122, and the aggressor conductor loop 1102B and the victim conductor loop 1101 are included in the printed circuit board 1123. The semiconductor substrate 1121 in which neither the victim conductor loop 1101 nor the aggressor conductor loops 1102A and 1102B are formed may be omitted.

R in FIG. 112 illustrates a schematic diagram of a stacked structure in which all of the victim conductor loop 1101 and the aggressor conductor loops 1102A and 1102B are included in the printed circuit board 1123. The semiconductor substrate 1121 and the package substrate 1122 in which neither the victim conductor loop 1101 nor the aggressor conductor loops 1102A and 1102B are formed may be omitted.

A stacking order of the respective substrates illustrated in A to R of FIG. 112 may be reversed and positions of the victim conductor loop 1101 and the aggressor conductor loop 1102A or the aggressor conductor loop 1102B may be reversed upside down.

As described above, the victim conductor loop 1101 and the aggressor conductor loops 1102A and 1102B can be formed in any region of the semiconductor substrate 1121, the package substrate 1122, and the printed circuit board 1123.

<Example of Package Stack of First Semiconductor Substrate 101 and Second Semiconductor Substrate 102 Forming Solid-State Imaging Device 100>

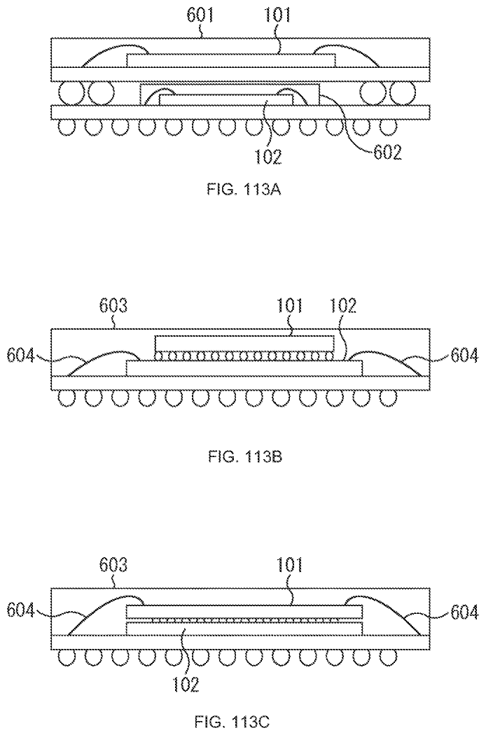

FIG. 113 is a diagram illustrating an example of package stack of the first semiconductor substrate 101 and the second semiconductor substrate 102 forming the solid-state imaging device 100.

The first semiconductor substrate 101 and the second semiconductor substrate 102 may be stacked in any way as a package.

For example, the first semiconductor substrate 101 and the second semiconductor substrate 102 are individually sealed with a sealing material, and resultant packages 601 and 602 may be stacked, as illustrated in A of FIG. 113.

Alternatively, the first semiconductor substrate 101 and the second semiconductor substrate 102 may be sealed with a sealing material in a state in which the first semiconductor substrate 101 and the second semiconductor substrate 102 are stacked, thereby forming the package 603, as illustrated in B or C of FIG. 113. In this case, the bonding wire 604 may be connected to the second semiconductor substrate 102 as illustrated in B of FIG. 113, or may be connected to the first semiconductor substrate 101 as illustrated in C of FIG. 113.

Further, the package may have any form. For example, a CSP (chip size package) or a WL-CSP (wafer level chip size package) may be used, and an interposer substrate or a rewiring layer may be used in the package. Further, any form without a package may be used. For example, a semiconductor substrate may be mounted as a chip on board (COB). For example, any one of a BGA (Ball Grid Array), a COB (Chip On Board), a COT (Chip On Tape), a CSP (Chip Size Package/Chip Scale Package), a DIMM (Dual In-line Memory Module), a DIP (Dual In-line Package), an FBGA (Fine-pitch Ball Grid Array), an FLGA (Fine-pitch Land Grid Array), an FQFP (Fine-pitch Quad Flat Package), an HSIP (Single In-line Package with Heatsink), an LCC (Leadless Chip Carrier), an LFLGA (Low profile Fine pitch Land Grid Array), an LGA (Land Grid Array), an LQFP (Low-profile Quad Flat Package), an MC-FBGA (Multi-Chip Fine-pitch Ball Grid Array), an MCM (Multi-Chip Module), an MCP (Multi-Chip Package), an M-CSP (Molded Chip Size Package), an MFP (Mini Flat Package), an MQFP (Metric Quad Flat Package), an MQUAD (Metal Quad), an MSOP (Micro Small Outline Package), a PGA (Pin Grid Array), a PLCC (Plastic Leaded Chip Carrie), a PLCC (Plastic Leadless Chip Carrie), a QFI (Quad Flat I-leaded Package), a QFJ (Quad Flat J-leaded Package), a QFN (Quad Flat non-leaded Package), a QFP (Quad Flat Package), a QTCP (Quad Tape Carrier Package), a QUIP (Quad In-line Package), an SDIP (Shrink Dual In-line Package), an SIMM (Single In-line Memory Module), an SIP (Single In-line Package), an S-MCP (Stacked Multi Chip Package), an SNB (Small Outline Non-leaded Board), an SOI (Small Outline I-leaded Package), an SOJ (Small Outline J-leaded Package), an SON (Small Outline Non-leaded Package), an SOP (Small Outline Package), an SSIP (Shrink Single In-line Package), an SSOP (Shrink Small Outline Package), an SZIP (Shrink Zigzag In-line Package), a TAB (Tape-Automated Bonding), a TCP (Tape Carrier Package), a TQFP (Thin Quad Flat Package), a TSOP (Thin Small Outline Package), a TSSOP (Thin Shrink Small Outline Package), a UCSP (Ultra Chip Scale Package), a UTSOP (Ultra Thin Small Outline Package), a VSO (Very Short Pitch Small Outline Package), a VSOP (Very Small Outline Packag), a WL-CSP (Wafer Level Chip Size Package), a ZIP (Zigzag In-line Package), and a p.MCP (Micro Multi-Chip Package) may be used.

Further, the present technology can also be applied to, for example, any one of a CCD (Charge-Coupled Device) image sensor, a CCD sensor, a CMOS sensor, a MOS sensor, an IR (Infrared) sensor, an ultraviolet (UV) sensor, a ToF (Time of Flight) sensor, and a distance measurement sensor, a circuit board, a device, and an electronic device.

Further, the present technology is suitable for a sensor, a circuit board, a device, or an electronic device in which some devices such as transistors, diodes, or antennas are arranged in an array, and is suitable for a sensor, a circuit board, a device, or an electronic device in which some devices are arranged in an array on substantially a single, but the present technology is not limited thereto.

The present technology can be applied to, for example, various memory sensors relevant to a memory device, circuit boards for a memory, memory devices, or electronic devices including a memory, various CCD sensors relevant to a CCD, circuit boards for a CCD, CCD devices, or electronic devices including a CCD, various CMOS sensors relevant to a CMOS, circuit boards for a CMOS, CMOS devices, or electronic devices including a CMOS, various MOS sensors relevant to an MOS, circuit boards for an MOS, MOS devices, or electronic devices including an MOS, various display sensors relevant to a light emitting device, circuit boards for a display, display devices, or electronic devices including a display, various laser sensors relevant to a light emitting device, circuit boards for a laser, laser devices, or electronic devices including a laser, various antenna sensors relevant to an antenna device, circuit boards for antenna, antenna devices, electronic devices including an antennas, and the like. Among these, the present technology is suitable for a sensor, a circuit board, a device, or an electronic device including a victim conductor loop with a variable loop path, a sensor, a circuit board, a device, or an electronic device including a control line or a signal line, a sensor, a circuit board, a device, or an electronic device including a horizontal control line or a vertical signal line, and the like, but the present technology is not limited thereto.

<11. Arrangement Examples of Conductive Shields>

In the above-described configuration example, although the example in which the inductive noise can be reduced by devising the configurations of the conductor layer A (wiring layer 165A) and the conductor layer B (wiring layer 165B) has been described, a configuration for further reducing the inductive noise by further providing an conductive shield will be described.

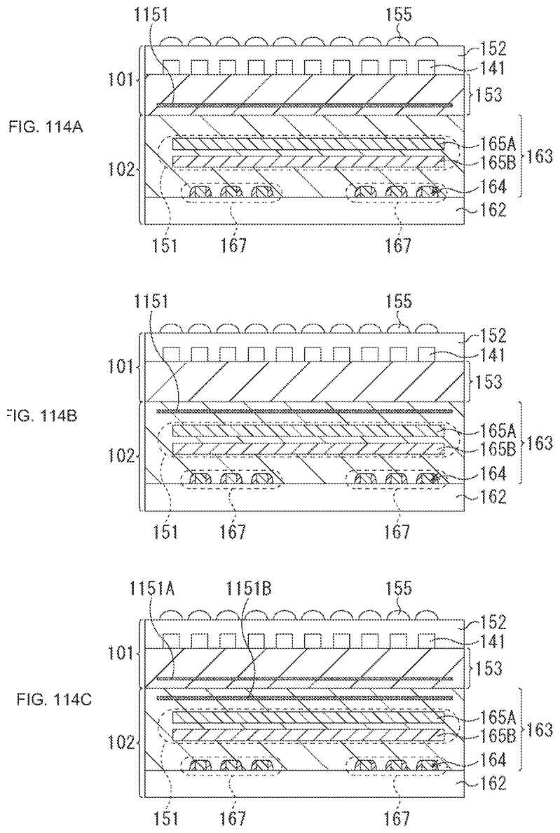

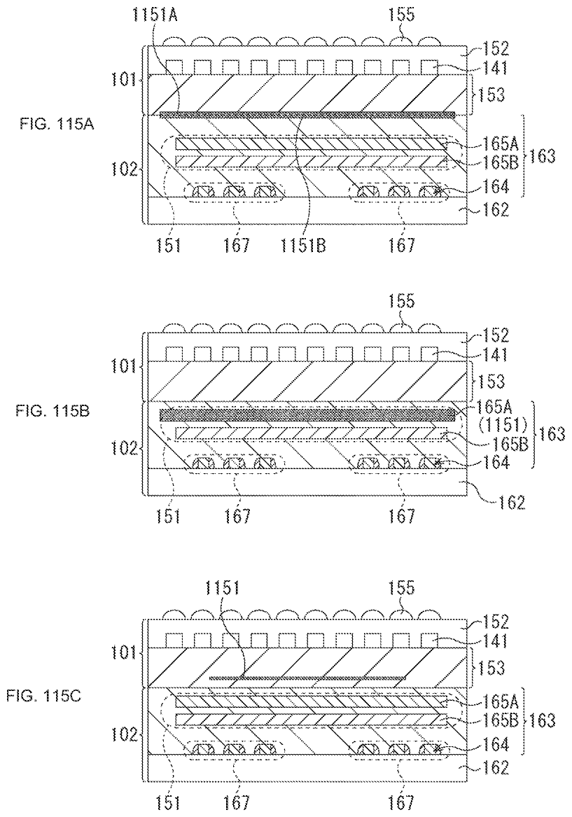

FIGS. 114 and 115 are cross-sectional views illustrating a configuration example in which a conductive shield is provided for the solid-state imaging device 100 in which the first semiconductor substrate 101 and the second semiconductor substrate 102 illustrated in FIG. 6 are stacked.

In FIGS. 114 and 115, a configuration other than the conductive shield is the same as the structure illustrated in FIG. 6 and thus, description thereof will be appropriately omitted.

A of FIG. 114 is a cross-sectional view illustrating the first configuration example in which a conductive shield is provided in the solid-state imaging device 100 illustrated in FIG. 6.

In A of FIG. 114, a conductive shield 1151 is formed in the multilayer wiring layer 153 of the first semiconductor substrate 101.

B of FIG. 114 is a cross-sectional view illustrating the second configuration example in which a conductive shield is provided in the solid-state imaging device 100 illustrated in FIG. 6.

In B of FIG. 114, the conductive shield 1151 is formed within the multilayer wiring layer 163 of the second semiconductor substrate 102.

C of FIG. 114 is a cross-sectional view illustrating the third configuration example in which a conductive shield is provided in the solid-state imaging device 100 illustrated in FIG. 6.

In C of FIG. 114, the conductive shield 1151 is formed on each of the multilayer wiring layers of the first semiconductor substrate 101 and the second semiconductor substrate 102. More specifically, a conductive shield 1151A is formed in the multilayer wiring layer 153 of the first semiconductor substrate 101, and a conductive shield 1151B is formed within the multilayer wiring layer 163 of the second semiconductor substrate 102.

A of FIG. 115 is a cross-sectional view illustrating the fourth configuration example in which a conductive shield is provided in the solid-state imaging device 100 illustrated in FIG. 6.

In A of FIG. 115, the conductive shields 1151 are formed in the respective multilayer wiring layers of the first semiconductor substrate 101 and the second semiconductor substrate 102 and bonded. More specifically, the conductive shield 1151A is formed on a bonding surface with the multilayer wiring layer 163 of the second semiconductor substrate 102 within the multilayer wiring layer 153 of the first semiconductor substrate 101, the conductive shield 1151B is formed on a bonding surface with the multilayer wiring layer 153 of the first semiconductor substrate 101 within the multilayer wiring layer 163 of the second semiconductor substrate 102, and the conductive shields 1151A and 1151B are bonded by, for example, the same type of metal bonding such as Cu—Cu bonding, Au—Au bonding, or Al—Al bonding, or different types of metal bonding such as Cu—Au bonding, Cu—Ad bonding, or Au—Al bonding.

C of FIG. 114 and A of FIG. 115 illustrate examples in which the planar regions of the conductive shields 1151A and 1151B match, but the planar regions may overlap at least partially and be bonded.

B of FIG. 115 is a cross-sectional view illustrating the fifth configuration example in which a conductive shield is provided in the solid-state imaging device 100 illustrated in FIG. 6.

In B of FIG. 115, the wiring layer 165A which is the conductor layer A also has a function of the conductive shield 1151. A part of the wiring layer 165A may be the conductive shield 1151.

C of FIG. 115 is a cross-sectional view illustrating the sixth configuration example in which a conductive shield is provided in the solid-state imaging device 100 illustrated in FIG. 6.

In the sixth configuration example in C of FIG. 115, the conductive shield 1151 is formed within the multilayer wiring layer 153 as in the first configuration example illustrated in A of FIG. 114, but a planar region in which the conductive shield 1151 is formed is smaller than the planar regions of the wiring layer 165A which is the conductor layer A and the wiring layer 165B which is the conductor layer B.

It is preferable for an area of the planar region in which the conductive shield 1151 is formed to be equal to or larger than an area of the planar region of the wiring layer 165A that is the conductor layer A and the wiring layer 165B that is the conductor layer B as in the first configuration example in A of FIG. 114, but the area of the planar region in which the conductive shield 1151 is formed may be smaller than the area of the planar region of the wiring layer 165A and the wiring layer 165B as illustrated in B of FIG. 115.

It is possible to further reduce the inductive noise by providing the conductive shield 1151 as in the first to sixth configuration examples of FIGS. 114 and 115.

In the first to sixth configuration examples of FIGS. 114 and 115, the wiring layer shielded by the conductive shield 1151 is an example of two layers including the wiring layer 165A and the wiring layer 165B, but the wiring layer may be one layer.

In the first to sixth configuration examples of FIGS. 114 and 115, a magnetic shield may be used instead of the conductive shield 1151. The magnetic shield may be conductive or may be non-conductive. When the magnetic shield is conductive, it is possible to further reduce the inductive noise and capacitive noise.

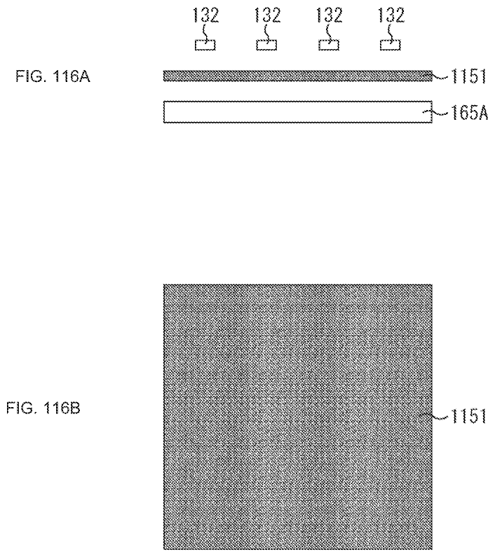

Next, an arrangement and a planar shape of the conductive shield 1151 with respect to the signal line 132 formed in the first semiconductor substrate 101 will be described with reference to FIGS. 116 to 119.

FIGS. 116 to 119 illustrates first to the fourth configuration examples of the arrangement and the planar shape of the conductive shield 1151 with respect to the signal line 132. The first to fourth configuration examples of FIGS. 116 to 119 are the same except for a planar shape of the conductive shield 1151.

A of FIG. 116 is a cross-sectional view illustrating a positional relationship in the Z direction between the signal line 132 on which an analog pixel signal is transmitted, and the conductive shield 1151 and the wiring layer 165A in the first semiconductor substrate 101. B of FIG. 116 is a plan view illustrating a planar shape of the conductive shield 1151.

The conductive shield 1151 is arranged between the signal line 132 and the wiring layer 165A, as illustrated in A of FIG. 116. The planar shape of the conductive shield 1151 can be formed as a surface shape, as illustrated in B of FIG. 116.

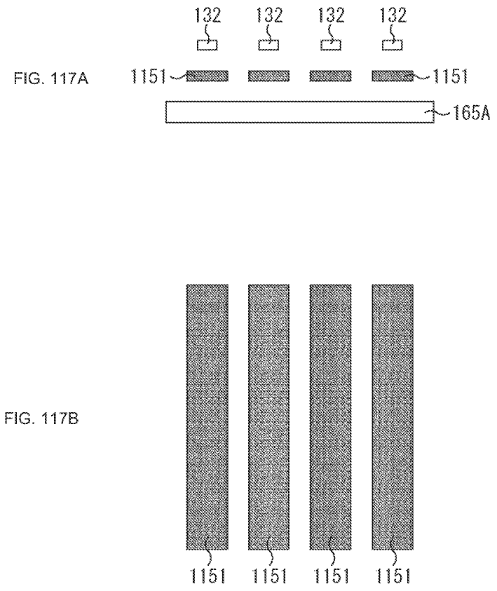

Alternatively, the planar shape of the conductive shield 1151 can be formed in a straight shape, and each straight region can be formed to overlap the signal line 132 in a one-to-one correspondence, as in the second configuration example of A and B of FIG. 117.

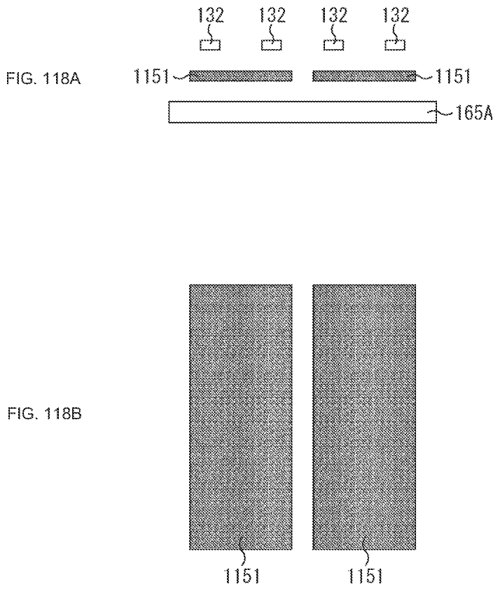

Alternatively, it is not necessary for each straight region of the conductive shield 1151 to have a one-to-one correspondence with the signal line 132 as in the second configuration example of A and B of FIG. 117, and one straight region may be formed to overlap a plurality of signal lines 132, as in the third configuration example of A and B of FIG. 118. Although FIG. 118 illustrates a planar shape in which one straight region of the conductive shield 1151 corresponds to two signal lines 132, a planar shape in which the straight region corresponds to three or more signal lines 132 may be illustrated.

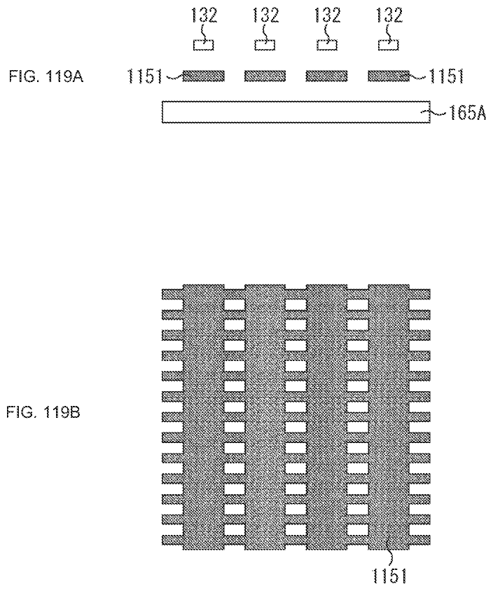

Alternatively, the planar shape of the conductive shield 1151 may not be formed in a straight shape, but may be formed in a mesh shape, as in the fourth configuration example of A and B of FIG. 119. A conductor width, gap width, and conductor period of a vertical conductor extending in a vertical direction (Y direction) of the mesh conductive shield 1151 and a horizontal conductor extending in a horizontal direction (X direction) may be different or may be the same.

Although the conductive shield 1151 has one layer in the first to fourth configuration examples of FIGS. 116 to 119, the conductive shield 1151 may have two layers as illustrated in C of FIG. 114 and A of FIG. 115. Further, the wiring layer 165A illustrated in FIGS. 116 to 119 is the same as the wiring layer 165B.

Although the conductive shield 1151 is formed at a position overlapping with the entire region of the signal line 132, the conductive shield 1151 may be formed at a position overlapping with a part of the region or formed at a position not overlapping the region. However, since noise is often propagated via the signal line, it is preferable for the conductive shield 1151 to be formed at a position overlapping with the signal line 132.

Although the position at which the conductive shield 1151 is formed with respect to the signal line 132 on which the analog pixel signal is transferred in the first semiconductor substrate 101 has been described, a signal line for transferring another signal rather than the signal line 132 for transferring the pixel signal may be used or a control line, a wiring, a conductor, or GND may be used. It is preferable for the conductive shield 1151 to be connected to GND or a negative power supply in order to efficiently reduce noise, but the conductive shield 1151 may be connected to another control line, another signal line, another conductor, or another wiring. Alternatively, the conductive shield 1151 may not be connected to another control line, another signal line, another conductor, another wiring, or the like.

It is possible to further reduce the inductive noise and capacitive noise by providing the conductive shield 1151.

<12. Configuration Examples when Conductor Layer Includes Three Layers>

<Arrangement Example when Conductor Layer Includes Three Layers>

In each of the configuration examples described above, the wiring pattern of two-layer conductor layer including the conductor layer A that is the wiring layer 165A and the conductor layer B that is the wiring layer 165B has been described.

However, a third conductor layer may be further arranged near the two-layer conductor layer including the wiring layer 165A (conductor layer A) and the wiring layer 165B (conductor layer B).

The third conductor layer can be used as, for example, a wiring for relaying GND or a negative power supply to the Vss wiring of the conductor layer A which is the wiring layer 165A, a wiring for relaying a positive power supply to the Vdd wiring of the conductor layer B which is the wiring layer 165B, or a reinforcing wiring for minimizing the voltage drop (IR-Drop) of the conductor layer A or the conductor layer B.

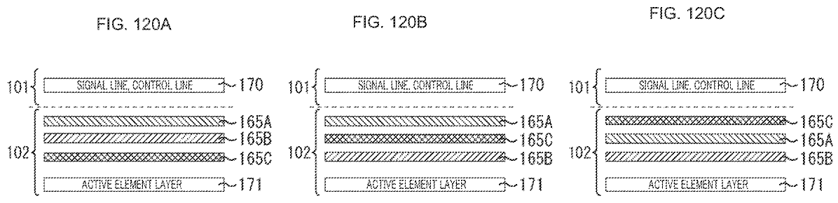

When the third conductor layer is referred to as a wiring layer 165C or a conductor layer C in correspondence with names of the wiring layer 165A and the wiring layer 165B or the conductor layers A and B in each of the configuration examples described above, the wiring layer 165C, which is the third conductor layer, is arranged with respect to the wiling layer 165A and the wiring layer 165B in the positional relationship of any one of A to C of FIG. 120.

A to C of FIG. 120 are schematic cross-sectional views illustrating an arrangement example of the wiring layer 165C with respect to the wiring layer 165A and the wiring layer 165B.

A wiring layer 170 (fourth conductor layer) including at least a part of the control line 133 that controls a transistor of the pixel 131 or at least a part of the signal line 132 that transmits a pixel signal is formed on the first semiconductor substrate 101, and an active element layer 171 including active elements such as the MOS transistor 164 is formed in the second semiconductor substrate 102. At least a part of the control line 133 or at least a part of the signal line 132 may form at least a part of the above-described victim conductor loop (the victim conductor loop 11 or the victim conductor loop 1101), but the present technology is not limited thereto. The wiring layer 165A is arranged on the wiring layer 170 side of the first semiconductor substrate 101, and the wiring layer 165B is arranged on the active element layer 171 side, as described with reference to FIG. 6 or the like.

With respect to the arrangement of the wiring layer 165A and the wiring layer 165B, the wiring layer 165C (conductor layer C) may be arranged between the wiring layer 165B and the active element layer 171 as illustrated in A of FIG. 120. In this case, the respective wiring layers are stacked in an order of the wiring layer 170, the wiring layer 165A, the wiring layer 165B, the wiring layer 165C, and the active element layer 171 from the first semiconductor substrate 101 side.

Alternatively, the wiring layer 165C (conductor layer C) may be arranged between the wiring layer 165A and the wiring layer 165B, as illustrated in B of FIG. 120. In this case, the wiring layers are stacked in an order of the wiring layer 170, the wiring layer 165A, the wiring layer 165C, the wiring layer 165B, and the active element layer 171 from the first semiconductor substrate 101 side.

Further, the wiring layer 165C (conductor layer C) may be arranged between the wiring layer 170 and the wiring layer 165A, as illustrated in C of FIG. 120. In this case, the respective wiring layers are stacked in an order of the wiring layer 170, the wiring layer 165C, the wiring layer 165A, the wiring layer 165B, and the active element layer 171 from the first semiconductor substrate 101 side.

FIG. 120 is a diagram illustrating a positional relationship between three conductor layers including the wiring layers 165A to 165C, and an arrangement of the wiring layer 170 of the first semiconductor substrate 101 or the active element layer 171 of the second semiconductor substrate 102 may be reversed. Further, the first semiconductor substrate 101 may not include either the signal line 132 or the control line 133, and even when the first semiconductor substrate 101 may include both the signal line 132 and the control line 133, at least a part of either the signal line 132 or the control line 133 may be formed in the wiring layer 170. Further, the signal line 132 or the control line 133 may be included in the second semiconductor substrate 102 rather than the first semiconductor substrate 101. Further, at least a part of the signal line 132 or the control line 133 may be included in the first semiconductor substrate 101 and the second semiconductor substrate 102, and for example, the signal line 132 or the control line 133 may be configured over at least the first semiconductor substrate 101 and the second semiconductor substrate 102. Further, at least one of the wiring layer 165A, the wiring layer 165B, and the wiring layer 165C may be provided in the second semiconductor substrate 102 instead of the first semiconductor substrate 101. Further, the wiring layer 170 of the first semiconductor substrate 101 or the active element layer 171 of the second semiconductor substrate 102 may be omitted. Further, the first semiconductor substrate 101 and the second semiconductor substrate 102 may be integrally configured as one semiconductor substrate, not as separate bodies. Further, the wiring layer 170 may be interpreted as the victim conductor loop 1101, the wiring layer 165A may be interpreted as the aggressor conductor loop 1102A, and the wiring layer 165B may be interpreted as the aggressor conductor loop 1102B, the wiring layer 165C may be arranged at any position in the substrate arrangement example illustrated in FIGS. 109 to 112, and it is preferable for the positional relationship between the three conductor layers of the wiring layers 165A to 165C to be the positional relationship illustrated in FIG. 120, but the present technology is not limited thereto.

<Problem When Conductor Layer Includes Three Layers>

In each of the configuration examples described above, in the two-layer conductor layer including the conductor layer A (wiring layer 165A) and the conductor layer B (wiring layer 165B), a wiring layout that shields the emitted hot carrier light from the active element group 167 and at least reduces the inductive noise, capacitive noise, or voltage drop has been proposed, but the inductive noise may be increased depending on a wiring layout of the third conductor layer.

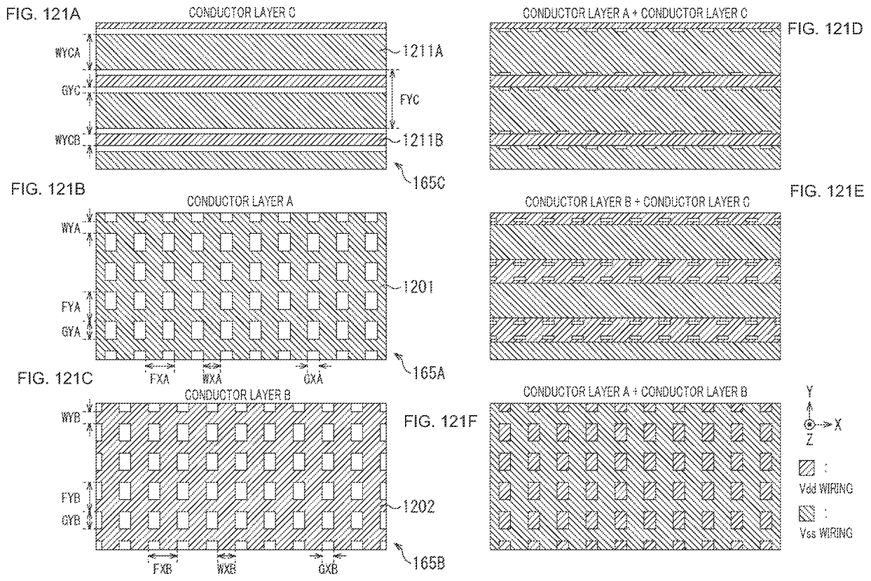

FIG. 121 is a diagram illustrating an example of the wiring pattern of the wiring layer 165C.

A of FIG. 121 illustrates the conductor layer C (wiring layer 165C), B of FIG. 121 illustrates the conductor layer A (wiring layer 165A), and C of FIG. 121 illustrates the conductor layer B (wiring layer 165B).

Further, D of FIG. 121 is a plan view in a state in which the conductor layers A and C are stacked, E of FIG. 121 is a plan view in a state in which the conductor layers B and C are stacked, and F of FIG. 121 is a plan view in a state in which the conductor layer A and the conductor layer B are stacked.

In a coordinate system in FIG. 121, a horizontal direction indicates an X-axis, a vertical direction indicates a Y-axis, and a direction orthogonal to an XY plane indicates a Z-axis.

In the conductor layer A (wiring layer 165A) and the conductor layer B (wiring layer 165B) in FIG. 121, the eleventh configuration example using mesh conductors of which a resistance values in the X direction (first direction) differs from a resistance values in the Y direction (second line), which has been described with reference to FIG. 36 is adopted.

The conductor layer A in B of FIG. 121 includes a mesh conductor 1201. The mesh conductor 1201 has a conductor width WXA, a gap width GXA, and a conductor period FXA in the X direction, and has a conductor width WYA, a gap width GYA, and a conductor period FYA in the Y direction. The mesh conductor 1201 is a conductor having a shape in which basic patterns (first basic patterns) of the conductor period FXA and the conductor period FYA are repeatedly arranged on a single plane. The mesh conductor 1201 is, for example, a wiring (Vss wiring) connected to GND or a negative power supply.

In the mesh conductor 1201, the conductor width WXA>conductor width WYA and the gap width GYA>gap width GXA. A gap region of the mesh conductor 1201 has a shape in which a region in the Y direction is longer than a region in the X direction, a resistance value differs in the X direction and the Y direction, and the resistance value in the Y direction is smaller than the resistance value in the X direction. Therefore, in the mesh conductor 1201, it is easy for a current to flow in the Y direction than in the X direction.

The conductor layer B in C of FIG. 121 includes a mesh conductor 1202. The mesh conductor 1202 has a conductor width WXB, a gap width GXB, and a conductor period FXB in the X direction, and has a conductor width WYB, a gap width GYB, and a conductor period FYB in the Y direction. The mesh conductor 1202 is a conductor having a shape in which basic patterns (second basic patterns) of the conductor period FXB and the conductor period FYB are repeatedly arranged on a single plane. The mesh conductor 1202 is, for example, a wiring (Vdd wiring) connected to a positive power supply.

In the mesh conductor 1202, the conductor width WXB>conductor width WYB and the gap width GYB>gap width GXB. A gap region of the mesh conductor 1202 has a shape in which a region in the Y direction is longer than a region in the X direction, a resistance value differs in the X direction and the Y direction, and the resistance value in the Y direction is smaller than the resistance value in the X direction. Therefore, in the mesh conductor 1202, it is easy for a current to flow in the Y direction than in the X direction.

The mesh conductor 1201 of the conductor layer A and the mesh conductor 1202 of the conductor layer B have a differential structure. That is, the current distribution of the mesh conductor 1201 of the conductor layer A and the current distribution of the mesh conductor 1202 of the conductor layer B have substantially the same and opposite characteristics, as described in the eleventh configuration example and the like. Here, “substantially the same” means a difference in a range that can be regarded as equal, but may be a difference in a range that does not exceed at least twice, for example. More specifically, substantially the same AC currents flow in end portions of the mesh conductor 1201 of the conductor layer A and the mesh conductor 1202 of the conductor layer B, and current directions are opposite directions in the mesh conductor 1201 and the mesh conductor 1202. As a result, a magnetic field generated by the current distribution of the mesh conductor 1201 and a magnetic field generated by the current distribution of the mesh conductor 1202 are effectively offset. Thereby, it is possible to curb inductive noise.

Further, since there is no region to be opened due to stacking of the conductor layer A and the conductor layer B as illustrated in F of FIG. 121, it is possible to shield the hot carrier light emitted from the active element group 167.

On the other hand, the conductor layer C in A of FIG. 121 is a conductor layer having a low sheet resistance in which it is easy for a current to flow, and a straight conductor 1211A long in the X direction and a straight conductor 1211B long in the X direction are alternately arranged periodically in the Y direction. The straight conductor 1211A is, for example, a wiring (Vss wiring) connected to GND or a negative power supply. The straight conductor 1211B is, for example, a wiring (Vdd wiring) connected to a positive power supply. The straight conductor 1211A is connected to, for example, a pad (not illustrated) in the outer peripheral portion of the semiconductor substrate, and is electrically connected to the mesh conductor 1201 of the conductor layer A. The mesh conductor 1201 of the conductor layer A and the straight conductor 1211A of the conductor layer C may be electrically connected by, for example, the conductor via extended in the Z direction. The straight conductor 1211B is connected to, for example, a pad (not illustrated) in the outer peripheral portion of the semiconductor substrate, and is electrically connected to the mesh conductor 1202 of the conductor layer B. The mesh conductor 1202 of the conductor layer B and the straight conductor 1211B of the conductor layer C may be electrically connected by the conductor via extended in the Z direction, for example.

The straight conductor 1211A has a conductor width WYCA in the Y direction, the straight conductor 1211B has a conductor width WYCB in the Y direction, and the conductor width WYCA of the straight conductor 1211A is larger than the conductor width WYCB of the straight conductor 1211B (conductor width WYCA>conductor width WYCB). A gap having a gap width GYC is formed between the straight conductor 1211A and the straight conductor 1211B in the Y direction. One straight conductor 1211A and one straight conductor 1211B are periodically arranged in the Y direction in a conductor period FYC (=conductor width WYCA+conductor width WYCB+2×gap width GYC).

When the conductor layer C in which the straight conductor 1211A and the straight conductor 1211B are periodically arranged in the Y direction in the conductor period FYC is viewed in a predetermined planar range (planar region), the conductor width WYCA of the straight conductor 1211A and the conductor width WYCB of the straight conductor 1211B differs and thus, a sum of the conductor widths WYCA of the plurality of straight conductors 1211A in the predetermined planar range greatly differs from a sum of the conductor widths WYCB of the plurality of straight conductors 1211B. In this case, since a current distribution of the straight conductor 1211A greatly differs from a current distribution of the straight conductor 1211B, the occurrence of the inductive noise cannot be curbed, and the inductive noise is increased. Specifically, since a resistance value in the X direction greatly differs between the straight conductor 1211A and the straight conductor 1211B, the current distribution greatly differs between the straight conductor 1211A and the straight conductor 1211B, and a total amount of current flowing through the straight conductor 1211A is larger than a total amount of current flowing in the straight conductor 1211B. Further, according to a law of current conservation (Kirchhoffs first law), a total amount of current flowing through the mesh conductor 1202 is larger than a total amount of current flowing through the mesh conductor 1201. Accordingly, since the current distribution greatly differs between the mesh conductor 1201 and the mesh conductor 1202, the occurrence of inductive noise cannot be curbed, and the inductive noise is increased. Therefore, an effect of curbing the inductive noise in the two-layer conductor layer of the conductor layer A or the conductor layer B can be reduced depending on the wiring layout of the conductor layer C.

Therefore, hereinafter, a configuration in which the inductive noise is effectively reduced when the wiring layers 165A to 165C have a stacked structure of three conductor layers will be described. Since the configuration example of FIG. 121 may be applicable depending on a magnitude of the inductive noise, the configuration example of FIG. 121 is not excluded.

<First Configuration Example of Three-Layer Conductor Layer>

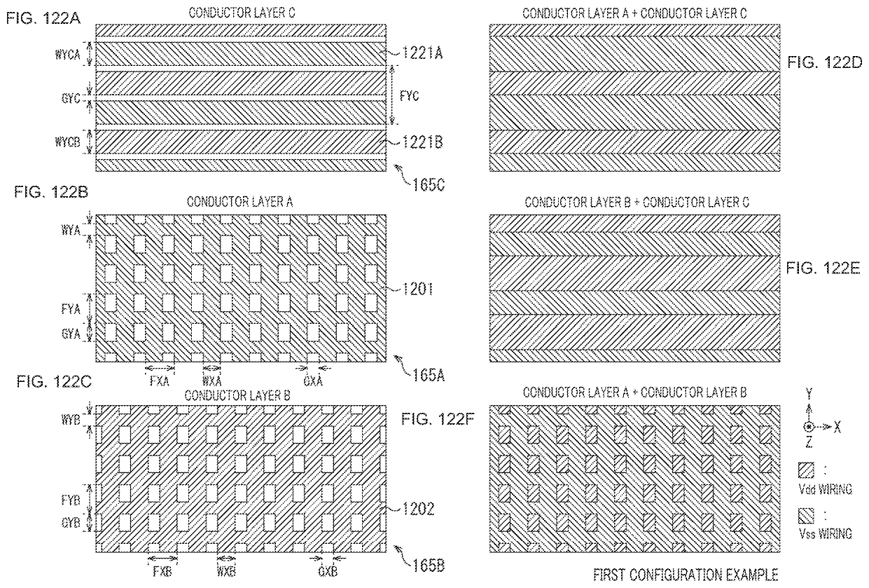

FIG. 122 illustrates a first configuration example of the three-layer conductor layer.

A of FIG. 122 illustrates the conductor layer C (wiring layer 165C), B of FIG. 122 illustrates the conductor layer A (wiring layer 165A), and C of FIG. 122 illustrates the conductor layer B (wiring layer 165B).

D of FIG. 122 is a plan view in a state in which the conductor layer A and the conductor layer C are stacked, E of FIG. 122 is a plan view in a state in which the conductor layer B and the conductor layer C are stacked, and F of FIG. 122 is a plan view in a state in which the conductor layer A and the conductor layer B are stacked.

The conductor layer A in B of FIG. 122 includes a mesh conductor 1201 as in FIG. 121. That is, the mesh conductor 1201 has a conductor width WXA, a gap width GXA, and a conductor period FXA in the X direction, and has a conductor width WYA, a gap width GYA, and a conductor period FYA in the Y direction. The mesh conductor 1201 is a conductor having a shape in which basic patterns (first basic patterns) of the conductor period FXA and the conductor period FYA are repeatedly arranged on a single plane. The mesh conductor 1201 is, for example, a wiring (Vss wiring) connected to GND or a negative power supply.

The conductor layer B in C of FIG. 122 includes a mesh conductor 1202 as in FIG. 121. That is, the mesh conductor 1202 has a conductor width WXB, a gap width GXB, and a conductor period FXB in the X direction, and has a conductor width WYB, a gap width GYB, and a conductor period FYB in the Y direction. The mesh conductor 1202 is a conductor having a shape in which basic patterns (second basic patterns) of the conductor period FXB and the conductor period FYB are repeatedly arranged on a single plane. The mesh conductor 1202 is, for example, a wiring (Vdd wiring) connected to a positive power supply. The conductor periods of the mesh conductor 1201 and the mesh conductor 1202 are the same. That is, conductor period FXA=conductor period FXB and conductor period FYA=conductor period FYB. The conductor periods may be substantially the same. Here, “substantially the same” means a difference in a range that can be regarded as the same, but may be a difference in a range that does not exceed at least twice, for example.

The conductor layer C in A of FIG. 122 is a conductor layer having a low sheet resistance through which it is easy for a current to flow, and includes a straight conductor 1221A (third basic pattern) long in the X direction and a straight conductor 1221B (first conductor pattern) long in the X direction (fourth basic pattern) that are alternately arranged periodically in the Y direction.

The straight conductor 1221A is, for example, a wiring (Vss wiring) connected to GND or a negative power supply. The straight conductor 1221B is, for example, a wiring (Vdd wiring) connected to a positive power supply. The straight conductor 1221A and the straight conductor 1221B are differential conductors (differential structures) of which current directions are opposite to each other. The straight conductor 1221A is connected to, for example, a pad (not illustrated) in the outer peripheral portion of the semiconductor substrate, and is electrically connected to the mesh conductor 1201 of the conductor layer A. The mesh conductor 1201 of the conductor layer A and the straight conductor 1221A of the conductor layer C may be electrically connected by the conductor via extended in the Z direction, for example. The straight conductor 1221B is connected to, for example, a pad (not illustrated) in the outer peripheral portion of the semiconductor substrate, and is electrically connected to the mesh conductor 1202 of the conductor layer B. The mesh conductor 1202 of the conductor layer B and the straight conductor 1221B of the conductor layer C may be electrically connected by, for example, the conductor via extended in the Z direction.

The straight conductor 1221A has a conductor width WYCA in the Y direction, the straight conductor 1221B has a conductor width WYCB in the Y direction, and the conductor width WYCA of the straight conductor 1221A, and the conductor width WYCB of the straight conductor 1221B are the same (conductor width WYCA=conductor width WYCB). The conductor width WYCA and the conductor width WYCB may not be the same or may be substantially the same (conductor width WYCA≈conductor width WYCB). A gap having a gap width GYC is formed between the straight conductor 1221A and the straight conductor 1221B in the Y direction.

One straight conductor 1221A and one straight conductor 1221B are periodically arranged in the Y direction in a conductor period FYC (=conductor width WYCA+conductor width WYCB+2×gap width GYC). The conductor period FYC of the straight conductor 1221A and the conductor period FYC of the straight conductor 1221B are the same or substantially the same. p Further, the conductor period FYC, which is a repetition period of the straight conductor 1221A of the conductor layer C, is an integral multiple of the conductor period FYA, which is a repetition period of the mesh conductor 1201 of the conductor layer A in the Y direction. FIG. 122 illustrates an example in which the conductor period FYC is twice the conductor period FYA.

The conductor period FYC that is a repetition period of the straight conductor 1221B of the conductor layer C is an integral multiple of the conductor period FYB that is a repetition period of the mesh conductor 1202 of the conductor layer B in the Y direction. FIG. 122 illustrates an example in which the conductor period FYC is twice the conductor period FYB.

The conductor width WYCA, the conductor width WYCB, and the gap width GYC can be designed to have any values.

When the conductor layer C in which the straight conductor 1221A and the straight conductor 1221B are periodically arranged in the Y direction in the conductor period FYC is viewed in a predetermined planar range (planar region), the conductor width WYCA of the straight conductor 1221A is the same or substantially the same as the conductor width WYCB of the straight conductor 1221B and thus, a sum of the conductor widths WYCA of the plurality of the straight conductors 1221A in the predetermined planar range is the same or substantially the same as a sum of the conductor widths WYCB of the plurality of the straight conductors 1221B. Accordingly, a current distribution of the straight conductor 1221A is the same or substantially the same as a current distribution of the straight conductor 1221B and thus, it is possible to curb the occurrence of inductive noise.

Further, for example, when the conductor layer C is arranged near the wiring layer 170 as illustrated in C of FIG. 120, capacitive noise caused by capacitive coupling between the straight conductor 1221A and the straight conductor 1221B of the conductor layer C and the signal line 132 or the control line 133 of the wiring layer 170 can occur, but since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure, and it is possible to shield the hot carrier light emitted from the active element group 167, as illustrated in F of FIG. 122, and the stack of the conductor layers A and C and the stack of the conductor layers B and C also have a light shielding structure as illustrated in D and E of FIG. 122, and the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

Further, when the mesh conductor 1201 of the conductor layer A is electrically connected to the straight conductor 1221A of the conductor layer C, and the mesh conductor 1202 of the conductor layer B is electrically connected to the straight conductor 1221B of the conductor layer C, an amount of current in the conductor layers A and B can be reduced and thus, the inductive noise or the voltage drop from the conductor layer A or B can be further reduced.

<Second Configuration Example of Three-Layer Conductor Layer>

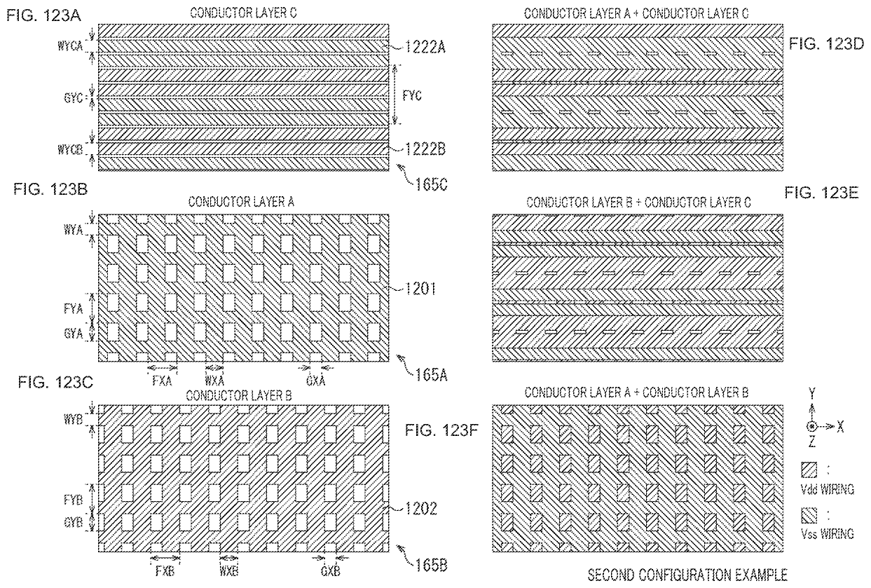

FIG. 123 illustrates a second configuration example of the three-layer conductor layer.

A of FIG. 123 illustrates the conductor layer C (wiring layer 165C), B of FIG. 123 illustrates the conductor layer A (wiring layer 165A), and C of FIG. 123 illustrates the conductor layer B (wiring layer 165B).

Further, D of FIG. 123 is a plan view in a state in which the conductor layers A and C are stacked, E of FIG. 123 is a plan view in a state in which the conductor layers B and C are stacked, and F of FIG. 123 is a plan view in a state in which the conductor layer A and the conductor layer B are stacked.

Since the conductor layer A in B of FIG. 123 is the same mesh conductor 1201 as the first configuration example of FIG. 122, and the conductor layer B in C of FIG. 123 is the same mesh conductor 1202 as the first configuration example of FIG. 122, description thereof is omitted.

The conductor layer C in A of FIG. 123 has a configuration in which a straight conductor 1222A long in the X direction and a straight conductor 1222B long in the X direction are alternately arranged periodically in the Y direction in units of two conductors.

The straight conductor 1222A is, for example, a wiring (Vss wiring) connected to GND or a negative power supply. The straight conductor 1222B is, for example, a wiring (Vdd wiring) connected to a positive power supply. The straight conductor 1222A and the straight conductor 1222B are differential conductors of which current directions are opposite to each other. The straight conductor 1222A is connected to, for example, a pad (not illustrated) in the outer peripheral portion of the semiconductor substrate, and is electrically connected to the mesh conductor 1201 of the conductor layer A. The mesh conductor 1201 of the conductor layer A and the straight conductor 1222A of the conductor layer C may be electrically connected by, for example, the conductor via extended in the Z direction. The straight conductor 1222B is connected to, for example, a pad (not illustrated) in the outer peripheral portion of the semiconductor substrate, and is electrically connected to the mesh conductor 1202 of the conductor layer B. The mesh conductor 1202 of the conductor layer B and the straight conductor 1222B of the conductor layer C may be electrically connected by, for example, the conductor via extended in the Z direction.

The straight conductor 1222A has a conductor width WYCA in the Y direction, the straight conductor 1222B has a conductor width WYCB in the Y direction, and the conductor width WYCA of the straight conductor 1222A and the conductor width WYCB of the straight conductor 1222B are the same (conductor width WYCA=conductor width WYCB). The conductor width WYCA and the conductor width WYCB may not be the same or may be substantially the same (conductor width WYCA≈conductor width WYCB). A gap having the gap width GYC is formed between the straight conductors 1222A adjacent in the Y direction, between the straight conductors 1222B, or between the straight conductor 1222A and the straight conductor 1222B.

The two straight conductors 1222A and the two straight conductors 1222B are periodically arranged in the Y direction in the conductor period FYC (=2×conductor width WYCA+2×conductor width WYCB+4×gap width GYC). In other words, the conductor period FYC of the two straight conductors 1222A and the conductor period FYC of the two straight conductors 1222B are the same or substantially the same.

The conductor width WYCA, the conductor width WYCB, and the gap width GYC can be designed to have any values. Although FIG. 123 illustrates an example in which the two straight conductors 1222A and 1222B are periodically arranged, but the present technology is not limited thereto and, for example, three or more straight conductors may be periodically arranged. Further, FIG. 123 illustrates an example in which the same number of straight conductors are periodically arranged in the straight conductor 1222A and the straight conductor 1222B, but the present technology is not limited thereto, and different numbers of straight conductors may be periodically arranged in the straight conductor 1222A and the straight conductor 1222B.

When the conductor layer C in which the straight conductor 1222A and the straight conductor 1222B are periodically arranged in the Y direction in the conductor period FYC is viewed in a predetermined planar range (planar region), the conductor width WYCA of the straight conductor 1222A is the same or substantially the same as the conductor width WYCB of the straight conductor 1222B and thus, a sum of the conductor widths WYCA of the plurality of straight conductors 1222A in the predetermined planar range is the same or substantially the same as a sum of the conductor widths WYCB of the plurality of straight conductors 1222B. Accordingly, a current distribution of the straight conductor 1222A is the same or substantially the same as a current distribution of the straight conductor 1222B and thus, it is possible to curb the occurrence of inductive noise.

Further, for example, when the conductor layer C is arranged near the wiring layer 170 as illustrated in C of FIG. 120, capacitive noise caused by capacitive coupling between the straight conductor 1222A and the straight conductor 1222B of the conductor layer C and the signal line 132 or the control line 133 of the wiring layer 170 can occur, but since the straight conductor 1222A and the straight conductor 1222B have the same wiring pattern repeated in the Y direction, it is possible to completely offset the capacitive noise in the Y direction. It is possible to greatly reduce the capacitive noise when the conductor layer C is closer to the wiring layer 170.

As illustrated in F of FIG. 123, the stack of the conductor layers A and B has a light shielding structure, which can shield the hot carrier light emitted from the active element group 167, and a light shielding property in a certain range is maintained even in the stack of the conductor layers A and C and the stack of the conductor layers B and C, as illustrated in D and E of FIG. 123. Accordingly, since light shielding constraints of the conductor layers A and B can be mitigated, it is possible to maximize the use of the conductor area of the conductor layers A and B, and it is possible to reduce the wiring resistance and reduce the voltage drop. Further, it is possible to improve the degree of freedom in a layout of the conductor layers A and B.

Further, when the mesh conductor 1201 of the conductor layer A is electrically connected to the straight conductor 1222A of the conductor layer C, and the mesh conductor 1202 of the conductor layer B is electrically connected to the straight conductor 1222B of the conductor layer C, an amount of current in the conductor layers A and B can be reduced and thus, the inductive noise or the voltage drop from the conductor layer A or B can be further reduced.

<Modification Examples of Second Configuration Example of Three-Layer Conductor Layer>

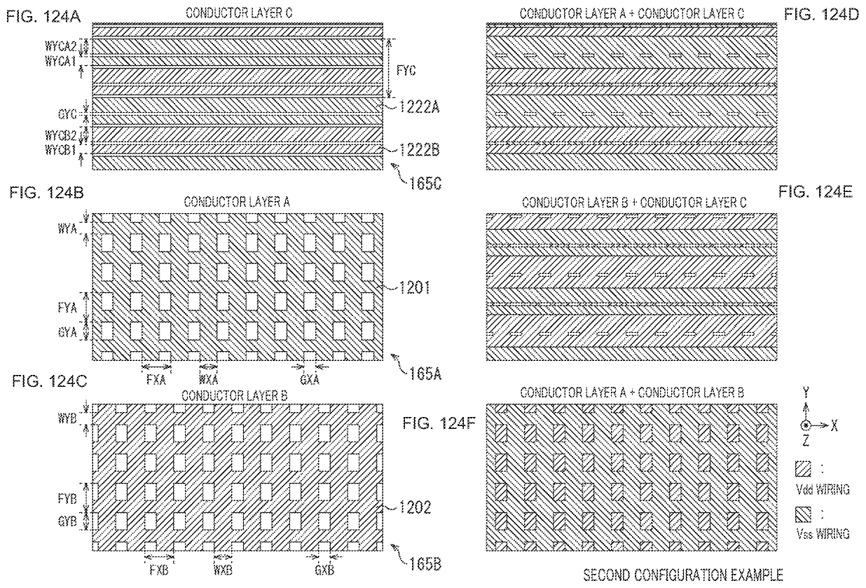

FIG. 124 illustrates a first modification example of the second configuration example of the three-layer conductor layer.

A to F in FIG. 124 correspond to A to F in FIG. 123, respectively, description of common parts denoted by the same reference signs will be appropriately omitted, and different portions will be described.

In the second configuration example of FIG. 123, in the conductor layer C, the two conductors 1222A adjacent to each other in the Y direction have the same conductor width WYCA in the Y direction. On the other hand, in the first modification example of FIG. 124, the conductor widths of the two straight conductors 1222A adjacent in the Y direction differ between the conductor width WYCA1 and the conductor width WYCA2 (conductor width WYCA1<conductor width WYCA2). The conductor width WYCA1 and the conductor width WYCA2 can be designed to have any values.

Similarly, in the second configuration example of FIG. 123, in the conductor layer C, two straight conductors 1222B adjacent in the Y direction have the same conductor width WYCB in the Y direction. On the other hand, in the first modification example of FIG. 124, the conductor widths of the two straight conductors 1222B adjacent in the Y direction differ between the conductor width WYCB1 and the conductor width WYCB2 (conductor width WYCB1<conductor width WYCB2). The conductor width WYCB1 and the conductor width WYCB2 can be designed to have any values.

The first modification example of FIG. 124 is the same as the second configuration example of FIG. 123 except that the conductor widths of the straight conductors 1222A and 1222B differ from each other.

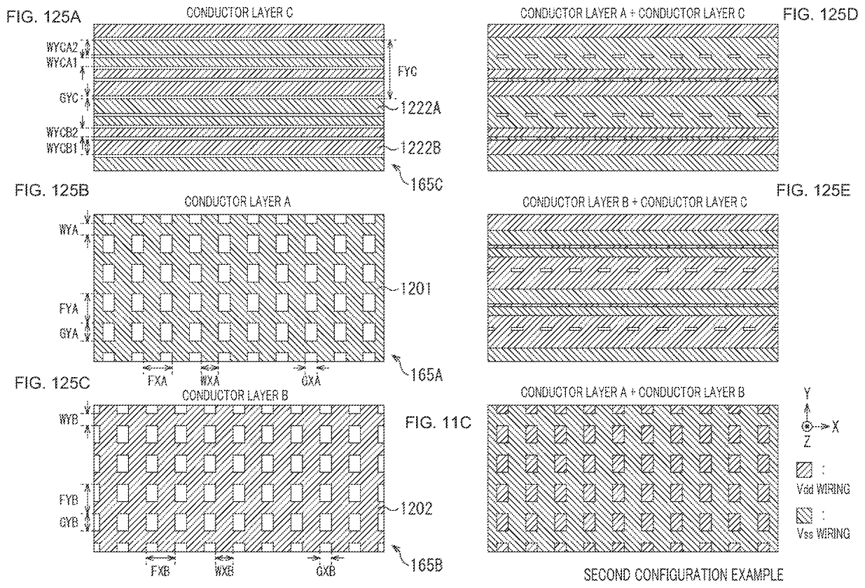

FIG. 125 illustrates a second modification example of the second configuration example of the three-layer conductor layer.

A to F of FIG. 125 correspond to A to F of FIG. 123, respectively, description of common portions denoted by the same reference signs will be appropriately omitted, and different portions will be described.

The second modification example of FIG. 125 differs from the second configuration example of FIG. 123 and is the same as the first modification example of FIG. 124 in that the conductor widths of the two straight conductors 1222A adjacent in the Y direction differ in the conductor layer C. Further, the second modification example of FIG. 125 differs from the second configuration example of FIG. 123 and is the same as the first modification example of FIG. 124 in that the conductor widths of the two straight conductors 1222B adjacent to each other in the Y direction differ from each other.

On the other hand, in the first modification example illustrated in FIG. 124, the arrangement of the two straight conductors 1222A having different conductor widths is the same as the arrangement of the two straight conductors 1222B. Specifically, when the two straight conductors 1222A are arranged in the Y direction in an order of the straight conductor 1222A having a small conductor width (the conductor width WYCA1) and the straight conductor 1222A having a large conductor width of a conductor width (the conductor width WYCA2), the two straight conductors 1222B are also arranged in the Y direction in an order of the straight conductor 1222B having a small conductor width (the conductor width WYCB1) and the straight conductor 1222B having a large conductor width of a conductor width (the conductor width WYCB2).

On the other hand, in the second modification example of FIG. 125, the arrangement of the two straight conductors 1222A having different conductor widths differs from the arrangement of the two straight conductors 1222B. Specifically, when the two straight conductors 1222A are arranged in the Y direction in an order of the straight conductor 1222A having a small conductor width (the conductor width WYCA1) and the straight conductor 1222A having a large conductor width (the conductor width WYCA2), the two straight conductors 1222B are also arranged in the Y direction in an order of the straight conductor 1222B having a small conductor width of a conductor width (the conductor width WYCB1) and the straight conductor 1222B having a large conductor width (the conductor width WYCB2). In other words, the two straight conductors 1222A and 1222B having different conductor widths are arranged in mirror symmetry in the Y direction.

The second modification example of FIG. 125 is the same as the second configuration example of FIG. 123 except that the conductor widths of the straight conductors 1222A and 1222B differ from each other.

Even in the first modification example and the second modification example of FIGS. 124 and 125, when the conductor layer C is viewed in a predetermined planar range (planar region), a sum of the conductor widths WYCA1 and WYCA2 of the plurality of straight conductors 1222A in the predetermined planar range is the same or substantially the same as a sum of the conductor widths WYCB1 and WYCB2 of the plurality of straight conductors 1222B. Accordingly, the current distribution of the straight conductor 1222A is the same or substantially the same as the current distribution of the straight conductor 1222B, it is possible to curb the occurrence of inductive noise.

Even in the first modification example and the second modification example of FIGS. 124 and 125, it is possible to greatly reduce the capacitive noise and to mitigate a light shielding constraint of the conductor layers A and B. Further, it is possible to reduce the wiring resistance and reduce the voltage drop. Further, it is possible to improve a degree of freedom in a layout of the conductor layers A and B.

<Third Configuration Example of Three-Layer Conductor Layer>

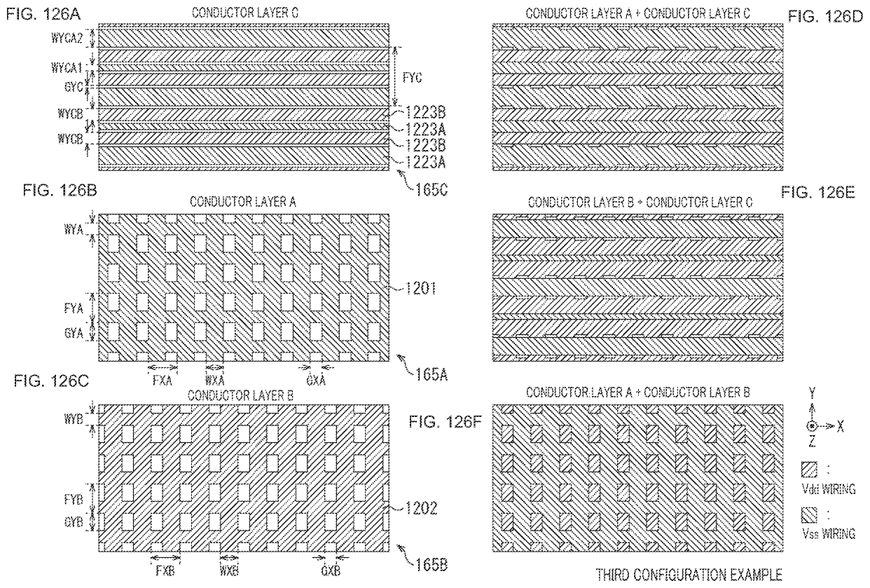

FIG. 126 illustrates a third configuration example of the three-layer conductor layer.

A of FIG. 126 illustrates the conductor layer C (wiring layer 165C), B of FIG. 126 illustrates the conductor layer A (wiring layer 165A), and C of FIG. 126 illustrates the conductor layer B (wiring layer 165B).

Further, D of FIG. 126 is a plan view in a state in which the conductor layers A and C are stacked, E of FIG. 126 is a plan view in a state in which the conductor layers B and C are stacked, and F of FIG. 126 is a plan view in a state in which the conductor layer A and the conductor layer B are stacked.

Since the conductor layer A in B of FIG. 126 is the same mesh conductor 1201 as in the first configuration example of FIG. 122 and the conductor layer B in C of FIG. 126 is the same mesh conductor 1202 as in the first configuration example of FIG. 122, description thereof is omitted.

The conductor layer C in A of FIG. 126 is the same as in the first configuration example of FIG. 122 in that the straight conductor 1223A long in the X direction and the straight conductor 1223B long in the X direction are alternately arranged periodically in the Y direction. However, in the first configuration example of FIG. 122, the conductor widths of the straight conductors 1221A arranged in order in the Y direction are all the same conductor width WYCA.

On the other hand, in the third configuration example of FIG. 126, for the straight conductors 1223A among the straight conductors 1223A and the straight conductors 1223B alternately arranged periodically in the Y direction, the straight conductors 1223A having different conductor widths WYCA1 and conductor widths WYCA2 are alternately arranged in the Y direction, whereas for the straight conductors 1223B, the straight conductors 1223A having the same conductor width WYCB are arranged.

The third configuration example of FIG. 126 is the same as the first configuration example of FIG. 122 except that the conductor widths of the straight conductors 1223A and 1223B differ from each other.

That is, the straight conductor 1223A is, for example, a wiring (Vss wiring) connected to GND or a negative power supply. The straight conductor 1223B is, for example, a wiring (Vdd wiring) connected to a positive power supply. The straight conductors 1223A and 1223B are differential conductors of which current directions are opposite to each other. The straight conductor 1223A is connected to, for example, a pad (not illustrated) in the outer peripheral portion of the semiconductor substrate, and is electrically connected to the mesh conductor 1201 of the conductor layer A. The mesh conductor 1201 of the conductor layer A and the straight conductor 1223A of the conductor layer C may be electrically connected by the conductor via extended in the Z direction, for example. The straight conductor 1223B is connected to, for example, a pad (not illustrated) in the outer peripheral portion of the semiconductor substrate, and is electrically connected to the mesh conductor 1202 of the conductor layer B. The mesh conductor 1202 of the conductor layer B and the straight conductor 1223B of the conductor layer C may be electrically connected by, for example, the conductor via extended in the Z direction.

A gap having the gap width GYC is formed between the straight conductor 1223A and the straight conductor 1223B adjacent in the Y direction. The two straight conductors 1223A and the two straight conductors 1223B are periodically arranged in the Y direction in the conductor period FYC (=conductor width WYCA1+conductor width WYCA2+2×conductor width WYCB+4×gap width GYC). The conductor width WYCA1, the conductor width WYCA2, the conductor width WYCB, and the gap width GYC can be designed to have any values. Further, FIG. 126 illustrates an example in which the two straight conductors 1223A and 1223B are periodically arranged, but the present technology is not limited thereto and, for example, three or more straight conductors may be periodically arranged. Further, FIG. 126 illustrates an example in which the same number of straight conductors are periodically arranged in the straight conductor 1223A and the straight conductor 1223B, but the present technology is not limited thereto, and different numbers of straight conductors may be periodically arranged in the straight conductor 1223A and the straight conductor 1223B.

When the conductor layer C in which the straight conductor 1223A and the straight conductor 1223B are periodically arranged in the Y direction in the conductor period FYC is viewed in a predetermined planar range (planar region), a sum of the conductor widths WYCA1 and WYCA2 of the plurality of conductors 1223A in a predetermined planar range is the same or substantially the same as a sum of the conductor widths WYCB of the plurality of straight conductors 1223B. Accordingly, since a current distribution of the straight conductor 1223A is the same or substantially the same as a current distribution of the straight conductor 1223B and thus, it is possible to curb the occurrence of inductive noise.

Even in the third configuration example of FIG. 126, it is possible to greatly reduce the capacitive noise and to mitigate a light shielding constraint of the conductor layers A and B. Further, it is possible to reduce the wiring resistance and reduce the voltage drop. Further, it is possible to improve a degree of freedom in a layout of the conductor layers A and B.

<Modification Examples of Third Configuration Example of Three-Layer Conductor Layer>

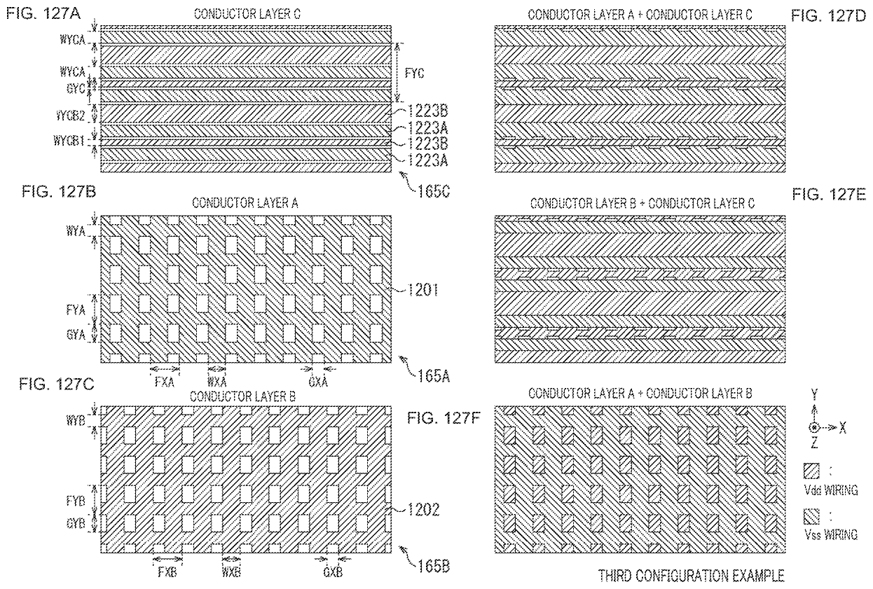

FIG. 127 illustrates a modification example of the third configuration example of the three-layer conductor layer.

A to F of FIG. 127 correspond to A to F in FIG. 126, respectively, and description of common portions denoted by the same reference signs will be appropriately omitted and different portions will be described.

In the third configuration example of FIG. 126, in the straight conductors 1223A and the straight conductors 1223B alternately arranged periodically in the Y direction in the conductor layer C, the conductor widths of the straight conductors 1223A include two types including the conductor width WYCA1 and the conductor width WYCA2, and the respective straight conductors 1223B have the same conductor width WYCB.

On the other hand, in the modification example of the third configuration example of FIG. 127, in the straight conductors 1223A and the straight conductors 1223B alternately arranged periodically in the Y direction in the conductor layer C, the straight conductors 1223A have the same conductor width WYCA, and conductor widths of the straight conductor 1223B include two types including the conductor width WYCB1 and the conductor width WYCB2. In the modification example of the third configuration example of FIG. 127, regarding the straight conductors 1223B, the straight conductors 1223B having different conductor widths WYCB1 and WYCB2 are alternately arranged in the Y direction.

The modification example of the third configuration example of FIG. 127 is the same as the third configuration example of FIG. 126 except that the conductor widths of the straight conductors 1223A and 1223B differ from each other.

When the conductor layer C in which the straight conductor 1223A and the straight conductor 1223B are periodically arranged in the Y direction in the conductor period FYC is viewed in a predetermined planar range (planar region), a sum of the conductor widths WYCA of the plurality of straight conductor 1223A in the predetermined planar range is the same or substantially the same as a sum of the conductor widths WYCB1 and WYCB2 of the plurality of straight conductors 1223B. Accordingly, the current distribution of the straight conductor 1223A is the same or substantially the same as the current distribution of the straight conductor 1223B and thus, it is possible to curb the occurrence of inductive noise.

Even in the modification example of the third configuration example of FIG. 127, it is possible to greatly reduce the capacitive noise and to mitigate a light shielding constraint of the conductor layers A and B. Further, it is possible to reduce the wiring resistance and reduce the voltage drop. Further, it is possible to improve a degree of freedom in a layout of the conductor layers A and B.

<Fourth Configuration Example of Three-Layer Conductor Layer>

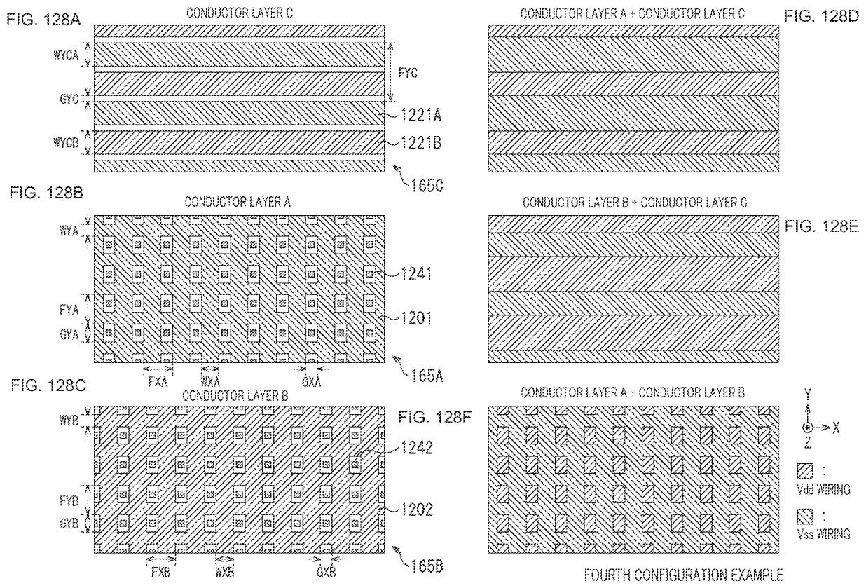

FIG. 128 illustrates a fourth configuration example of the three-layer conductor layer.

A of FIG. 128 illustrates the conductor layer C (wiring layer 165C), B of FIG. 128 illustrates the conductor layer A (wiring layer 165A), and C of FIG. 128 illustrates the conductor layer B (wiring layer 165B).

Further, D of FIG. 128 is a plan view in a state in which the conductor layers A and C are stacked, and E of FIG. 128 is a plan view in a state in which the conductor layers B and C are stacked, and F of FIG. 128 is a plan view in a state in which the conductor layer A and the conductor layer B are stacked.

In the fourth configuration example of FIG. 128, portions corresponding to those of the first configuration example illustrated in FIG. 122 are denoted by the same reference signs, description of the portions will be appropriately omitted, and description will be focused on different portions.

The conductor layer C in A of FIG. 128 is the same as the conductor layer C of the first configuration example illustrated in FIG. 122. That is, the conductor layer C has a configuration in which the straight conductors 1221A long in the X direction and the straight conductors 1221B long in the X direction are alternately arranged periodically in the Y direction in the conductor period FYC.

The conductor layer A in B of FIG. 128 has the same mesh conductor 1201 as that in FIG. 121. Further, the conductor layer A includes a relay conductor 1241 (first relay conductor) in the gaps having the gap width GXA in the X direction and the gap width GYA in the Y direction of the mesh conductor 1201. The relay conductors 1241 are arranged in a one-to-one manner in all the gaps of the mesh conductors 1201. Intervals between the relay conductors 1241, in other words, periods of the relay conductors 1241 also include the conductor periods FXA and FYA.

The relay conductor 1241 is, for example, a wiring (Vdd wiring) connected to a positive power supply, and in the case of the stacking order illustrated in C of FIG. 120, the mesh conductor 1202 of the conductor layer B is electrically connected to the straight conductor 1221B of the conductor layer C, for example, by a conductor via extending in the Z direction. In other words, the mesh conductor 1202 of the conductor layer B is electrically connected to the straight conductor 1221B of the conductor layer C via the relay conductor 1241 of the conductor layer A. Further, in the relay conductor 1241, for example, in the case of the stacking order illustrated in A of FIG. 120, the mesh conductor 1202 of the conductor layer B may be electrically connected to a conductor of a conductor layer different from the conductor layers A to C, for example, by a conductor via extending in the Z direction. Further, in the relay conductor 1241, for example, in the case of the stacking order illustrated in B of FIG. 120, the straight conductor 1221B of the conductor layer C may be electrically connected to a conductor of a conductor layer different from the conductor layers A to C, for example, by a conductor via extending in the Z direction. Further, all of the relay conductors 1241 may not be used for electrical connection, all of the relay conductors 1241 may be used for electrical connection, and some of the relay conductors 1241 may be used for electrical connection.

By providing the relay conductor 1241, it becomes possible to connect the mesh conductor 1202 to the straight conductor 1221B at a substantially shortest distance or a short distance to draw a power supply voltage and it is possible to reduce a voltage drop, energy loss, or inductive noise.

The conductor layer B in C of FIG. 128 has the same mesh conductor 1202 as that of FIG. 121. Further, the conductor layer B includes a relay conductor 1242 (second relay conductor) in the gap having the gap width GXB in the X direction and the gap width GYB in the Y direction of the mesh conductor 1202. The relay conductors 1242 are arranged in a one-to-one manner in all the gaps of the mesh conductors 1202. Intervals between the relay conductors 1242, in other words, the period of the relay conductors 1242 are also the conductor periods FXB and FYB.

The relay conductor 1242 is, for example, a wiring (Vss wiring) connected to a GND or a negative power supply, and in the case of the stacking order illustrated in A of FIG. 120, the mesh conductor 1201 of the conductor layer A is electrically connected to the straight conductor 1221A of the conductor layer C, for example, by a conductor via extending in the Z direction. In other words, the mesh conductor 1201 of the conductor layer B is electrically connected to the straight conductor 1221A of the conductor layer C via the relay conductor 1242 of the conductor layer B. Further, in the relay conductor 1242, for example, in the case of the stacking order illustrated in C of FIG. 120, the mesh conductor 1201 of the conductor layer A may be electrically connected to a conductor of a conductor layer different from the conductor layers A to C, for example, by a conductor via extending in the Z direction. Further, in the relay conductor 1242, for example, in the case of the stacking order illustrated in B of FIG. 120, the straight conductor 1221A of the conductor layer C may be electrically connected to a conductor of a conductor layer different from the conductor layers A to C, for example, by a conductor via extending in the Z direction. Further, all of the relay conductors 1242 may not be used for electrical connection, all of the relay conductors 1242 may be used for electrical connection, and some of the relay conductors 1242 may be used for electrical connection.

By providing the relay conductor 1242, the mesh conductor 1201 and the straight conductor 1221A can be connected to each other at a substantially shortest distance or a short distance, and a voltage drop, energy loss, or inductive noise can be reduced.

Further, since the straight conductor 1221A and the straight conductor 1221B in A of FIG. 128 are conductors that are long in the X direction, a direction in which it is easy for a current to flow is the X direction. Further, a direction in which it is easy for a current to flow in the mesh conductors 1201 and 1202 of B and C of FIG. 128 is the Y direction. Therefore, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse it is difficult for a current to concentrate), it is possible to further reduce the inductive noise.

As illustrated in F of FIG. 128, the stack of the conductor layers A and B has a light shielding structure. Further, as illustrated in D and E of FIG. 128, the stack of the conductor layers A and C and the stack of the conductor layers B and C also have a light shielding structure, and a light shielding property is maintained. Thereby, it is possible to shield the hot carrier light emitted from the active element group 167. Further, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

<Modification Examples of Fourth Configuration Example of Three-Layer Conductor Layer>

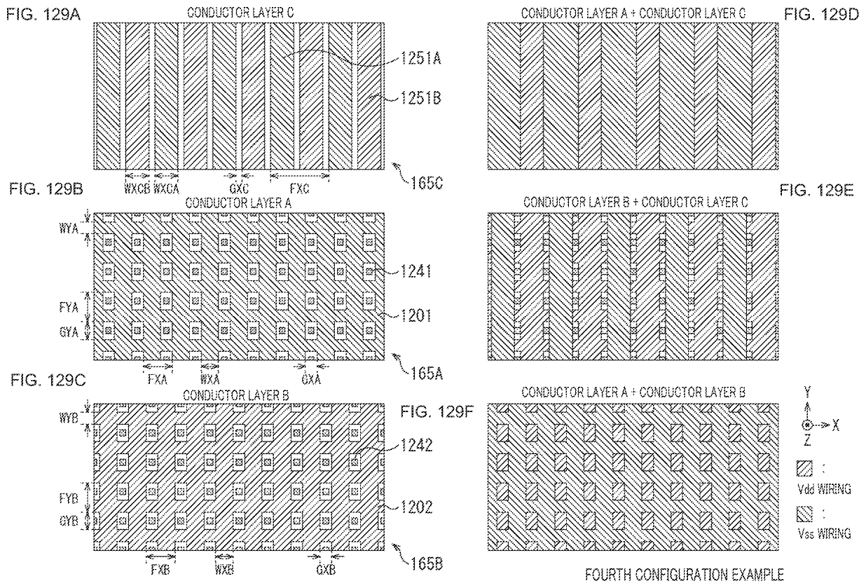

FIG. 129 illustrates a first modification example of the fourth configuration example of the three-layer conductor layer.

A of FIG. 129 illustrates the conductor layer C (wiring layer 165C), B of FIG. 129 illustrates the conductor layer A (wiring layer 165A), and C of FIG. 129 illustrates the conductor layer B (wiring layer 165B).

Further, D of FIG. 129 is a plan view in a state in which the conductor layer A and the conductor layer C are stacked, E of FIG. 129 is a plan view in a state in which the conductor layer B and the conductor layer C are stacked, and F of FIG. 129 is a plan view in a state in which the conductor layer A and the conductor layer B are stacked.

In FIG. 129, portions corresponding to those of the fourth configuration example illustrated in FIG. 128 are denoted by the same reference signs, description of the portions will be appropriately omitted, and description will be focused on different portions.

In the first modification example of the fourth configuration example, only a configuration of the conductor layer C in A of FIG. 129 differs from that in FIG. 128.

In the conductor layer C in A of FIG. 128, the straight conductor 1221A long in the X direction and the straight conductor 1221B long in the X direction are alternately arranged periodically in the Y direction in the conductor period FYC. Further, a direction in which it is easy for a current to flow in the conductor layer C and a direction in which it is easy for a current to flow in the conductor layers A and B are substantially orthogonal and differ by about 90 degrees.

On the other hand, in the conductor layer C in A of FIG. 129, a straight conductor 1251A long in the Y direction and a straight conductor 1251B long in the Y direction are alternately arranged periodically in the X direction.

Further, since the straight conductor 1251A and the straight conductor 1251B in A of FIG. 129 are conductors that are long in the Y direction, a direction in which it is easy for a current to flow is the Y direction. Further, a direction in which it is easy for a current to flow in the mesh conductors 1201 and 1202 of B and C of FIG. 128 is the Y direction. Accordingly, a direction in which it is easy for a current to flow in the conductor layer C is the same or substantially the same as a direction in which it is easy for a current to flow in the conductor layers A and B. In this case, it is possible to further reduce the voltage drop depending on the wiring layout. About 90 degrees and substantially the same in the direction may be a range in which a difference between the two directions can be regarded as 90 or the same degrees, but is a state in which there is no difference of at least 45 degrees or more with respect to the 90 or the same degrees.

The straight conductor 1251A is, for example, a wiring (Vss wiring) connected to GND or a negative power supply. The straight conductor 1251B is, for example, a wiring (Vdd wiring) connected to a positive power supply. The straight conductor 1251A and the straight conductor 1251B are differential conductors of which current directions are opposite to each other. The straight conductor 1251A is connected to, for example, a pad (not illustrated) in the outer peripheral portion of the semiconductor substrate, and is electrically connected to the mesh conductor 1201 of the conductor layer A. The mesh conductor 1201 of the conductor layer A and the straight conductor 1251A of the conductor layer C may be electrically connected by, for example, the conductor via extended in the Z direction. The straight conductor 1251B is connected to, for example, a pad (not illustrated) in the outer peripheral portion of the semiconductor substrate, and is electrically connected to the mesh conductor 1202 of the conductor layer B. The mesh conductor 1202 of the conductor layer B and the straight conductor 1251B of the conductor layer C may be electrically connected by, for example, the conductor via extended in the Z direction.

The straight conductor 1251A has a conductor width WXCA in the X direction, the straight conductor 1251B has a conductor width WXCB in the X direction, and the conductor width WXCA of the straight conductor 1251A and the conductor width WXCB of the straight conductor 1251B are the same or substantially the same (conductor width WXCA=conductor width WXCB, and conductor width WXCA≈conductor width WXCB). A gap having a gap width GXC is formed between the straight conductor 1251A and the straight conductor 1251B in the Y direction.

Then, one straight conductor 1251A and one straight conductor 1251B are periodically arranged in the X direction in a conductor period FXC (=conductor width WXCA+conductor width +2×gap width GXC). In other words, the conductor period FXC of the straight conductor 1251A is the same or substantially the same as the conductor period FXC of the straight conductor 1251B.

The conductor period FXC, which is a repetition period of the straight conductor 1251A of the conductor layer C, is an integral multiple of the conductor period FXA, which is a repetition period of the mesh conductor 1201 of the conductor layer A in the X direction. FIG. 129 illustrates an example in which the conductor period FXC is twice the conductor period FYA.

The conductor period FXC, which is a repetition period of the straight conductor 1251B of the conductor layer C, is an integral multiple of the conductor period FXB, which is a repetition period of the mesh conductor 1202 of the conductor layer B in the X direction. FIG. 129 illustrates an example in which the conductor period FXC is twice the conductor period FXB.

The conductor width WXCA, the conductor width WXCB, and the gap width GXC can be designed to have any values.

When the conductor layer C in which the straight conductor 1251A and the straight conductor 1251B are periodically arranged in the X direction at the conductor period FXC is viewed in a predetermined planar range (planar region), the conductor width WXCA of the straight conductor 1251A is the same or substantially the same as the conductor width WXCB of the straight conductor 1251B and thus, a sum of the conductor widths WXCA of the plurality of straight conductors 1251A in the predetermined planar range is the same or substantially the same as a sum of the conductor widths WXCB of the plurality of straight conductors 1251B. Accordingly, the current distribution of the straight conductor 1251A is the same or substantially the same as the current distribution of the straight conductor 1251B and thus, it is possible to curb the occurrence of inductive noise.

Further, for example, when the conductor layer C is arranged near the wiring layer 170 as illustrated in C of FIG. 120, capacitive noise caused by capacitive coupling between the straight conductor 1251A and the straight conductor 1251B of the conductor layer C and the signal line 132 or the control line 133 of the wiring layer 170 can occur, but since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 129 such that the hot carrier light emitted from the active element group 167 can be shielded, and the stack of the conductor layers A and C also has a light shielding structure as illustrated in D of FIG. 129 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1201 of the conductor layer A and the straight conductor 1251A of the conductor layer C are electrically connected to each other and the mesh conductor 1202 of the conductor layer B and the straight conductor 1251B of the conductor layer C are electrically connected to each other, an amount of current flowing through the conductor layers A and B can be reduced and thus, it is possible to further reduce inductive noise or voltage drop from the conductor layer A or B.

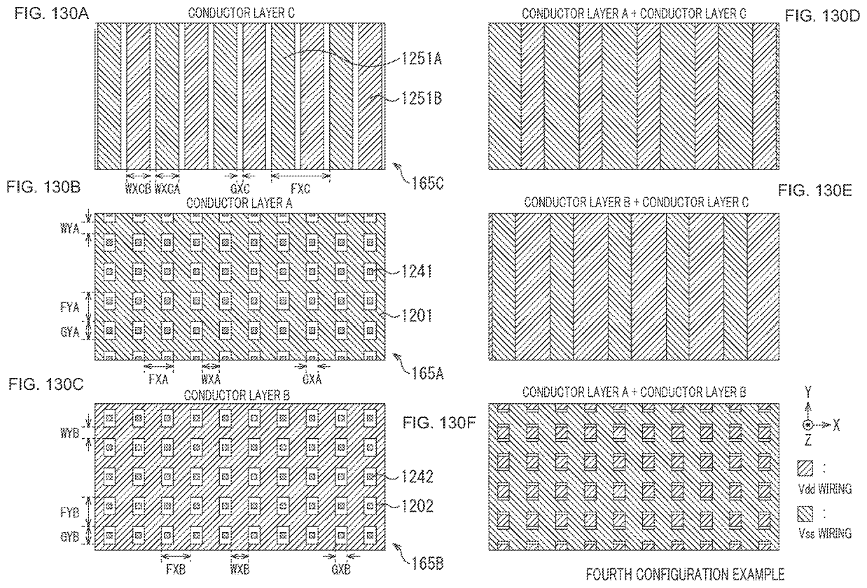

FIG. 130 illustrates a second modification example of the fourth configuration example of the three-layer conductor layer.

A to F of FIG. 130 correspond to A to F in FIG. 129, respectively, description of common parts denoted by the same reference signs will be appropriately omitted, and different portions will be described.

In the first modification example of FIG. 129, among positions of the gaps of the mesh conductor 1201 of the conductor layer A and the mesh conductor 1202 of the conductor layer B, the positions in the X direction differ from each other and the positions in the Y direction match.

On the other hand, in the second modification example of FIG. 130, among positions of the gaps of the mesh conductor 1201 of the conductor layer A and the mesh conductor 1202 of the conductor layer B, the positions in the X direction match and the positions in the Y direction differ from each other.

In other words, when the conductors of the mesh conductor 1201 of the conductor layer A and the mesh conductor 1202 of the conductor layer B in the same or substantially the same direction as a direction (Y direction) in which the signal line 132 of the wiring layer 170 extends are compared with each other, all the conductors overlap when viewed from a stacking direction. The conductor layer A and the conductor layer B having such a configuration correspond to the sixth configuration example of the conductor layers A and B illustrated in FIG. 27, and it is possible to greatly reduce the inductive noise as shown in the results of the simulation in C of FIG. 28.

When the position of the relay conductor 1241 of the conductor layer A is compared with the position of the relay conductor 1242 of the conductor layer B, the positions in the X direction differ and the positions in the Y direction are the same in the first modification example of FIG. 129. On the other hand, in the second modification example of FIG. 130, the positions in the X direction are the same and the positions in the Y direction differ.

In the first modification example of FIG. 129, the stack of the conductor layers A and B and the stack of the conductor layers A and C have a light shielding structure, and the light shielding property is maintained. On the other hand, in the second modification example of FIG. 130, the stack of the conductor layers A and C and the stack of the conductor layers B and C have a light shielding structure, and the light shielding property is maintained.

The second modification example of FIG. 130 is the same as the first modification example of FIG. 129 except for the points described above.

Even in the second modification example of FIG. 130, when the conductor layer C is viewed in a predetermined planar range (planar region), the current distribution of the straight conductor 1251A is the same or substantially the same as the current distribution of the straight conductor 1251B and thus, it is possible to curb occurrence of inductive noise.

Further, since the capacitive noise can be completely offset in the X direction, the capacitive noise can be greatly reduced. Since the stack of the conductor layers A and C and the stack of the conductor layers B and C have the light shielding structure, light shielding constraints of the conductor layers A and B can be significantly mitigated. Further, it is possible to reduce the wiring resistance and reduce the voltage drop. Further, it is possible to improve a degree of freedom in a layout of the conductor layers A and B

<Fifth Configuration Example of Three-Layer Conductor Layer>

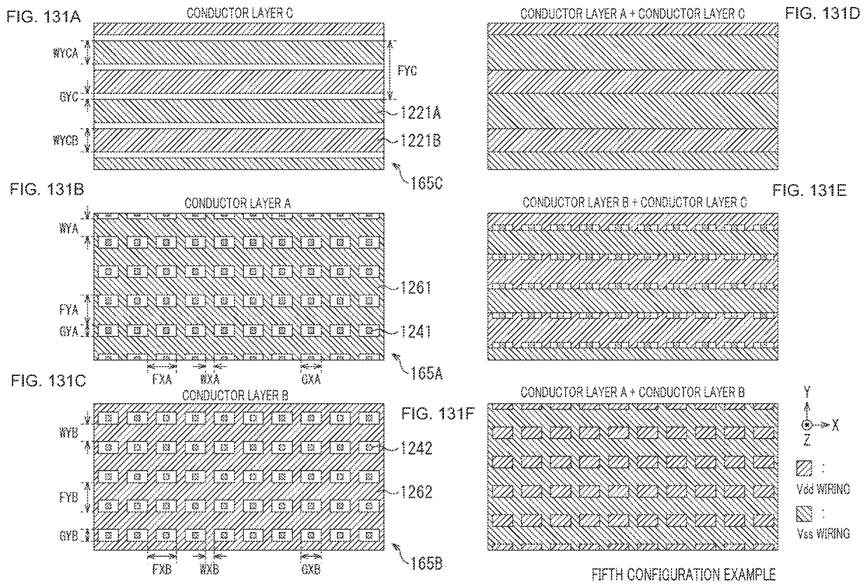

FIG. 131 illustrates a fifth configuration example of the three-layer conductor layer.

A of FIG. 131 illustrates the conductor layer C (wiring layer 165C), B of FIG. 131 illustrates the conductor layer A (wiring layer 165A), and C of FIG. 131 illustrates the conductor layer B (wiring layer 165B).

D of FIG. 131 is a plan view in a state in which the conductor layer A and the conductor layer C are stacked, E of FIG. 131 is a plan view in a state in which the conductor layer B and the conductor layer C are stacked, and F of FIG. 131 is a plan view in a state in which the conductor layer A and the conductor layer B are stacked.

In the fifth configuration example of FIG. 131, portions corresponding to those of the fourth configuration example illustrated in FIG. 128 are denoted by the same reference signs, description of the portions will be appropriately omitted, and description will be focused on different portions.

The conductor layer A in FIG. 131 includes a mesh conductor 1261. The mesh conductor 1261 differs from the mesh conductor 1201 of the fourth configuration example illustrated in FIG. 128 in a ratio of the gap width GXA in the X direction to the gap width GYA in the Y direction. Specifically, in the mesh conductor 1201 of the conductor layer A of the fourth configuration example illustrated in FIG. 128, (gap width GYA/gap width GXA)>1, whereas the mesh conductor 1261 of the conductor layer A in the fifth configuration example in B of FIG. 131. (gap width GYA/gap width GXA)<1.

In other words, the mesh conductor 1201 of the conductor layer A of the fourth configuration example illustrated in FIG. 128 is a conductor in which the conductor width WXA>conductor width WYA and the gap width GYA>gap width GXA, and it is easy for a current to flow in the Y direction, whereas the mesh conductor 1261 of the conductor layer A of the fifth configuration example illustrated in B of FIG. 131 is a conductor in which the conductor width WXA<conductor width WYA and the gap width GYA<gap width GXA, and it is easy for a current to flow in the X direction.

Further, in other words, a direction in which it is easy for a current to flow in the conductor layer C of the fourth configuration example illustrated in FIG. 128 is substantially orthogonal to and differ by about 90 degrees from a direction in which it is easy for a current to flow in the conductor layers A and B, whereas a direction in which it is easy for a current to flow in the conductor layer C in the fifth configuration example in B of FIG. 131 is the same or substantially the same as a direction in which it is easy for a current to flow in the conductor layers A and B. In the case of the fifth configuration example of FIG. 131, it is possible to further reduce the voltage drop depending on a wiring layout.

In the fourth configuration example illustrated in FIG. 128, when the positions of the gaps of the mesh conductor 1201 of the conductor layer A and the mesh conductor 1202 of the conductor layer B are compared with each other, the positions in the X direction differ and the positions in the Y direction match.

On the other hand, in the fifth configuration example in B of FIG. 131, positions of the gaps of the mesh conductor 1261 of the conductor layer A and the mesh conductor 1262 of the conductor layer B in the X direction match and positions in the Y direction differs.

In other words, when the conductors of the mesh conductor 1261 of the conductor layer A and the mesh conductor 1262 of the conductor layer B in the same or substantially the same direction as a direction (Y direction) in which the signal line 132 of the wiring layer 170 extends are compared with each other, all the conductors overlap when viewed from a stacking direction. The conductor layer A and the conductor layer B having such a configuration correspond to the sixth configuration example of the conductor layers A and B illustrated in FIG. 27, and it is possible to greatly reduce the inductive noise as shown in the results of the simulation in C of FIG. 28.

The second modification example of FIG. 130 is the same as the fourth configuration example illustrated in FIG. 128 except for the points described above.

The conductor layer C in A of FIG. 131 is the same as the conductor layer C of the fourth configuration example illustrated in FIG. 128. Therefore, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 131 such that the hot carrier light emitted from the active element group 167 can be shielded, and the stack of the conductor layers A and C also has a light shielding structure as illustrated in D of FIG. 131 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1261 of the conductor layer A is electrically connected to the straight conductor 1221A of the conductor layer C and the mesh conductor 1262 of the conductor layer B is electrically connected to the straight conductor 1221B of the conductor layer C, an amount of current flowing through the conductor layers A and B can be reduced and thus, it is possible to further reduce inductive noise or voltage drop from the conductor layer A or B.

<Sixth Configuration Example of Three-Layer Conductor Layer>

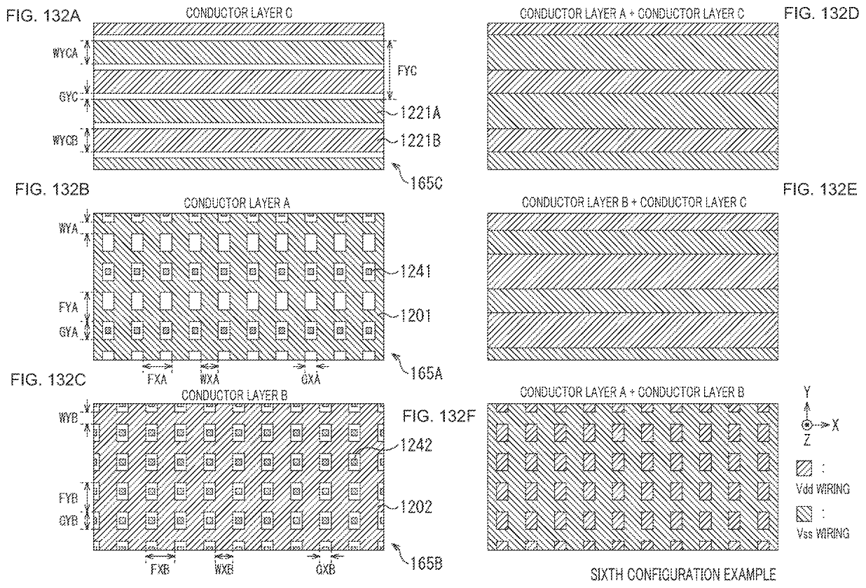

FIG. 132 illustrates a sixth configuration example of the three-layer conductor layer.

A of FIG. 132 illustrates the conductor layer C (wiring layer 165C), B of FIG. 132 illustrates the conductor layer A (wiring layer 165A), and C of FIG. 132 illustrates the conductor layer B (wiring layer 165B).

D of FIG. 132 is a plan view in a state in which the conductor layer A and the conductor layer C are stacked, E of FIG. 132 is a plan view in a state in which the conductor layer B and the conductor layer C are stacked, and F of FIG. 132 is a plan view in a state in which the conductor layer A and the conductor layer B are stacked.

In the sixth configuration example of FIG. 132, portions corresponding to those of the fourth configuration example illustrated in FIG. 128 are denoted by the same reference signs, description of the portions will be appropriately omitted, and description will be focused on different portions.

The sixth configuration example of FIG. 132 has a configuration in which some of the relay conductors 1241 of the conductor layer A in the fourth configuration example illustrated in FIG. 128 are omitted. Specifically, in the fourth configuration example of FIG. 128, the relay conductors 1241 are formed in all the gaps of the mesh conductor 1201 in a matrix form, whereas in the sixth configuration example of FIG. 132, a row in which the relay conductors 1241 are formed and a row in which the relay conductors 1241 are not formed are alternately arranged in units of rows in the Y direction. The relay conductors 1241 of the conductor layer A are located in an XY planar region of the straight conductor 1221B of the conductor layer C.

Thus, the relay conductors 1241 formed in the respective gaps of the mesh conductor 1201 may be thinned out instead of being arranged in all the gaps and arranged in some of the gaps. It is possible to keep constraints of an occupation rate of the wiring region in the conductor layer A, or the like and to increase a degree of freedom in a design of the wiring layout.

The sixth configuration example of FIG. 132 is the same as the fourth configuration example illustrated in FIG. 128 except for the points described above.

The conductor layer C in A of FIG. 132 is the same as the conductor layer C of the fourth configuration example illustrated in FIG. 128. Therefore, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 132 such that the hot carrier light emitted from the active element group 167 can be shielded, and the stack of the conductor layers A and C and the stack of the conductor layers B and C also have a light shielding structure as illustrated in D and E of FIG. 132 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

By providing the relay conductor 1241 in the conductor layer A, it becomes possible to connect the mesh conductor 1202 to the straight conductor 1221B at a substantially shortest distance or a short distance to draw a power supply voltage and it is possible to reduce a voltage drop, energy loss, or inductive noise.

By providing the relay conductor 1242 on the conductor layer B, the mesh conductor 1201 and the straight conductor 1221A can be connected to each other at a substantially shortest distance or a short distance, and a voltage drop, energy loss, or inductive noise can be reduced.

In the sixth configuration example of FIG. 132, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse it is difficult for a current to concentrate), it is possible to further reduce the inductive noise.

<Modification Examples of Sixth Configuration Example of Three-Layer Conductor Layer>

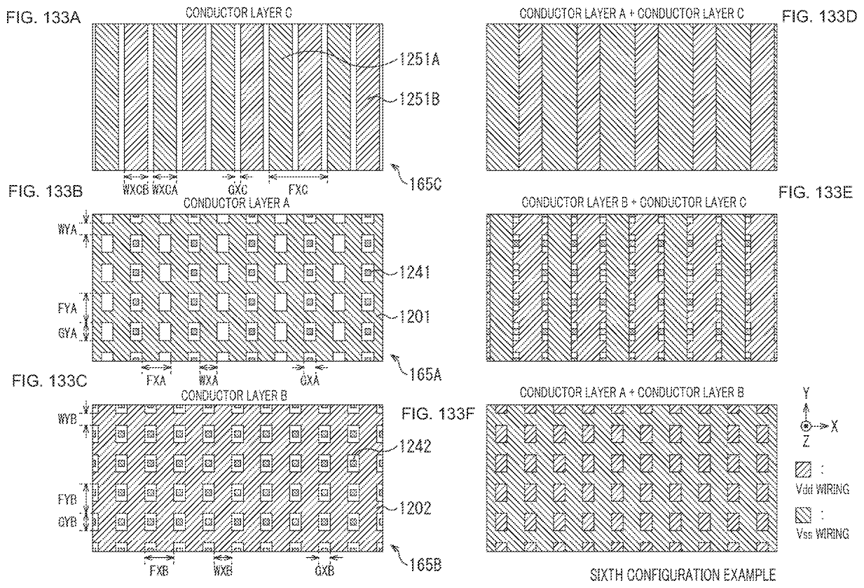

FIG. 133 illustrates a modification example of the sixth configuration example of the three-layer conductor layer.

A of FIG. 133 illustrates the conductor layer C (wiring layer 165C), B of FIG. 133 illustrates the conductor layer A (wiring layer 165A), and C of FIG. 133 illustrates the conductor layer B (wiring layer 165B).

D of FIG. 133 is a plan view in a state in which the conductor layer A and the conductor layer C are stacked, E of FIG. 133 is a plan view in a state in which the conductor layer B and the conductor layer C are stacked, and F of FIG. 133 is a plan view in a state in which the conductor layer A and the conductor layer B are stacked.

In FIG. 133, portions corresponding to those of the sixth configuration example illustrated in FIG. 132 are denoted by the same reference signs, description of the portions will be appropriately omitted, and description will be focused on different portions.

In the modification example of the sixth configuration example, the configurations of the conductor layers A and C differ from those in the sixth configuration example of FIG. 132.

In the conductor layer C in A of FIG. 132, the straight conductors 1221A long in the X direction and the straight conductors 1221B long in the X direction are alternately arranged periodically in the Y direction. Accordingly, a direction in which it is easy for a current to flow in the conductor layer C and a direction in which it is easy for a current to flow in the conductor layers A and B are substantially orthogonal and differ by about 90 degrees.

On the other hand, in the conductor layer C in A of FIG. 133, the straight conductor 1251A long in the Y direction and the straight conductor 1251B long in the Y direction are alternately arranged periodically in the X direction. Accordingly, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

Next, in the conductor layer A in B of FIG. 132, a row in which the relay conductors 1241 are formed and a row in which the relay conductors 1241 are not formed are alternately arranged in units of rows in the Y direction in the gaps of the mesh conductor 1201 in a matrix form.

On the other hand, in the conductor layer A in B of FIG. 133, a column in which the relay conductors 1241 are formed and a column in which the relay conductors 1241 are not formed are alternately arranged in units of columns in the X direction in the gaps of the mesh conductor 1201 in a matrix form. The relay conductor 1241 of the conductor layer A is located in the XY planar region of the straight conductor 1251 B of the conductor layer C.

The modification example of the sixth configuration example of FIG. 133 is the same as the sixth configuration example illustrated in FIG. 132 except for the points described above.

The conductor layer C in A of FIG. 133 is the same as the conductor layer C of the first modification example of the fourth configuration example illustrated in FIG. 129. Therefore, the current distribution of the straight conductor 1251A is the same or substantially the same as the current distribution of the straight conductor 1251B and thus, it is possible to curb the occurrence of inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 133 such that the hot carrier light emitted from the active element group 167 can be shielded, and the stack of the conductor layers A and C also has a light shielding structure as illustrated in D of FIG. 133 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1201 of the conductor layer A and the straight conductor 1251A of the conductor layer C are electrically connected to each other and the mesh conductor 1202 of the conductor layer B and the straight conductor 1251B of the conductor layer C are electrically connected to each other, an amount of current flowing through the conductor layers A and B can be reduced and thus, it is possible to further reduce inductive noise or voltage drop from the conductor layer A or B.

Although the relay conductor 1241 of the conductor layer A is thinned out and the relay conductor 1242 of the conductor layer B is not thinned out in the modification example of the sixth configuration example of FIG. 133, a configuration in which the relay conductor 1241 of the conductor layer A is not thinned out and the relay conductor 1242 of the conductor layer B is thinned out may be adopted.

<Seventh Configuration Example of Three-Layer Conductor Layer>

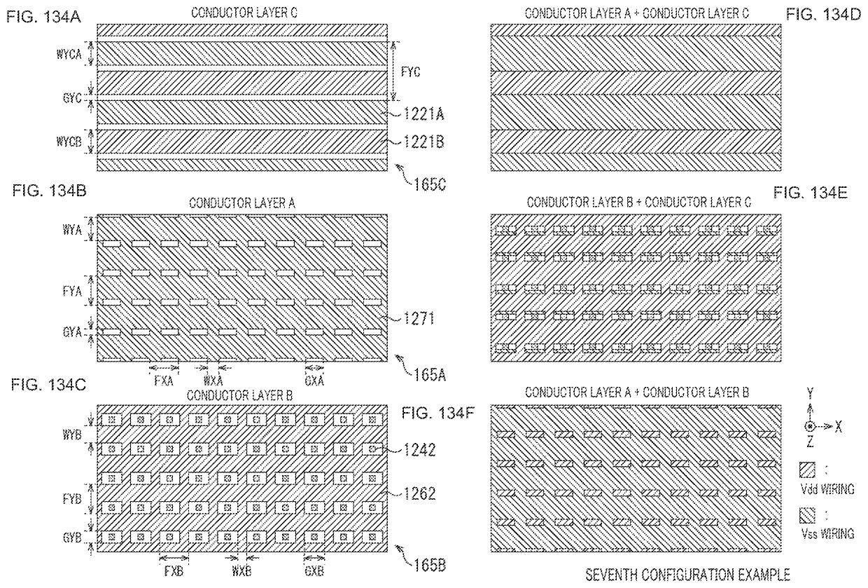

FIG. 134 illustrates a seventh configuration example of the three-layer conductor layer.

A of FIG. 134 illustrates the conductor layer C (wiring layer 165C), B of FIG. 134 illustrates the conductor layer A (wiring layer 165A), and C of FIG. 134 illustrates the conductor layer B (wiring layer 165B).

Further, D of FIG. 134 is a plan view in a state in which the conductor layers A and C are stacked, E of FIG. 134 is a plan view in a state in which the conductor layers B and C are stacked, and F of FIG. 134 is a plan view in a state in which the conductor layer A and the conductor layer B are stacked.

In the seventh configuration example of FIG. 134, portions corresponding to those of the fifth configuration example illustrated in FIG. 131 are denoted by the same reference signs, description of the portions will be appropriately omitted, and description will be focused on different portions.

The seventh configuration example differs from the fifth configuration example of FIG. 131 in only the configuration of the conductor layer A in B of FIG. 134. The conductor layers B and C of the seventh configuration example are the same as the conductor layers B and C of the fifth configuration example of FIG. 131.

The conductor layer A in B of FIG. 134 in the seventh configuration example includes a mesh conductor 1271. Further, in the conductor layer A, the relay conductor 1241 is not formed in the gap having the gap width GXA in the X direction and the gap width GYA in the Y direction of the mesh conductor 1271.

In other words, the gap width GXA and the gap width GYA of the mesh conductor 1271 in B of FIG. 134 are smaller than the gap width GXA and the gap width GYA of the mesh conductor 1261 in B of FIG. 131, and there is not enough space to form the relay conductor 1241.

The seventh configuration example of FIG. 134 is the same as the fifth configuration example illustrated in FIG. 131 except for the points described above.

The conductor layer C in A of FIG. 134 is the same as the conductor layer C of the fifth configuration example illustrated in FIG. 131. Therefore, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 134 such that the hot carrier light emitted from the active element group 167 can be shielded, and the stack of the conductor layers A and C also has a light shielding structure as illustrated in D of FIG. 134 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

The seventh configuration example of FIG. 134 is particularly suitable for a stacking order in which the three layers including the conductor layers A to C can be electrically connected, specifically, the stacking order illustrated in B of FIG. 120. In the case of an order of stacking the conductor layers A, C, and B illustrated in B of FIG. 120, the mesh conductor 1271 of the conductor layer A and the straight conductor 1221A of the conductor layer C can be connected to each other by a conductor via in the Z direction in a part of a region in which the planar regions overlap each other, and the mesh conductor 1262 and the relay conductor 1242 of the conductor layer B can be connected to the respective the straight conductors 1221B and 1221A of the conductor layer C so that such conductors having the same current characteristics are connected to each other, via conductor vias in the Z direction in the part of the region in which the planar regions overlap each other.

<Eighth Configuration Example of Three-Layer Conductor Layer>

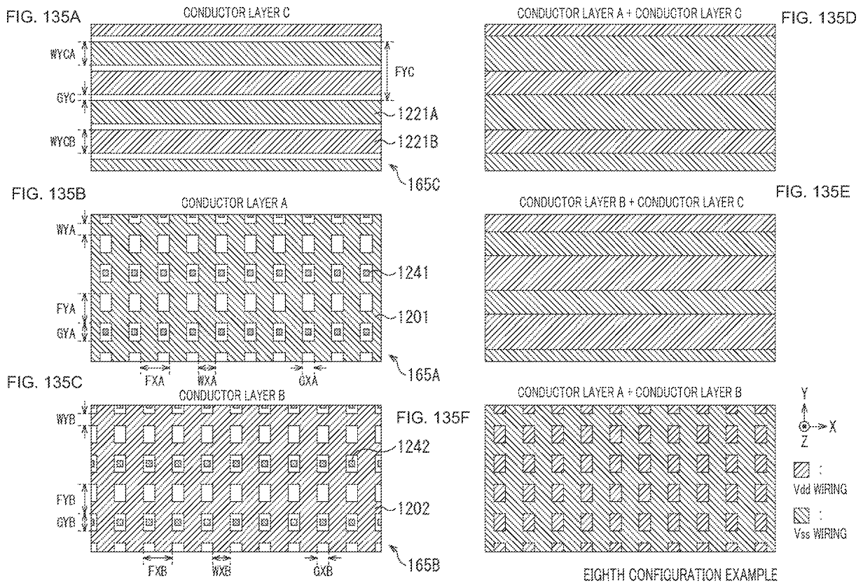

FIG. 135 illustrates an eighth configuration example of the three-layer conductor layer.

A of FIG. 135 illustrates the conductor layer C (wiring layer 165C), B of FIG. 135 illustrates the conductor layer A (wiring layer 165A), and C of FIG. 135 illustrates the conductor layer B (wiring layer 165B).

Further, D of FIG. 135 is a plan view in a state in which the conductor layers A and C are stacked, E of FIG. 135 is a plan view in a state in which the conductor layers B and C are stacked, and F of FIG. 135 is a plan view in a state in which the conductor layer A and the conductor layer B are stacked.

The eighth configuration example of FIG. 135 has a configuration in which a part of the fourth configuration example illustrated in FIG. 128 is changed, and the eighth configuration example of FIG. 135 will be described through a comparison with the fourth configuration example. In FIG. 135, portions corresponding to those in FIG. 128 are denoted by the same reference signs.

The conductor layer C in A of FIG. 135 is the same as the conductor layer C of the fourth configuration example illustrated in A of FIG. 128. That is, the conductor layer C has a configuration in which the straight conductors 1221A long in the X direction and the straight conductors 1221B long in the X direction are alternately arranged periodically in the Y direction.

The conductor layer A in B of FIG. 128 has a configuration in which some of the relay conductors 1241 of the conductor layer A in the fourth configuration example illustrated in FIG. 128 are omitted. Specifically, in the fourth configuration example of FIG. 128, the relay conductors 1241 are formed in all the gaps of the mesh conductor 1201 in a matrix form, whereas in the eighth configuration example of FIG. 135, a row in which the relay conductors 1241 are formed and a row in which the relay conductors 1241 are not formed are alternately arranged in units of rows in the Y direction.

Similarly, the conductor layer B in C of FIG. 128 has a configuration in which some of the relay conductors 1242 of the conductor layer B in the fourth configuration example illustrated in FIG. 128 are omitted. Specifically, in the fourth configuration example of FIG. 128, the relay conductors 1242 are formed in all the gaps of the mesh conductor 1201 in a matrix form, whereas in the eighth configuration example of FIG. 135, a row in which the relay conductors 1242 are formed and a row in which the relay conductors 1242 are not formed are alternately arranged in units of rows in the Y direction.

Therefore, the eighth configuration example of FIG. 135 has a configuration in which, for the conductor layer A, the relay conductors 1241 arranged in the gaps of the mesh conductor 1201 in the matrix form are thinned out every other row in units of rows from the fourth configuration example illustrated in FIG. 128 and, for the conductor layer B, the relay conductors 1242 arranged in the gaps of the mesh conductors 1202 in the matrix form are thinned out every other row in units of rows.

The eighth configuration example of FIG. 135 is the same as the fourth configuration example illustrated in FIG. 128 except for the points described above.

When the conductor layer C in A of FIG. 135 is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 135 such that the hot carrier light emitted from the active element group 167 can be shielded, and the stack of the conductor layers A and C and the stack of the conductor layers B and C also have a light shielding structure as illustrated in D and E of FIG. 135 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

By providing the relay conductor 1241 in the conductor layer A, it becomes possible to connect the mesh conductor 1202 to the straight conductor 1221B at a substantially shortest distance or a short distance to draw a power supply voltage and it is possible to reduce a voltage drop, energy loss, or inductive noise.

By providing the relay conductor 1242 in the conductor layer B, the mesh conductor 1201 and the straight conductor 1221A can be connected to each other at a substantially shortest distance or a short distance, and a voltage drop, energy loss, or inductive noise can be reduced.

In the eighth configuration example of FIG. 135, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse it is difficult for a current to concentrate), it is possible to further reduce the inductive noise.

<First Modification Example of Eighth Configuration Example of Three-Layer Conductor Layer>

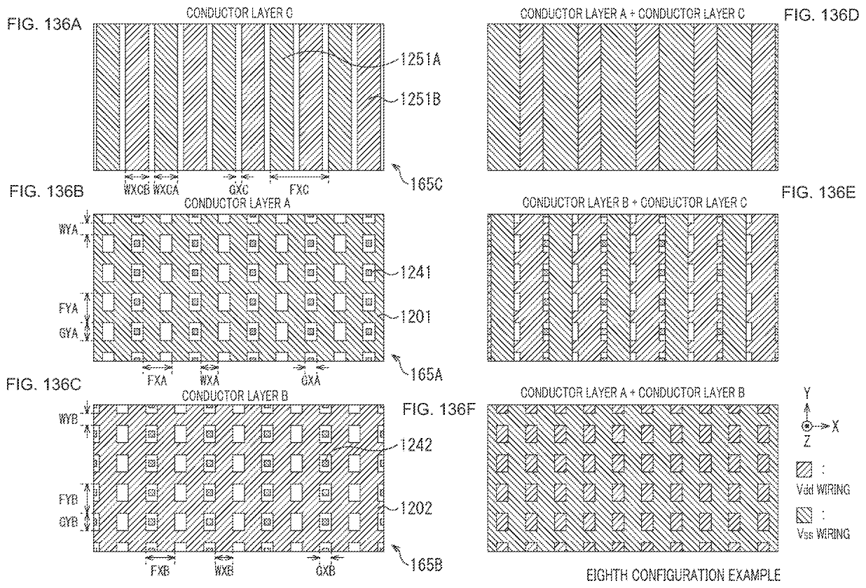

FIG. 136 illustrates a first modification example of the eighth configuration example of the three-layer conductor layer.

A of FIG. 136 illustrates the conductor layer C (wiring layer 165C), B of FIG. 136 illustrates the conductor layer A (wiring layer 165A), and C of FIG. 136 illustrates the conductor layer B (wiring layer 165B).

Further, D of FIG. 136 is a plan view in a state in which the conductor layers A and C are stacked, E of FIG. 136 is a plan view in a state in which the conductor layers B and C are stacked, and F of FIG. 136 is a plan view in a state in which the conductor layer A and the conductor layer B are stacked.

In FIG. 136, portions corresponding to those of the eighth configuration example illustrated in FIG. 135 are denoted by the same reference signs, description of the portions will be appropriately omitted, and description will be focused on different portions.

In the first modification example of the eighth configuration example, the configurations of the conductor layers A to C differ from the eighth configuration example of FIG. 135.

In the conductor layer C illustrated in A of FIG. 135, the straight conductors 1221 A long in the X direction and the straight conductors 1221B long in the X direction are alternately arranged periodically in the Y direction. Accordingly, a direction in which it is easy for a current to flow in the conductor layer C and a direction in which it is easy for a current to flow in the conductor layers A and B are substantially orthogonal and differ by about 90 degrees.

On the other hand, in the conductor layer C in A of FIG. 136, the straight conductor 1251A long in the Y direction and the straight conductor 1251B long in the Y direction are alternately arranged periodically in the X direction. Accordingly, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

Next, in the conductor layer A illustrated in B of FIG. 135, a row in which the relay conductors 1241 are formed and a row in which the relay conductors 1241 are not formed are alternately arranged in units of rows in the Y direction in the gaps of the mesh conductor 1201 in a matrix form.

On the other hand, in the conductor layer A in B of FIG. 136, a column in which the relay conductors 1241 are formed and a column in which the relay conductors 1241 are not formed are alternately arranged in units of columns in the X direction in the gaps of the mesh conductor 1201 in a matrix form. The relay conductor 1241 of the conductor layer A is located in the XY planar region of the straight conductor 1251 B of the conductor layer C.

Further, in the conductor layer B illustrated in C of FIG. 135, a row in which the relay conductors 1242 are formed and a row in which the relay conductors 1242 are not formed are alternately arranged in units of rows in the Y direction in the gaps in a matrix form of the mesh conductors 1202.

On the other hand, in the conductor layer B in C of FIG. 136, a column in which the relay conductors 1242 are formed and a column in which the relay conductors 1242 are not formed are alternately arranged in units of columns in the X direction in the gaps in a matrix form of the mesh conductors 1202.

The first modification example of the eighth configuration example of FIG. 136 is the same as the eighth configuration example illustrated in FIG. 135 except for the points described above.

When the conductor layer C in A of FIG. 136 is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 136 such that the hot carrier light emitted from the active element group 167 can be shielded, and the stack of the conductor layers A and C also has a light shielding structure as illustrated in D of FIG. 136 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1201 of the conductor layer A and the straight conductor 1251A of the conductor layer C are electrically connected to each other and the mesh conductor 1202 of the conductor layer B and the straight conductor 1251B of the conductor layer C are electrically connected to each other, an amount of current flowing through the conductor layers A and B can be reduced and thus, it is possible to further reduce inductive noise or voltage drop from the conductor layer A or B.

By providing the relay conductor 1241 in the conductor layer A, it becomes possible to connect the mesh conductor 1202 and the straight conductor 1251B at a substantially shortest distance or a short distance to draw a power supply, and it is possible to reduce a voltage drop, energy loss, or inductive noise.

By providing the relay conductor 1242 on the conductor layer B, the mesh conductor 1201 and the straight conductor 1251A can be connected to each other at a substantially shortest distance or a short distance, and a voltage drop, energy loss, or inductive noise can be reduced.

<Second Modification Example of Eighth Configuration Example of Three-Layer Conductor Layer>

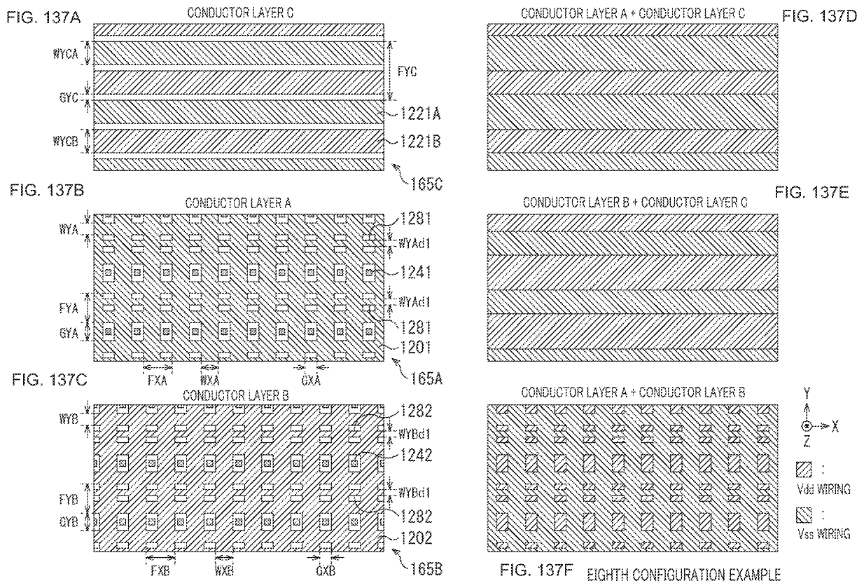

FIG. 137 illustrates a second modification example of the eighth configuration example of the three-layer conductor layer.

A of FIG. 137 illustrates the conductor layer C (wiring layer 165C), B of FIG. 137 illustrates the conductor layer A (wiring layer 165A), and C of FIG. 137 illustrates the conductor layer B (wiring layer 165B).

D of FIG. 137 is a plan view in a state in which the conductor layer A and the conductor layer C are stacked, E of FIG. 137 is a plan view in a state in which the conductor layer B and the conductor layer C are stacked, and F of FIG. 137 is a plan view in a state in which the conductor layer A and the conductor layer B are stacked.

In FIG. 137, portions corresponding to those of the eighth configuration example illustrated in FIG. 135 are denoted by the same reference signs, description of the portions will be appropriately omitted, and description will be focused on different portions.

In the second modification example of the eighth configuration example, the configurations of the conductor layers A and B differ from the eighth configuration example of FIG. 135.

When the conductor layer A in B of FIG. 137 is compared with the eighth configuration example illustrated in FIG. 135, a reinforcing conductor 1281 having a conductor width WYAdl in the Y direction is newly added in the gap in which the relay conductor 1241 of the mesh conductor 1201 is not formed. The reinforcing conductor 1281 is a straight conductor of which a conductor width in the X direction is the gap width GXA and is long in the X direction.

When the conductor layer B in C of FIG. 137 is compared with the eighth configuration example illustrated in FIG. 135, a reinforcing conductor 1282 having a conductor width WYBd1 in the Y direction is newly added in the gap in which the relay conductor 1242 of the mesh conductor 1202 is not formed. The reinforcing conductor 1282 is a straight conductor of which a conductor width in the X direction is the gap width GXB and is long in the X direction.

The second modification example of the eighth configuration example of FIG. 137 is the same as the eighth configuration example illustrated in FIG. 135 except for the points described above.

When the conductor layer C in A of FIG. 137 is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 137 such that the hot carrier light emitted from the active element group 167 can be shielded, and the stack of the conductor layers A and C and the stack of the conductor layers B and C also have a light shielding structure as illustrated in D and E of FIG. 137 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

By providing the relay conductor 1241 in the conductor layer A, it becomes possible to connect the mesh conductor 1202 to the straight conductor 1221B at a substantially shortest distance or a short distance to draw a power supply voltage and it is possible to reduce a voltage drop, energy loss, or inductive noise.

By providing the relay conductor 1242 on the conductor layer B, the mesh conductor 1201 and the straight conductor 1221A can be connected to each other at a substantially shortest distance or a short distance, and a voltage drop, energy loss, or inductive noise can be reduced.

In the second modification example of the eighth configuration example of FIG. 137, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse (it is difficult for a current to concentrate), it is possible to further reduce the inductive noise.

By disposing the reinforcing conductor 1281 that is long in the X direction at a position in which the relay conductor 1241 is thinned out in the conductor layer A, the wiring resistance can be reduced and thus, it is possible to further reduce the voltage drop. It is possible to also reduce the inductive noise by reducing the voltage drop.

By disposing the reinforcing conductor 1282 that is long in the X direction at the position in which the relay conductor 1242 is thinned out in the conductor layer B, the wiring resistance can be reduced and thus, it is possible to further reduce the voltage drop. It is possible to also reduce the inductive noise by reducing the voltage drop.

### THIRD MODIFICATION EXAMPLE OF EIGHTH CONFIGURATION EXAMPLE OF THREE-LAYER CONDUCTOR LAYER

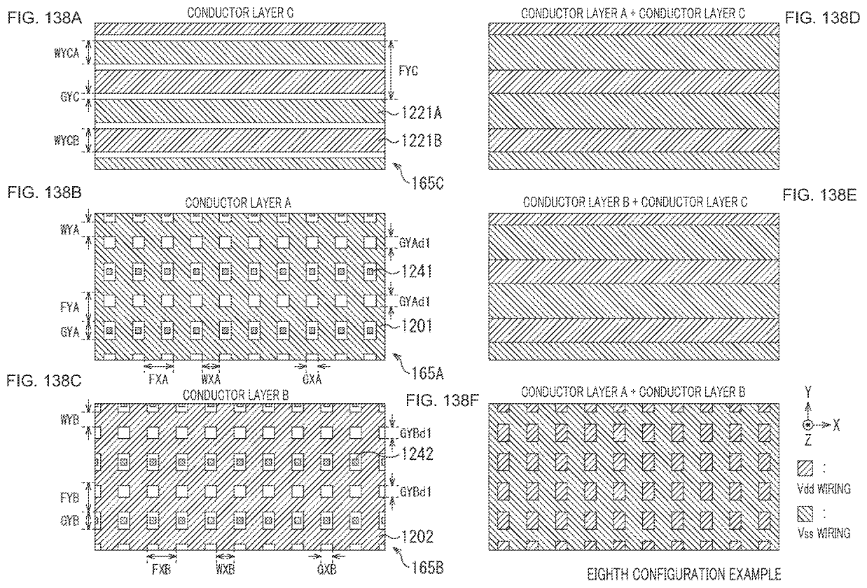

FIG. 138 illustrates a third modification example of the eighth configuration example of the three-layer conductor layer.

A of FIG. 138 illustrates the conductor layer C (wiring layer 165C), B of FIG. 138 illustrates the conductor layer A (wiring layer 165A), and C of FIG. 138 illustrates the conductor layer B (wiring layer 165B).

Further, D of FIG. 138 is a plan view in a state in which the conductor layers A and C are stacked, E of FIG. 138 is a plan view in a state in which the conductor layers B and C are stacked, and F of FIG. 138 is a plan view in a state in which the conductor layer A and the conductor layer B are stacked.

In FIG. 138, portions corresponding to those of the eighth configuration example illustrated in FIG. 135 are denoted by the same reference signs, description of the portions will be appropriately omitted, and description will be focused on different portions.

In the third modification example of the eighth configuration example, the configurations of the conductor layers A and B differ from that of the eighth configuration example of FIG. 135.

First, in the case of the conductor layer A, in the eighth configuration example illustrated in FIG. 135, the respective gaps of the mesh conductor 1201 in a matrix form commonly have the gap width GYA in the Y direction. In other words, the gap width GYA in the Y direction are the same in all the gaps in the matrix form of the mesh conductor 1201.

On the other hand, in the conductor layer A in B of FIG. 138, the gap in which the relay conductor 1241 is formed has the gap width GYA in the Y direction, and the gap in which the relay conductor 1241 is not formed has a gap width GYAd1 in the Y direction smaller than the gap width GYA (gap width GYA>gap width GYAd1).

Next, in the case of the conductor layer B, in the eighth configuration example illustrated in FIG. 135, the gaps in a matrix form of the mesh conductors 1202 commonly have the gap width GYB in the Y direction. In other words, the gap width GYB in the Y direction is the same in all the gaps in a matrix form of the mesh conductors 1202.

On the other hand, in the conductor layer A in B of FIG. 138, the gap in which the relay conductor 1242 is formed has the gap width GYB in the Y direction, and the gap in which the relay conductor 1242 is not formed has a gap width GYBd1 in the Y direction smaller than the gap width GYB (gap width GYB>gap width GYBd1).

A third modification example of the eighth configuration example in FIG. 138 is the same as the eighth configuration example illustrated in FIG. 135 except for the points described above.

When the conductor layer C in A of FIG. 138 is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 138 such that the hot carrier light emitted from the active element group 167 can be shielded, and the stack of the conductor layers A and C and the stack of the conductor layers B and C also have a light shielding structure as illustrated in D and E of FIG. 138 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

By providing the relay conductor 1241 in the conductor layer A, it becomes possible to connect the mesh conductor 1202 to the straight conductor 1221B at a substantially shortest distance or a short distance to draw a power supply voltage and it is possible to reduce a voltage drop, energy loss, or inductive noise.

By providing the relay conductor 1242 on the conductor layer B, the mesh conductor 1201 and the straight conductor 1221A can be connected to each other at a substantially shortest distance or a short distance, and a voltage drop, energy loss, or inductive noise can be reduced.

In the third modification example of the eighth configuration example of FIG. 138, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse (it is difficult for a current to concentrate), it is possible to further reduce the inductive noise.

In the conductor layer A, by the gap width GYAd1 at the position in which the relay conductor 1241 is thinned out being made smaller than the gap width GYA at the position in which the relay conductor 1241 is formed, the wiring resistance can be reduced and thus, it is possible to further reduce the voltage drop. It is possible to also reduce the inductive noise by reducing the voltage drop.

In the conductor layer B, by the gap width GYBd1 at the position in which the relay conductor 1242 is thinned out being made smaller than the gap width GYB at the position in which the relay conductor 1242 is formed, the wiring resistance can be reduced and thus, it is possible to further reduce the voltage drop. It is possible to also reduce the inductive noise by reducing the voltage drop.

In the third modification example of the eighth configuration example of FIG. 138, when the conductor width WYA of the mesh conductor 1201 of the conductor layer A in the Y direction is increased, the gap width GYAd1 at the position in which the relay conductor 1241 is thinned out may be smaller than the gap width GYA at the position in which the relay conductor 1241 is formed, and the conductor width WYA in the Y direction may be the same as that in the eighth configuration example in FIG. 135. The same applies to the mesh conductor 1202 of the conductor layer B.

### FOURTH MODIFICATION EXAMPLE OF EIGHTH CONFIGURATION EXAMPLE OF THREE-LAYER CONDUCTOR LAYER

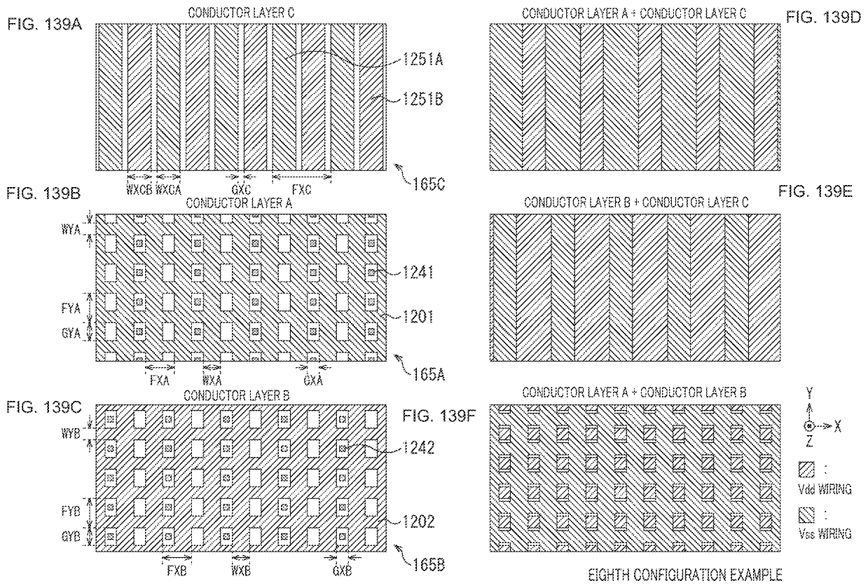

FIG. 139 illustrates a fourth modification example of the eighth configuration example of the three-layer conductor layer.

A of FIG. 139 illustrates the conductor layer C (wiring layer 165C), B of FIG. 139 illustrates the conductor layer A (wiring layer 165A), and C of FIG. 139 illustrates the conductor layer B (wiring layer 165B).

Further, D of FIG. 139 is a plan view in a state in which the conductor layers A and C are stacked, E of FIG. 139 is a plan view in a state in which the conductor layers B and C are stacked, and F of FIG. 139 is a plan view in a state in which the conductor layer A and the conductor layer B are stacked.

The fourth modification example of the eighth configuration example of FIG. 139 has a configuration in which the first modification example of the eighth configuration example of FIG. 136 is partially modified. In FIG. 139, portions corresponding to those in FIG. 136 are denoted by the same reference signs, description of the portions will be appropriately omitted, and different portions will be described.

In the first modification example of FIG. 136, when the positions of the gaps of the mesh conductor 1201 of the conductor layer A and the mesh conductor 1202 of the conductor layer B are compared with each other, the positions in the X direction differ and the positions in the Y direction match.

On the other hand, in the fourth modification example of FIG. 139, when the positions of the gaps of the mesh conductor 1201 of the conductor layer A and the mesh conductor 1202 of the conductor layer B are compared with each other, the positions in the X direction match and the positions in the Y direction differ from each other.

The fourth modification example of the eighth configuration example of FIG. 139 is the same as the first modification example of FIG. 136 except for the points described above. For example, the fourth modification example is the same as the first modification example in that, in the conductor layer A, a column in which the relay conductors 1241 are formed and a column in which the relay conductors 1241 are not formed are alternately arranged in units of columns in the X direction in the gaps of the mesh conductor 1201 in a matrix form and, in the conductor layer B, a column in which the relay conductors 1242 are formed and a column in which the relay conductors 1242 are not formed are alternately arranged in units of columns in the X direction in the gaps in a matrix form of the mesh conductors 1202.

Further, the fourth modification example of the eighth configuration example of FIG. 139 corresponds to a configuration in which the relay conductors 1241 are thinned out every other column in units of columns in the conductor layer A from the second modification example of the fourth configuration example illustrated in FIG. 130, and the relay conductors 1242 are thinned out every other column in units of columns in the conductor layer B from the second modification example of the fourth configuration example illustrated in FIG. 130.

When the conductor layer C in A of FIG. 139 is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

As illustrated in D and E of FIG. 139, the stack of the conductor layers A and C and the stack of the conductor layers B and C have a light shielding structure such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1201 of the conductor layer A and the straight conductor 1251A of the conductor layer C are electrically connected to each other and the mesh conductor 1202 of the conductor layer B and the straight conductor 1251B of the conductor layer C are electrically connected to each other, an amount of current flowing through the conductor layers A and B can be reduced and thus, it is possible to further reduce inductive noise or voltage drop from the conductor layer A or B.

In the conductor layer C in A of FIG. 139, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

By providing the relay conductor 1241 in the conductor layer A, it becomes possible to connect the mesh conductor 1202 and the straight conductor 1251B at a substantially shortest distance or a short distance to draw a power supply, and it is possible to reduce a voltage drop, energy loss, or inductive noise.

By providing the relay conductor 1242 on the conductor layer B, the mesh conductor 1201 and the straight conductor 1251A can be connected to each other at a substantially shortest distance or a short distance, and a voltage drop, energy loss, or inductive noise can be reduced.

### FIFTH MODIFICATION EXAMPLE OF EIGHTH CONFIGURATION EXAMPLE OF THREE-LAYER CONDUCTOR LAYER

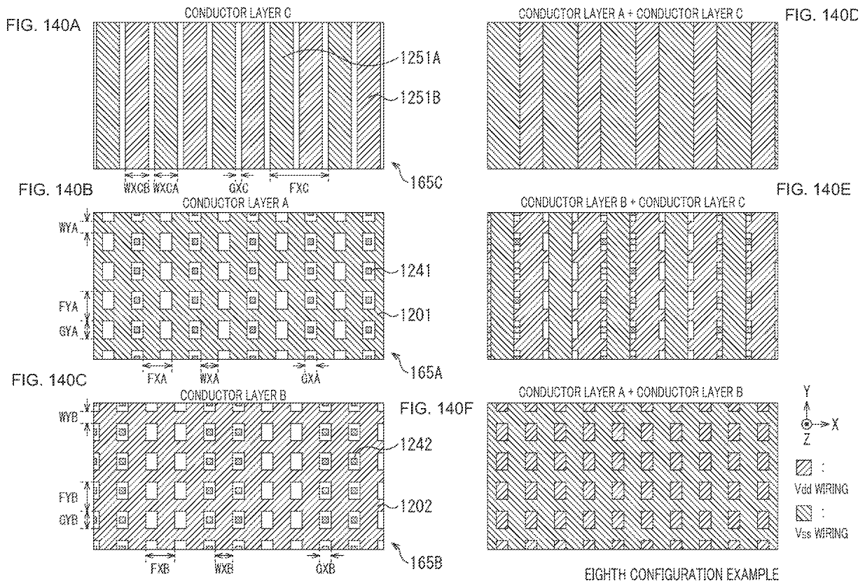

FIG. 140 illustrates a fifth modification example of the eighth configuration example of the three-layer conductor layer.

A of FIG. 140 illustrates the conductor layer C (wiring layer 165C), B of FIG. 140 illustrates the conductor layer A (wiring layer 165A), and C of FIG. 140 illustrates the conductor layer B (wiring layer 165B).

D of FIG. 140 is a plan view in a state in which the conductor layer A and the conductor layer C are stacked, E of FIG. 140 is a plan view in a state in which the conductor layer B and the conductor layer C are stacked, and F of FIG. 140 is a plan view in a state in which the conductor layer A and the conductor layer B are stacked.

The fifth modification example of the eighth configuration example of FIG. 140 has a configuration in which a part of the first modification example of the eighth configuration example illustrated in FIG. 136 is changed. In FIG. 140, portions corresponding to those in FIG. 136 are denoted by the same reference signs, description of the portions will be appropriately omitted, and different portions will be described.

The fifth modification example of the eighth configuration example differs from the first modification example of the eighth configuration example in FIG. 136 in only a configuration of the conductor layer B.

In the first modification example of FIG. 136, in the conductor layer B, a column in which the relay conductors 1242 are formed and a column in which the relay conductors 1242 are not formed are alternately arranged in units of columns in the X direction in the gaps in a matrix form of the mesh conductors 1202. In other words, the relay conductors 1241 are thinned out every other row in units of columns.

On the other hand, in the conductor layer B of FIG. 140, a column in which the relay conductors 1242 are formed and a column in which the relay conductors 1242 are not formed are alternately arranged in units of two columns in the X direction in the gaps in a matrix form of the mesh conductors 1202. In other words, the relay conductors 1241 are thinned out every two columns in units of two columns.

The fifth modification example of the eighth configuration example of FIG. 140 is the same as the first modification example of the eighth configuration example of FIG. 136 except for the points described above.

When the conductor layer C in A of FIG. 140 is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 140 such that the hot carrier light emitted from the active element group 167 can be shielded, and the stack of the conductor layers A and C also has a light shielding structure as illustrated in D of FIG. 140 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, when the mesh conductor 1201 of the conductor layer A and the straight conductor 1251A of the conductor layer C are electrically connected to each other and the mesh conductor 1202 of the conductor layer B and the straight conductor 1251B of the conductor layer C are electrically connected to each other, an amount of current flowing through the conductor layers A and B can be reduced and thus, it is possible to further reduce inductive noise or voltage drop from the conductor layer A or B.

In the conductor layer C in A of FIG. 140, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

By providing the relay conductor 1241 in the conductor layer A, it becomes possible to connect the mesh conductor 1202 and the straight conductor 1251B at a substantially shortest distance or a short distance to draw a power supply, and it is possible to reduce a voltage drop, energy loss, or inductive noise.

By providing the relay conductor 1242 on the conductor layer B, the mesh conductor 1201 and the straight conductor 1251A can be connected to each other at a substantially shortest distance or a short distance, and a voltage drop, energy loss, or inductive noise can be reduced.

### NINTH CONFIGURATION EXAMPLE OF THREE-LAYER CONDUCTOR LAYER

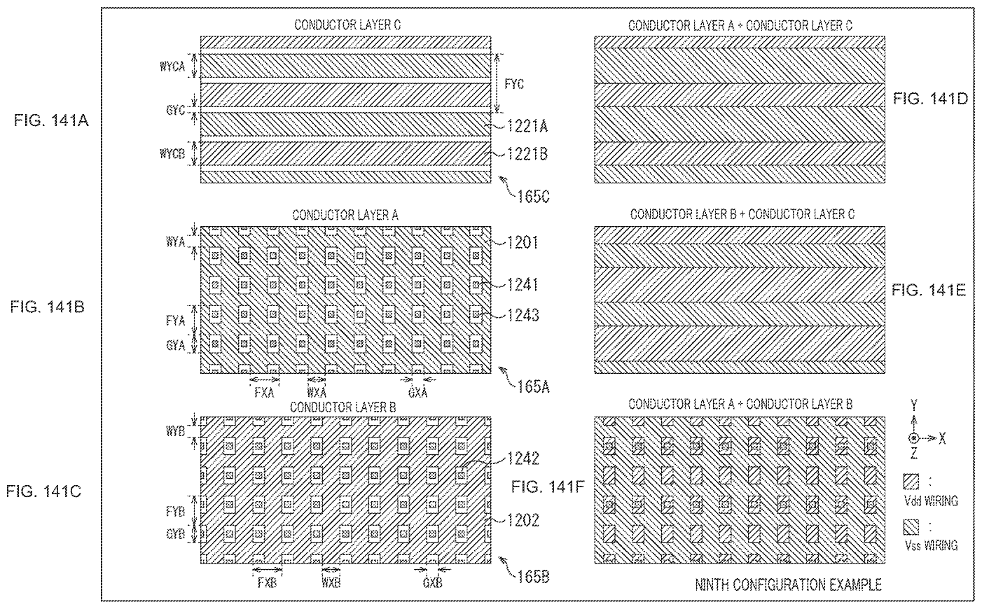

FIG. 141 illustrates a ninth configuration example of the three-layer conductor layer.

A of FIG. 141 illustrates the conductor layer C (wiring layer 165C), B of FIG. 141 illustrates the conductor layer A (wiring layer 165A), and C of FIG. 141 illustrates the conductor layer B (wiring layer 165B).

Further, D of FIG. 141 is a plan view in a state in which the conductor layers A and C are stacked, E of FIG. 141 is a plan view in a state in which the conductor layers B and C are stacked, and F of FIG. 141 is a plan view in a state in which the conductor layer A and the conductor layer B are stacked.

The ninth configuration example in FIG. 141 has a configuration in which the sixth configuration example in FIG. 132 is partially modified. In FIG. 141, portions corresponding to those in FIG. 132 are denoted by the same reference signs, description of the portions will be appropriately omitted, and different portions will be described.

The ninth configuration example differs from the sixth configuration example in FIG. 132 in only the configuration of the conductor layer A.

In the conductor layer A of the sixth configuration example in FIG. 132, a row in which the relay conductors 1241 are formed and a row in which the relay conductors 1241 are not formed are alternately arranged in units of rows in the Y direction in the gaps of the mesh conductor 1201 in a matrix form.

The conductor layer A of the ninth configuration example of FIG. 141 has a configuration in which a relay conductor 1243 (third relay conductor) is newly provided in the gap between the rows in which the relay conductor 1241 of the conductor layer A of the sixth configuration example of FIG. 132 is not formed. The relay conductor 1243 is, for example, a wiring (Vss wiring) connected to GND or a negative power supply.

That is, the conductor layer A of the ninth configuration example of FIG. 141 includes the mesh conductors 1201, and has a configuration in which a row in which the relay conductors 1241 are formed and a row in which the relay conductors 1243 are formed are alternately arranged in units of rows in the Y direction in gaps of the mesh conductors 1201 in a matrix form.

For example, when the conductor layers A to C of the ninth configuration example of FIG. 141 are arranged in a stacking order of the conductor layer B, the conductor layer C, and the conductor layer A, in which the conductor layer C is arranged in the middle, the relay conductor 1242 of the conductor layer B can be connected to the straight conductor 1221A of the conductor layer C by a conductor via in the Z direction, and the mesh conductor 1202 of the conductor layer B can be connected to the straight conductor 1221B of the conductor layer C by a conductor via in the Z direction. Further, the relay conductor 1241 of the conductor layer A can be connected to the straight conductor 1221B of the conductor layer C by a conductor via in the Z direction, and the relay conductor 1243 can be connected to the straight conductor 1221A of the conductor layer C by a conductor via in the Z direction. Further, the mesh conductor 1201 of the conductor layer A can be connected to the straight conductor 1221A of the conductor layer C by the conductor via in the Z direction. Further, the relay conductor 1243 may be connected to a conductor in a conductor layer different from the conductor layers A to C by a conductor via in the Z direction. Further, all of the relay conductors 1243 may not be used for electrical connection, all of the relay conductors 1243 may be used for electrical connection, and some of the relay conductors 1243 may be used for electrical connection.

By providing the relay conductor 1241 in the conductor layer A, it is possible to make a connection to the straight conductor 1221B at a substantially shortest distance or a short distance, and it is possible to reduce a voltage drop, energy loss, or inductive noise.

By providing the relay conductor 1243 on the conductor layer A, it is possible to make a connection to the straight conductor 1221A at a substantially shortest distance or a short distance, and it is possible to reduce a voltage drop, energy loss, or inductive noise.

By providing the relay conductor 1242 on the conductor layer B, it is possible to make a connection to the straight conductor 1221A at a substantially shortest distance or a short distance, and it is possible to reduce a voltage drop, energy loss, or inductive noise.

The ninth configuration example of FIG. 141 is the same as the sixth configuration example of FIG. 132 except for the points described above.

The conductor layer C in A of FIG. 141 is the same as the conductor layer C of the sixth configuration example in FIG. 132. Therefore, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 141 such that the hot carrier light emitted from the active element group 167 can be shielded, and the stack of the conductor layers A and C and the stack of the conductor layers B and C also have a light shielding structure as illustrated in D and E of FIG. 141 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

In the ninth configuration example of FIG. 141, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse (it is difficult for a current to concentrate), it is possible to further reduce the inductive noise.

### FIRST MODIFICATION EXAMPLE OF NINTH CONFIGURATION EXAMPLE OF THREE-LAYER CONDUCTOR LAYER

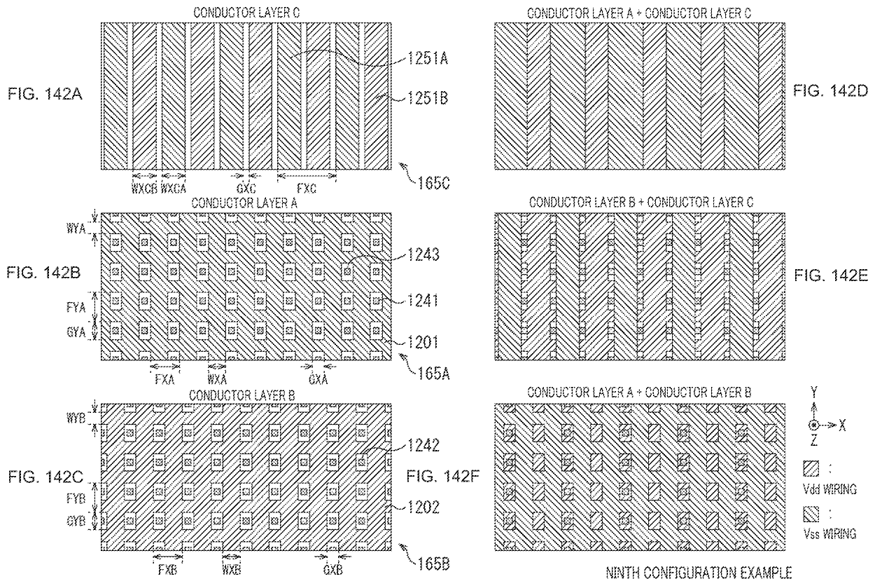

FIG. 142 illustrates a first modification example of the ninth configuration example of the three-layer conductor layer.

A of FIG. 142 illustrates the conductor layer C (wiring layer 165C), B of FIG. 142 illustrates the conductor layer A (wiring layer 165A), and C of FIG. 142 illustrates the conductor layer B (wiring layer 165B).

Further, D of FIG. 142 is a plan view in a state in which the conductor layers A and C are stacked, E of FIG. 142 is a plan view in a state in which the conductor layers B and C are stacked, and F of FIG. 142 is a plan view in a state in which the conductor layer A and the conductor layer B are stacked.

The first modification example of the ninth configuration example has a structure in which a part of the first modification example of the sixth configuration example of FIG. 133 is changed. In FIG. 142, portions corresponding to those in FIG. 133 are denoted by the same reference signs, description of the portions will be appropriately omitted, and different portions will be described.

The first modification example of the ninth configuration example differs from the first modification example of the sixth configuration example in FIG. 133 in only the configuration of the conductor layer A.

In the conductor layer A of the first modification example of the sixth configuration example of FIG. 133, a column in which the relay conductors 1241 are formed and a column in which the relay conductors 1241 are not formed are alternately arranged in units of columns in the Y direction in the gaps of the mesh conductor 1201 in a matrix form.

The conductor layer A of the first modification example of the ninth configuration example of FIG. 142 has a configuration in which the relay conductor 1243 is newly provided in a gap between rows in which the relay conductor 1241 of the conductor layer A of the first modification example of the sixth configuration example of FIG. 133 is not formed.

That is, the conductor layer A of the first modification example of the ninth configuration example of FIG. 142 has a configuration in which the conductor layer A has the mesh conductor 1201, and a column in which the relay conductors 1241 are formed and a column in which the relay conductors 1243 are formed are alternately arranged in units of columns in the X direction in the gaps of the mesh conductor 1201 in a matrix form.

For example, when the conductor layers A to C of the ninth configuration example of FIG. 142 are arranged in a stacking order of the conductor layer B, the conductor layer C, and the conductor layer A, in which the conductor layer C is arranged in the middle, the relay conductor 1242 of the conductor layer B is connected to the straight conductor 1251A of the conductor layer C, and the mesh conductor 1202 of the conductor layer B can be connected to the straight conductor 1251B of the conductor layer C by a conductor via in the Z direction. Further, the relay conductor 1241 of the conductor layer A can be connected to the straight conductor 1251B of the conductor layer C, and the relay conductor 1243 can be connected to the straight conductor 1251A of the conductor layer C. Further, the mesh conductor 1201 of the conductor layer A and the straight conductor 1251A of the conductor layer C can be connected by a conductor via in the Z direction.

By providing the relay conductor 1241 in the conductor layer A, it is possible to make a connection to the straight conductor 1251B at a substantially shortest distance or a short distance, and it is possible to reduce a voltage drop, energy loss, or inductive noise.

By providing the relay conductor 1243 on the conductor layer A, it is possible to make a connection to the straight conductor 1251A at a substantially shortest distance or a short distance, and a voltage drop, energy loss, or inductive noise can be reduced.

By providing the relay conductor 1242 on the conductor layer B, it is possible to make a connection to the straight conductor 1251A at a substantially shortest distance or a short distance, and it is possible to reduce a voltage drop, energy loss, or inductive noise.

The first modification example of the ninth configuration example of FIG. 142 is the same as the first modification example of the sixth configuration example of FIG. 133 except for the points described above.

The conductor layer C in A of FIG. 142 is the same as the conductor layer C of the sixth configuration example in FIG. 132. Therefore, when the conductor layer C is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 142 such that the hot carrier light emitted from the active element group 167 can be shielded, and the stack of the conductor layers A and C also has a light shielding structure as illustrated in D of FIG. 142 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

In the first modification example of the ninth configuration example of FIG. 142, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

### SECOND MODIFICATION EXAMPLE OF NINTH CONFIGURATION EXAMPLE OF THREE-LAYER CONDUCTOR LAYER

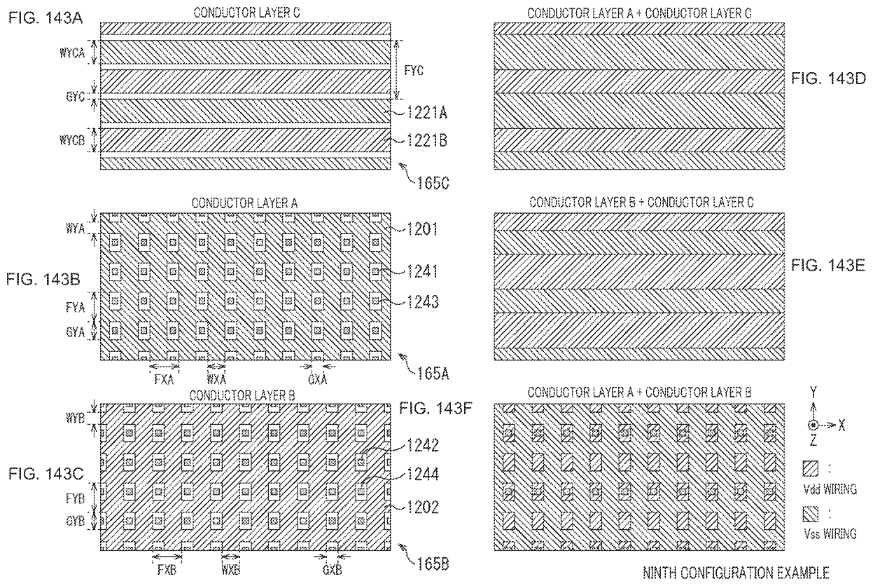

FIG. 143 illustrates a second modification example of the ninth configuration example of the three-layer conductor layer.

A of FIG. 143 illustrates the conductor layer C (wiring layer 165C), B of FIG. 143 illustrates the conductor layer A (wiring layer 165A), and C of FIG. 143 illustrates the conductor layer B (wiring layer 165B).

Further, D of FIG. 143 is a plan view in a state in which the conductor layers A and C are stacked, E of FIG. 143 is a plan view in a state in which the conductor layers B and C are stacked, and F of FIG. 143 is a plan view in a state in which the conductor layer A and the conductor layer B are stacked.

The second modification example of the ninth configuration example has a configuration in which the ninth configuration example of FIG. 141 is partially modified. In FIG. 143, portions corresponding to those in FIG. 141 are denoted by the same reference signs, description of the portions will be appropriately omitted, and different portions will be described.

The second modification example of the ninth configuration example differs from the ninth configuration example of FIG. 141 in only a configuration of the conductor layer B.

The conductor layer B of the ninth configuration example of FIG. 141 has the mesh conductor 1202, and the relay conductors 1242 are formed in all the gaps in a matrix form of the mesh conductors 1202.

On the other hand, in the second modification example of the ninth configuration example of FIG. 143, a row in which the relay conductors 1242 are formed in the respective gaps of the mesh conductor 1201 and a row in which the relay conductors 1244 (fourth relay conductors) are formed are alternately arranged in units of rows in the Y direction. The relay conductor 1244 is, for example, a wiring (Vdd wiring) connected to a positive power supply.

For example, when the conductor layers A to C of the second modification example of the ninth configuration example of FIG. 143 are arranged in a stacking order of the conductor layer B, the conductor layer A, and the conductor layer C, in which the conductor layer A is arranged in the middle, the relay conductor 1242 of the conductor layer B is connected to the mesh conductor 1201 of the conductor layer C by a conductor via in the Z direction, and the relay conductor 1244 of the conductor layer B is connected to the mesh conductor 1202 of the conductor layer B via a conductor of a conductor layer different from the conductive layers A to C. Further, the mesh conductor 1202 of the conductor layer B can be connected to the relay conductor 1241 of the conductor layer A by the conductor via in the Z direction. The relay conductor 1241 of the conductor layer A can be connected to the straight conductor 1221B of the conductor layer C by a conductor via in the Z direction, and the relay conductor 1243 can be connected to the straight conductor 1221A of the conductor layer C by a conductor via in the Z direction. Further, the mesh conductor 1201 of the conductor layer A can be connected to the straight conductor 1221A of the conductor layer C by a conductor via in the Z direction. Further, all of the relay conductors 1244 may not be used for electrical connection, all of the relay conductors 1244 may be used for electrical connection, and some of the relay conductors 1244 may be used for electrical connection. In the second modification example of the ninth configuration example of FIG. 143, although there is a displacement, the Vdd wiring and the Vss wiring in the conductor layers A and B have the same or substantially the same shape. Therefore, the layout of the conductor layers A to C can be easily designed and it is easy for the Vdd wiring and the Vss wiring to have a suitable current relationship or voltage relationship in some cases.

By providing the relay conductor 1241 in the conductor layer A, it is possible to make a connection to the straight conductor 1221B at a substantially shortest distance or a short distance, and it is possible to reduce a voltage drop, energy loss, or inductive noise.

By providing the relay conductor 1243 on the conductor layer A, it is possible to make a connection to the straight conductor 1221A at a substantially shortest distance or a short distance, and it is possible to reduce a voltage drop, energy loss, or inductive noise.

By providing the relay conductor 1242 on the conductor layer B, it is possible to make a connection to the straight conductor 1221A at a substantially shortest distance or a short distance, and it is possible to reduce a voltage drop, energy loss, or inductive noise.

By providing the relay conductor 1244 on the conductor layer B, it is possible to make a connection to the straight conductor 1221B at a substantially shortest distance or a short distance, and it is possible to reduce a voltage drop, energy loss, or inductive noise.

The second modification example of the ninth configuration example of FIG. 143 is the same as the ninth configuration example of FIG. 141, except for the points described above.

The conductor layer C in A of FIG. 143 is the same as the conductor layer C of the ninth configuration example in FIG. 141. Therefore, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 143 such that the hot carrier light emitted from the active element group 167 can be shielded, and the stack of the conductor layers A and C and the stack of the conductor layers B and C also have a light shielding structure as illustrated in D and E of FIG. 143 such that the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

In the ninth configuration example of FIG. 143, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse (it is difficult for a current to concentrate), it is possible to further reduce the inductive noise.

### THIRD MODIFICATOIN EXAMPLE OF NINTH CONFIGURATION EXAMPLE OF THREE-LAYER CONDUCTOR LAYER

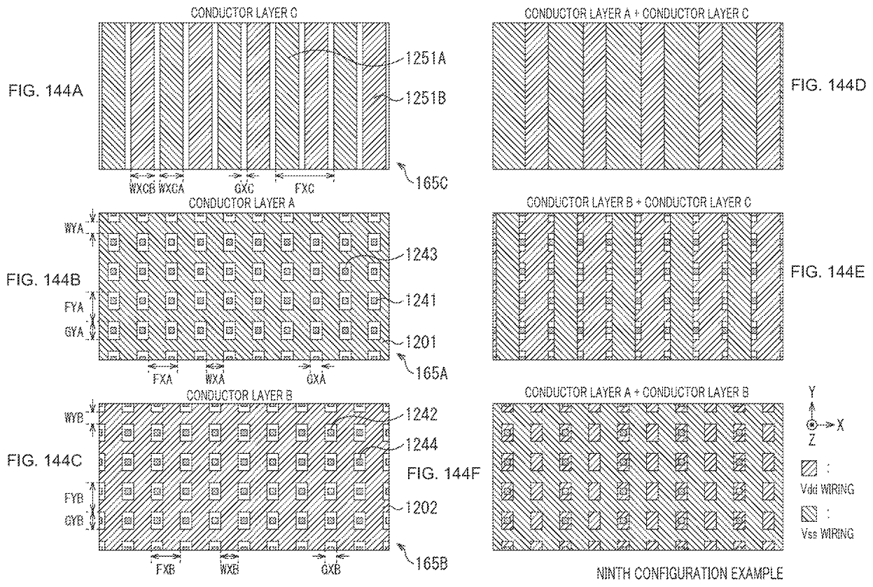

FIG. 144 illustrates a third modification example of the ninth configuration example of the three-layer conductor layer.

A of FIG. 144 illustrates the conductor layer C (wiring layer 165C), B of FIG. 144 illustrates the conductor layer A (wiring layer 165A), and C of FIG. 144 illustrates the conductor layer B (wiring layer 165B).

Further, D in FIG. 144 is a plan view in a state in which the conductor layer A and the conductor layer C are stacked, E of FIG. 144 is a plan view in a state in which the conductor layer B and the conductor layer C are stacked, and F of FIG. 144 is a plan view in a state in which the conductor layer A and the conductor layer B are stacked.

The third modification example of the ninth configuration example has a configuration in which a part of the first modification example of the ninth configuration example of FIG. 142 is changed. In FIG. 144, portions corresponding to those in FIG. 142 are denoted by the same reference signs, description of the portions will be appropriately omitted, and different portions will be described.

The third modification example of the ninth configuration example differs from the first modification example of the ninth configuration example in FIG. 142 in only the configuration of the conductor layer B.

The conductor layer B of the first modification example of the ninth configuration example of FIG. 142 has the mesh conductor 1202, and the relay conductors 1242 are formed in all the gaps in a matrix form of the mesh conductors 1202.

On the other hand, the conductor layer B of the third modification example of the ninth configuration example of FIG. 144 has a configuration in which the conductor layer B has the mesh conductor 1202, and a column in which the relay conductors 1242 are formed and a column in which the relay conductors 1244 are formed are alternately arranged in units of columns in the X direction in the gaps of the mesh conductor 1202 in a matrix form.

For example, when the conductor layers A to C of the third modification example of the ninth configuration example of FIG. 144 are arranged in a stacking order of the conductor layer B, the conductor layer A, and the conductor layer C, in which the conductor layer A is arranged in the middle, the relay conductor 1242 of the conductor layer B is connected to the mesh conductor 1201 of the conductor layer A by a conductor via in the Z direction, and the relay conductor 1244 of the conductor layer B is connected to the mesh conductor 1202 of the conductor layer B via a conductor of a conductor layer different from the conductor layers A to C. Further, the mesh conductor 1202 of the conductor layer B can be connected to the relay conductor 1241 of the conductor layer A by a conductor via in the Z direction. The relay conductor 1241 of the conductor layer A can be connected to the straight conductor 1251B of the conductor layer C by a conductor via in the Z direction, and the relay conductor 1243 can be connected to the straight conductor 1251A of the conductor layer C by a conductor via in the Z direction. Further, the mesh conductor 1201 of the conductor layer A can be connected to the straight conductor 1251A of the conductor layer C by a conductor via in the Z direction. In the third modification example of the ninth configuration example of FIG. 144, there is a displacement, but the Vdd wiring and the Vss wiring in the conductor layers A and B have the same or substantially the same shape. Therefore, the layout of the conductor layers A to C may be able to be easily designed, and it may be easy for the Vdd wiring and the Vss wiring to have a suitable current relationship or voltage relationship.

By providing the relay conductor 1241 in the conductor layer A, it is possible to make a connection to the straight conductor 1251B at a substantially shortest distance or a short distance, and it is possible to reduce a voltage drop, energy loss, or inductive noise.

By providing the relay conductor 1243 on the conductor layer A, it is possible to make a connection to the straight conductor 1251A at a substantially shortest distance or a short distance, and a voltage drop, energy loss, or inductive noise can be reduced.

By providing the relay conductor 1242 on the conductor layer B, it is possible to make a connection to the straight conductor 1251A at a substantially shortest distance or a short distance, and it is possible to reduce a voltage drop, energy loss, or inductive noise.

By providing the relay conductor 1244 on the conductor layer B, it is possible to make a connection to the straight conductor 1251B at a substantially shortest distance or a short distance, and it is possible to reduce a voltage drop, energy loss, or inductive noise.

The third modification example of the ninth configuration example of FIG. 144 is the same as the first modification example of the ninth configuration example of FIG. 142 except for the points described above.

The conductor layer C in A of FIG. 144 is the same as the conductor layer C of the first modification example of the ninth configuration example of FIG. 142. Therefore, when the conductor layer C is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

The stack of the conductor layers A and B has a light shielding structure as illustrated in F of FIG. 144 such that the hot carrier light emitted from the active element group 167 can be shielded, and the stack of the conductor layers A and C also has a light shielding structure as illustrated in D of FIG. 144 such that the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

In the third modification example of the ninth configuration example of FIG. 144, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

### FOURTH MODIFICATION EXAMPLE OF NINTH CONFIGURATION EXAMPLE OF THREE-LAYER CONDUCTOR LAYER

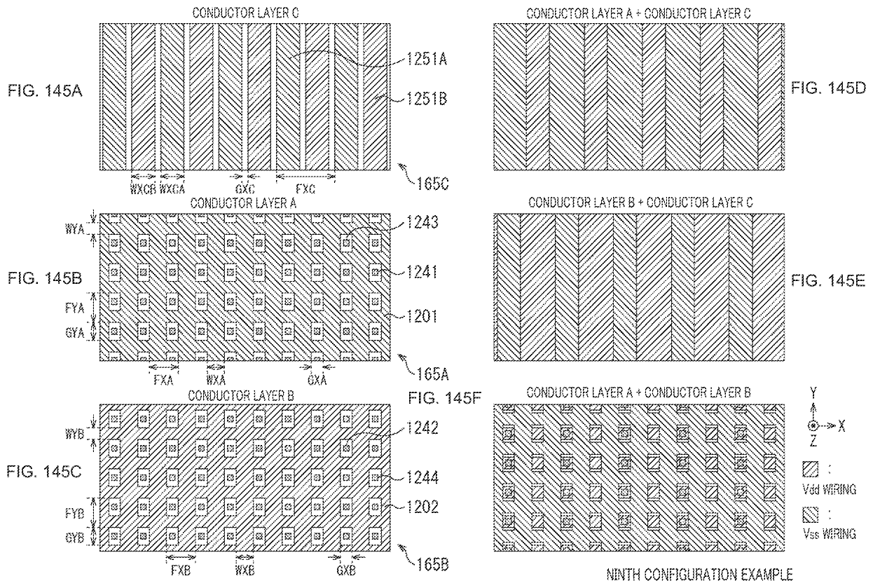

FIG. 145 illustrates a fourth modification example of the ninth configuration example of the three-layer conductor layer.

A of FIG. 145 illustrates a conductor layer C (wiring layer 165C), B of FIG. 145 illustrates a conductor layer A (wiring layer 165A), and C of FIG. 145 illustrates a conductor layer B (wiring layer 165B).

Further, D in FIG. 145 is a plan view in a state in which the conductor layers A and C are stacked, E of FIG. 145 is a plan view in a state in which the conductor layers B and C are stacked, and F of FIG. 145 is a plan view in a state in which the conductor layer A and the conductor layer B are stacked.

The fourth modification example of the ninth configuration example has a configuration in which a part of the third modification example of the ninth configuration example of FIG. 144 is changed. In FIG. 145, portions corresponding to those in FIG. 144 are denoted by the same reference signs, description of the portions will be appropriately omitted, and different portions will be described.

In the third modification example of FIG. 144, when the positions of the gaps of the mesh conductor 1201 of the conductor layer A and the mesh conductor 1202 of the conductor layer B are compared with each other, the positions in the X direction differ and the positions in the Y direction match.

On the other hand, in the fourth modification example of FIG. 145, when the positions of the gaps of the mesh conductor 1201 of the conductor layer A and the mesh conductor 1202 of the conductor layer B are compared with each other, the positions in the X direction match and the positions in the Y direction differ.

Further, for example, when positions of the relay conductor 1241 of the conductor layer A is compared with positions of the relay conductor 1244 of the conductor layer B, the positions in the X direction differ and the positions in the Y direction match in the third modification example of FIG. 144. On the other hand, in the fourth modification example of FIG. 145, the positions in the X direction are the same and the positions in the Y direction differ.

Further, for example, when positions of the relay conductor 1243 of the conductor layer A is compared with positions of the relay conductor 1242 of the conductor layer B, the positions in the X direction differ and the positions in the Y direction match in the third modification example of FIG. 144. On the other hand, in the fourth modification example of FIG. 145, the positions in the X direction are the same and the positions in the Y direction differ.

In the third modification example of FIG. 144, the stack of the conductor layers A and B and the stack of the conductor layers A and C have a light shielding structure, and the light shielding property is maintained. On the other hand, in the fourth modification example of FIG. 145, the stack of the conductor layers A and C and the stack of the conductor layers B and C have a light shielding structure, and the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

Further, for example, when the conductor layers A to C of the fourth modification example of the ninth configuration example of FIG. 145 are arranged in a stacking order of the conductor layer B, the conductor layer C, and the conductor layer A, in which the conductor layer C is arranged in the middle, the relay conductor 1242 of the conductor layer B is connected to the straight conductor 1251A of the conductor layer C by a conductor via in the Z direction, and the relay conductor 1244 of the conductor layer B is connected to the straight conductor 1251B of the conductor layer C by a conductor via in the Z direction C. Further, the mesh conductor 1202 of the conductor layer B can be connected to the straight conductor 1251B of the conductor layer C by a conductor via in the Z direction. The relay conductor 1241 of the conductor layer A can be connected to the straight conductor 1251B of the conductor layer C by a conductor via in the Z direction, and the relay conductor 1243 can be connected to the straight conductor 1251A of the conductor layer C by a conductor via in the Z direction. Further, the mesh conductor 1201 of the conductor layer A can be connected to the straight conductor 1251A of the conductor layer C by a conductor via in the Z direction. Further, the relay conductor 1244 may be connected to a conductor in a conductor layer different from the conductor layers A to C by a conductor via in the Z direction.

The fourth modification example of FIG. 145 is the same as the third modification example of FIG. 144 except for the points described above.

When the conductor layer C in A of FIG. 145 is viewed in a predetermined planar range (planar region), the current distribution of the straight conductor 1251A is the same or substantially the same as the current distribution of the straight conductor 1251B and thus, it is possible to curb the occurrence of the inductive noise.

Since the straight conductor 1251A and the straight conductor 1251B have the same wiring pattern repeated in the X direction, it is possible to completely offset the capacitive noise in the X direction. It is possible to greatly reduce the capacitive noise when the conductor layer C is closer to the wiring layer 170.

In the fourth modification example of the ninth configuration example of FIG. 145, a direction in which it is easy for a current to flow in the conductor layer C is the same or substantially the same as a direction in which it is easy for a current to flow in the conductor layers A and B. In this case, it is possible to further reduce the voltage drop depending on the wiring layout.

By providing the relay conductor 1241 in the conductor layer A, it is possible to make a connection to the straight conductor 1251B at a substantially shortest distance or a short distance, and it is possible to reduce a voltage drop, energy loss, or inductive noise.

By providing the relay conductor 1243 on the conductor layer A, it is possible to make a connection to the straight conductor 1251A at a substantially shortest distance or a short distance, and a voltage drop, energy loss, or inductive noise can be reduced.

By providing the relay conductor 1242 on the conductor layer B, it is possible to make a connection to the straight conductor 1251A at a substantially shortest distance or a short distance, and it is possible to reduce a voltage drop, energy loss, or inductive noise.

By providing the relay conductor 1244 on the conductor layer B, it is possible to make a connection to the straight conductor 1251B at a substantially shortest distance or a short distance, and it is possible to reduce a voltage drop, energy loss, or inductive noise.

### TENTH CONFIGURATION EXAMPLE OF THREE-LAYER CONDUCTOR LAYER

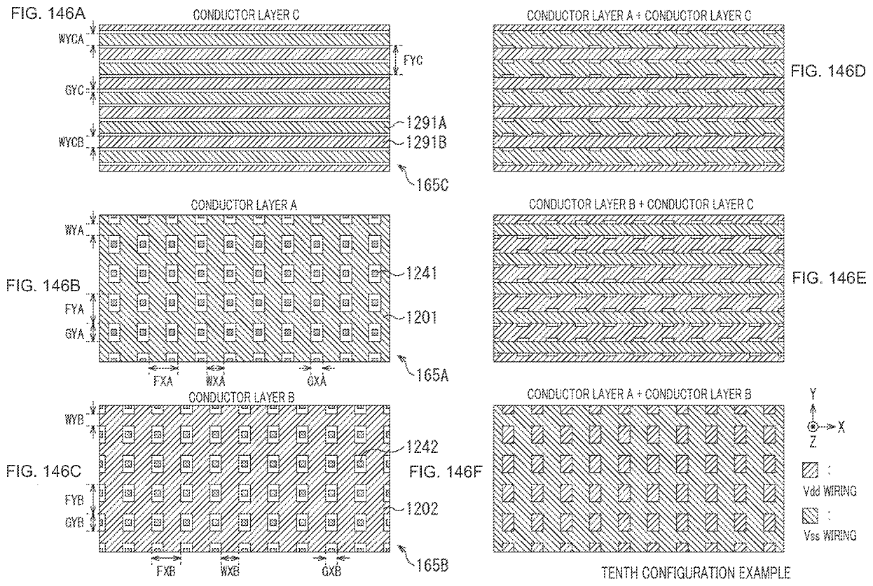

FIG. 146 illustrates a tenth configuration example of the three-layer conductor layer.

A of FIG. 146 illustrates the conductor layer C (wiring layer 165C), B of FIG. 146 illustrates the conductor layer A (wiring layer 165A), and C of FIG. 146 illustrates the conductor layer B (wiring layer 165B).

Further, D of FIG. 146 is a plan view in a state in which the conductor layers A and C are stacked, E of FIG. 146 is a plan view in a state in which the conductor layers B and C are stacked, and F of FIG. 146 is a plan view in a state in which the conductor layer A and the conductor layer B are stacked.

The tenth configuration example has a configuration in which the fourth configuration example of FIG. 128 is partially modified. In FIG. 146, portions corresponding to those in FIG. 128 are denoted by the same reference signs, description of the portions will be appropriately omitted, and different portions will be described.

In the tenth configuration example, only a configuration of the conductor layer C differs from the fourth configuration example in FIG. 128.

The conductor layer C in A of FIG. 146 has a configuration in which a straight conductor 1291A long in the X direction and a straight conductor 1291B long in the X direction are alternately arranged periodically in the Y direction. The straight conductor 1219 A is, for example, a wiring (Vss wiring) connected to GND or a negative power supply. The straight conductor 1291B is, for example, a wiring (Vdd wiring) connected to a positive power supply.

In the fourth configuration example of FIG. 128, the conductor period FYC that is a repetition period of the straight conductor 1221A of the conductor layer C of FIG. 128 is twice the conductor period FYA that is a repetition period in the Y direction of the mesh conductor 1201 of the conductor layer A in B of FIG. 128.

On the other hand, the conductor period FYC that is a repetition period of the straight conductor 1291A of the conductor layer C in A of FIG. 146 is one time the conductor period FYA that is a repetition period in the Y direction of the mesh conductor 1201 of the conductor layer A in B of FIG. 146.

Similarly, in the fourth configuration example of FIG. 128, the conductor period FYC of the straight conductor 1221B of the conductor layer C in A of FIG. 128 is twice the conductor period FYB of the mesh conductor 1202 of the conductor layer B in C of FIG. 128, whereas the conductor period FYC of the straight conductor 1291B of the conductor layer C in A of FIG. 146 is one time the conductor period FYB of the mesh conductor 1202 of the conductor layer B in C of FIG. 146.

The tenth configuration example of FIG. 146 is the same as the fourth configuration example of FIG. 128 except for the points described above.

When the conductor layer C in A of FIG. 146 is viewed in a predetermined planar range (planar region), a current distribution of the straight conductor 1291A is the same or substantially the same as the current distribution of the straight conductor 1291B and thus, it is possible to curb the occurrence of the inductive noise.

Since the straight conductor 1291A and the straight conductor 1291B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 146 such that the hot carrier light emitted from the active element group 167 can be shielded, and in the stack of the conductor layers A and C and the stack of the conductor layers B and C, the light shielding property is also maintained in a certain range, as illustrated in D and E of FIG. 132. Accordingly, since light shielding constraint of the conductor layers A and B can be mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

In the tenth configuration example of FIG. 146, a direction in which it is easy for a current to flow in the conductor layer C and a direction in which it is easy for a current to flow in the conductor layers A and B are substantially orthogonal and differ from each other by about 90 degrees. Accordingly, since it is easy for the current to diffuse (it is difficult for a current to concentrate), it is possible to further reduce the inductive noise.

By providing the relay conductor 1241 in the conductor layer A, it is possible to make a connection to the straight conductor 1291B at a substantially shortest distance or a short distance, and it is possible to reduce a voltage drop, energy loss, or inductive noise.

By providing the relay conductor 1242 on the conductor layer B, it is possible to make a connection to the straight conductor 1291A at a substantially shortest distance or a short distance, and it is possible to reduce a voltage drop, energy loss, or inductive noise.

### MODIFICATION EXAMPLES OF TENTH CONFIGURATION EXAMPLE OF THREE-LAYER CONDUCTOR LAYER

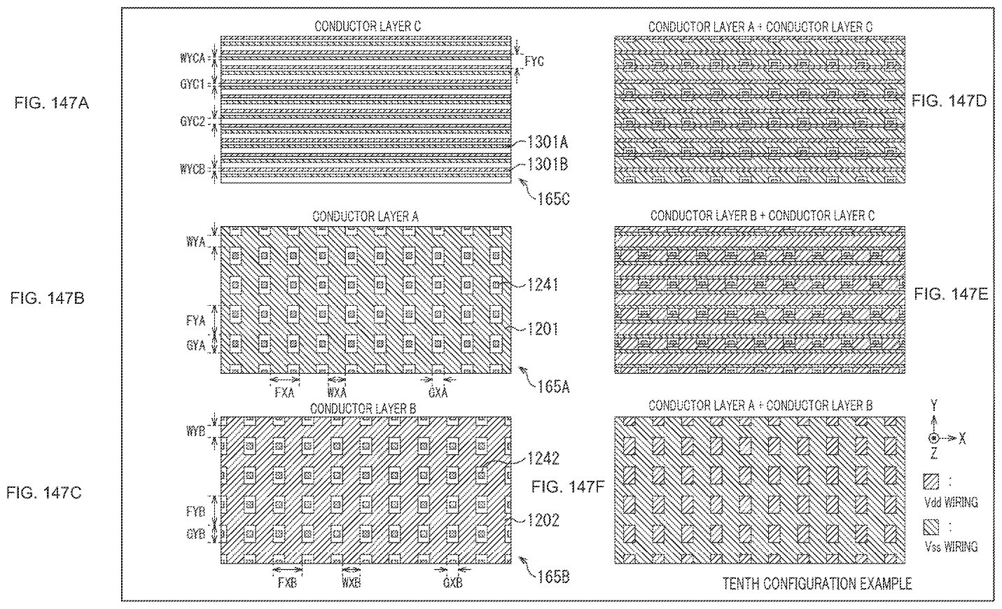

FIG. 147 illustrates a modification example of the tenth configuration example of the three-layer conductor layer.

A of FIG. 147 illustrates the conductor layer C (wiring layer 165C), B of FIG. 147 illustrates the conductor layer A (wiring layer 165A), and C of FIG. 147 illustrates the conductor layer B (wiring layer 165B).

Further, D of FIG. 147 is a plan view in a state in which the conductor layers A and C are stacked, E of FIG. 147 is a plan view in a state in which the conductor layers B and C are stacked, and F of FIG. 147 is a plan view in a state in which the conductor layer A and the conductor layer B are stacked.

The modification example of the tenth configuration example has a configuration in which the fourth configuration example of FIG. 128 is partially modified. In FIG. 147, portions corresponding to those in FIG. 128 are denoted by the same reference signs, description of the portions will be appropriately omitted, and different portions will be described.

In the modification example of the tenth configuration example, only a configuration of the conductor layer C differs from the fourth configuration example of FIG. 128.

The conductor layer C in A of FIG. 147 has a configuration in which a straight conductor 1301A long in the X direction and a straight conductor 1301B long in the X direction are alternately arranged periodically in the Y direction. The straight conductor 1301A is, for example, a wiring (Vss wiring) connected to GND or a negative power supply. The straight conductor 1301B is, for example, a wiring (Vdd wiring) connected to a positive power supply. Intervals between the straight conductor 1301A and the straight conductor 1301B are alternately arranged in a gap width GYC1 and a gap width GYC2.

In the fourth configuration example of FIG. 128, the conductor period FYC that is a repetition period of the straight conductor 1221A of the conductor layer C in A of FIG. 128 is twice the conductor period FYA that is a repetition period in the Y direction of the mesh conductor 1201 of the conductor layer A in B of FIG. 128.

On the other hand, the conductor period FYC that is a repetition period of the straight conductor 1301A of the conductor layer C in A of FIG. 147 is (1/integer) times the conductor period FYA that is a repetition period in the Y direction of the mesh conductor 1201 of the conductor layer A in B of FIG. 147. FIG. 147 illustrates an example in which the conductor period FYC is ½ times the conductor period FYA.

Similarly, in the fourth configuration example of FIG. 128, the conductor period FYC of the straight conductor 1221B of the conductor layer C in A of FIG. 128 is twice the conductor period FYB of the mesh conductor 1202 of the conductor layer A in C of FIG. 128, whereas the conductor period FYC of the straight conductor 1301B of the conductor layer C in A of FIG. 147 is (1/integer) times the conductor period FYB of the mesh conductor 1202 of the conductor layer B in C of FIG. 147. FIG. 147 illustrates an example in which the conductor period FYC is ½ times the conductor period FYB.

The modification example of the tenth configuration example of FIG. 147 is the same as the fourth configuration example of FIG. 128 except for the points described above.

When the conductor layer C in A of FIG. 147 is viewed in a predetermined planar range (planar region), a current distribution of the straight conductor 1301A is the same or substantially the same as a current distribution of the straight conductor 1301B and thus, it is possible to curb the occurrence of the inductive noise.

Since the straight conductor 1301A and the straight conductor 1301B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure as illustrated in F of FIG. 147 such that the hot carrier light emitted from the active element group 167 can be shielded, and in the stack of the conductor layers A and C and the stack of the conductor layers B and C, the light shielding property is also maintained in a certain range as illustrated in D and E of FIG. 132. Accordingly, since the light shielding constraint of the conductor layers A and B can be mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

In the modification example of the tenth configuration example of FIG. 147, a direction in which it is easy for a current to flow in the conductor layer C and a direction in which it is easy for a current to flow in the conductor layers A and B are substantially orthogonal and differ from each other by about 90 degrees.

Accordingly, since it is easy for the current to diffuse (it is difficult for a current to concentrate), it is possible to further reduce the inductive noise.

By providing the relay conductor 1241 in the conductor layer A, it is possible to make a connection to the straight conductor 1301B at a substantially shortest distance or a short distance, and a voltage drop, energy loss, or inductive noise can be reduced.

By providing the relay conductor 1242 on the conductor layer B, it is possible to make a connection to the straight conductor 1301A at a substantially shortest distance or a short distance, and it is possible to reduce a voltage drop, energy loss, or inductive noise.

### ELEVENTH CONFIGURATION EXAMPLE OF THREE-LAYER CONDUCTOR LAYER

The first to tenth configuration examples of the three-layer conductor layer in which the eleventh configuration example using the mesh conductor of which a resistance value in the X direction and a resistance value in the Y direction differ is adopted as the configurations of the conductor layers A and B have been described. In other words, the description in which the configuration in which the gap width GXA in the X direction differs from the gap width GYA in the Y direction and the gap width GXB in the X direction differs from the gap width GYB in the Y direction, as in the mesh conductors 1201 and 1202 of the fourth configuration example of FIG. 128 or the mesh conductors 1261 and 1602 of the fifth configuration example of FIG. 131, is adopted as the conductor layer A and the conductor layer B has been given.

However, for the conductor layers A and B, any one of the first to thirteenth configuration examples of the conductor layers A and B described in FIGS. 12 to 41 can be adopted.

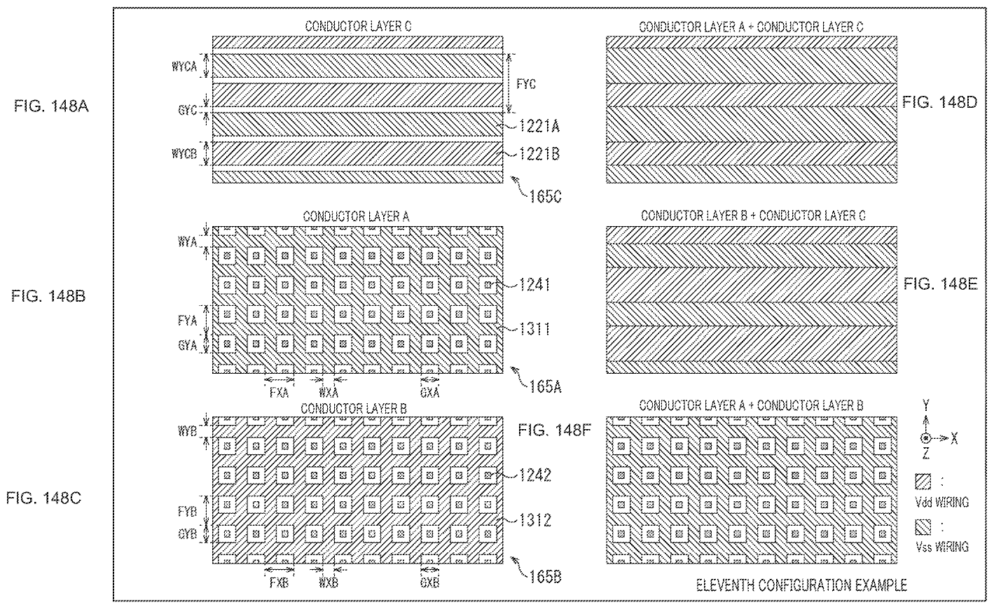

Next, a configuration in which the conductor layer C (wiring layer 165C) has the configuration adopted in FIG. 122 and the like, and mesh conductors of which a resistance value in the X direction is the same as a resistance value in the Y direction are adopted for the conductor layer A and the conductor layer B will be described with reference to FIGS. 148 to 152.

FIG. 148 illustrates the eleventh configuration example of the three-layer conductor layer.

A of FIG. 148 illustrates the conductor layer C (wiring layer 165C), B of FIG. 148 illustrates the conductor layer A (wiring layer 165A), and C of FIG. 148 illustrates the conductor layer B (wiring layer 165B).

Further, D of FIG. 148 is a plan view in a state in which the conductor layers A and C are stacked, E of FIG. 148 is a plan view in a state in which the conductor layers B and C are stacked, and F of FIG. 148 is a plan view in a state in which the conductor layer A and the conductor layer B are stacked.

In the eleventh configuration example of FIG. 148, portions corresponding to those of the fourth configuration example illustrated in FIG. 128 are denoted by the same reference signs, description of the portions will be appropriately omitted, and description will be focused on different portions.

The conductor layer C in A of FIG. 148 has a configuration in which the straight conductors 1221A long in the X direction and the straight conductors 1221B long in the X direction are alternately arranged periodically in the Y direction in the conductor period FYC.

The conductor layer A in B of FIG. 148 includes a mesh conductor 1311. The mesh conductor 1311 has a conductor width WXA, a gap width GXA, and a conductor period FXA in the X direction, and has a conductor width WYA, a gap width GYA, and a conductor period FYA in the Y direction. Here, conductor width WXA=conductor width WYA, gap width GXA=gap width GYA, and conductor period FXA=conductor period FYA. A relay conductor 1241 is arranged in each of the gaps of the mesh conductors 1201. Intervals between the relay conductors 1241, in other words, periods of the relay conductors 1241 also include the conductor period FXA and FYA. The mesh conductor 1311 is, for example, a wiring (Vss wiring) connected to GND or a negative power supply.

The conductor layer B in C of FIG. 148 includes a mesh conductor 1312. The mesh conductor 1312 has a conductor width WXB, a gap width GXB, and a conductor period FXB in the X direction, and has a conductor width WYB, a gap width GYB, and a conductor period FYB in the Y direction. Here, conductor width WXB=conductor width WYB, gap width GXB=gap width GYB, and conductor period FXB=conductor period FYB. Further, a relay conductor 1242 is arranged in each of gaps of the mesh conductor 1312. Intervals between the relay conductors 1242, in other words, periods of the relay conductors 1242 also include the conductor periods FXB and FYB. The mesh conductor 1312 is, for example, a wiring (Vdd wiring) connected to a positive power supply.

As illustrated in B and C of FIG. 148, a plane position of the relay conductor 1241 formed on the conductor layer A is the same as a plane position of the relay conductor 1242 formed on the conductor layer B. In other words, both the mesh conductor 1311 of the conductor layer A and the mesh conductor 1312 of the conductor layer B both overlap when viewed in a stacking direction. The conductor layer A and the conductor layer B having such a configuration correspond to the second configuration example of the conductor layers A and B illustrated in FIG. 15, and it is possible to greatly reduce the inductive noise as shown in the results of the simulation in FIG. 17.

Therefore, this is suitable in a stack order in which the conductor layer C (wiring layer 165C) is arranged between the conductor layer A (wiring layer 165A) and the conductor layer B (wiring layer 165B) as illustrated in B of FIG. 120, the mesh conductor 1311 of the conductor layer A and the straight conductor 1221A of the conductor layer C are connected by a conductor via in the Z direction, and the planar conductor 1312 of the conductor layer B and the straight conductor 1221B of the conductor layer C are connected by a conductor via in the Z direction.

When the conductor layer C is viewed in a predetermined planar range (planar region), the current distribution of the straight conductor 1221A is the same or substantially the same as the current distribution of the straight conductor 1221 B and thus, it is possible to curb the occurrence of inductive noise.

Since the straight conductor 1221A and the straight conductor 1221B of the conductor layer C have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B does not have a light shielding structure as illustrated in F of FIG. 148, but the light shielding structure is formed by the stack of the conductor layers A and C and the stack of the conductor layers B and C as illustrated in D and E of FIG. 148, and the light shielding property is maintained. Thereby, it is possible to shield the hot carrier light emitted from the active element group 167. Further, since light shielding constraints of the conductor layers A and B can be greatly mitigated, it is possible to maximize the use of the conductor area of the conductor layers A and B, and it is possible to reduce the wiring resistance and further reduce the voltage drop. It is possible to improve the degree of freedom in a layout of the conductor layers A and B.

### TWELFTH CONFIGURATION EXAMPLE OF THREE-LAYER CONDUCTOR LAYER

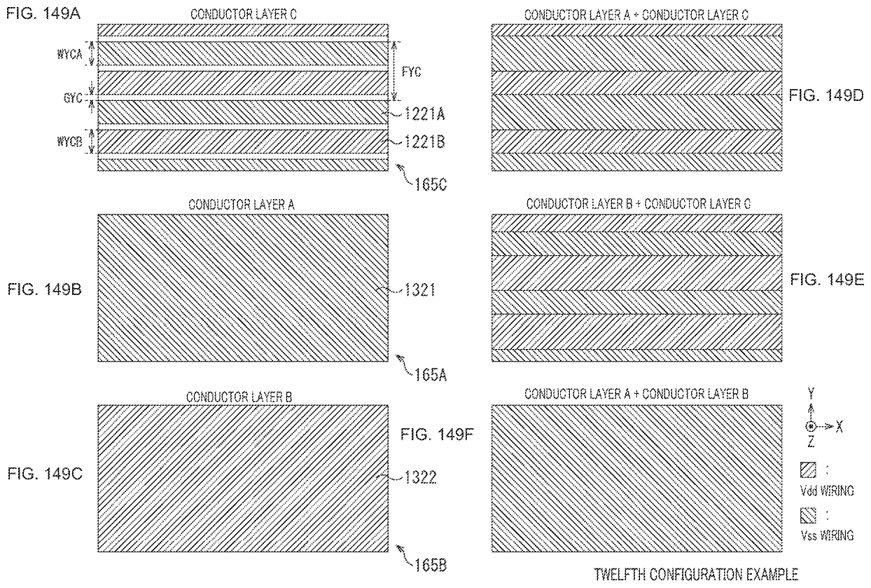

FIG. 149 illustrates a twelfth configuration example of the three-layer conductor layer.

A of FIG. 149 illustrates a conductor layer C (wiring layer 165C), B of FIG. 149 illustrates a conductor layer A (wiring layer 165A), and C of FIG. 149 illustrates a conductor layer B (wiring layer 165B).

Further, D of FIG. 149 is a plan view in a state in which the conductor layers A and C are stacked, E of FIG. 149 is a plan view in a state in which the conductor layers B and C are stacked, and F of FIG. 149 is a plan view in a state in which the conductor layer A and the conductor layer B are stacked.

In the twelfth configuration example of FIG. 149, portions corresponding to those of the fourth configuration example illustrated in FIG. 128 are denoted by the same reference signs, description of the portions will be appropriately omitted, and description will be focused on different portions.

The conductor layer C in A of FIG. 149 has a configuration in which the straight conductors 1221A long in the X direction and the straight conductors 1221B long in the X direction are alternately arranged periodically in the Y direction in the conductor period FYC.

The conductor layer A in B of FIG. 149 includes the planar conductor 1321. The planar conductor 1321 is, for example, a wiring (Vss wiring) connected to GND or a negative power supply.

The conductor layer B in C of FIG. 149 includes the planar conductor 1322. The planar conductor 1322 is, for example, a wiring (Vdd wiring) connected to a positive power supply.

When the conductor layer C is viewed in a predetermined planar range (planar region), the current distribution of the straight conductor 1221A is the same or substantially the same as the current distribution of the straight conductor 1221 B and thus, it is possible to curb the occurrence of inductive noise.

Since the straight conductor 1222A and the straight conductor 1222B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure, and it is possible to shield the hot carrier light emitted from the active element group 167 as illustrated in F of FIG. 149, and the stack of the conductor layers A and C and the stack of the conductor layers B and C also have a light shielding structure as illustrated in D and E of FIG. 149, and the light shielding property is maintained.

Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

The twelfth configuration example of the three-layer conductor layer is suitable in a stack order in which the conductor layer C (wiring layer 165C) as illustrated in B of FIG. 120 is arranged between the conductor layer A (wiring layer 165A) and the conductor layer B (wiring layer 165B), the planar conductor 1321 of the conductor layer A and the straight conductor 1221A of the conductor layer C are connected by a conductor via in the Z direction, and the mesh conductor 1322 of the conductor layer B and the straight conductor 1221B of the conductor layer C are connected by a conductor via in the Z direction.

### MODIFICATION EXAMPLES OF TWELFTH CONFIGURATION EXAMPLE OF THREE-LAYER CONDUCTOR LAYER

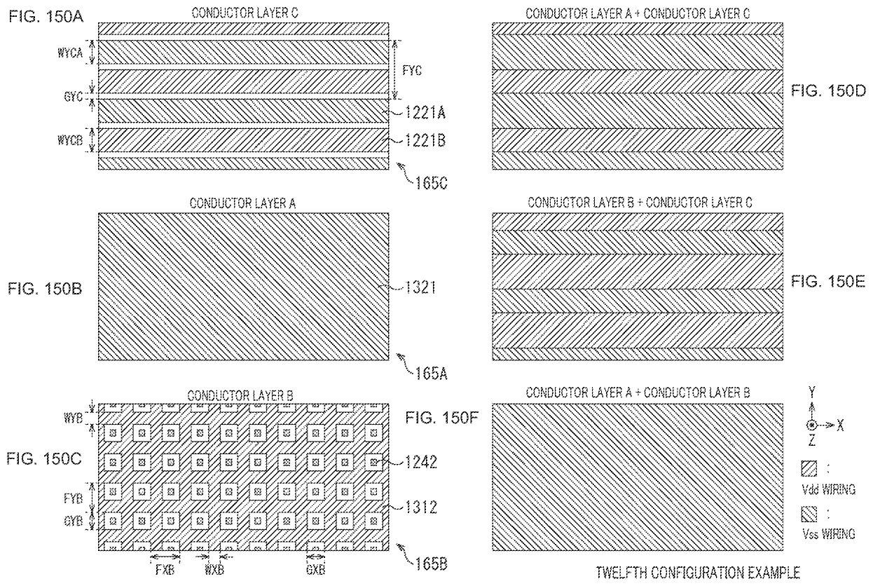

FIG. 150 illustrates a first modification example of the twelfth configuration example of the three-layer conductor layer.

A of FIG. 150 illustrates the conductor layer C (wiring layer 165C), B of FIG. 150 illustrates the conductor layer A (wiring layer 165A), and C of FIG. 150 illustrates the conductor layer B (wiring layer 165B).

Further, D of FIG. 150 is a plan view in a state in which the conductor layers A and C are stacked, E of FIG. 150 is a plan view in a state in which the conductor layers B and C are stacked, and F of FIG. 150 is a plan view in a state in which the conductor layer A and the conductor layer B are stacked.

In FIG. 150, parts corresponding to the eleventh and twelfth configuration examples illustrated in FIGS. 148 and 149 are denoted by the same reference signs, description of the portions will be appropriately omitted, and description will be focused on different portions.

The first modification example of the twelfth configuration example differs from that in FIG. 149 in only the configuration of the conductor layer B in C of FIG. 150.

The conductor layer B in C of FIG. 150 includes a mesh conductor 1312 and a relay conductor 1242 formed in a gap of the mesh conductor 1312.

In the twelfth configuration example illustrated in FIG. 149, for the conductor layer A, the mesh conductor 1311 and the relay conductor 1241 of the eleventh configuration example of the three-layer conductor layer illustrated in FIG. 148 are changed to the planar conductor 1321, and for the conductor layer B, the mesh conductor 1312 and the relay conductor 1242 of the eleventh configuration example of the three-layer conductor layer illustrated in FIG. 148 are changed to the planar conductor 1322.

On the other hand, in the first modification example of the twelfth configuration example of FIG. 150, for the conductor layer A, the mesh conductor 1311 and the relay conductor 1241 of the eleventh configuration example of the three-layer conductor layer illustrated in FIG. 148 are changed to the planar conductor 1321, and the conductor layer B includes the mesh conductor 1312 and the relay conductor 1242, which are the same as those in the eleventh configuration example of the three-layer conductor layer illustrated in FIG. 148.

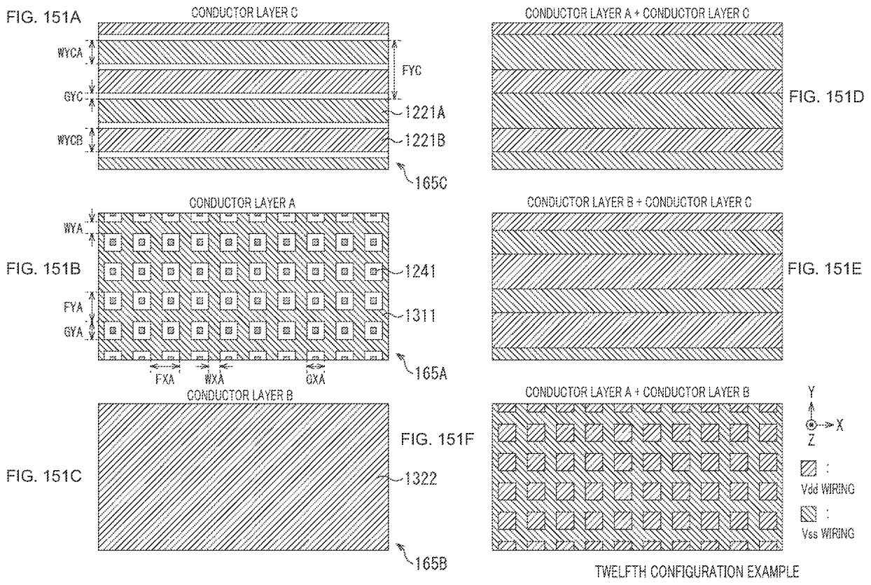

FIG. 151 illustrates a second modification example of the twelfth configuration example of the three-layer conductor layer.

A of FIG. 151 illustrates a conductor layer C (wiring layer 165C), B of FIG. 151 illustrates a conductor layer A (wiring layer 165A), and C of FIG. 151 illustrates a conductor layer B (wiring layer 165B).

Further, D of FIG. 151 is a plan view in a state in which the conductor layer A and the conductor layer C are stacked, E of FIG. 151 is a plan view in a state in which the conductor layer B and the conductor layer C are stacked, and F of FIG. 151 is a plan view in a state in which the conductor layer A and the conductor layer B are stacked.

In FIG. 151, parts corresponding to the eleventh and twelfth configuration examples illustrated in FIGS. 148 and 149 are denoted by the same reference signs, description of the portions will be appropriately omitted, and description will be focused on different portions.

The second modification example of the twelfth configuration example differs from that of FIG. 149 in only the configuration of the conductor layer A in B of FIG. 151.

In the twelfth configuration example illustrated in FIG. 149, for the conductor layer A, the mesh conductor 1311 and the relay conductor 1241 of the eleventh configuration example of the three-layer conductor layer illustrated in FIG. 148 are changed to the planar conductor 1321 and, for the conductor layer B, the mesh conductor 1312 and the relay conductor 1242 of the eleventh configuration example of the three-layer conductor layer illustrated in FIG. 148 are changed to the planar conductor 1322.

On the other hand, in the second modification example of the twelfth configuration example of FIG. 151, the conductor layer A includes the mesh conductor 1311 and the relay conductor 1241, which are the same as those in the eleventh configuration example of the three-layer conductor layer illustrated in FIG. 148 and, for the conductor layer B, the mesh conductor 1312 and the relay conductor 1242 of the eleventh configuration example of the three-layer conductor layer illustrated in FIG. 148 are changed to the planar conductor 1322.

Even in the first modification example and the second modification example, the same operations and effects as those in the twelfth configuration example illustrated in FIG. 149 are achieved.

That is, when the conductor layer C is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1222A and the straight conductor 1222B have the same wiring pattern repeated in the Y direction, it is possible to completely offset the capacitive noise in the Y direction. It is possible to greatly reduce the capacitive noise when the conductor layer C is closer to the wiring layer 170.

The stack of the conductor layers A and B has a light shielding structure, and it is possible to shield the hot carrier light emitted from the active element group 167, and the stack of the conductor layers A and C and the stack of the conductor layers B and C also have a light shielding structure, and the light shielding property is maintained. Accordingly, since light shielding constraints of the conductor layers A and B can be greatly mitigated, it is possible to maximize use of the conductor area of the conductor layers A and B, and to reduce a wiring resistance and further reduce the voltage drop. Further, it is possible to improve the degree of freedom in a layout of the conductor layers A and B.

The first modification example of FIG. 150 is particularly suitable for a stacking order in which the three layers including the conductor layers A to C can be electrically connected, specifically, a stacking order illustrated in A and B of FIG. 120. For example, in the case of an order of stacking the conductor layers A, B, and C illustrated in A of FIG. 120, the planar conductor 1321 of the conductor layer A and the relay conductor 1242 of the conductor layer B can be connected to each other, and the mesh conductor 1312 and the relay conductor 1242 of the conductor layer B can be connected to the respective the straight conductors 1221B and 1221A of the conductor layer C so that such conductors having the same current characteristics are connected to each other, via conductor vias in the Z direction in a part of a region in which the planar regions overlap each other.

The second modification example of FIG. 151 is particularly suitable for a stacking order in which the three layers including the conductor layers A to C can be electrically connected, specifically, a stacking order illustrated in B and C of FIG. 120. For example, in the case of the stack order of the conductor layers A, C, and B illustrated in B of FIG. 120, the mesh conductor 1311 and the relay conductor 1241 of the conductor layer A can be respectively connected to the straight conductors 1221A and 1221B of the conductor layer C by conductor vias in the Z direction, so that the conductors having the same current characteristics are connected to each other, in a part of a region in which the planar regions overlap, and the planar conductor 1322 of the conductor layer B and the straight conductor 1221B of the conductor layer C can be connected to each other.

### THIRTEENTH CONFIGURATION EXAMPLE OF THREE-LAYER CONDUCTOR LAYER

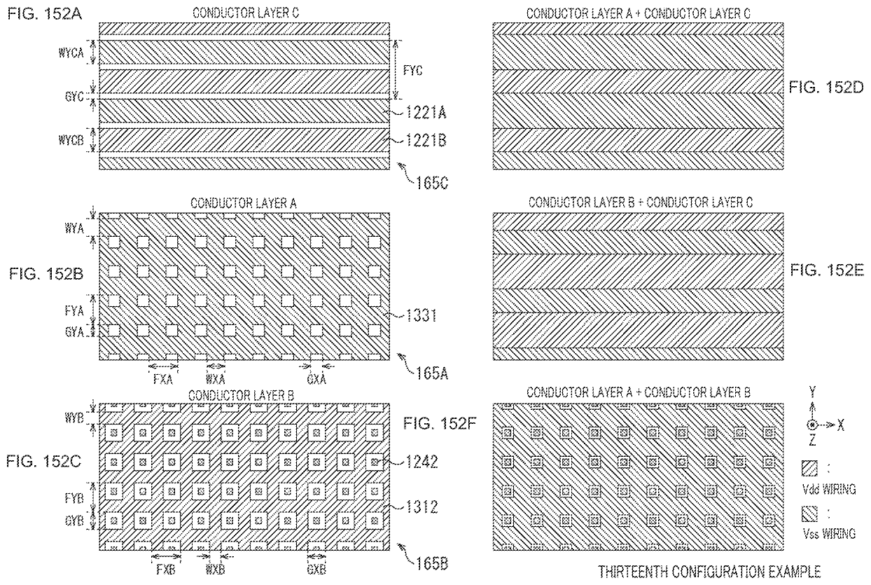

FIG. 152 illustrates a thirteenth configuration example of the three-layer conductor layer.

A of FIG. 152 illustrates the conductor layer C (wiring layer 165C), B of FIG. 152 illustrates the conductor layer A (wiring layer 165A), and C of FIG. 152 illustrates the conductor layer B (wiring layer 165B).

Further, D of FIG. 152 is a plan view in a state in which the conductor layers A and C are stacked, E of FIG. 152 is a plan view in a state in which the conductor layers B and C are stacked, and F of FIG. 152 is a plan view in a state in which the conductor layer A and the conductor layer B are stacked.

In the twelfth configuration example of FIG. 152, parts corresponding to the eleventh configuration example illustrated in FIG. 148 are denoted by the same reference signs, description of the portions will be appropriately omitted, and description will be focused on different portions.

The thirteenth configuration example differs from that of FIG. 148 in only the configuration of the conductor layer A in B of FIG. 152.

The conductor layer A in B of FIG. 152 includes a mesh conductor 1331. The mesh conductor 1331 is, for example, a wiring (Vss wiring) connected to GND or a negative power supply. The mesh conductor 1331 has a conductor width WXA, a gap width GXA, and a conductor period FXA in the X direction, and has a conductor width WYA, a gap width GYA, and a conductor period FYA in the Y direction. Here, conductor width WXA=conductor width WYA, gap width GXA=gap width GYA, and conductor period FXA=conductor period FYA. However, the gap width GXA and the gap width GYA of the gaps of the mesh conductor 1331 are smaller than the gap width GXB and the gap width GYB of the gaps of the mesh conductor 1312 of the conductor layer B (gap width GXA=gap width GYA<gap width GXB=gap width GYB). Further, no relay conductor is formed in the gap between the mesh conductors 1331.

The thirteenth configuration example of FIG. 152 is the same as the eleventh configuration example of FIG. 148 except for the points described above.

When the conductor layer C in A of FIG. 152 is viewed in a predetermined planar range (planar region), the current distribution of the straight conductor 1221A is the same or substantially the same as the current distribution of the straight conductor 1221B and thus, it is possible to curb the occurrence of the inductive noise.

Since the straight conductor 1221A and the straight conductor 1221B have the same wiring pattern repeated in the Y direction, it is possible to completely offset the capacitive noise in the Y direction. It is possible to greatly reduce the capacitive noise when the conductor layer C is closer to the wiring layer 170.

As illustrated in D and E of FIG. 152, each of the stack of the conductor layers A and C and the stack of the conductor layers B and C has a light shielding structure, and the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

By providing the relay conductor 1242 on the conductor layer B, it is possible to make a connection to the straight conductor 1221A at a substantially shortest distance or a short distance, and it is possible to reduce a voltage drop, energy loss, or inductive noise.

The thirteenth configuration example of FIG. 152 is particularly suitable for a stacking order in which the three layers including the conductor layers A to C can be electrically connected, specifically, the stacking order illustrated in B of FIG. 120. For example, in the case of an order of stacking the conductor layers A, C, and B illustrated in B of FIG. 120, the mesh conductor 1331 of the conductor layer A can be connected to the straight conductor 1221A of the conductor layer C by the conductor via in the Z direction, and the mesh conductor 1312 and the relay conductor 1242 of the conductor layer B can be connected to the respective the straight conductors 1221B and 1221A of the conductor layer C so that such conductors having the same current characteristics are connected to each other, via conductor vias in the Z direction in the part of the region in which the planar regions overlap each other.

### FOURTEENTH CONFIGURATION EXAMPLE OF THREE-LAYER CONDUCTOR LAYER

In the first to thirteenth configuration examples of the three-layer conductor layer described above, a configuration in which a straight conductor long in the X direction or a straight conductor long in the Y direction, which is a so-called vertical stripe or horizontal stripe wiring pattern, has been adopted as the configuration of the conductor layer C and described.

However, the conductor layer C is not limited to the wiring pattern of vertical stripes or horizontal stripes.

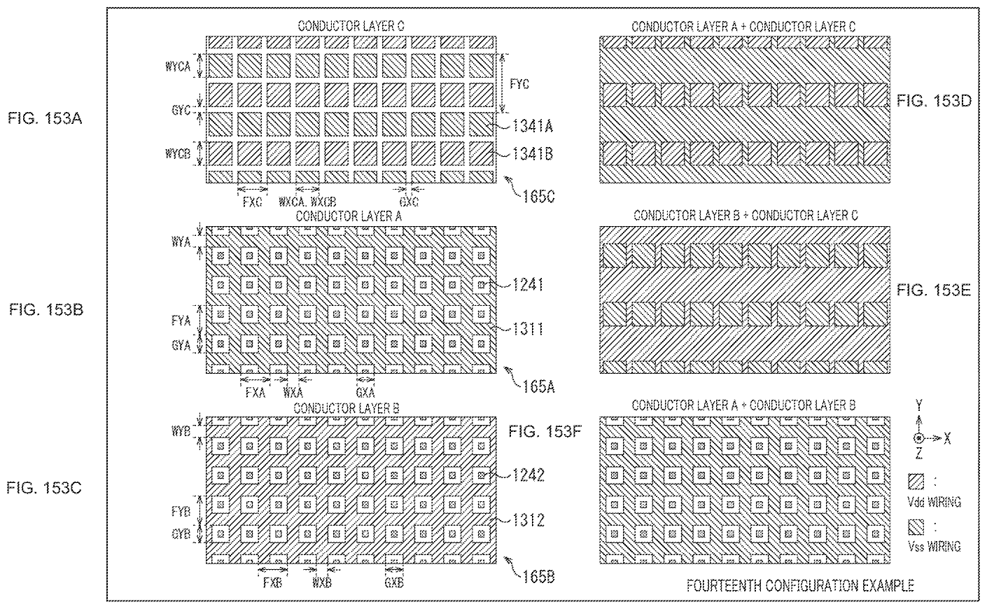

Next, a case in which the conductor layer C has a configuration other than the wiring pattern of vertical stripes or horizontal stripes in FIGS. 153 to 163 will be described.

FIG. 153 illustrates a fourteenth configuration example of the three-layer conductor layer.

A of FIG. 153 illustrates a conductor layer C (wiring layer 165C), B of FIG. 153 illustrates a conductor layer A (wiring layer 165A), and C of FIG. 153 illustrates a conductor layer B (wiring layer 165B).

Further, D of FIG. 153 is a plan view in a state in which the conductor layer A and the conductor layer C are stacked, E of FIG. 153 is a plan view in a state in which the conductor layer B and the conductor layer C are stacked, and F of FIG. 153 is a plan view in a state in which the conductor layer A and the conductor layer B are stacked.

In the fourteenth configuration example of FIG. 153, portions corresponding to those of the eleventh configuration example illustrated in FIG. 148 are denoted by the same reference signs, description of the portions will be appropriately omitted, and description will be focused on different portions.

In the fourteenth configuration example, only a configuration of the conductor layer C in A of FIG. 153 differs from that in FIG. 148.

The conductor layer C in A of FIG. 153 has a configuration in which a plurality of rectangular conductors 1341A and 1341B are repeatedly arranged on a single plane in a predetermined repetition period. The rectangular conductor 1341A is, for example, a wiring (Vss wiring) connected to GND or a negative power supply. The rectangular conductor 1341B is, for example, a wiring (Vdd wiring) connected to a positive power supply.

Specifically, a row in which the rectangular conductors 1341A are repeatedly arranged with a gap width GXC in the X direction and a row in which the rectangular conductors 1341B are repeatedly arranged with a gap width GXC in the X direction are alternately arranged periodically in the Y direction. The rectangular conductors 1341A and 1341B are repeatedly arranged in a conductor period FXC in the X direction and are repeatedly arranged in a conductor period FYC in the Y direction. There is a gap having a gap width GYC between the rectangular conductor 1341A and the rectangular conductor 1341B in the Y direction. The rectangular conductor 1341A has the conductor width WXCA in the X direction and the conductor width WYCA in the Y direction, and the rectangular conductor 1341B has the conductor width WXCB in the X direction and the conductor width WYCB in the Y direction. Here, the conductor widths WXCA, WYCA, WXCB, and WYCB are the same (conductor width WXCA=conductor width WYCA=conductor width WXCB=conductor width WYCB).

The fourteenth configuration example of FIG. 153 is the same as the eleventh configuration example of FIG. 148 except for the points described above.

When the conductor layer C in A of FIG. 153 is viewed in a predetermined planar range (planar region), a current distribution of the rectangular conductor 1341A is the same or substantially the same as a current distribution of the rectangular conductor 1341B and thus, it is possible to curb the occurrence of the inductive noise.

Since the rectangular conductor 1341A and the rectangular conductor 1341B have the same wiring pattern repeated in the Y direction, it is possible to completely offset the capacitive noise in the Y direction. It is possible to greatly reduce the capacitive noise when the conductor layer C is closer to the wiring layer 170.

As illustrated in D and E of FIG. 153, each of the stack of the conductor layers A and C and the stack of the conductor layers B and C has a light shielding structure, and the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

By providing the relay conductor 1241 in the conductor layer A, it is possible to make a connection to the rectangular conductor 1341B at a substantially shortest distance or a short distance, and a voltage drop, energy loss, or inductive noise can be reduced.

By providing the relay conductor 1242 on the conductor layer B, it is possible to make a connection to the rectangular conductor 1341A at a substantially shortest distance or a short distance, and a voltage drop, energy loss, or inductive noise can be reduced.

### MODIFICATION EXAMPLES OF FOURTEENTH CONFIGURATION EXAMPLE OF THREE-LAYER CONDUCTOR LAYER

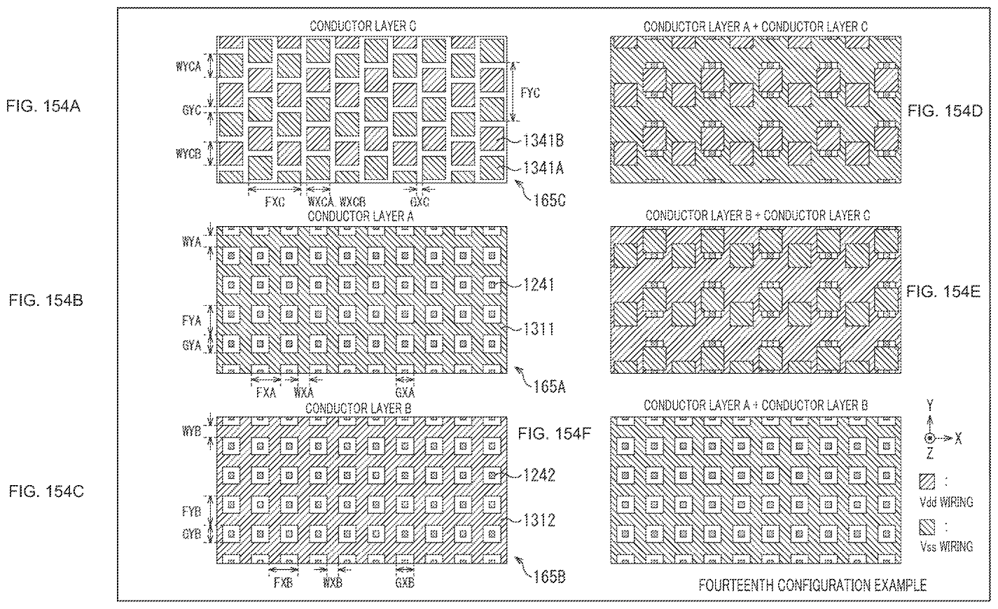

FIG. 154 illustrates a first modification example of the fourteenth configuration example of the three-layer conductor layer.

A of FIG. 154 illustrates the conductor layer C (wiring layer 165C), B of FIG. 154 illustrates the conductor layer A (wiring layer 165A), and C of FIG. 154 illustrates the conductor layer B (wiring layer 165B).

Further, D of FIG. 154 is a plan view in a state in which the conductor layer A and the conductor layer C are stacked, E of FIG. 154 is a plan view in a state in which the conductor layer B and the conductor layer C are stacked, and F of FIG. 154 is a plan view in a state in which the conductor layer A and the conductor layer B are stacked.

In FIG. 154, portions corresponding to those in the fourteenth configuration example illustrated in FIG. 153 are denoted by the same reference signs, description of the portions will be appropriately omitted, and description will be focused on different portions.

In the first modification example of the fourteenth configuration example, only a configuration of the conductor layer C in A of FIG. 154 differs from that of FIG. 153, and configurations of the conductor layers A and B are the same as that of FIG. 153.

The conductor layer C in A of FIG. 154 is the same as that in FIG. 153 in that the conductor layer C has a configuration in which a plurality of rectangular conductors 1341A and 1341B are repeatedly arranged on a single plane in a predetermined repetition period, but differs from that in FIG. 153 in that, in adjacent columns, the arrangement is displaced by ¼ of the conductor period FYC in the Y direction. The conductor period FXC, which is the repetition period in the X direction, is in units of two columns.

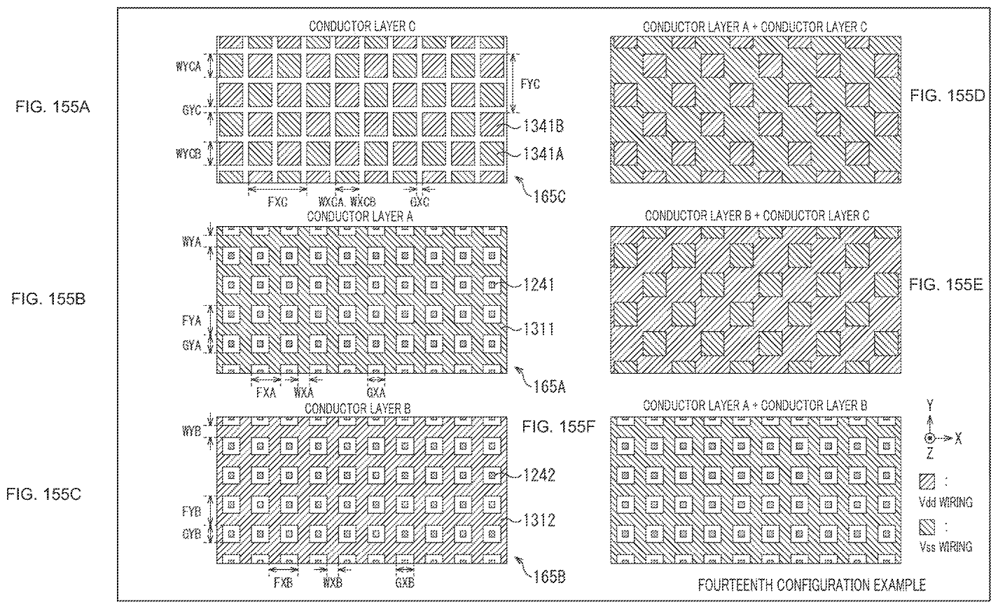

FIG. 155 illustrates a second modification example of the fourteenth configuration example of the three-layer conductor layer.

A of FIG. 155 illustrates the conductor layer C (wiring layer 165C), B of FIG. 155 illustrates the conductor layer A (wiring layer 165A), and C of FIG. 155 illustrates the conductor layer B (wiring layer 165B).

Further, D of FIG. 155 is a plan view in a state in which the conductor layers A and C are stacked, E of FIG. 155 is a plan view in a state in which the conductor layers B and C are stacked, and F of FIG. 155 is a plan view in a state in which the conductor layer A and the conductor layer B are stacked.

In FIG. 155, portions corresponding to those in the fourteenth configuration example illustrated in FIG. 153 are denoted by the same reference signs, description of the portions will be appropriately omitted, and description will be focused on different portions.

In the second modification example of the fourteenth configuration example, only a configuration of the conductor layer C in A of FIG. 155 differs from that of FIG. 149, and configurations of the conductor layers A and B are the same as that of FIG. 149.

The conductor layer C in A of FIG. 155 is the same as that in FIG. 149 in that the conductor layer C has a configuration in which a plurality of rectangular conductors 1341A and 1341B are repeatedly arranged on a single plane in a predetermined repetition period, but differs from that in FIG. 149 in that, in adjacent columns, the arrangement is displaced by ½ of the conductor period FYC in the Y direction. The conductor period FXC, which is the repetition period in the X direction, is in units of two columns. An amount of displacement of the rectangular conductors 1341A and 1341B in the Y direction in the adjacent columns can be designed to be any value.

In the first modification example and the second modification example of the fourteenth configuration example of FIGS. 154 and 155, when the conductor layer C is viewed in a predetermined planar range (planar region), a current distribution of the rectangular conductor 1341A is the same or substantially the same as a current distribution of the rectangular conductor 1341B and thus, it is possible to curb the occurrence of the inductive noise.

Further, in the first modification example and the second modification example of the fourteenth configuration example, since the rectangular conductor 1341A and the rectangular conductor 1341B have the same wiring pattern repeated in the Y direction, it is possible to completely offset the capacitive noise in the Y direction. It is possible to greatly reduce the capacitive noise when the conductor layer C is closer to the wiring layer 170.

In the second modification example of the fourteenth configuration example of FIG. 155, further, since the rectangular conductor 1341A and the rectangular conductor 1341B have the same wiring pattern repeated in the X direction, it is possible to completely offset the capacitive noise in the X direction. It is possible to greatly reduce the capacitive noise when the conductor layer C is closer to the wiring layer 170.

In the first modification example of the fourteenth configuration example of FIG. 154, the light shielding property is maintained in a certain range by the stack of the conductor layers A and B, the stack of the conductor layers A and C, and the stack of the conductor layers B and C. Accordingly, since light shielding constraints of the conductor layers A and B can be slightly mitigated, it is possible to maximize use of the conductor area of the conductor layers A and B and to reduce the wiring resistance and further reduce the voltage drop. Further, it is possible to improve the degree of freedom in a layout of the conductor layers A and B.

In the second modification example of the fourteenth configuration example of FIG. 155, each of the stack of the conductor layers A and C and the stack of the conductor layers B and C has a light shielding structure, and the light shielding property is maintained. Accordingly, since light shielding constraints of the conductor layers A and B can be greatly mitigated, it is possible to maximize the use of the conductor area of the conductor layers A and B, and it is possible to reduce the wiring resistance and further reduce the voltage drop. Further, it is possible to improve the degree of freedom in a layout of the conductor layers A and B.

By providing the relay conductor 1241 in the conductor layer A, it is possible to make a connection to the rectangular conductor 1341B at a substantially shortest distance or a short distance, and a voltage drop, energy loss, or inductive noise can be reduced.

By providing the relay conductor 1242 on the conductor layer B, it is possible to make a connection to the rectangular conductor 1341A at a substantially shortest distance or a short distance, and a voltage drop, energy loss, or inductive noise can be reduced.

### OTHER MODIFICATION EXAMPLES OF FOURTEENTH CONFIGURATION EXAMPLE OF THREE-LAYER CONDUCTOR LAYER

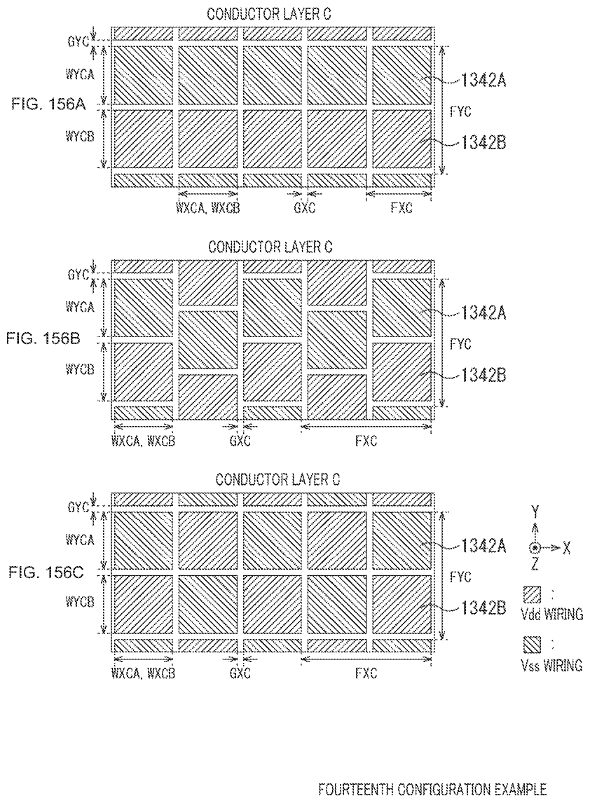

Hereinafter, other modification examples of the fourteenth configuration example of the three-layer conductor layer illustrated in FIG. 153 will be described with reference to FIGS. 156 to 163.

In the modification examples of the fourteenth configuration example, since only a configuration of the conductor layer C is changed as in the first and second modification examples of FIGS. 154 and 155, only the configuration of the conductor layer C is illustrated in FIGS. 156 to 163. Further, in FIGS. 156 to 163, the configuration of the conductor layer C will be described through a comparison with the conductor layer C of the fourteenth configuration example illustrated in A of FIG. 153.

A of FIG. 156 illustrates a conductor layer C of a third modification example of the fourteenth configuration example of the three-layer conductor layer.

The conductor layer C in A of FIG. 156 has a configuration in which a plurality of rectangular conductors 1342A and 1342B are repeatedly arranged on a single plane in a predetermined repetition period. The rectangular conductor 1342A is, for example, a wiring (Vss wiring) connected to GND or a negative power supply. The rectangular conductor 1342B is, for example, a wiring (Vdd wiring) connected to a positive power supply.

The conductor layer C in A of FIG. 156 differs from the conductor layer C in A of FIG. 153 in conductor sizes of the rectangular conductors 1342A and 1342B, that is, the conductor widths WXCA, WYCA, WXCB, and WYCB. The conductor widths WXCA, WYCA, WXCB, and WYCB are the same (conductor width WXCA=conductor width WYCA=conductor width WXCB=conductor width WYCB).

The conductor layer C in A of FIG. 156 can completely offset the capacitive noise in the Y direction. It is possible to greatly reduce the capacitive noise when the conductor layer C is closer to the wiring layer 170.

Further, it is possible to further reduce the wiring resistance by making the conductor sizes of the rectangular conductors 1342A and 1342B larger than those in the fourteenth configuration example illustrated in A of FIG. 153.

B of FIG. 156 illustrates a conductor layer C of a fourth modification example of the fourteenth configuration example of the three-layer conductor layer.

The conductor layer C in B of FIG. 156 is the same as that in A of FIG. 156 in that the conductor layer C has a configuration in which a plurality of rectangular conductors 1342A and 1342B are repeatedly arranged on a single plane in a predetermined repetition period, but differs from that in A of FIG. 156 in that, in adjacent columns, the arrangement is displaced by ¼ of the conductor period FYC in the Y direction.

The conductor period FXC, which is the repetition period in the X direction, is in units of two columns.

The conductor layer C in B of FIG. 156 can completely offset the capacitive noise in the Y direction. It is possible to greatly reduce the capacitive noise when the conductor layer C is closer to the wiring layer 170.

C of FIG. 156 illustrates a conductor layer C of a fifth modification example of the fourteenth configuration example of the three-layer conductor layer.

The conductor layer C in C of FIG. 156 is the same as that in A of FIG. 156 in that the conductor layer C has a configuration in which a plurality of rectangular conductors 1342A and 1342B are repeatedly arranged on a single plane in a predetermined repetition period, but differs from that in A of FIG. 156 in that, in adjacent columns, the arrangement is displaced by ½ of the conductor period FYC in the Y direction. It can also be said that, in the adjacent rows, the arrangement is displaced by ½ of the conductor period FXC in the X direction. The conductor period FXC in the X direction is units of two columns, and the conductor period FYC in the Y direction is units of two rows. An amount of displacement of the rectangular conductors 1342A and 1342B in the Y direction in the adjacent columns can be designed to have any value.

The conductor layer C in C of FIG. 156 can completely offset the capacitive noise in the Y direction. It is possible to greatly reduce the capacitive noise when the conductor layer C is closer to the wiring layer 170.

Further, the conductor layer C in C of FIG. 156 can completely offset the capacitive noise in the X direction. It is possible to greatly reduce the capacitive noise when the conductor layer C is closer to the wiring layer 170.

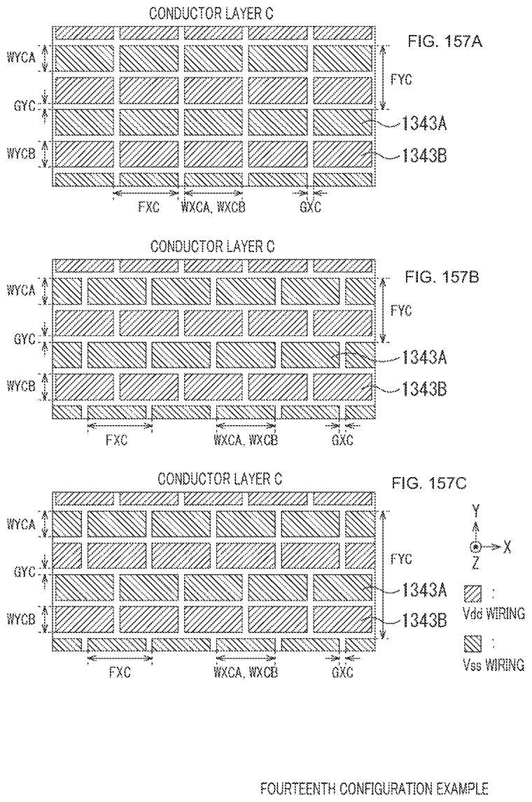

A of FIG. 157 illustrates a conductor layer C of a sixth modification example of the fourteenth configuration example of the three-layer conductor layer.

The conductor layer C in A of FIG. 157 has a configuration in which a plurality of rectangular conductors 1343A and 1343B are repeatedly arranged on a single plane in a predetermined repetition period. The rectangular conductor 1343A is, for example, a wiring (Vss wiring) connected to GND or a negative power supply. The rectangular conductor 1343B is, for example, a wiring (Vdd wiring) connected to a positive power supply.

The conductor layer C in A of FIG. 157 differs from the conductor layer C in A of FIG. 153 in conductor sizes of the rectangular conductors 1343A and 1343B, specifically, the conductor widths WXCA and WXCB. The rectangular conductors 1343A and 1343B have rectangular shapes, and the conductor width WXCA>conductor width WYCA, and the conductor width WXCB>conductor width WYCB. Further, the conductor width WXCA is equal to the conductor width WXCB, and the conductor width WYCA is equal to the conductor width WYCB (conductor width WXCA=conductor width WXCB, and conductor width WYCA=conductor width WYCB).

The conductor layer C in A of FIG. 157 can completely offset the capacitive noise in the Y direction. It is possible to greatly reduce the capacitive noise when the conductor layer C is closer to the wiring layer 170.

B of FIG. 157 illustrates a conductor layer C of a seventh modification example of the fourteenth configuration example of the three-layer conductor layer.

The conductor layer C in B of FIG. 157 is the same as that in A of FIG. 157 in that the conductor layer C has a configuration in which a plurality of rectangular conductors 1343A and 1343B are repeatedly arranged on a single plane in a predetermined repetition period, but differs in that the arrangement is displaced by ½ of the conductor period FXC in the X direction in the adjacent rows. The conductor period FYC, which is the repetition period in the Y direction, is units of two rows. An amount of displacement of the rectangular conductors 1343A and 1343B in the X direction in the adjacent rows can be designed to have any value.

In the conductor layer C in B of FIG. 157, since the rectangular conductor 1343A and the rectangular conductor 1343B do not have the same wiring pattern repeated in the Y direction, there is an X position in which the capacitive noise cannot be completely offset in the Y direction.

Therefore, when the conductor period FXC in the X direction is displaced by ½, the conductor layer C can be configured as shown by C of FIG. 157.

C of FIG. 157 illustrates a conductor layer C of an eighth modification example of the fourteenth configuration example of the three-layer conductor layer.

The conductor layer C in C of FIG. 157 has a configuration in which the arrangement is displaced by ½ of the conductor period FXC in the X direction in units of two rows of the rectangular conductors 1343A and 1343B adjacent to each other in the Y direction and are arranged repeatedly on a single plane in a predetermined repetition period.

The conductor layer C in C of FIG. 157 can completely offset the capacitive noise in the Y direction. It is possible to greatly reduce the capacitive noise when the conductor layer C is closer to the wiring layer 170.

An amount of displacement in the X direction in units of two adjacent rows of the rectangular conductors 1343A and 1343B can be designed to have any value. Further, the displacement of the rectangular conductors 1343A and 1343B in the unit of two rows in the X direction may be displacement of non-adjacent rectangular conductors in two rows rather than the adjacent rectangular conductors in the two rows. Further, it is not necessary for the displacement of the rectangular conductors 1343A and 1343B in units of two rows in the X direction to be in units of two rows because the capacitive noise can be completely offset in the Y direction when a sum of the conductor widths in the Y direction of the rectangular conductor 1343A is the same as a sum of the conductor widths in the Y direction of the rectangular conductor 1343B when viewed in a predetermined planar range (planar region). In other words, the rectangular conductors 1343A and 1343B may be displaced in the X direction by a displacement amount designed to be any value in units of a plurality of rows, which are two or more rows, regardless of whether or not the rows are adjacent to each other. The present disclosure is suitable for a case in which the sum of the conductor widths in the Y direction of the rectangular conductor 1343A is the same or substantially the same as the sum of the conductor widths in the Y direction of the rectangular conductor 1343B when viewed in the predetermined planar range (planar region), but is not limited thereto.

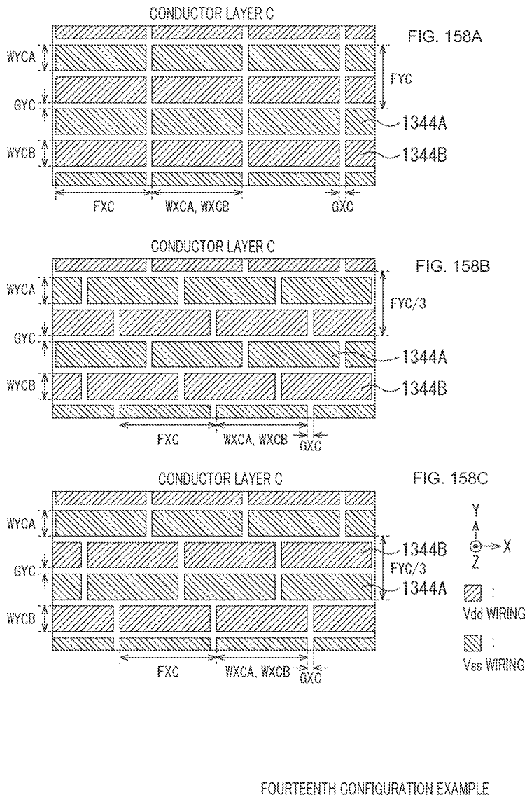

A of FIG. 158 illustrates a conductor layer C of a ninth modification example of the fourteenth configuration example of the three-layer conductor layer.

The conductor layer C in A of FIG. 158 has a configuration in which a plurality of rectangular conductors 1344A and 1344B are repeatedly arranged on a single plane in a predetermined repetition period. The rectangular conductor 1344A is, for example, a wiring (Vss wiring) connected to GND or a negative power supply. The rectangular conductor 1344B is, for example, a wiring (Vdd wiring) connected to a positive power supply.

The conductor layer C in A of FIG. 158 differs from the conductor layer C in A of FIG. 157 in the conductor sizes of the rectangular conductors 1344A and 1344B, specifically, the conductor widths WXCA and WXCB. The conductor widths WXCA and WXCB of the rectangular conductors 1344A and 1344B in A of FIG. 158 are larger than the conductor widths WXCA and WXCB of the rectangular conductors 1343A and 1343B in A of FIG. 157.

The rectangular conductors 1344A and 1344B have a rectangular shape, and the conductor width WXCA>conductor width WYCA and the conductor width WXCB>conductor width WYCB. Further, the conductor width WXCA is equal to the conductor width WXCB, and the conductor width WYCA is equal to the conductor width WYCB (conductor width WXCA=conductor width WXCB, and conductor width WYCA=conductor width WYCB).

The conductor layer C in A of FIG. 158 can completely offset the capacitive noise in the Y direction. It is possible to greatly reduce the capacitive noise when the conductor layer C is closer to the wiring layer 170.

B of FIG. 158 illustrates a conductor layer C of a tenth modification example of the fourteenth configuration example of the three-layer conductor layer.

The conductor layer C in B of FIG. 158 is the same as that in A of FIG. 158 in that the conductor layer C has a configuration in which a plurality of rectangular conductors 1344A and 1344B are repeatedly arranged on a single plane in a predetermined repetition period, but differs in that the arrangement is displaced by ⅓ of the conductor period FXC in the X direction in the adjacent rows. The conductor period FYC, which is the repetition period in the Y direction, is units of 6 rows.

The conductor layer C in B of FIG. 158 can completely offset the capacitive noise in the Y direction. It is possible to greatly reduce the capacitive noise when the conductor layer C is closer to the wiring layer 170.

C of FIG. 158 illustrates a conductor layer C of an eleventh modification example of the fourteenth configuration example of the three-layer conductor layer.

The conductor layer C in C of FIG. 158 has a configuration in which the arrangement is displaced by ⅓ of the conductor period FXC in the X direction in units of two rows of the rectangular conductors 1344A and 1344B adjacent to each other in the Y direction and are arranged repeatedly on a single plane in a predetermined repetition period.

The conductor layer C in C of FIG. 158 can completely offset the capacitive noise in the Y direction. It is possible to greatly reduce the capacitive noise when the conductor layer C is closer to the wiring layer 170.

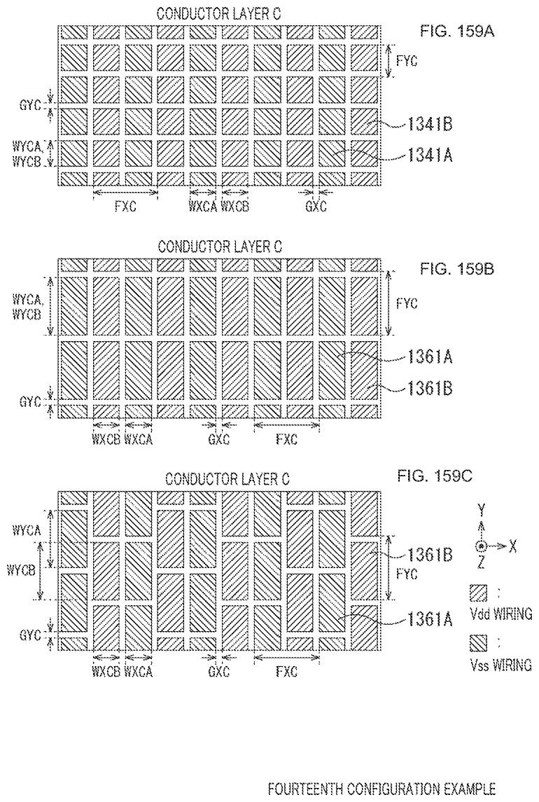

A of FIG. 159 illustrates a conductor layer C of a twelfth modification example of the fourteenth configuration example of the three-layer conductor layer.

The conductor layer C in A of FIG. 159 has a configuration in which a plurality of rectangular conductors 1341A and 1341B are repeatedly arranged on a single plane in a predetermined repetition period.

The conductor layer C in A of FIG. 159 differs from the conductor layer C in A of FIG. 153 in an arrangement direction of the rectangular conductors 1341A and 1341B. Specifically, in the conductor layer C in A of FIG. 153, each of the rectangular conductors 1341A and 1341B is repeatedly arranged in the X direction in the conductor period FXC, and the rectangular conductors 1341A and 1341B are alternately periodically arranged in the Y direction. On the other hand, in the conductor layer C in A of FIG. 159, each of the rectangular conductors 1341A and 1341B is repeatedly arranged in the Y direction in the conductor period FYC, and the rectangular conductors 1341A and 1341B are alternately periodically arranged in the X direction.

The conductor layer C in A of FIG. 159 can completely offset the capacitive noise in the X direction. It is possible to greatly reduce the capacitive noise when the conductor layer C is closer to the wiring layer 170.

B of FIG. 159 illustrates a conductor layer C of a thirteenth modification example of the fourteenth configuration example of the three-layer conductor layer.

The conductor layer C in B of FIG. 159 has a configuration in which a plurality of rectangular conductors 1361A and 1361B are repeatedly arranged on a single plane in a predetermined repetition period. The rectangular conductor 1361A is, for example, a wiring (Vss wiring) connected to GND or a negative power supply. The rectangular conductor 1361B is, for example, a wiring (Vdd wiring) connected to a positive power supply.

The conductor layer C in B of FIG. 159 differs from the conductor layer C in A of FIG. 159 in a conductor sizes of the rectangular conductors 1361A and 1361B, specifically, the conductor widths WYCA and WYCB. The rectangular conductors 1361A and 1361B have a rectangular shape, and the conductor width WXCA<conductor width WYCA, and the conductor width WXCB<conductor width WYCB. Further, the conductor width WXCA is equal to the conductor width WXCB, and the conductor width WYCA is equal to the conductor width WYCB (conductor width WXCA=conductor width WXCB, and conductor width WYCA=conductor width WYCB).

The conductor layer C in B of FIG. 159 can completely offset the capacitive noise in the X direction. It is possible to greatly reduce the capacitive noise when the conductor layer C is closer to the wiring layer 170.

Although not illustrated in the drawings, a configuration in which the rectangular conductors 1361A and 1361B are displaced by ½ of the conductor period FYC in the Y direction and repeatedly arranged on a single plane in a predetermined repetition period in adjacent columns or a configuration in which the rectangular conductors 1361A and 1361B are displaced by ⅓ of the conductor period FYC in the Y direction in the adjacent columns can also be adopted. Further, an amount of displacement of the rectangular conductors 1361A and 1361B in the Y direction in the adjacent columns can be designed to be any value. Further, the rectangular conductors 1361A and 1361B may be displaced in the Y direction by a displacement amount designed to have any value in units of a plurality of columns, which are two or more columns, regardless of whether or not the rectangular conductors 1361A and 1361B are adjacent to each other, and the present disclosure is suitable for a case in which a sum of conductor widths of the rectangular conductor 1361A in the X direction is the same or substantially the same as a sum of conductor widths of the rectangular conductor 1361B in the X direction when viewed in a predetermined planar range (a planar region), but is not limited thereto.

C of FIG. 159 illustrates a conductor layer C of a fourteenth modification example of the fourteenth configuration example of the three-layer conductor layer.

The conductor layer C in C of FIG. 159 has a configuration in which the arrangement is displaced by ½ of the conductor period FYC in the Y direction in units of two columns of the rectangular conductors 1361A and 1361B adjacent to each other in the X direction and are arranged repeatedly on a single plane in a predetermined repetition period.

The conductor layer C in C of FIG. 159 can completely offset the capacitive noise in the X direction. It is possible to greatly reduce the capacitive noise when the conductor layer C is closer to the wiring layer 170.

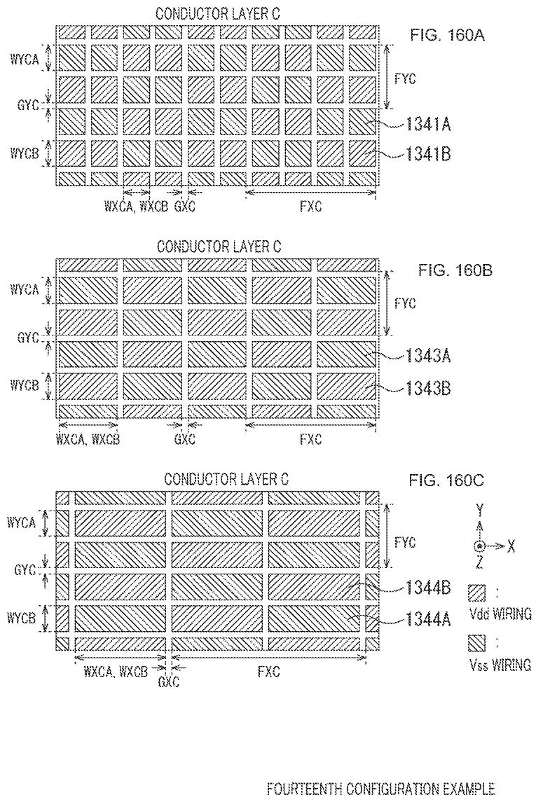

A of FIG. 160 illustrates a conductor layer C of a fifteenth modification example of the fourteenth configuration example of the three-layer conductor layer.

The conductor layer C in A of FIG. 160 has a configuration in which two rectangular conductors 1341A and two rectangular conductors 1341B are arranged on a single plane in predetermined repetition periods in the X direction and the Y direction. A gap between the adjacent rectangular conductors 1341A, a gap between the adjacent rectangular conductors 1341B, and a gap between the adjacent rectangular conductors 1341A and 1341B have a gap width GXC in the X direction and a gap width GYC in the Y direction. The two rectangular conductors 1341A and the two rectangular conductors 1341B are arranged repeatedly in a conductor period FXC in the X direction and in a conductor period FYC in the Y direction.

B of FIG. 160 illustrates a conductor layer C of a sixteenth modification example of the fourteenth configuration example of the three-layer conductor layer.

The conductor layer C in B of FIG. 160 is the same as that in A of FIG. 157 in that the conductor layer C has a configuration in which a plurality of rectangular conductors 1343A and 1343B are repeatedly arranged on a single plane in a predetermined repetition period, but differs from that in A of FIG. 157 in that, in adjacent columns, the arrangement is displaced by ½ of the conductor period FYC in the Y direction. It can be said that the arrangement is displaced by ½ of the conductor period FXC in the X direction in the adjacent rows. The conductor period FXC in the X direction is units of two columns, and the conductor period FYC in the Y direction is units of two rows.

C of FIG. 160 illustrates a conductor layer C of a seventeenth modification example of the fourteenth configuration example of the three-layer conductor layer.

The conductor layer C in C of FIG. 160 is the same as that in A of FIG. 158 in that the conductor layer C has a configuration in which a plurality of rectangular conductors 1344A and 1344B are repeatedly arranged on a single plane in a predetermined repetition period, but differs from that in A of FIG. 158 in that, in adjacent columns, the arrangement is displaced by ½ of the conductor period FYC in the Y direction. It can be said that the arrangement is displaced by ½ of the conductor period FXC in the X direction in the adjacent rows. The conductor period FXC in the X direction is units of two columns, and the conductor period FYC in the Y direction is units of two rows. The conductor layer C in B of FIG. 160 and the conductor layer C in C of FIG. 160 differ only in the conductor widths WXCA and WXCB in the X direction.

The conductor layer C in A to C of FIG. 160 can completely offset the capacitive noise in both the X direction and the Y direction. It is possible to greatly reduce the capacitive noise when the conductor layer C is closer to the wiring layer 170.

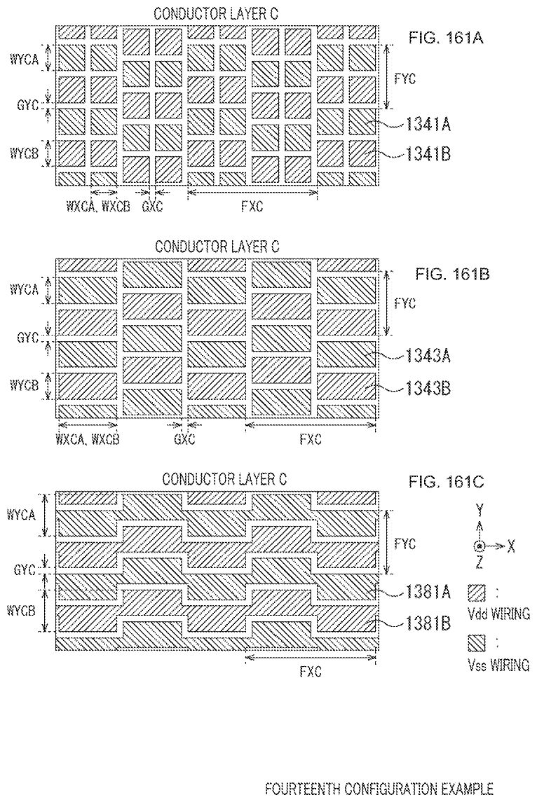

A of FIG. 161 illustrates a conductor layer C of an eighteenth modification example of the fourteenth configuration example of the three-layer conductor layer.

The conductor layer C in A of FIG. 161 is the same as that in A of FIG. 156 in that the conductor layer C has a configuration in which two rectangular conductors 1341A and two rectangular conductors 1341B are arranged on a single plane in predetermined repetition periods in the X direction and the Y direction, but differs in that the arrangement is displaced by ¼ of the conductor period FYC in the Y direction in units of two columns.

B of FIG. 161 illustrates a conductor layer C of a nineteenth modification example of the fourteenth configuration example of the three-layer conductor layer.

The conductor layer C in B of FIG. 161 is the same as that in A of FIG. 157 in that the conductor layer C has a configuration in which a plurality of rectangular conductors 1343A and 1343B are repeatedly arranged on a single plane in a predetermined repetition period, but differs from that in A of FIG. 157 in that, in adjacent columns, the arrangement is displaced by ¼ of the conductor period FYC in the Y direction.

C of FIG. 161 illustrates a conductor layer C of a twentieth modification example of the fourteenth configuration example of the three-layer conductor layer.

The conductor layer C in C of FIG. 161 has a configuration in which conductors 1381A and 1381B are arranged on a single plane in a predetermined repetition period in the Y direction. The conductor 1381A is, for example, a wiring (Vss wiring) connected to GND or a negative power supply. The conductor 1381B is, for example, a wiring (Vdd wiring) connected to a positive power supply.

The conductor 1381A has a shape in which all the rectangular conductors 1343A arranged in the X direction in B of FIG. 161 are connected by the shortest path. The conductor 1381B has a shape in which all the rectangular conductors 1343B arranged in the X direction in B of FIG. 161 are connected by the shortest path. The gap width GXC and the gap width GYC in C of FIG. 161 correspond to minimum widths in the X and Y directions between adjacent conductors. The conductor 1381A and the conductor 1381B may not have a shape in which all rectangular conductors arranged in the X direction in B of FIG. 161 are connected by the shortest path and may have, for example, a meander shape or a meandering shape.

The conductor layers C in A to C of FIG. 161 can completely offset capacitive noise in the Y direction and offset partial capacitive noise in the X direction. It is possible to greatly reduce the capacitive noise when the conductor layer C is closer to the wiring layer 170.

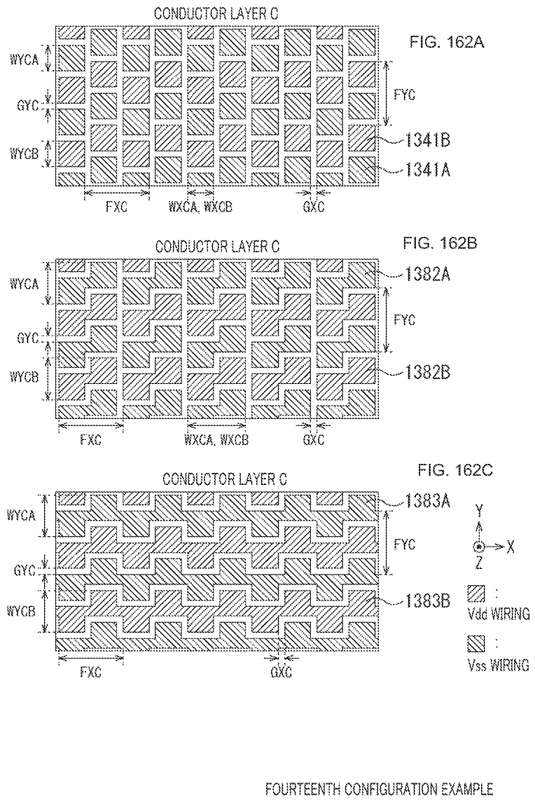

A of FIG. 162 illustrates a conductor layer C of a twenty-first modification example of the fourteenth configuration example of the three-layer conductor layer.

The conductor layer C in A of FIG. 162 is the same as that in A of FIG. 153 in that the conductor layer C has a configuration in which a plurality of rectangular conductors 1341A and 1341B are repeatedly arranged on a single plane in a predetermined repetition period, but differs from that in A of FIG. 153 in that, in adjacent columns, the arrangement is displaced by ¼ of the conductor period FYC in the Y direction.

B of FIG. 162 illustrates a conductor layer C of a twenty-second modification example of the fourteenth configuration example of the three-layer conductor layer.

The conductor layer C in B of FIG. 162 has a configuration in which conductors 1382A and 1382B are periodically arranged on a single plane in the conductor period FXC in the X direction and the conductor period FYC in the Y direction. The conductor 1382A is, for example, a wiring (Vss wiring) connected to GND or a negative power supply. The conductor 1382B is, for example, a wiring (Vdd wiring) connected to a positive power supply. The conductor 1382A has the conductor width WXCA in the X direction and the conductor width WYCA in the Y direction, and the conductor 1382B has the conductor width WXCB in the X direction and the conductor width WYCB in the Y direction. The gap width GXC and the gap width GYC in B of FIG. 162 correspond to minimum widths in the X and Y directions between adjacent conductors.

The conductor 1382A has a shape in which two rectangular conductors 1341A arranged in the X direction in A of FIG. 162 are connected by the shortest path. The conductor 1382B has a shape in which two rectangular conductors 1341B arranged in the X direction in A of FIG. 162 are connected by the shortest path. The conductor 1382A and the conductor 1382B may not have a shape in which the conductors are connected by the shortest path, and may have a shape in which two or more rectangular conductors arranged in the X direction in A of FIG. 162 are electrically connected.

C of FIG. 162 illustrates a conductor layer C of a twenty-third modification example of the fourteenth configuration example of the three-layer conductor layer.

The conductor layer C in C of FIG. 162 has a configuration in which conductor 1383 A and 1383B are arranged on a single plane in a predetermined repetition period in the Y direction. The conductor 1383A is, for example, a wiring (Vss wiring) connected to GND or a negative power supply. The conductor 1383B is, for example, a wiring (Vdd wiring) connected to a positive power supply. The conductor 1383A has a conductor width WYCA in the Y direction, and the conductor 1382B has a conductor width WYCB in the Y direction. The gap width GXC and the gap width GYC in C of FIG. 162 correspond to minimum widths in the X and Y directions between adjacent conductors.

The conductor 1383A has a shape in which all the rectangular conductors 1341A arranged in the X direction in A of FIG. 162 are connected by the shortest path. The conductor 1383B has a shape in which all the rectangular conductors 1341B arranged in the X direction in A of FIG. 162 are connected by the shortest path. The conductor 1383A and the conductor 1383B may not have a shape in which all rectangular conductors arranged in the X direction in A of FIG. 162 are connected by the shortest path and may have, for example, a meander shape or a meandering shape.

The conductor layers C in A to C of FIG. 162 can completely offset capacitive noise in the Y direction and offset partial capacitive noise in the X direction. It is possible to greatly reduce the capacitive noise when the conductor layer C is closer to the wiring layer 170.

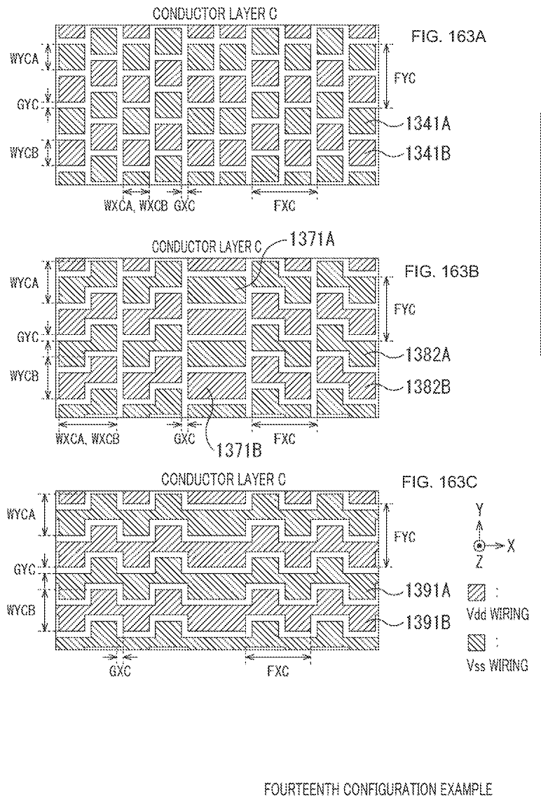

A of FIG. 163 illustrates a conductor layer C of a twenty-fourth modification example of the fourteenth configuration example of the three-layer conductor layer.

The conductor layer C in A of FIG. 163 is the same as that in A of FIG. 153 in that the conductor layer C has a configuration in which are repeatedly arranged the rectangular conductors 1341A and 1341B on a single plane in a predetermined repetition period, but differs from that in A of FIG. 153 in that there are both a region in which, in adjacent columns, the arrangement is displaced by ¼ of the conductor period FYC in the Y direction and a region in which the arrangement is not displaced. The conductor layer C in A of FIG. 163 has a configuration in which the conductors are folded back in the X direction in the conductor period FXC with reference to a center in the X direction of the two rectangular conductors 1341A and 1341B not displaced in the Y direction and repeatedly arranged.

B of FIG. 163 illustrates a conductor layer C of a twenty-fifth modification example of the fourteenth configuration example of the three-layer conductor layer.

A conductor layer C in B of FIG. 163 has a configuration in which rectangular conductors 1371A and 1371B are arranged and the conductors 1382A and 1382B are repeatedly arranged on a single plane in a predetermined repetition period.

The conductor layer C in B of FIG. 163 has a configuration in which the conductors 1382A and 1382B are folded back at a center of the rectangular conductors 1371A and 1371B in the X direction, and the conductors 1382A and 1382B are repeatedly arranged in the X direction in the conductor period FXC.

C of FIG. 163 illustrates a conductor layer C of the twenty-sixth modification example of the fourteenth configuration example of the three-layer conductor layer.

The conductor layer C in C of FIG. 163 has a configuration in which the conductors 1391A and 1391B are arranged on a single plane in a predetermined repetition period in the Y direction. The conductor 1391A is, for example, a wiring (Vss wiring) connected to GND or a negative power supply. The conductor 1391B is, for example, a wiring (Vdd wiring) connected to a positive power supply. The conductor 1391A has a conductor width WYCA in the Y direction, and the conductor 1391B has a conductor width WYCB in the Y direction. The gap width GXC and the gap width GYC in C of FIG. 163 correspond to minimum widths in the X and Y directions between adjacent conductors.

The conductor 1391A has a shape in which all the rectangular conductors 1371A and conductors 1382A arranged in the X direction in B of FIG. 163 are connected by the shortest path. The conductor 1391B has a shape in which all rectangular conductors 1371B and conductors 1382B arranged in the X direction in B of FIG. 163 are connected by the shortest path. The conductor 1391A and the conductor 1391B may not have a shape in which all rectangular conductors arranged in the X direction in B of FIG. 163 are connected by the shortest path and may have, for example, a meander shape or a meandering shape.

The conductor layer C in C of FIG. 163 has a configuration in which the conductors are folded back and repeatedly arranged in the X direction in the conductor period FXC in units of the same regions as those of the conductor layer C in B of FIG. 163.

The conductor layers C in A to C of FIG. 163 have a conductor arrangement that is mirror-symmetrical in the X direction.

The conductor layers C in A to C of FIG. 163 can completely offset capacitive noise in the Y direction and offset partial capacitive noise in the X direction. It is possible to greatly reduce the capacitive noise when the conductor layer C is closer to the wiring layer 170. Although some specific examples have been described above, the first to fourteenth configuration examples or the modification examples thereof (FIGS. 122 to 163) are suitable for, particularly, a stacking order in which three layers of the conductor layers A to C can be electrically connected by a conductor via extended in the Z direction. Specifically, the configuration examples and modification examples thereof illustrated in FIGS. 122 to 127, 134, 148, 149, and 152 to 163 are suitable for the stacking order illustrated in B of FIG. 120. Further, the configuration example and the modification example thereof illustrated in FIG. 150 are suitable for the stacking order illustrated in A and B of FIG. 120. Further, the configuration examples and the modification examples thereof illustrated in FIGS. 129, 131, 133, 135 to 138, 140, 142 to 144, 146, 147, and 151 are suitable for the stacking order illustrated in B and C of FIG. 120. Further, the configuration example and the modification example thereof illustrated in FIGS. 128, 130, 132, 139, 141, and 145 are suitable for the stacking order illustrated in A to C of FIG. 120.

### OTHER MODIFICATION EXAMPLES OF THREE-LAYER CONDUCTOR LAYER

In each configuration example described above, for example, the conductor described as the wiring (Vss wiring) connected to the GND or the negative power supply may be, for example, the wiring (Vdd wiring) connected to the positive power supply and, for example, the conductor described as the wiring (Vdd wiring) connected to the positive power supply may be, for example, the wiring (Vss wiring) connected to the GND or the negative power supply. The voltages Vdd or Vss may be GND and a power supply or may be two types of power supplies having different voltages. It is preferable for the voltages Vdd and Vss to have two different polarities, but the present technology is not limited thereto. It is preferable for the number or a total area of the conductor vias, which extend in the Z direction, connecting the conductor layers A, B, and C to be the same between Vdd and Vss in the predetermined planar range (planar region), but the present technology is not limited thereto. When the relay conductors arranged in the gaps are thinned out, thinning methods other than the above-described examples may be used and, for example, the relay conductors may be thinned out randomly.

The conductor layer C is a conductor layer having a low sheet resistance in which it is easy for a current to flow, but may be a conductor layer having a high sheet resistance in which it is difficult for a current to flow. It is preferable for the conductor layer C not to be a conductor layer in which it is most difficult for a current to flow in the circuit board, the semiconductor substrate, and the electronic device, but the present technology is not limited thereto. It is preferable for the conductor layer C to be a conductor layer in which current flows most easily in the circuit board, the semiconductor substrate, and the electronic device, but the present technology is not limited thereto. It is preferable for the conductor layer C to be a conductor layer in which it is easy for a current to flow as compared with at least one of the conductor layer A and the conductor layer B, but the present technology is not limited thereto. It is preferable for the conductor layer C to be a conductor layer in which it is easy for a current to flow next to the conductor layer A in a circuit board, a semiconductor substrate, or an electronic device, but it is not limited thereto. It is preferable for the conductor layer C to be a conductor layer in which it is easy for a current to flow next to the conductor layer B in a circuit board, a semiconductor substrate, or an electronic device, but it is not limited thereto. For example, the conductor layer C may be a conductor layer in which it is most difficult for a current to flow in the first semiconductor substrate 101 or the second semiconductor substrate 102. For example, the conductor layer C may be a conductor layer in which it is most easy for a current to flow in the first semiconductor substrate 101 or the second semiconductor substrate 102. For example, the conductor layer C may be a conductor layer in which it is easy for a current to flow second in the first semiconductor substrate 101 or the second semiconductor substrate 102. For example, the conductor layer C may be a conductor layer in which it is easy for a current to flow third in the first semiconductor substrate 101 or the second semiconductor substrate 102. For example, the conductor layer C may be a conductor layer in which it is easy for a current to flow next to the conductor layer A in the first semiconductor substrate 101 or the second semiconductor substrate 102. For example, the conductor layer C may be a conductor layer in which it is easy for a current to flow next to the conductor layer B in the first semiconductor substrate 101 or the second semiconductor substrate 102.

The conductor layer in which it is easy for a current to flow in the circuit board, the semiconductor substrate, or the electronic device described above may be considered to be one of a conductor layer in which it is easy for a current to flow in the circuit board, a conductor layer in which it is easy for a current to flow in the semiconductor substrate, and a conductor layer in which it is easy for a current to flow in the electronic device. Further, the conductor layer in which it is difficult for a current to flow in the circuit board, the semiconductor substrate, or the electronic device described above may be considered to be one of a conductor layer in which it is difficult for a current to flow in the circuit board, a conductor layer in which it is difficult for a current to flow in the semiconductor substrate, and a conductor layer in which it is difficult for a current to flow in the electronic device. Further, the conductor layer in which it is easy for a current to flow can be replaced with a conductor layer having a low sheet resistance, and the conductor layer in which it is difficult for a current to flow can be replaced with a conductor layer having a high sheet resistance.

A metal such as copper, aluminum, tungsten, chromium, nickel, tantalum, molybdenum, titanium, gold, silver, or iron, or a mixture, compound, or alloy containing at least one of these may be mainly used as a material of the conductor used for the conductor layer C. Further, a semiconductor such as silicon, germanium, compound semiconductor, and organic semiconductor may be included. Further, an insulating material such as cotton, paper, polyethylene, polyvinyl chloride, natural rubber, polyester, epoxy resin, melamine resin, phenol resin, polyurethane, synthetic resin, mica, asbestos, glass fiber, or porcelain may be included. Further, the conductor layer C may be a conductor layer of the uppermost metal layer or lowermost metal layer, that is, the uppermost layer or lowermost layer, and may be a conductor layer that is used for the same type of metal bonding such as Cu—Cu bonding, Au—Au bonding, or Al—Al bonding or different types of metal bonding such as Cu—Au bonding, Cu—Al bonding, or Au—Al bonding.

A planar layout of the respective conductor layers A to C may be reversed in the X direction or may be reversed in the Y direction. Further, the planar layout may be rotated clockwise by a predetermined angle (for example, 90 degrees) or may be rotated counterclockwise by a predetermined angle (for example, −90 degrees). Further, the description has been given using the example in which all conductor periods, all conductor widths, and all gap widths are equal in some of the respective configuration examples described above, but the present technology is not limited thereto. For example, the conductor periods, the conductor widths, or the gap widths may not be equal, or the conductor periods, the conductor widths, or the gap widths may be changed depending on positions. Further, the description has been given using the example in which the conductor periods, the conductor widths, the gap widths, the wiring shapes, the wiring positions, or the numbers of wirings are substantially the same in the Vdd wiring and the Vss wiring in some of the configuration examples described above, but the present technology is not limited thereto. For example, in the Vdd wiring and the Vss wiring, the conductor periods may differ, the conductor widths may differ, the gap widths may differ, the wiring shapes may differ, the wiring positions may differ, the wiring positions may be displaced or misaligned, and the numbers of wirings may differ.

<13. Application Examples>

The technology according to the present disclosure is not limited to the description of the above-described embodiments and modification examples or application examples, and various modifications can be made. Some of the respective components in each embodiment and the modification example or application example thereof may be omitted, some or all thereof may be changed, some or all thereof may be modified, some thereof may be replaced with other components, and the other components may be added to some or all thereof. Further, some or all of the respective components in each embodiment and the modification example or application example thereof may be divided into a plurality of parts or may be separated into a plurality of parts, and functions or characteristics may differ in at least some of the plurality of divided or separated components. Further, at least some of the respective components in the above-described embodiments and the modification examples or application examples thereof may be combined for a different embodiment. Further, at least some of the respective components in the above-described embodiments and the modification examples or application examples thereof may be moved for a different embodiment. Further, a coupling element or a relay element may be added to a combination of at least some of the respective components in the above-described embodiments and the modification examples or application examples thereof, for a different embodiment. Further, a switching element or a switching function may be added to a combination of at least some of the respective components in the above-described embodiments and the modification examples or application examples thereof, for a different embodiment.

In the solid-state imaging device 100 according to the present embodiment, the conductors forming the conductor layers A and B, which can be aggressor conductor loops, are the Vdd wirings or the Vss wirings. That is, currents flow in the conductor layers A and B in opposite directions in at least a part of a region thereof, and at a certain time, when a current flows in the conductor layer A from the top to the bottom in the drawing, a current flows in the conductor layer B from the bottom to the top in the drawing. It is preferable for magnitudes of the currents to be the same. The description has been given using an example in which the conductors forming the conductor layers A and B are configured in the second semiconductor substrate, but the present technology is not limited thereto. For example, the conductors may be configured in the first semiconductor substrate, or part or all of the conductors may be formed at locations other than the second semiconductor substrate.

Signals flowing through the conductor layers A and B may be any signals other than Vdd or Vss as long as the signals are differential signals in which a direction of a current changes in a time direction. That is, a signal of which a current I changes with a time t (a minute current change in a minute time dt is dI) flows through the conductor layers A and B. Even when a DC current basically flows through the conductor layers A and B, the current I changes with the time t in a case in which there is rising of the current, a time transition of the current, falling of the current, or the like.

For example, a magnitude of the current flowing through the conductor layer A may not be the same as a magnitude of the current flowing through the conductor layer B. On the other hand, the magnitude of the current flowing through the conductor layer A may be the same as the magnitude of the current flowing through the conductor layer B (currents changing with time flow through the conductor layers A and B at a substantially the same timing). Generally, it is possible to further curb a magnitude of induced electromotive force generated in the victim conductor loop when the currents changing with time flow through the conductor layers A and B at a substantially the same timing than when the magnitude of the current flowing in the conductor layer A is not the same as the magnitude of the current flowing in the conductor layer B. On the other hand, the signals flowing through the conductor layers A and B may not be differential signals. For example, both may be Vdd wirings, Vss wirings, GND wirings, signal lines of the same type, signal lines of different types, or the like. Further, the conductors forming the conductor layers A and B may be conductors that are not connected to a power supply or a signal source. In these cases, although the effect of curbing inductive noise is reduced, other inventive effects can be obtained.

Further, a frequency signal having a predetermined frequency, such as a clock signal, may flow in the conductor layers A and B. Further, for example, an AC power supply current may flow in the conductor layers A and B. Further, for example, the same frequency signal may flow in the conductor layers A and B. Further, a signal including a plurality of frequency components may flow in the conductor layers A and B. On the other hand, a DC signal in which the current I does not change at all according to the time t may flow. In this case, an effect that the inductive noise can be curbed cannot be obtained, but other inventive effects can be obtained. On the other hand, no signal may flow. In this case, effects of inductive noise curbing, capacitive noise curbing, and voltage drop (IR-Drop) reduction cannot be obtained, but other inventive effects can be obtained.

### <14. Configuration Example of Imaging Device>

The solid-state imaging device 100 described above can be applied to, for example, a camera system such as a digital camera or a video camera, a mobile phone having an imaging function, another device having an imaging function, or an electronic device including a semiconductor device having a high-sensitivity analog element such as a flash memory.

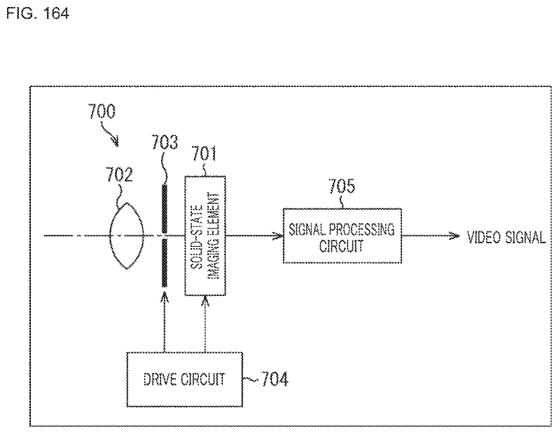

FIG. 164 is a block diagram illustrating a configuration example of an imaging device 700 as an example of the electronic device.

The imaging device 700 includes a solid-state imaging element 701, an optical system 702 that guides incident light to the solid-state imaging element 701, a shutter mechanism 703 provided between the solid-state imaging element 701 and the optical system 702, and a driving circuit 704 that drives the solid-state imaging element 701. Further, the imaging device 700 includes a signal processing circuit 705 that processes an output signal of the solid-state imaging element 701.

The solid-state imaging element 701 corresponds to the solid-state imaging device 100 described above. The optical system 702 includes, for example, an optical lens group, and causes image light (incident light) from a subject to be incident on the solid-state imaging element 701. Accordingly, signal charge is accumulated in the solid-state imaging element 701 for a certain period. The shutter mechanism 703 controls a light irradiation period and a light shielding period of the incident light with respect to the solid-state imaging element 701.

The driving circuit 704 supplies a drive signal to the solid-state imaging element 701 and the shutter mechanism 703. The driving circuit 704 controls an operation in which the solid-state imaging element 701 outputs a signal to the signal processing circuit 705 and a shutter operation of the shutter mechanism 703 according to the supplied drive signal. That is, in this example, an operation of transferring a signal from the solid-state imaging element 701 to the signal processing circuit 705 is performed by the drive signal (timing signal) supplied from the driving circuit 704.

The signal processing circuit 705 performs various signal processing on the signal transferred from the solid-state imaging element 701. The signal (video signal) subjected to various signal processing is stored in a storage medium (not illustrated) such as a memory or is output to a monitor (not illustrated).

According to the electronic device such as the imaging device 700 described above, it is possible to curb, in the solid-state imaging element 701, occurrence of noise due to leakage of light such as hot carrier light emitted from an active element such as a MOS transistor or a diode into a light reception element at the time of operation in a peripheral circuit portion. Therefore, it is possible to provide a high-quality electronic device with improved image quality.

<15. Example of Application to In-Body Information Acquisition System>

The technology according to the present disclosure (the present technology) can be applied to various products. For example, the technology according to the present disclosure may be applied to an in-body information acquisition system for patients using a capsule endoscope.

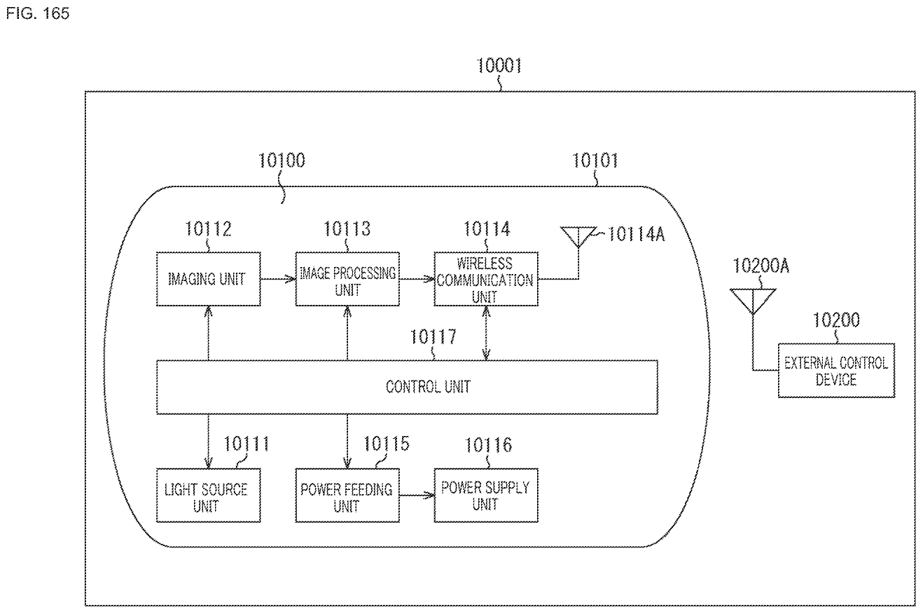

FIG. 165 is a block diagram illustrating an example of a schematic configuration of the in-body information acquisition system for patients using a capsule endoscope to which the technology according to the present disclosure can be applied.

An in-body information acquisition system 10001 includes a capsule endoscope 10100 and an external control device 10200.

The capsule endoscope 10100 is swallowed by a patient at the time of examination. The capsule endoscope 10100 has an imaging function and a wireless communication function, and sequentially captures images of the inside of an organ such as a stomach or an intestine (hereinafter also referred to as in-body images) at predetermined intervals while moving inside the organ through peristaltic movement or the like before the capsule endoscope 10100 is naturally discharged from the patient, and sequentially wirelessly transmits information on the in-body images to the external control device 10200 outside the body.

The external control device 10200 generally controls an operation of the in-body information acquisition system 10001. Further, the external control device 10200 receives the information on the in-body image transmitted from the capsule endoscope 10100, and generates image data for displaying the in-body image on a display device (not illustrated) on the basis of the received information on the in-body image.

Thus, the in-body information acquisition system 10001 can obtain the in-body images obtained by imaging a state of the in-body of the patient from time to time before the capsule endoscope 10100 is discharged after the capsule endoscope 10100 is swallowed.

A configurations and function of the capsule endoscope 10100 and the external control device 10200 will be described in more detail.

The capsule endoscope 10100 includes a capsule type casing 10101, and a light source unit 10111, an imaging unit 10112, an image processing unit 10113, a wireless communication unit 10114, a power feeding unit 10115, a power supply unit 10116, and the control unit 10117 are accommodated in the casing 10101.

The light source unit 10111 includes a light source such as a light emitting diode (LED), and irradiates an imaging visual field of the imaging unit 10112 with light.

The imaging unit 10112 includes an imaging element and an optical system including a plurality of lenses provided in front of the imaging element. Reflected light (hereinafter referred to as observation light) of light radiated to a body tissue that is an observation target is condensed by the optical system and is incident on the imaging element. In the imaging unit 10112, the imaging element photoelectrically converts the observation light incident thereon to generate an image signal corresponding to the observation light. The image signal generated by the imaging unit 10112 is provided to the image processing unit 10113.

The image processing unit 10113 includes a processor such as a central processing unit (CPU) or a graphics processing unit (GPU), and performs various signal processing on the image signal generated by the imaging unit 10112. The image processing unit 10113 provides the image signal subjected to the signal processing to the wireless communication unit 10114 as RAW data.

The wireless communication unit 10114 performs a predetermined process such as a modulation process on the image signal subjected to the signal processing by the image processing unit 10113, and transmits the resultant image signal to the external control device 10200 via an antenna 10114A. Further, the wireless communication unit 10114 receives a control signal regarding drive control of the capsule endoscope 10100 from the external control device 10200 via the antenna 10114A. The wireless communication unit 10114 provides the control signal received from the external control device 10200 to the control unit 10117.

The power feeding unit 10115 includes, for example, a power reception antenna coil, a power regeneration circuit that regenerates power from a current generated in the antenna coil and a boosting circuit. The power feeding unit 10115 generates power using a so-called non-contact charging principle.

The power supply unit 10116 includes a secondary battery and stores power generated by the power feeding unit 10115. Although, for example, an arrow indicating a supply destination of power from the power supply unit 10116 is not illustrated in FIG. 165 in order to avoid making the drawings complicated, power stored in the power supply unit 10116 is the light source unit 10111, the imaging unit 10112, the image processing unit 10113, the wireless communication unit 10114, and the control unit 10117 and can be used to drive these.

The control unit 10117 includes a processor such as a CPU, and appropriately controls driving of the light source unit 10111, the imaging unit 10112, the image processing unit 10113, the wireless communication unit 10114, and the power feeding unit 10115 according to control signals transmitted from the external control device 10200.

The external control device 10200 includes a processor such as a CPU or GPU, or a microcomputer or a control board in which a processor and a storage element such as a memory are both mounted. The external control device 10200 transmits the control signal to the control unit 10117 of the capsule endoscope 10100 via an antenna 10200A to control an operation of the capsule endoscope 10100. In the capsule endoscope 10100, for example, light irradiation conditions for the observation target in the light source unit 10111 can be changed according to the control signal from the external control device 10200. Further, imaging conditions (for example, a frame rate, an exposure value, and the like in the imaging unit 10112) can be changed according to the control signal from the external control device 10200. Further, content of processing in the image processing unit 10113 or conditions (for example, a transmission interval or the number of transmission images) in which the wireless communication unit 10114 transmits the image signal may be changed according to the control signal from the external control device 10200.

Further, the external control device 10200 performs various image processing on the image signal transmitted from the capsule endoscope 10100 and generates image data for displaying the captured in-body image on the display device. As the image processing, for example, various signal processing such as a development process (demosaic processing), a high image quality processing (for example, a band enhancement process, super-resolution processing, a noise reduction (NR) process and/or a camera shake correction process), and/or an enlargement process (electronic zoom processing) can be performed. The external control device 10200 controls driving of the display device so that the captured in-body image is displayed on the basis of the generated image data. Alternatively, the external control device 10200 may cause the generated image data to be recorded in a recording device (not illustrated) or may cause the image data to be printed and output by a printing device (not illustrated).

The example of the in-body information acquisition system to which the technology according to the present disclosure can be applied has been described above. The technology according to the present disclosure can be applied to the imaging unit 10112 in the configuration described above. Specifically, the solid-state imaging device 100 described above can be applied as the imaging unit 10112. By applying the technology according to the present disclosure to the imaging unit 10112, applying the technology according to the present disclosure to the imaging unit 10112, it is possible to curb occurrence of noise and obtain a clearer surgical part image and thus, inspection accuracy is improved.

<16. Example of Application to Endoscopic Surgery System>

The technology according to the present disclosure (the present technology) can be applied to various products. For example, the technology according to the present disclosure may be applied to an endoscopic surgery system.

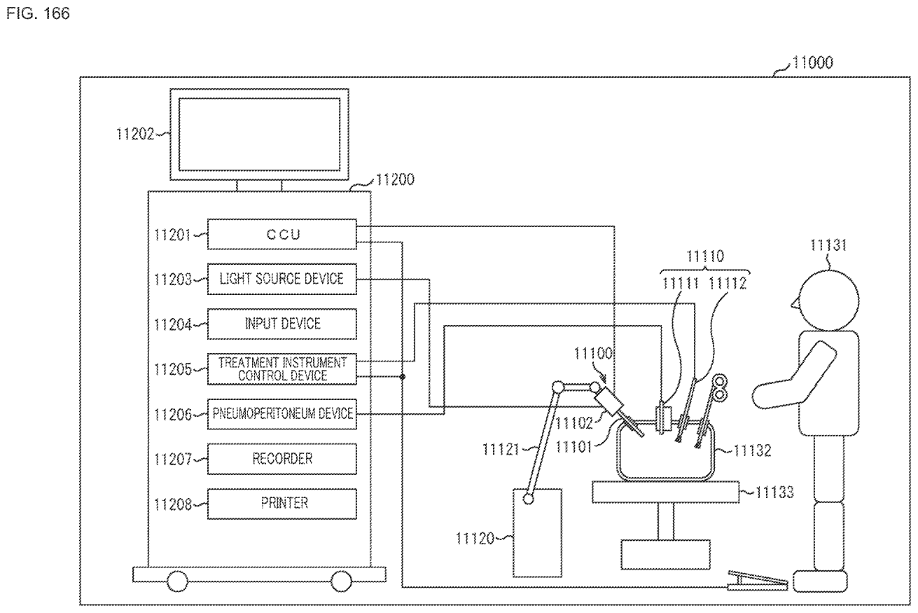

FIG. 166 is a diagram illustrating an example of a schematic configuration of an endoscopic surgery system to which the technology according to the present disclosure (the present technology) can be applied.

FIG. 166 illustrates a state in which an operator (doctor) 11131 is performing surgery on a patient 11132 on a patient bed 11133 using the endoscopic surgery system 11000. As illustrated, the endoscopic surgery system 11000 includes an endoscope 11100, another surgical tool 11110 such as a pneumoperitoneum tube 11111 or an energy treatment tool 11112, a support arm device 11120 that supports the endoscope 11100, and a cart 11200 in which various devices for endoscopic surgery are mounted.

The endoscope 11100 includes a lens barrel 11101 of which a region having a predetermined length from a distal end is inserted into a body cavity of the patient 11132, and a camera head 11102 connected to a base end of the lens barrel 11101. Although the endoscope 11100 configured as a so-called rigid mirror having the rigid lens barrel 11101 is illustrated in the illustrated example, the endoscope 11100 may be configured as a so-called flexible mirror having a flexible lens barrel.

An opening in which an objective lens is fitted is provided at a distal end of the lens barrel 11101. A light source device 11203 is connected to the endoscope 11100, and light generated by the light source device 11203 is guided to the distal end of the lens barrel by a light guide extending inside the lens barrel 11101 and is radiated toward the observation target in the body cavity of the patient 11132 via the objective lens. The endoscope 11100 may be a direct-viewing endoscope or may be a perspective endoscope or a side-viewing endoscope.

An optical system and an imaging element are provided inside the camera head 11102, and the reflected light (observation light) from the observation target is condensed on the imaging element by the optical system. The observation light is photoelectrically converted by the imaging element, and an electrical signal corresponding to the observation light, that is, an image signal corresponding to an observation image is generated. The image signal is transmitted to a CCU (Camera Control Unit) 11201 as RAW data.

The CCU 11201 includes, for example, a central processing unit (CPU) and a graphics processing unit (GPU), and generally controls operations of the endoscope 11100 and the display device 11202. Further, the CCU 11201 receives an image signal from the camera head 11102, and performs, on the image signal, various image processing such as a development process (demosaic processing) for displaying an image based on the image signal.

The display device 11202 displays the image based on the image signal subjected to the image processing by the CCU 11201 under the control of the CCU 11201.

The light source device 11203 is configured of a light source such as a light emitting diode (LED), and supplies the endoscope 11100 with irradiation light for imaging a surgical part or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of irradiation light, a magnification, a focal length, or the like) of the endoscope 11100.

A treatment instrument control device 11205 controls driving of the energy treatment tool 11112 for tissue ablation, incision, blood vessel sealing, or the like. A pneumoperitoneum device 11206 sends a gas into the body cavity of the patient 11132 through the pneumoperitoneum tube 11111 in order to inflate the body cavity of the patient 11132 for the purpose of securing a visual field and a working space of the operator using the endoscope 11100. A recorder 11207 is a device capable of recording various pieces of information regarding surgery. A printer 11208 is a device that can print various types of information on surgery in various formats such as text, images, or graphs.

The light source device 11203 that supplies the endoscope 11100 with the irradiation light for imaging the surgical part can be configured of, for example, an LED, a laser light source, or a white light source configured of a combination thereof. When a white light source is formed by a combination of RGB laser light sources, it is possible to control an output intensity and an output timing of each color (each wavelength) with high accuracy and thus, the light source device 11203 adjusts white balance of the captured image. Further, in this case, the observation target is time-divisionally irradiated with laser light from the respective RGB laser light sources, and driving of the imaging element of the camera head 11102 is controlled in synchronization with the irradiation timing, such that images corresponding to respective RGB can be captured in a time division manner. According to this method, it is possible to obtain a color image without providing a color filter to the imaging element.

Further, the driving of the light source device 11203 may be controlled to change the intensity of the output light at predetermined time intervals. It is possible to acquire images in a time-division manner by controlling the driving of the imaging element of the camera head 11102 in synchronization with a timing at which the intensity of the light is changed, and it is possible to generate a high dynamic range image without so-called blackout and whiteout by combining the images.

Further, the light source device 11203 may be configured to be able to supply light in a predetermined wavelength band corresponding to special light observation. In the special light observation, for example, a so-called narrow band light observation (narrow band imaging) in which a body tissue is irradiated with light in a narrower band than irradiation light (that is, white light) in normal observation using wavelength dependence of absorption of light in the body tissue, so that a predetermined tissue such as a blood vessel on a mucosal surface layer is imaged with high contrast is performed. Alternatively, in the special light observation, fluorescence observation in which an image is obtained using fluorescence generated by irradiation with excitation light may be performed. In the fluorescence observation, for example, the body tissue is irradiated with excitation light for observation of fluorescence from the body tissue (autofluorescence observation), or a reagent such as indocyanine green (ICG) is locally injected into the body tissue and the body tissue is irradiated with excitation light corresponding to a fluorescence wavelength of the reagent, thereby obtaining a fluorescence image. The light source device 11203 may be configured to be able to supply narrow band light and/or the excitation light corresponding to such special light observation.

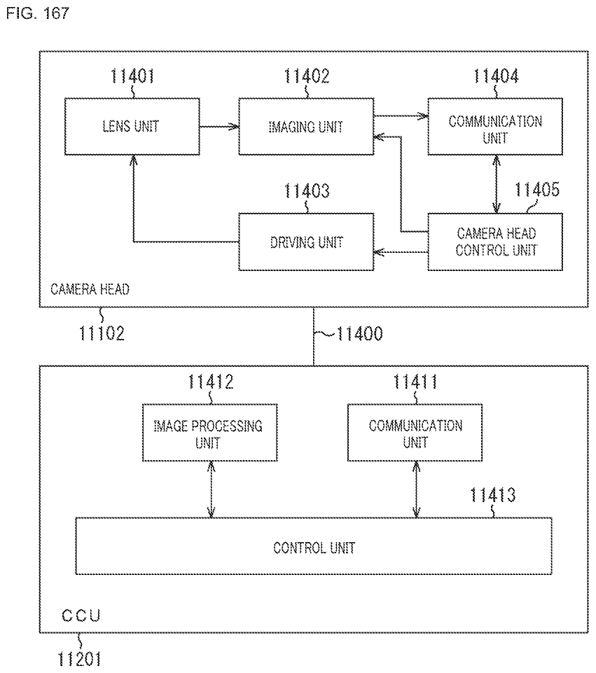

FIG. 167 is a block diagram illustrating an example of a functional configuration of the camera head 11102 and the CCU 11201 illustrated in FIG. 166.

The camera head 11102 includes a lens unit 11401, an imaging unit 11402, a driving unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other via a transmission cable 11400.

The lens unit 11401 is an optical system provided at a portion for connection to the lens barrel 11101. The observation light taken in from the distal end of the lens barrel 11101 is guided to the camera head 11102 and incident on the lens unit 11401. The lens unit 11401 is configured of a combination of a plurality of lenses including a zoom lens and a focus lens.

The imaging unit 11402 includes an imaging element. The number of imaging elements constituting the imaging unit 11402 may be one (so-called single-plate type) or plural (so-called multi-plate type). When the imaging unit 11402 is configured as a multi-plate type, image signals corresponding to R, G, and B, for example, may be generated by the respective imaging elements and may be combined to obtain a color image. Alternatively, the imaging unit 11402 may be configured to have a pair of imaging elements for respectively acquiring image signals for a right eye and a left eye corresponding to a 3D (Dimensional) display. The performed 3D display enables the operator 11131 to more accurately ascertain a depth of a living tissue in the surgical part. When the imaging unit 11402 is configured as the multi-plate type, a plurality of systems of lens units 11401 may be provided in correspondence to the respective imaging element.

Further, the imaging unit 11402 may not be provided in the camera head 11102. For example, the imaging unit 11402 may be provided immediately after the objective lens inside the lens barrel 11101.

The driving unit 11403 includes an actuator, and moves the zoom lens and the focus lens of the lens unit 11401 by a predetermined distance along an optical axis under the control of the camera head control unit 11405. Accordingly, the magnification and focus of the image captured by the imaging unit 11402 can be adjusted appropriately.

The communication unit 11404 is configured of a communication device for transmitting or receiving various pieces of information to or from the CCU 11201. The communication unit 11404 transmits the image signal obtained from the imaging unit 11402 as RAW data to the CCU 11201 via the transmission cable 11400.

The communication unit 11404 also receives a control signal for controlling the driving of the camera head 11102 from the CCU 11201 and supplies the control signal to the camera head control unit 11405. The control signal includes, for example, information on the imaging conditions such as information indicating that the frame rate of the captured image is designated, information indicating that the exposure value at the time of imaging is designated, and/or information indicating that the magnification and the focus of the captured image are designated.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, auto focus (AF) function, and auto white balance (AWB) function are mounted in the endoscope 11100.

The camera head control unit 11405 controls the driving of the camera head 11102 on the basis of the control signal from the CCU 11201 received via the communication unit 11404.

The communication unit 11411 includes a communication device for transmitting and receiving various pieces of information to and from the camera head 11102. The communication unit 11411 receives the image signal transmitted from the camera head 11102 via the transmission cable 11400.

Further, the communication unit 11411 transmits the control signal for controlling the driving of the camera head 11102 to the camera head 11102. The image signal or the control signal can be transmitted by electric communication, optical communication, or the like.

The image processing unit 11412 performs various image processing on the image signal that is the RAW data transmitted from the camera head 11102.

The control unit 11413 performs various controls regarding imaging of the surgical part or the like using the endoscope 11100 and a display of a captured image obtained by imaging the surgical part or the like. For example, the control unit 11413 generates the control signal for controlling the driving of the camera head 11102.

Further, the control unit 11413 causes the display device 11202 to display the captured image obtained by imaging the surgical part or the like on the basis of the image signal subjected to the image processing by the image processing unit 11412. In this case, the control unit 11413 may recognize various objects in the captured image using various image recognition technologies. For example, the control unit 11413 can detect a shape, color, or the like of an edge of the object included in the captured image to recognize surgical tools such as forceps, a specific living body part, bleeding, a mist at the time of use of the energy treatment tool 11112, and the like. When the control unit 11413 causes the display device 11202 to display the captured image, the control unit 11413 may cause various types of surgery support information to be superimposed and displayed on an image of the surgical part using a recognition result. By the surgery support information displayed in a superimposed manner and presented to the operator 11131, it is possible to reduce a burden on the operator 11131 and for the operator 11131 to reliably proceed with surgery.

The transmission cable 11400 that connects the camera head 11102 to the CCU 11201 is an electrical signal cable compatible with communication of an electrical signal, an optical fiber compatible with optical communication, or a composite cable thereof.

Here, although wired communication is performed using the transmission cable 11400 in the illustrated example, communication between the camera head 11102 and the CCU 11201 may be performed wirelessly.

The example of the endoscopic surgery system to which the technology according to the present disclosure can be applied has been described above. The technology according to the present disclosure can be applied to, for example, the imaging unit 11402 of the camera head 11102 in the configuration described above. Specifically, the solid-state imaging device 100 described above can be applied as the imaging unit 11402. By applying the technology according to the present disclosure to the imaging unit 11402, it is possible to curb occurrence of noise and obtain a clearer image of the surgical part and thus, the operator can reliably confirm the surgical part.

Here, although the endoscopic surgery system has been described as an example, the technology according to the present disclosure may be applied to, for example, a microscopic surgery system.

<17. Example of Application to Moving Objects>

Further, the technology according to the present disclosure may be realized as a device mounted in any type of moving objects such as an automobile, an electric vehicle, a hybrid electric vehicle, a motorcycle, a bicycle, a personal mobility, an airplane, a drone, a ship, or a robot.

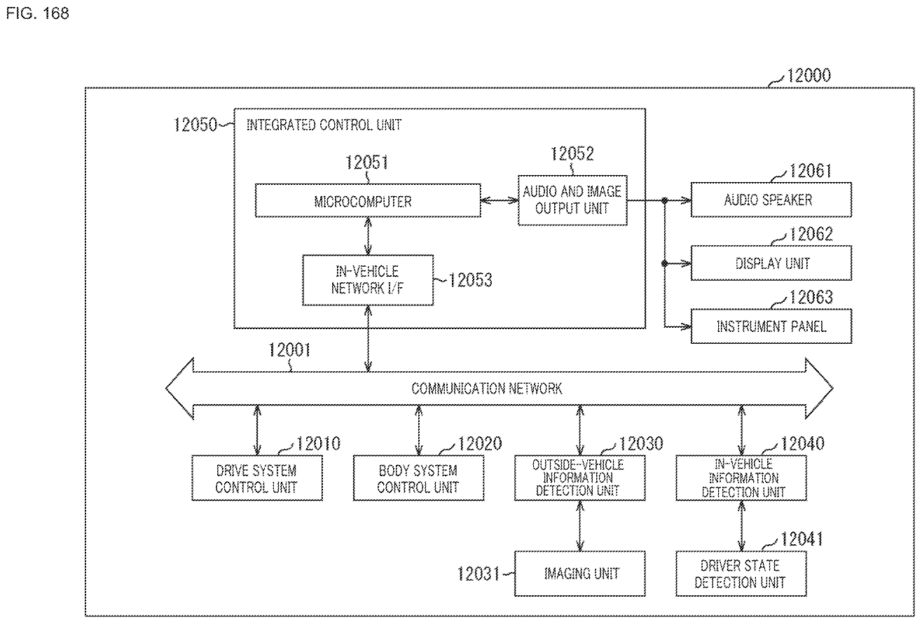

FIG. 168 is a block diagram illustrating a schematic configuration example of a vehicle control system that is an example of a moving object control system to which the technology according to the present disclosure can be applied.

The vehicle control system 12000 includes a plurality of electronic control units connected via a communication network 12001. In the example illustrated in FIG. 168, the vehicle control system 12000 includes a drive system control unit 12010, a body system control unit 12020, an outside-vehicle information detection unit 12030, an in-vehicle information detection unit 12040, and an integrated control unit 12050. Further, a microcomputer 12051, an audio and image output unit 12052, and an in-vehicle network interface (I/F) 12053 are illustrated as a functional configuration of the integrated control unit 12050.

The drive system control unit 12010 controls an operation of devices relevant to a drive system of a vehicle according to various programs. For example, the drive system control unit 12010 functions as a control device of a driving force generation device for generating a driving force of a vehicle, such as an internal combustion engine or a driving motor, a driving force transmission mechanism for transmitting the driving force to wheels, a steering mechanism for adjusting a steering angle of the vehicle, a braking device that generates a braking force of a vehicle, and the like.

The body system control unit 12020 controls an operation of various devices mounted in a vehicle body according to various programs. For example, the body system control unit 12020 functions as a control device of a keyless entry system, a smart key system, a power window device, various lamps such as a head lamp, a back lamp, a brake lamp, a blinker, or a fog lamp, or the like. In this case, radio waves or signals of various switches transmitted from a portable device with which keys are replaced may be input to the body system control unit 12020. The body system control unit 12020 receives an input of the radio waves or signals and controls a door lock device, a power window device, lamps, and the like of the vehicle.

The outside-vehicle information detection unit 12030 detects information on the outside of the vehicle in which the vehicle control system 12000 is mounted. For example, an imaging unit 12031 is connected to the outside-vehicle information detection unit 12030. The outside-vehicle information detection unit 12030 causes the imaging unit 12031 to capture an image of a vehicle exterior and receives a captured image. The outside-vehicle information detection unit 12030 may perform an object detection process or a distance detection process for people, vehicles, obstacles, signs, or characters on a road surface, or the like on the basis of the received image.

The imaging unit 12031 is an optical sensor that receives light and outputs an electrical signal according to an amount of received light. The imaging unit 12031 can output the electrical signal as an image or as distance measurement information. The light received by the imaging unit 12031 may be visible light or invisible light such as infrared rays.

The in-vehicle information detection unit 12040 detects in-vehicle information. A driver state detection unit 12041 that detects a state of the driver, for example, is connected to the in-vehicle information detection unit 12040. The driver state detection unit 12041 includes, for example, a camera that images the driver, and the in-vehicle information detection unit 12040 may calculate a degree of fatigue or a degree of concentration of the driver on the basis of the detection information input from the driver state detection unit 12041 or may determine whether or not the driver is asleep.

The microcomputer 12051 can calculate a control target value of the driving force generation device, the steering mechanism, or the braking device on the basis of the information on the inside or the outside of the vehicle acquired by the outside-vehicle information detection unit 12030 or the in-vehicle information detection unit 12040, and output a control command to the drive system control unit 12010. For example, the microcomputer 12051 can perform cooperative control aiming at realizing functions of advanced driver assistance system (ADAS) including vehicle collision avoidance or impact mitigation, follow-up traveling based on an inter-vehicle distance, vehicle speed maintenance traveling, vehicle collision warning, vehicle lane deviation warning, and the like.

Further, the microcomputer 12051 can control the driving force generation device, the steering mechanism, the braking device, or the like on the basis of the information on the vicinity of the vehicle acquired by the outside-vehicle information detection unit 12030 or the in-vehicle information detection unit 12040 to perform cooperative control aiming at, for example, autonomous driving in which the vehicle autonomously travels without depending on an operation of the driver.

Further, the microcomputer 12051 can output a control command to the body system control unit 12020 on the basis of the information on the outside of the vehicle acquired by the outside-vehicle information detection unit 12030. For example, the microcomputer 12051 can control a headlamp according to a position of a preceding vehicle or an oncoming vehicle detected by the outside-vehicle information detection unit 12030 to perform cooperative control aiming at achieving antiglare such as switching from a high beam to a low beam.

The audio and image output unit 12052 transmits an output signal of at least one of an audio and an image to an output device capable of visually or audibly notifying a passenger of the vehicle or the outside of the vehicle of information. In the example of FIG. 168, examples of the output device include an audio speaker 12061, a display unit 12062, and an instrument panel 12063. The display unit 12062 may include, for example, at least one of an onboard display and a head-up display.

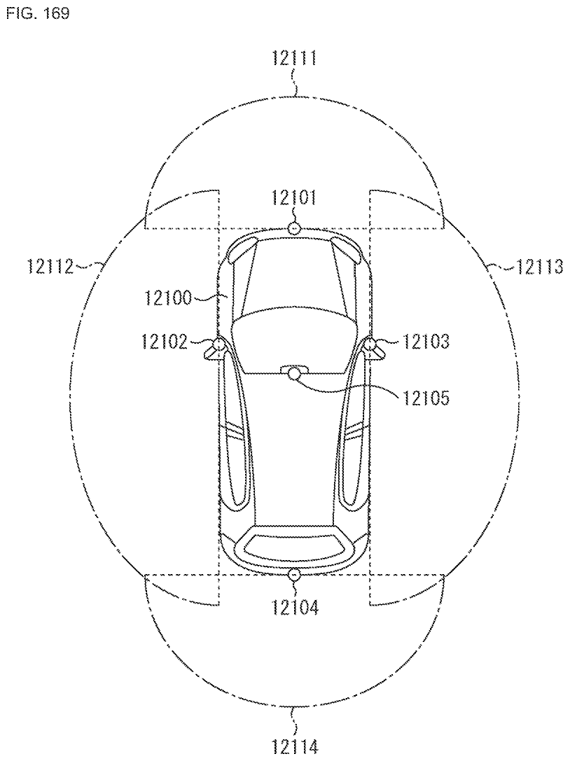

FIG. 169 is a diagram illustrating an example of an installation position of the imaging unit 12031.

In FIG. 169, a vehicle 12100 includes imaging units 12101, 12102, 12103, 12104, and 12105 as the imaging unit 12031.

The imaging units 12101, 12102, 12103, 12104, and 12105 are provided at positions such as a front nose, side mirrors, a rear bumper, a back door, and an upper portion of a windshield in a vehicle interior of the vehicle 12100. The imaging unit 12101 included in the front nose and the imaging unit 12105 included in the upper portion of the windshield in the vehicle interior mainly acquire an image of a region in front of the vehicle 12100. The imaging units 12102 and 12103 included in the side mirrors mainly acquire images of the side of the vehicle 12100. The imaging unit 12104 included in the rear bumper or the back door mainly acquires an image of a region behind the vehicle 12100. The images of the region in front acquired by the imaging units 12101 and 12105 are mainly used for detection of preceding vehicles, pedestrians, obstacles, traffic signals, traffic signs, lanes, and the like.

FIG. 169 illustrates an example of an imaging range of the imaging units 12101 to 12104. An imaging range 12111 indicates an imaging range of the imaging unit 12101 provided in the front nose, imaging ranges 12112 and 12113 indicate imaging ranges of the imaging units 12102 and 12103 provided in the respective side mirrors, and an imaging range 12114 indicates an imaging range of the imaging unit 12104 provided in the rear bumper or the back door. For example, by image data captured by the imaging units 12101 to 12104 being superimposed, a bird's-eye view image of the vehicle 12100 viewed from above can be obtained.

At least one of the imaging units 12101 to 12104 may have a function of acquiring distance information. For example, at least one of the imaging units 12101 to 12104 may be a stereo camera including a plurality of imaging elements or may be an imaging element having pixels for phase difference detection.

For example, the microcomputer 12051 can obtain a distance to each three-dimensional object in the imaging range 12111 to 12114 and a temporal change in the distance (a relative speed with respect to the vehicle 12100) on the basis of the distance information obtained from the imaging units 12101 to 12104, to thereby extract, particularly, the closest three-dimensional object on a traveling path of the vehicle 12100, which is a three-dimensional object traveling at a predetermined speed (for example, 0 km/h or more) in the substantially same direction as the vehicle 12100, as a preceding vehicle. Further, the microcomputer 12051 can set an inter-vehicle distance to be secured in front of the preceding vehicle in advance, and perform automatic brake control (including follow-up stop control), automatic acceleration control (including follow-up start control), and the like. Thus, it is possible to perform cooperative control aiming at, for example, autonomous driving in which the vehicle autonomously travels without depending on an operation of the driver.

For example, the microcomputer 12051 can classify three-dimensional object data regarding three-dimensional objects into a two-wheeled vehicle, an ordinary vehicle, a large vehicle, a pedestrian, a utility pole, and other three-dimensional objects on the basis of the distance information obtained from the imaging units 12101 to 12104, extract the objects, and use the objects for automatic avoidance of obstacles. For example, the microcomputer 12051 identifies an obstacle around the vehicle 12100 as an obstacle visible to the driver of the vehicle 12100 and an obstacle difficult to view. The microcomputer 12051 can determine a collision risk indicating a degree of risk of collision with each obstacle, and can output a warning to driver through the audio speaker 12061 or the display unit 12062 or perform forced deceleration or avoidance steering through the drive system control unit 12010 to perform driving assistance for collision avoidance when the collision risk is equal to or greater than a set value and there is a possibility of collision.

At least one of the imaging units 12101 to 12104 may be an infrared camera that detects infrared rays. For example, the microcomputer 12051 can determine whether or not a pedestrian is present in the captured images of the imaging units 12101 to 12104 to recognize the pedestrian. Such pedestrian recognition is performed, for example, according to a procedure of extracting feature points in the captured images of the imaging units 12101 to 12104 serving as infrared cameras and a procedure of performing a pattern matching process on a series of feature points indicating a contour of an object to determine whether the object is a pedestrian. When the microcomputer 12051 determines that the pedestrian is present in the captured images of the imaging units 12101 to 12104 and recognizes the pedestrian, the audio and image output unit 12052 controls the display unit 12062 so that the display unit 12062 displays the recognized pedestrian on which a rectangular contour line for highlighting is superimposed. Further, the audio and image output unit 12052 may control the display unit 12062 so that the display unit 12062 displays, for example, an icon indicating a pedestrian at a desired position.

An example of the vehicle control system to which the technology according to the present disclosure can be applied has been described above. The technology according to the present disclosure can be applied to, for example, the imaging unit 12031 in the configuration described above. Specifically, the solid-state imaging device 100 described above can be applied as the imaging unit 12031. By applying the technology according to the present disclosure to the imaging unit 12031, occurrence of noise is curbed and a captured image easier to view can be obtained and thus, appropriate assistance in driving of the driver can be realized.

The embodiment of the present technology is not limited to the above-described embodiments, and various modifications can be made without departing from the gist of the present technology.

The effects described in the present specification are merely examples and are not limited, and there may be effects other than those described in the present specification.

The present technology may also have the following configuration.

(1) A circuit board including: a first conductor layer having at least a first conductor portion including a conductor having a shape in which a first basic pattern having a planar or mesh shape is repeated on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

(2)

The circuit board according to (1), including: a fourth conductor layer including at least a part of a control line or a signal line, wherein the first to fourth conductor layers are stacked in an order of the fourth conductor layer, the first conductor layer, the second conductor layer, and the third conductor layer.

(3)

The circuit board according to (1) or 2, including: a fourth conductor layer including at least a part of a control line or a signal line, wherein the first to fourth conductor layers are stacked in an order of the fourth conductor layer, the first conductor layer, the third conductor layer, and the second conductor layer.

(4)

The circuit board according to any one of (1) to (3), including: a fourth conductor layer including at least a part of a control line or a signal line, wherein the first to fourth conductor layers are stacked in an order of the fourth conductor layer, the third conductor layer, the first conductor layer, and the second conductor layer.

(5)

The circuit board according to any one of (1) to (4), wherein a sum of conductor widths of the third basic pattern and a sum of conductor widths of the fourth basic pattern are substantially the same.

(6)

The circuit board according to any one of (1) to (5), wherein a repetition period of the first basic pattern and a repetition period of the second basic pattern are substantially the same.

(7)

The circuit board according to any one of (1) to (6), wherein a repetition period of the third basic pattern and a repetition period of the fourth basic pattern are substantially the same.

(8)

The circuit board according to any one of (1) to (7), wherein the first basic pattern, the second basic pattern, the third basic pattern, and the fourth basic pattern form a light shielding structure in at least a part of a region thereof.

(9)

The circuit board according to any one of (1) to (8), wherein the first basic pattern, the third basic pattern, and the fourth basic pattern form a light shielding structure in at least a part of a region thereof.

(10)

The circuit board according to any one of (1) to (9), wherein the second basic pattern, the third basic pattern, and the fourth basic pattern form a light shielding structure in at least a part of a region thereof.

(11)

The circuit board according to any one of (1) to (10), wherein the first basic pattern and the third basic pattern are electrically connected to each other, and the second basic pattern and the fourth basic pattern are electrically connected to each other.

(12)

The circuit board according to any one of (1) to (11), wherein the first conductor layer includes one or a plurality of first relay conductors in a gap having the mesh shape, the second basic pattern and the fourth basic pattern are electrically connected to each other via the first relay conductors, the second conductor layer includes one or a plurality of second relay conductors in gaps having a mesh shape, and the first basic pattern and the third basic pattern are electrically connected to each other via the second relay conductors.

(13)

The circuit board according to any one of (1) to (12), wherein a repetition period of the third basic pattern in at least one direction is an integral multiple of a repetition period of the first basic pattern in at least one direction.

(14)

The circuit board according to any one of (1) to (12), wherein a repetition period of the third basic pattern in at least one direction is a 1/integer of a repetition period of the first basic pattern in at least one direction.

(15)

The circuit board according to any one of (1) to (14), wherein a direction in which it is easy for a current of the first basic pattern or the second basic pattern to flow and a direction in which it is easy for a current of the third basic pattern or the fourth basic pattern to flow differ by substantially 90 degrees.

(16)

The circuit board according to any one of (1) to (15), wherein a direction in which it is easy for a current of the first basic pattern or the second basic pattern to flow and a direction in which it is easy for a current of the third basic pattern or the fourth basic pattern to flow are substantially the same.

(17)

The circuit board according to any one of (1) to (16), including: a fourth conductor layer including at least a part of a signal line, wherein, in the first basic pattern and the second basic pattern, all conductors in a direction substantially the same as a direction in which the signal line extends overlap when viewed in a stacking direction.

(18)

The circuit board according to any one of (1) to (17), wherein both a mesh pattern included at least in the first basic pattern and a mesh pattern included at least in the second basic pattern overlap in a stacking direction.

(19)

A semiconductor device including a circuit board, the circuit board including: a first conductor layer having at least a first conductor portion including a conductor having a shape in which a first basic pattern having a planar or mesh shape on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

(20)

An electronic device including a semiconductor device including a circuit board, the circuit board including: a first conductor layer having at least a first conductor portion including a conductor having a shape in which a first basic pattern having a planar or mesh shape is repeated on a single plane; a second conductor layer having at least a second conductor portion including a conductor having a shape in which a second basic pattern having a planar or mesh shape is repeated on a single plane; and a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein the first basic pattern and the second basic pattern form a differential structure, and the third basic pattern and the fourth basic pattern form a differential structure.

### REFERENCE SIGNS LIST

10 Pixel substrate

11 victim conductor loop

20 Logic substrate

21 Power supply wiring

100 Solid-state imaging device

101 First semiconductor substrate

102 Second semiconductor substrate

111 Pixel and analog processing unit

112 Digital processing unit

121 Pixel array

122 A/D conversion unit

123 Vertical scanning unit

131 Pixel

132 Signal line

133 Control line

141 Photodiode

142 Transfer transistor

143 Reset transistor

144 Amplification transistor

145 Selection transistor

151 Light shielding structure

152 Semiconductor substrate

153 Multilayer wiring layer

155 Optical member

162 Semiconductor substrate

163 Multilayer wiring layer

164 MOS transistor

165 (165A to 165C) Wiring layer

165a (165Aa, 165Ba) Main conductor portion

165b (165Ab, 165Bb) Lead conductor portion

167 Active element group

170 Wiring layer

171 Active element layer

191 Buffer region

192 Interlayer distance

193 Buffer region width

194 Light shielding target region

202 to 204 Circuit block

205 to 208 Light shielding target region

209 Non-light shielding target region

211, 212 Straight conductor

213, 214 Planar conductor

216, 217 Mesh conductor

221 Planar conductor

222 Mesh conductor

231, 232 Mesh conductor

241, 242 Mesh conductor

251, 252 Mesh conductor

261 Planar conductor

262 Mesh conductor

271, 272 Mesh conductor

281, 282 Mesh conductor

291, 292 Mesh conductor

301 to 306 Relay conductor

311,312 Mesh conductor

321, 322 Mesh conductor

331, 332 Mesh conductor

400 Wiring region

401, 402 Pad

501, 502 Wiring

601 to 603 Package

604 Bonding wire

700 Imaging device

701 Solid-state imaging element

702 Optical system

703 Shutter mechanism

704 Driving circuit

705 Signal processing circuit

811, 812 Mesh conductor

821Aa, 821Ab Mesh conductor

822Ab, 822Ba, 822Bb Mesh conductor

831Aa, 831Ab Mesh conductor

832Ba, 832Bb Mesh conductor

841, 842 Relay conductor

851Aa, 851Ab Mesh conductor

852Ba, 852Bb Mesh conductor

853, 854 Reinforcing conductor

855 Relay conductor

856,857 Reinforcing conductor

871,872 Reinforcing conductor

1000 Substrate

1001 (1001d, 1001s) Pad

1101 Victim conductor loop

1102A, 1102B Aggressor conductor loop

1121 Semiconductor substrate

1122 Package substrate

1123 Printed circuit board

1151 (1151A, 1151B) Conductive shield

1201, 1202 Mesh conductor

1221A, 1221B Straight conductor

1222A, 1222B Straight conductor

1241, 1242 Relay conductor

1251A, 1251B Straight conductor

1261, 1262 Mesh conductor

1281, 1282 Reinforcing conductor

1291A, 1291B Straight conductor

1301A, 1301B Straight conductor

1311, 1312 Mesh conductor

1. A circuit board comprising:
a first conductor layer having at least a first conductor portion including a conductor having a shape in which a first basic pattern having a planar or mesh shape is repeated on a single plane;
a second conductor layer having at least a second conductor portion including a conductor having a shape in which a second basic pattern having a planar or mesh shape is repeated on a single plane; and
a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein
the first basic pattern and the second basic pattern form a differential structure, and the third basic pattern and the fourth basic pattern form a differential structure.

2. The circuit board according to claim 1, comprising:
a fourth conductor layer including at least a part of a control line or a signal line, wherein the first to fourth conductor layers are stacked in an order of the fourth conductor layer, the first conductor layer, the second conductor layer, and the third conductor layer.

3. The circuit board according to claim 1, comprising:
a fourth conductor layer including at least a part of a control line or a signal line, wherein
the first to fourth conductor layers are stacked in an order of the fourth conductor layer, the first conductor layer, the third conductor layer, and the second conductor layer.

4. The circuit board according to claim 1, comprising:
a fourth conductor layer including at least a part of a control line or a signal line, wherein the first to fourth conductor layers are stacked in an order of the fourth conductor layer, the third conductor layer, the first conductor layer, and the second conductor layer.

5. The circuit board according to claim 1, wherein a sum of conductor widths of the third basic pattern and a sum of conductor widths of the fourth basic pattern are substantially equal to each other.

6. The circuit board according to claim 1, wherein a repetition period of the first basic pattern and a repetition period of the second basic pattern are substantially equivalent to each other.

7. The circuit board according to claim 1, wherein a repetition period of the third basic pattern and a repetition period of the fourth basic pattern are substantially equivalent to each other.

8. The circuit board according to claim 1, wherein the first basic pattern, the second basic pattern, the third basic pattern, and the fourth basic pattern form a light shielding structure in at least a part of a region thereof.

9. The circuit board according to claim 1, wherein the first basic pattern, the third basic pattern, and the fourth basic pattern form a light shielding structure in at least a part of a region thereof.

10. The circuit board according to claim 1, wherein the second basic pattern, the third basic pattern, and the fourth basic pattern form a light shielding structure in at least a part of a region thereof.

11. The circuit board according to claim 1, wherein the first basic pattern and the third basic pattern are electrically connected to each other, and the second basic pattern and the fourth basic pattern are electrically connected to each other.

12. The circuit board according to claim 1,
wherein the first conductor layer includes one or a plurality of first relay conductors in gaps having a mesh shape,
the second basic pattern and the fourth basic pattern are electrically connected to each other via the first relay conductors,
the second conductor layer includes one or a plurality of second relay conductors in gaps having a mesh shape, and
the first basic pattern and the third basic pattern are electrically connected to each other via the second relay conductors.

13. The circuit board according to claim 1, wherein a repetition period of the third basic pattern in at least one direction is an integral multiple of a repetition period of the first basic pattern in at least one direction.

14. The circuit board according to claim 1, wherein a repetition period of the third basic pattern in at least one direction is a 1/integer of a repetition period of the first basic pattern in at least one direction.

15. The circuit board according to claim 1, wherein a direction in which a current of the first basic pattern or the second basic pattern tends to flow and a direction in which a current of the third basic pattern or the fourth basic pattern tends to flow differ by substantially 90 degrees.

16. The circuit board according to claim 1, wherein a direction in which a current of the first basic pattern or the second basic pattern tends to flow and a direction in which a current of the third basic pattern or the fourth basic pattern tends to flow are substantially identical to each other.

17. The circuit board according to claim 1, comprising:
a fourth conductor layer including at least a part of a signal line, wherein, in the first basic pattern and the second basic pattern, all conductors in a direction substantially identical to a direction in which the signal line extends overlap when viewed in a stacking direction.

18. The circuit board according to claim 1, wherein both a mesh pattern included at least in the first basic pattern and a mesh pattern included at least in the second basic pattern overlap in a stacking direction.

19. A semiconductor device comprising a circuit board, the circuit board including:
a first conductor layer having at least a first conductor portion including a conductor having a shape in which a first basic pattern having a planar or mesh shape is repeated on a single plane;
a second conductor layer having at least a second conductor portion including a conductor having a shape in which a second basic pattern having a planar or mesh shape is repeated on a single plane; and
a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein
the first basic pattern and the second basic pattern form a differential structure, and the third basic pattern and the fourth basic pattern form a differential structure.

20. An electronic device comprising a semiconductor device including a circuit board, the circuit board including;
a first conductor layer having at least a first conductor portion including a conductor having a shape in which a first basic pattern having a planar or mesh shape is repeated on a single plane;
a second conductor layer having at least a second conductor portion including a conductor having a shape in which a second basic pattern having a planar or mesh shape is repeated on a single plane; and
a third conductor layer having at least a third conductor portion including a conductor having a shape in which a third basic pattern having a straight shape is repeated on a single plane and a fourth conductor portion including a conductor having a shape in which a fourth basic pattern having a straight shape is repeated on a single plane, wherein
the first basic pattern and the second basic pattern form a differential structure, and the third basic pattern and the fourth basic pattern form a differential structure.
